(19) United States
(12) Patent Application Publication
(10) Pub. No.: US 2025/0107436 A1
(43) Pub. Date: Mar. 27, 2025

(54) ORGANIC ELECTRIC ELEMENT COMPRISING COMPOUND FOR ORGANIC ELECTRIC ELEMENT AND AN ELECTRONIC DEVICE THEREOF

(71) Applicant: DUK SAN NEOLUX CO., LTD., Cheonan-si (KR)

(72) Inventors: Soung Yun MUN, Cheonan-si (KR); Hyung Dong LEE, Cheonan-si (KR); Jong Gwang PARK, Cheonan-si (KR); Sun Hee LEE, Cheonan-si (KR); Chi Hyun PARK, Cheonan-si (KR)

(73) Assignee: DUK SAN NEOLUX CO., LTD., Cheonan-si (KR)

(21) Appl. No.: 18/946,116

(22) Filed: Nov. 13, 2024

Related U.S. Application Data
(63) Continuation of application No. 18/709,369, filed on Jan. 1, 0001.

(30) Foreign Application Priority Data
Nov. 12, 2021 (KR) 10-2021-0155740

(51) Int. Cl. H10K 85/60; H10K 50/11; H10K 50/15; H10K 50/16

(52) U.S. Cl. CPC H10K 85/636; H10K 85/615; H10K 85/633; H10K 85/654; H10K 50/11; H10K 50/15; H10K 50/16; H10K 85/626; H10K 85/6572; H10K 85/6574; H10K 85/6576

(57) ABSTRACT

Provides are an organic electric element and an electronic device thereof including at least one of the compounds represented by Formula 1 and Formula 2 in the light-emitting auxiliary layer, and at least one of the compounds represented by Formula 3 and Formula 4 in the light-emitting layer, wherein the driving voltage of the organic electric element can be lowered and the efficiency and lifespan thereof can be improved by the compounds included in the light-emitting auxiliary layer and the light-emitting layer.

### TECHNICAL FIELD

The present invention relates to organic electric element using organic compound for organic electric element and electronic device thereof.

### BACKGROUND ART

Materials used as an organic material layer in an organic electric element may be classified into a light emitting material and a charge transport material, for example, a hole injection material, a hole transport material, an electron transport material, an electron injection material, and the like according to its function. Further, the light emitting material may be divided into a high molecular weight type and a low molecular weight type according to its molecular weight and may also be divided into a fluorescent material derived from excited singlet states of electron and a phosphorescent material derived from excited triplet states of electron according to its light emitting mechanism. Further, the light emitting material may be divided into blue, green, and red light emitting material and yellow and orange light emitting material required for better natural color reproduction according to its light emitting color.

When only one material is used as a light emitting material, the maximum emission wavelength shifts to a longer wavelength due to intermolecular interactions, as a result, there occur problems of deterioration in color purity or decrease in the efficiency of an element due to an emission attenuation effect. Therefore, a host/dopant system may be used as the light emitting material in order to enhance the color purity and increase the luminous efficiency through energy transfer. This is based on the principle that if a small amount of dopant having a smaller energy band gap than a host forming a light emitting layer is mixed in the light emitting layer, then excitons generated in the light emitting layer are transported to the dopant, thus emitting light with high efficiency. With regard to this, since the wavelength of the host is shifted to the wavelength band of the dopant, light having a desired wavelength can be obtained according to the type of the dopant.

Currently, power consumption is required more than more as size of display becomes larger and larger in the portable display market. Therefore, the power consumption is very important factor in the portable display with a limited power source of the battery, and efficiency and life span issues are also solved.

Efficiency, life span, driving voltage, and the like are correlated with each other. If the efficiency is increased, then driving voltage is relatively lowered, and the crystallization of an organic material due to Joule heating generated during operation is reduced as driving voltage is lowered, as a result of which life span shows a tendency to increase. However, efficiency cannot be maximized only by simply improving the organic material layer. This is because long life span and high efficiency can be simultaneously achieved when energy levels and T₁ values among the respective layers included in the organic material layer, inherent material properties (mobility, interfacial properties, etc.) and the like are optimal combination.

Therefore, there is a need to develop an emitting material that has high thermal stability and can achieve efficient charge balance in a light-emitting layer. In other words, in order to fully demonstrate the excellent characteristics of organic electric element, the materials forming an organic material layer of the element, such as a hole injection material, a hole transport material, a light-emitting material, an electron transport material and an electron injection material, must be supported by stable and efficient materials.

### DETAILED DESCRIPTION OF THE INVENTION

### Technical Challenge

An objection of the present invention is to provide organic electric element comprising the compound capable of lowering a driving voltage and improving luminous efficiency and lifetime of the element, and electronic device thereof.

### Means of Solving Problems

In an aspect of the present invention, the present invention provides an organic electric element including a light-emitting auxiliary layer containing a compound represented by Formula 1 or Formula 2 below, and a light-emitting layer containing a compound represented by Formula 3 or Formula 4 below.

<Formula 1> <Formula 2>

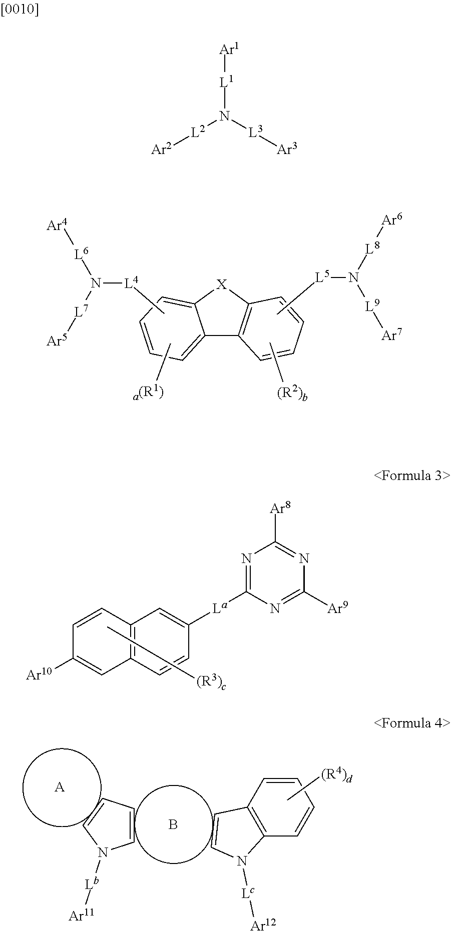

In another aspect of the present invention, the present invention provides an electronic device including the organic electric element.

### Effect of Invention

By including a compound represented by Formula 1 or Formula 2 of the present invention in a light-emitting auxiliary layer and by including a compound represented by Formula 3 or Formula 4 of the present invention in a light-emitting layer, the driving voltage of the element can be lowered and the luminous efficiency and lifespan of the element can be improved.

### BRIEF DESCRIPTION OF THE DRAWINGS

FIGS. 1 to 3 illustrate an example of organic electroluminescent element according to the present invention.

### DESCRIPTION OF REFERENCE NUMERALS

100, 200, 300: organic electric element 110: first electrode
120: hole injection layer
130: hole transport layer
140: light-emitting layer
160: electron injection layer
150: electron transport layer
170: second electrode
180: layer for improving light efficiency
210: buffer layer
220: light-emitting auxiliary layer
330: first hole transport layer
350: first electron transport layer
320: first hole injection layer
340: first light-emitting layer
360: first charge generation layer
361: second charge generation layer
420: second hole injection layer
430: second hole transport layer
440: second light-emitting layer
450: second electron transport layer
CGL: charge generation layer
ST1: first stack ST2: second stack

### DETAILED DESCRIPTION

Unless otherwise stated, the term “aryl group” or “arylene group” as used herein has, but not limited to, 6 to 60 carbon atoms. The aryl group or arylene group in the present invention may comprise a monocyclic ring, ring assemblies, a fused polycyclic system, a spiro compound and the like.

As used herein, the term “fluorenyl group” refers to a substituted or unsubstituted fluorenyl group, and “fluorenylene group” refers to a substituted or unsubstituted fluorenylene group. The fluorenyl group or fluorenylene group used in the present invention comprises a spiro compound formed by combining R and R′ with each other in the following structure, and also comprises compound formed by combining adjacent R's to each other. “Substituted fluorenyl group”, “substituted fluorenylene group” means that at least one of R, R′, R″ in the following structure is a substituent other than hydrogen, and R″ may be 1 to 8 in the following formula. In this specification, a fluorene group and a fluoreneylene group may be referred to as a fluorene group or fluorene regardless of the valence.

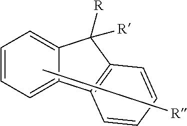

The term “spiro compound” as used herein has a spiro union which means union having one atom as the only common member of two rings. At this time, the atom shared between the two rings is called a ‘spiro atom’. The compounds are called ‘monospiro-’, ‘dispiro-’ or ‘trispiro-’ compound, respectively, depending on the number of spiro atoms in one compound.

The term “heterocyclic group” used in the specification comprises a non-aromatic ring as well as an aromatic ring like “heteroaryl group” or “heteroarylene group”. Unless otherwise stated, the term “heterocyclic group” means, but not limited to, a ring containing one or more heteroatoms and having 2 to 60 carbon atoms. Unless otherwise stated, the term “heteroatom” as used herein represents, for example, N, O, S, P or Si and may comprise a heteroatom group such as SO₂, P═O etc. instead of carbon forming a ring such as the following compound. In the specification, “heterocyclic group” comprises a monocyclic, ring assemblies, a fused polycyclic system, a spiro-compound and the like.

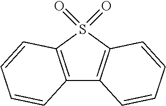 [SMILES: O=S1(=O)c2ccccc2-c2ccccc21]

The term “aliphatic ring group” as used herein refers to a cyclic hydrocarbon except for aromatic hydrocarbons, and comprises a monocyclic ring, ring assemblies, a fused polycyclic system, a spiro-compound and the like, and unless otherwise specified, it means a ring of 3 to 60 carbon atoms, but not limited thereto. For example, a fused ring of benzene being an aromatic ring and cyclohexane being a non-aromatic ring corresponds to aliphatic ring group.

In this specification, a ‘group name’ corresponding to an aryl group, an arylene group, a heterocyclic group, and the like exemplified for each symbol and its substituent may be written in the name of functional group reflecting the valence, and may also be described as the name of a parent compound. For example, in the case of phenanthrene which is a kind of aryl group, it may be described by distinguishing valence such as ‘phenanthryl (group)’ when it is ‘monovalent group’, and ‘phenanthrylene (group)’ when it is ‘divalent group’, and it may also be described as a parent compound name, ‘phenanthrene’, regardless of its valence. Similarly, in the case of pyrimidine, it may be described as ‘pyrimidine’ regardless of its valence, and it may also be described as the name of corresponding functional group such as pyrimidinyl (group) when it is ‘monovalent group’, and ‘pyrimidylene (group)’ when it is ‘divalent group’.

In addition, in the present specification, the numbers and alphabets indicating a position may be omitted when describing a compound name or a substituent name. For example, pyrido[4,3-d]pyrimidine, benzofuro[2,3-d]pyrimidine and 9,9-dimethyl-9H-fluorene can be described as pyridopyrimidine, benzofuropyrimidine and dimethylfluorene, respectively. Therefore, both benzo[g]quinoxaline and benzo[f]quinoxaline can be described as benzoquinoxaline.

In addition, unless otherwise expressed, where any formula of the present invention is represented by the following formula, the substituent according to the index may be defined as follows.

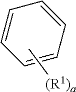

In the above formula, where a is an integer of zero, the substituent R¹ is absent, that is, hydrogen atoms are bonded to all the carbon constituting the benzene ring. Here, chemical formulas or compounds may be written without indicating the hydrogen bonded to carbon. In addition, one substituent R¹ is bonded to any carbon of the carbons forming the benzene ring when “a” is an integer of 1. Similarly, where “a” is an integer of 2 or 3, substituents R¹s may be bonded to the carbon of the benzene ring, for example, as followings. Also, where “a” is an integer of 4 to 6, substituents R¹s are bonded to the carbon of the benzene ring in a similar manner. Further, where “a” is an integer of 2 or more, R¹s may be the same or different from each other.

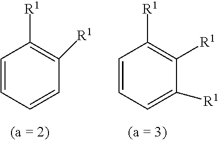

In addition, unless otherwise specified in the specification, the term ‘ring’ refers to an aryl ring, heteroaryl ring, fluorene ring, aliphatic ring, etc.

Additionally, a number-ring may refer to a condensed ring, and a number-membered ring may refer to the form of a single ring. For example, naphthalene corresponds to a two-fused (condensed) ring, anthracene to a three-fused (condensed) ring, thiophene or furan corresponds to a five-membered ring, and benzene or pyridine corresponds to a six-membered ring.

In addition, unless otherwise specified in the present specification, when adjacent groups are linked to each other to form a ring, the ring may be selected from the group consisting of a C₆-C₆₀ aromatic ring group, a fluorenyl group, a C₂-C₆₀ heterocyclic group containing at least one heteroatom selected from the group consisting of O, N, S, Si and P, and a C₃-C₆₀ aliphatic ring. Here, the aromatic ring group may include an aryl ring, and the heterocyclic group may include a heteroaryl ring.

Unless otherwise stated, the term “between adjacent groups”, for example, in case of the following Formulas, comprises not only “between R₁ and R₂”, “between R₂ and R₃”, “between R₃ and R₄”, “between R₅ and R₆”, but also “between R₇ and R₈” sharing one carbon, and may comprise “between substituents” attached to atom (carbon or nitrogen) consisting different ring, such as “between R₁ and R₇”, “between R₁ and R₈”, or “between R₄ and R₅” and the like. That is, where there are substituents bonded to adjacent elements constituting the same ring, the substituents may be correspond “adjacent groups”, and even if there are no adjacent substituents on the same ring, substituents attached to the adjacent ring may correspond to “adjacent groups”. In the following Formula, when the substituents bonded to the same carbon, such as R₇ and R₈, are linked to each other to form a ring, a compound containing a spiro-moiety may be formed.

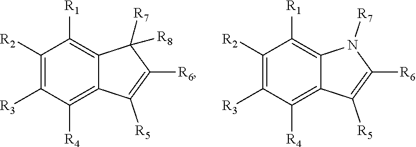

In addition, in the present specification, the expression ‘adjacent groups may be linked to each other to form a ring’ is used in the same sense as ‘adjacent groups are linked selectively to each other to form a ring’, and a case where at least one pair of adjacent groups may be bonded to each other to form a ring.

In addition, unless otherwise specified in the present specification, an aryl group, an arylene group, a fluorenyl group, a fluorenylene group, a heterocyclic group, an aliphatic ring group, an alkyl group, an alkenyl group, an alkynyl group, an alkoxyl group, an aryloxyl group, and a ring formed by adjacent groups may be each optionally substituted with one or more substituents selected from the group consisting of deuterium, halogen, an amino group unsubstituted or substituted with a C₁-C₂₀ alkyl group or a C₆-C₂₀ aryl group, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si and P, and a C₃-C₂₀ aliphatic ring group.

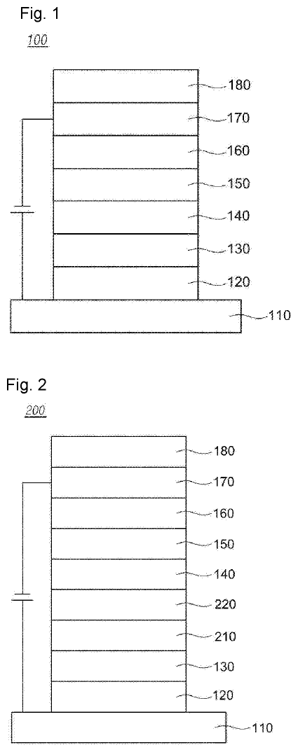

Hereinafter, referring to FIGS. 1 to 3, a lamination structure of an organic electric element including the compound of the present invention will be described.

In designation of reference numerals to components in respective drawings, it should be noted that the same elements will be designated by the same reference numerals although they are shown in different drawings. In addition, in the following description of the present invention, a detailed description of known functions and configurations incorporated herein will be omitted when it may make the subject matter of the present invention rather unclear.

Terms, such as first, second, A, B, (a), (b) or the like may be used herein when describing components of the present invention. Each of these terminologies is not used for defining an essence, order or sequence of a corresponding component but used merely to distinguish the corresponding component from other component(s). It will be understood that the expression ‘one component is “connected,” “coupled” or “joined” to another component’ comprises the case where a third component may be “connected,” “coupled” or “joined” between a first component and a second component as well as the case where the first component may be directly connected, coupled or joined to the second component.

In addition, it will be understood that when an element such as a layer, film, region or substrate is referred to as being “on” or “over” another element, it can be directly on the other element or intervening elements may also be present. In contrast, when an element is referred to as being “directly on” another element, there are no intervening elements present.

FIGS. 1 to 3 show an example of an organic electric element according to an embodiment of the present invention, respectively.

Referring to the FIG. 1, an organic electric element 100 according to an embodiment of the present invention includes a first electrode 110 formed on a substrate (not shown), a second electrode 170, and an organic material layer between the first electrode 110 and the second electrode 170.

The first electrode 110 may be an anode (positive electrode), and the second electrode 170 may be a cathode (negative electrode). In the case of an inverted organic electric element, the first electrode may be a cathode, and the second electrode may be an anode.

The organic material layer may be comprised a hole injection layer 120, a hole transport layer 130, a light emitting layer 140, an electron transport layer 150, and an electron injection layer 160. Specifically, a hole injection layer 120, a hole transport layer 130, a light-emitting layer 140, an electron transport layer 150, and an electron injection layer 160 may be formed on the first electrode 110 in sequence.

Preferably, a layer for improving the luminous efficiency 180 may be formed one side of sides of the first electrode 110 and the second electrode 170, wherein one side is not facing the organic material layer, as a result the luminous efficiency of an organic electric element can be improved.

For example, the light efficiency improving layer 180 may be formed on the second electrode 170, as a result, in the case of a top emission organic light emitting element, the optical energy loss due to Surface Plasmon Polaritons (SPPs) at the second electrode 170 may be reduced and in the case of a bottom emission organic light emitting element, the light efficiency improving layer 180 may serve as a buffer for the second electrode 170.

A buffer layer 210 or a light-emitting auxiliary layer 220 may be further formed between the hole transport layer 130 and the light emitting layer 140, which will be described with reference to FIG. 2.

Referring to FIG. 2, the organic electric element 200 according to another embodiment of the present invention may comprise a hole injection layer 120, a hole transport layer 130, a buffer layer 210, a light-emitting auxiliary layer 220, a light emitting layer 140, the electron transport layer 150, the electron injection layer 160, and a second electrode 170 formed on a first electrode 110 in sequence, and a layer for improving light efficiency 180 may be formed on the second electrode.

Although not shown in FIG. 2, an electron transport auxiliary layer may be further formed between the light emitting layer 140 and the electron transport layer 150.

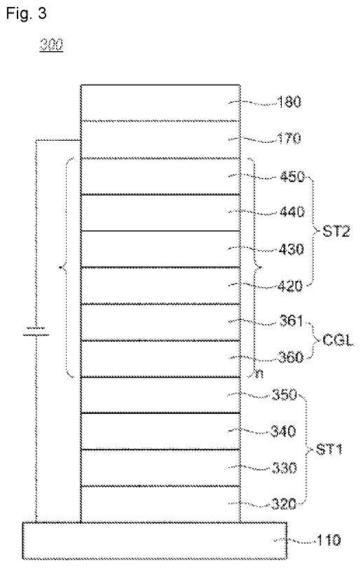

In addition, according to another embodiment of the present invention, the organic material layer may be a form consisting of multiple stacks, wherein the stacks comprise a hole transport layer, a light emitting layer, and an electron transport layer, respectively. This will be described with reference to FIG. 3.

Referring to FIG. 3, two or more sets of stacks of the organic material layers ST1 and ST2 may be formed between the first electrode 110 and the second electrode 170 in the organic electric element 300 according to another embodiment of the present invention, wherein the organic material layers are consisted of multiple layers, respectively, and the charge generation layer CGL may be formed between the stacks of the organic material layer.

Specifically, the organic electric element according to the embodiment of the present invention may comprise a first electrode 110, a first stack ST1, a charge generation layer CGL, a second stack ST2, and a second electrode 170 and a layer for improving light efficiency 180.

The first stack ST1 is an organic layer formed on the first electrode 110, and the first stack ST1 may comprise the first hole injection layer 320, the first hole transport layer 330, the first light emitting layer 340 and the first electron transport layer 350 and the second stack ST2 may comprise a second hole injection layer 420, a second hole transport layer 430, a second light emitting layer 440 and a second electron transport layer 450. As such, the first stack and the second stack may be the organic layers having the same or different stacked structures.

The charge generation layer CGL may be formed between the first stack ST1 and the second stack ST2. The charge generation layer CGL may comprise a first charge generation layer 360 and a second charge generation layer 361. The charge generating layer CGL is formed between the first light emitting layer 340 and the second light emitting layer 440 to increase the current efficiency generated in each light emitting layer and to smoothly distribute charges.

The first light emitting layer 340 may comprise a light emitting material comprising a blue host doped with a blue fluorescent dopant and the second light emitting layer 440 may comprise a light emitting material comprising a green host doped with a greenish yellow dopant and a red dopant together, but the material of the first light emitting layer 340 and the second light emitting layer 440 according to an embodiment of the present invention is not limited thereto.

In FIG. 3, n may be an integer of 1 to 5 and the charge generation layer CGL and the third stack may be further stacked on the second stack ST2 when n is 2.

When multiple light emitting layers are formed in a multi-layer stack structure as shown in FIG. 3, it is possible to manufacture an organic electroluminescent element that emits not only white light but also various colors, wherein the white light is emitted by the mixing effect of light emitted from each light emitting layer.

Compound(s) represented by Formula 1 to Formula 4 of the present invention may be included in an organic layer. For example, the compounds represented by Formulas 1 to 4 of the present invention can be used as a material for a hole injection layer 120, 320, 420, a hole transport layer 130, 330, 430, a buffer layer 210, a light-emitting auxiliary layer 220, and an electron transport layer 150, 350, 450, an electron injection layer 160, a light-emitting layer 140, 340, 440, or a layer for improving light efficiency 180, and preferably, the compound represented by Formula 1 or Formula 2 may be used as a material for a light-emitting auxiliary layer 220, and the compound represented by Formula 3 or Formula 4 may be used as a material for the light-emitting layers 140, 340, and 440.

Even if the cores of compounds are identical or similar to each other, the band gap, the electrical characteristics, the interface characteristics and the like may be different depending on which substituent is bonded at which position. Therefore, it is necessary to study the selection of the core and the combination with sub-substituent bonded to the core. In particular, long life span and high efficiency can be simultaneously achieved when the optimal combination of energy levels and T₁ values, inherent material properties (mobility, interfacial properties, etc.), and the like among the respective layers of an organic material layer is achieved.

Therefore, the energy level and T₁ value between the respective layers of the organic material layer, inherent material properties (mobility, interfacial properties, etc.) and the like can be optimized by using the compound represented by Formula 1 or Formula 2 may as a material for a light-emitting auxiliary layer 220, and the compound represented by Formula 3 or Formula 4 as a material for the light-emitting layers 140, 340, and 440.

The organic electric element according to an embodiment of the present invention may be manufactured using various deposition methods. The organic electric element according to an embodiment of the present invention may be manufactured using a PVD (physical vapor deposition) method or CVD (chemical vapor deposition) method. For example, the organic electric element may be manufactured by depositing a metal, a conductive metal oxide, or a mixture thereof on the substrate to form the anode 110, forming the organic material layer comprising the hole injection layer 120, the hole transport layer 130, the light emitting layer 140, the electron transport layer 150, and the electron injection layer 160 thereon, and then depositing a material, which can be used as the cathode 170, thereon. Also, a light-emitting auxiliary layer 220 may be formed between a hole transport layer 130 and a light emitting layer 140, and an electron transport auxiliary layer (not shown) may be further formed between a light emitting layer 140 and an electron transport layer 150 and, as described above, a stack structure may be formed.

Also, the organic material layer may be manufactured in such a manner that the fewer layers are formed using various polymer materials by a soluble process or solvent process, for example, spin coating, nozzle printing, inkjet printing, slot coating, dip coating, roll-to-roll, doctor blading, screen printing, or thermal transfer, instead of deposition. Since the organic material layer according to the present invention may be formed in various ways, the scope of protection of the present invention is not limited by a method of forming the organic material layer.

The organic electric element according to an embodiment of the present invention may be of a top emission type, a bottom emission type, or a dual emission type depending on the material used.

In addition, the organic electric element according to an embodiment of the present invention may be selected from the group consisting of an organic electroluminescent element, an organic solar cell, an organic photo conductor, an organic transistor, an element for monochromatic illumination and an element for a quantum dot display.

Another embodiment of the present invention provides an electronic device including a display device which includes the above described organic electric element, and a control unit for controlling the display device. Here, the electronic device may be a wired/wireless communication terminal which is currently used or will be used in the future, and covers all kinds of electronic devices including a mobile communication terminal such as a cellular phone, a navigation unit, a game player, various kinds of TVs, and various kinds of computers.

Hereinafter, an organic electric element according to one aspect of the present invention will be described.

In one aspect of the present invention, there is provided an organic electric element including a first electrode, a second electrode, and an organic material layer formed between the first electrode and the second electrode. The organic material layer includes a light-emitting layer, a hole transport layer formed between the first electrode and the light-emitting layer, and a light-emitting auxiliary layer formed between the hole transport layer and the light-emitting layer, wherein the light-emitting auxiliary layer includes compound represented by the following Formula 1 or Formula 2 and the light-emitting layer includes compound represented by the following Formula 3 or Formula 4.

The light-emitting auxiliary layer may include at least two of compounds represented by Formula 1 or Formula 2 below. In addition, the light-emitting auxiliary layer includes a first light-emitting auxiliary layer adjacent to the hole transport layer and a second light-emitting auxiliary layer adjacent to the light-emitting layer, and the first light-emitting auxiliary layer and the second light-emitting auxiliary layer may each comprise the following compound represented by Formula 1 or Formula 2.

In addition, the light-emitting layer may include at least two of compounds represented by Formula 3 or Formula 4 below, wherein the compound represented by Formula 3 and the compound represented by Formula 4 may be mixed at a weight ratio of 1:9 to 9:1.

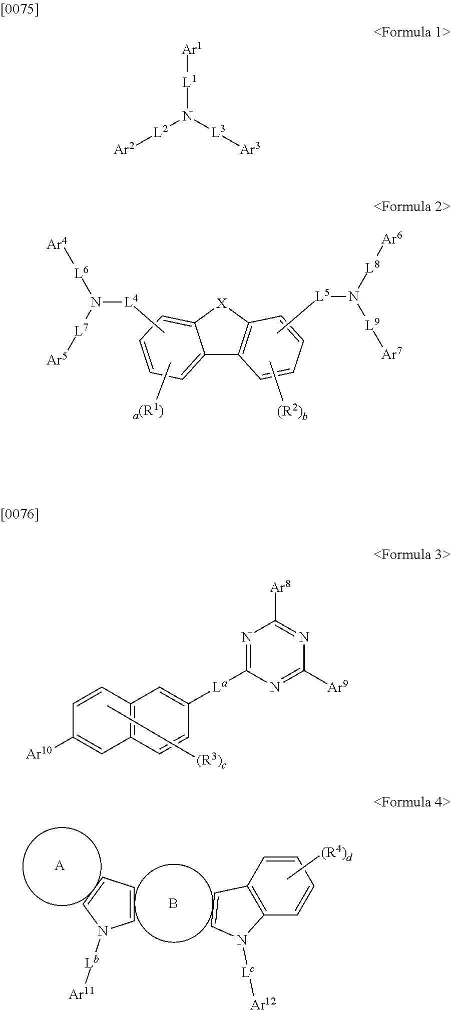

Additionally, a hole transport layer of the present invention may include compound represented by the following Formula 5.

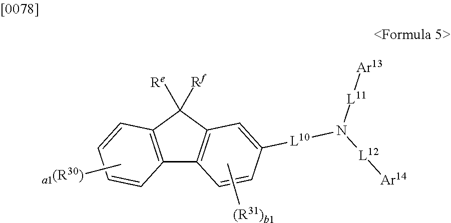

Additionally, an organic material layer of the present invention may include an electron transport layer formed between a second electrode and a light-emitting layer, wherein the electron transport layer may include a compound represented by the following Formula 6.

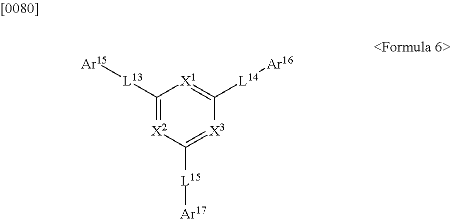

Hereinafter, Formulas 1 to 6 will be described.

In Formulas 1 to 6, each symbol may be defined as follows.

Ar¹ to Ar¹⁷ are each independently selected from the group consisting of a C₆-C₆₀ aryl group, a fluorenyl group, a C₂-C₆₀ heterocyclic group containing at least one heteroatom of O, N, S, Si and P, and a C₃-C₆₀ aliphatic ring group.

L¹ to L¹⁵, L^{a}, L^{b} and L^{c} are each independently selected from the group consisting of a single bond, a C₆-C₆₀ arylene group, a fluorenylene group, a C₃-C₆₀ aliphatic ring group, and a C₂-C₆₀ heterocyclic group containing at least one heteroatom of O, N, S, Si and P.

In Formula 2, X is O, S, C(R₁)(R₂) or N(R₃), in Formula 6, X¹ to X³ are each independently C(R₁₁) or N and at least one of these is N.

In Formula 4, A ring and B ring are each independently aryl ring or heteroaryl ring, at least one of the A ring and the B ring is a C₁₀ or greater aryl ring, and the A ring and the B ring may each be substituted with one or more R⁴ that is the same or different from each other.

R¹ to R⁴, R³⁰, R³¹, R₁, R₂, R₄, R₁₁, Rₑ and R_{f} are each independently selected from the group consisting of hydrogen, deuterium, halogen, a cyano group, a C₆-C₆₀ aryl group, a fluorenyl group, a C₂-C₆₀ heterocyclic group containing at least one heteroatom of O, N, S, Si and P, a C₃-C₆₀ aliphatic ring group, a C₁-C₂₀ alkyl group, a C₂-C₂₀ alkenyl group, a C₂-C₂₀ alkynyl group, a C₁-C₃₀ alkoxyl group, a C₆-C₂₀ aryloxy group and -L′-N(Rₐ)(R_{b}), and adjacent groups may be bonded to each other to form a ring, Rₑ and R_{f} may be bonded to each other to form a ring, R₁ and R₂ may be bonded to each other to form a ring. When Rₑ and R_{f} are bonded to each other, or R₁ and R₂ are bonded to each other, a spiro compound may be formed.

a, b and b1 are each an integer of 0 to 3, c is an integer of 0 to 6, d and a1 are each an integer of 0 to 4, and when each of these is an integer of 2 or more, each of R¹, each of R², each of R³, each of R⁴, each of R³⁰, each of R³¹ are the same as or different from each other.

A ring by adjacent groups, for example, adjacent R¹, adjacent R², adjacent R³, adjacent R⁴, adjacent R³⁰, adjacent R³¹ may be selected from the group consisting of a C₆-C₆₀ aromatic ring group, a fluorene group, a C₂-C₆₀ heterocyclic group containing at least one heteroatom of O, N, S, Si and P, and a C₃-C₆₀ aliphatic ring group.

When an aromatic ring group is formed by adjacent groups, the aromatic ring group may be a C₆-C₂₀, a C₆-C₁₈, a C₆-C₁₆, a C₆-C₁₄, a C₆-C₁₃, a C₆-C₁₂, a C₆-C₁₀, a C₆, a C₁₀, a C₁₂, a C₁₄, a C₁₅, a C₁₆, a C₁₈ aromatic ring group, specifically, benzene, naphthalene, anthracene, phenanthrene, pyrene or the like.

R₃ is selected from the group consisting of a C₆-C₆₀ aryl group, a fluorenyl group, a C₂-C₆₀ heterocyclic group containing at least one heteroatom of O, N, S, Si and P, and a C₃-C₆₀ aliphatic ring group.

L′ is selected from the group consisting of a single bond, a C₆-C₆₀ arylene group, a fluorenylene group, a C₃-C₆₀ aliphatic ring group, and a C₂-C₆₀ heterocyclic group containing at least one heteroatom of O, N, S, Si and P.

Rₐ and R_{b} are each independently selected from the group consisting of a C₆-C₆₀ aryl group, a fluorenyl group, a C₂-C₆₀ heterocyclic group containing at least one heteroatom of O, N, S, Si and P, and a C₃-C₆₀ aliphatic ring group.

When at least one of Ar¹ to Ar¹⁷, R¹ to R⁴, R³⁰, R³¹, R₁ to R₄, R₁₁, Rₐ, R_{b}, Rₑ and R_{f} is an aryl group, the aryl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, or a C₁₈ aryl group, specifically, phenyl, biphenyl, naphthyl, terphenyl, phenanthrene, triphenylene, or the like.

When at least one of L¹ to L¹⁵, L^{a}, L^{b}, L^{c}, L′ is an arylene group, the arylene group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈ arylene group, specifically, phenylene, biphenyl, naphthylene, terphenyl, phenanthrene, triphenylene, or the like.

When at least one of Ar¹ to Ar¹⁷, R¹ to R⁴, R³⁰, R³¹, R¹ to R⁴, R¹¹, Rₐ, R_{b}, Rₑ, R_{f}, L¹ to L¹⁵, L^{a}, L^{b}, L^{c}, L′ is a heterocyclic group, the heterocyclic group may be, for example, a C₂-C₃₀, a C₂-C₂₉, a C₂-C₂₈, a C₂-C₂₇, a C₂-C₂₆, a C₂-C₂₅, a C₂-C₂₄, a C₂-C₂₃, a C₂-C₂₂, a C₂-C₂₁, a C₂-C₂₀, a C₂-C₁₉, a C₂-C₁₈, a C₂-C₁₇, a C₂-C₁₆, a C₂-C₁₅, a C₂-C₁₄, a C₂-C₁₃, a C₂-C₁₂, a C₂-C₁₁, a C₂-C₁₀, a C₂-C₉, a C₂-C₈, a C₂-C₇, a C₂-C₆, a C₂-C₅, a C₂-C₄, a C₂-C₃, a C₂, a C₃, a C₄, a C₅, a C₆, a C₇, a C₃, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, or a C₂₉ heterocyclic group, specifically, pyridine, pyrimidine, pyrazine, pyridazine, triazine, furan, pyrrole, silole, indene, indole, phenyl-indole, benzoindole, phenyl-benzoindole, pyrazinoindol, quinoline, isoquinoline, benzoquinoline, pyridoquinoline, quinazoline, benzoquinazoline, dibenzoquinazoline, phenanthroquinazoline, quinoxaline, benzoquinoxaline, dibenzoquinoxaline, benzofuran, naphthobenzofuran, dibenzofuran, dinaphthofuran, thiophene, benzothiophene, dibenzothiophene, naphthobenzothiophene, dinaphthothiophene, carbazole, phenyl-carbazole, benzocarbazole, phenyl-benzocarbazole, naphthyl-benzocarbazole, dibenzocarbazole, indolocarbazole, benzofuropyridine, benzothienopyridine, benzofuropyridine, benzothienopyrimidine, benzofuropyrimidine, benzothienopyrazine, benzofuropyrazine, benzoimidazole, benzothiazole, benzooxazole, benzosiloe, phenanthroline, dihydro-phenylphenazine, 10-phenyl-10H-phenoxazine, phenoxazine, phenothiazine, dibenzodioxin, benzodibenzodioxin, thianthrene, 9,9-dimethyl-9H-xantene, 9,9-dimethyl-9H-thioxantene, dihydrodimethylphenylacridine, spiro[fluorene-9,9′-xanthene] and the like.

When at least one of Ar¹ to Ar¹⁷, R¹ to R⁴, R³⁰, R³¹, R₁ to R₄, R₁₁, Rₐ, R_{b}, Rₑ, R_{f} is a fluorenyl group or at least one of L¹ to L¹⁵, L^{a}, L^{b}, L^{c}, L′ is a fluorenylene group, the fluorenyl group or the fluorenylene group may be, for example, 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, and the like.

When at least one of R¹ to R⁴, R³⁰, R³¹, R₁, R₂, R₄, R₁₁, Rₑ and R_{f} is an alkyl group, the alkyl group may be, for example, a C₁-C₂₀, a C₁-C₁₀, a C₁-C₄, a C₁, a C₂, a C₃ and a C₄ alkyl group, specifically, methyl, ethyl, t-butyl, etc.

When at least one of R¹ to R⁴, R³⁰, R³¹, R₁, R₂, R₄, R₁₁, Rₑ and R_{f} is an alkoxy group, the alkoxy group may be, for example, a C₁-C₂₀, a C₁-C₁₀, a C₁-C₄, a C₁, a C₂, a C₃, a C₄ alkoxy group, specifically, a methoxy group, ethoxy group, etc.

In Formulas 1 to 6, the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R₁ and R₂ may be each optionally substituted with one or more substituents selected from the group consisting of deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group containing at least one heteroatom of O, N, S, Si and P, and a C₃-C₃₀ aliphatic ring group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R¹ and R² is substituted with an aryl group, the aryl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, or a C₃₀ aryl group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R¹ and R² is substituted with a heterocyclic group, the heterocyclic group may be, for example, a C₂-C₃₀, a C₂-C₂₉, a C₂-C₂₈, a C₂-C₂₇, a C₂-C₂₆, a C₂-C₂₅, a C₂-C₂₄, a C₂-C₂₃, a C₂-C₂₂, a C₂-C₂₁, a C₂-C₂₀, a C₂-C₁₉, a C₂-C₁₈, a C₂-C₁₇, a C₂-C₁₆, a C₂-C₁₅, a C₂-C₁₄, a C₂-C₁₃, a C₂-C₁₂, a C₂-C₁₁, a C₂-C₁₀, a C₂-C₉, a C₂-C₃, a C₂-C₇, a C₂-C₆, a C₂-C₅, a C₂-C₄, a C₂-C₃, a C₂, a C₃, a C₄, a C₅, a C₆, a C₇, a C₃, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, or a C₃₀ heterocyclic group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R₁ and R₂ is substituted with a fluorenyl group, the fluorenyl group may be 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl) 9-phenyl-9H-fluorene, and the like.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R₁ and R₂ is substituted with an aliphatic ring group, the aliphatic ring group may be, for example, a C₃-C₂₀, a C₃-C₁₉, a C₃-C₁₈, a C₃-C₁₇, a C₃-C₁₆, a C₃-C₁₅, a C₃-C₁₄, a C₃-C₁₃, a C₃-C₁₂, a C₃-C₁₁, a C₃-C₁₀, a C₃-C₈, a C₃-C₆, a C₆, a C₁₀, a C₁₁, a C₁₂, a C₁₃, a C₁₄, a C₁₅, a C₁₆, a C₁₇ or a C₁₈ aliphatic ring group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R₁ and R₂ is substituted with an alkyl group, the alkyl group may be, for example, a C₁-C₂₀, a C₁-C₁₀, a C₁-C₄, a C₁, a C₂, a C₃, or a C₄ alkoxy group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R₁ and R₂ is substituted with an alkoxy group, the alkoxy group may be, for example, a C₁-C₂₀, a C₁-C₁₀, a C₁-C₄, a C₁, a C₂, a C₃, or a C₄ alkoxy group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, the ring formed by adjacent groups, the ring formed by Rₑ and R_{f}, the ring formed by R₁ and R₂ is substituted with an aryloxy group, the aryloxy group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, or a C₃₀ aryloxy group.

Formula 1 may be represented by one of the following Formulas 1-1 to 1-9.

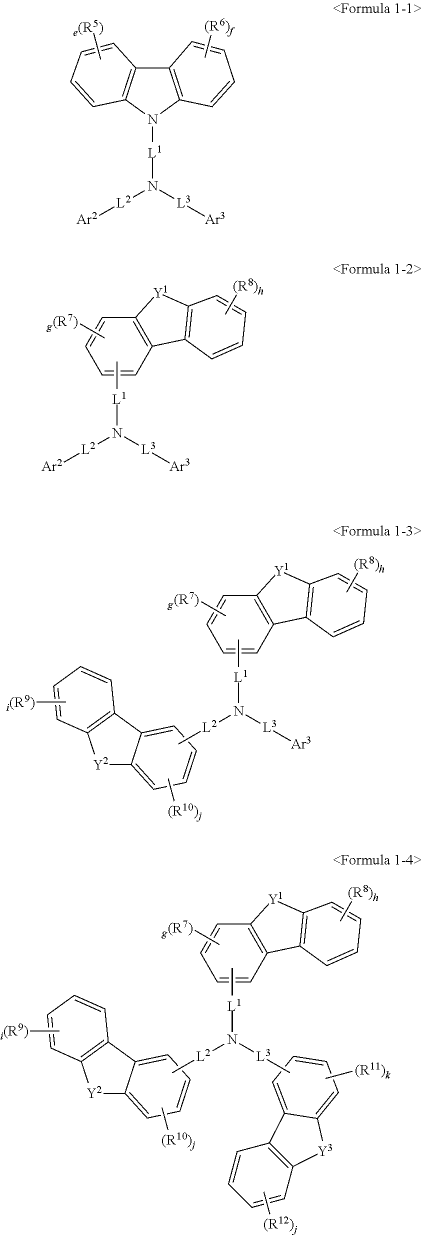

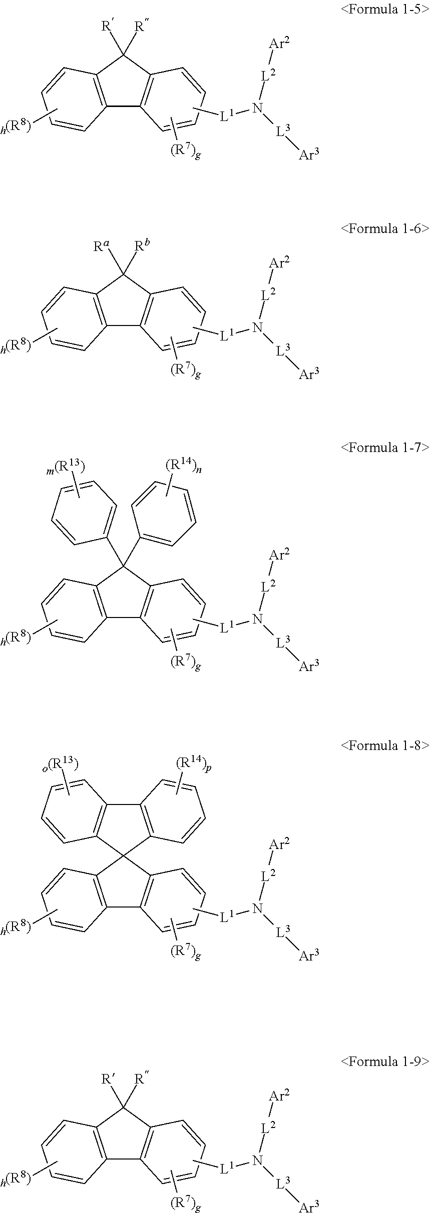

In Formula 1-1 to Formula 1-9, Ar², Ar³, L¹ to L³ are the same as defined for Formula 1, Y¹ to Y³ are each independently O, S, C(R₅)(R₆) or N(R₇).

R⁵ to R¹², R′, R″, R₅ and R₆ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group, and adjacent groups may be bonded to each other to form a ring, R₅ and R₆ may be bonded to each other to form a ring, and R′ and R″ may be bonded to each other to form a ring.

R^{a} and R^{b} are each independently a C₁-C₂₀ alkyl group.

R₇ is selected from the group consisting of a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group.

e, f, h, i, l, o and p are each an integer of 0 to 4, g, j and k are an integer of 0 to 3, m and n are each an integer of 0 to 5, and when each of these is an integer of 2 or more, each of R⁵, each of R⁶, each of R⁷, each of R⁸, each of R⁹, each of R¹⁰, each of R¹¹, each of R¹², each of R¹³, each of R¹⁴ are the same as or different from each other.

Formula 2 may be represented by one of the following Formulas 2-1 to 2-5.

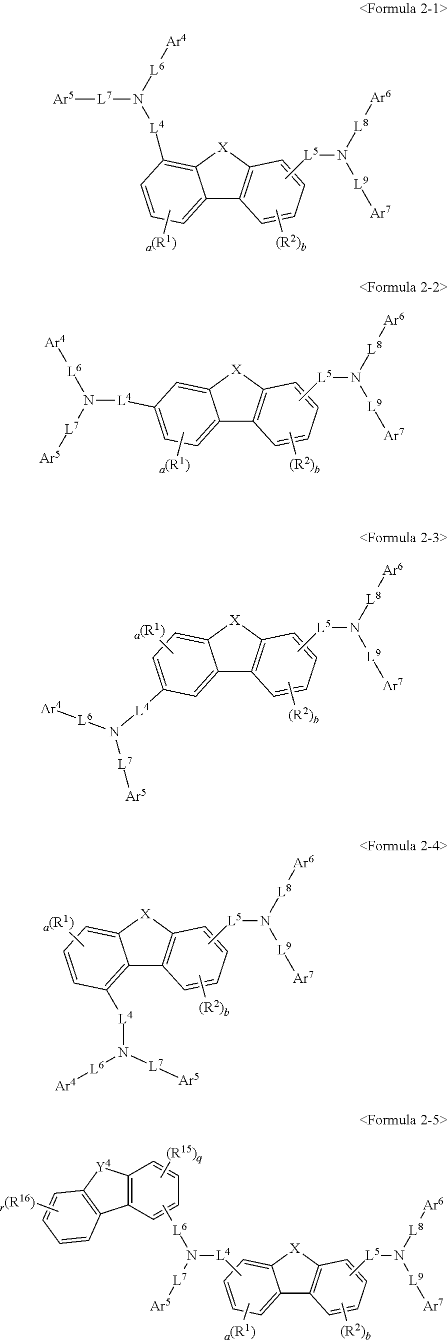

In Formula 2-1 to Formula 2-5, X, Ar⁴ to Ar⁷, L⁴ to L⁹, R¹, R², a, b are the same as defined for Formula 2, and Y⁴ is O, S, C(R₈)(R₉) or N(R₁₀).

R¹⁵, R¹⁶, R₈, R₉ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group, and adjacent groups may be bonded to each other to form a ring, and R₈ and R₉ may be bonded to each other to form a ring.

R₁₀ is selected from the group consisting of a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group.

q is an integer of 0 to 3, r is an integer of 0 to 4, and when each of these is an integer of 2 or more, each of R¹⁵, each of R¹⁶ are the same as or different from each other.

Formula 3 may be represented by one of the following Formulas 3-1 to 3-8.

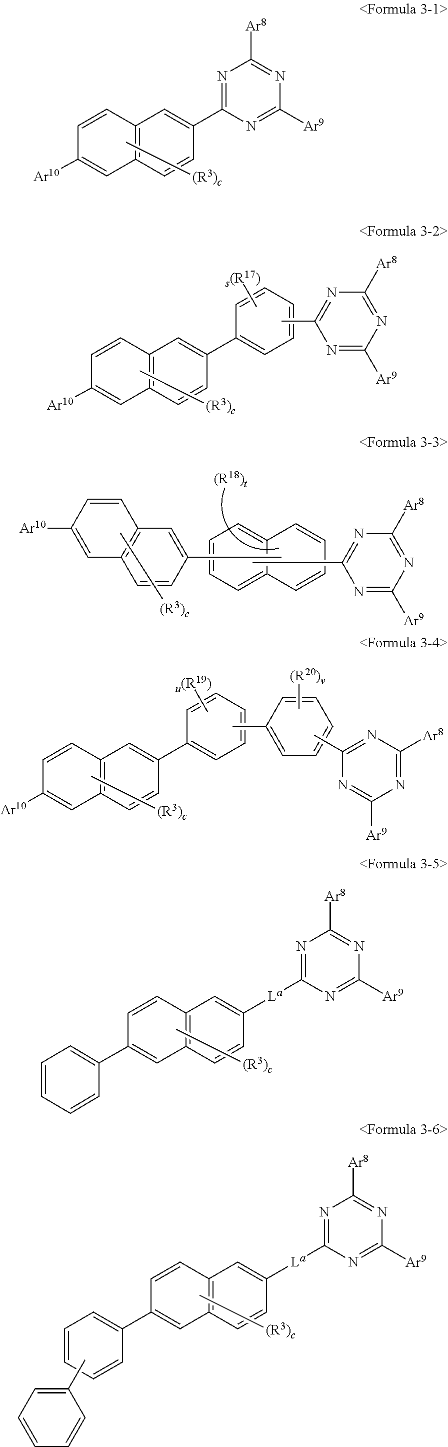

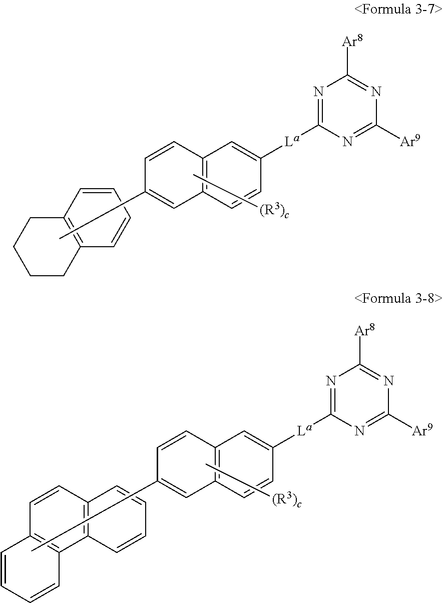

In Formula 3-1 to Formula 3-8, Ar⁸ to Ar¹⁰, L^{a}, R³, c are the same as defined for Formula 3.

R¹⁷ to R²⁰ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group, and adjacent groups may be bonded to each other to form a ring.

s, u and v are each an integer of 0 to 4, t is an integer of 0 to 6, and when each of these is an integer of 2 or more, each of R¹⁷, each of R¹⁸, each of R¹⁹, each of R²⁰ are the same as or different from each other.

Formula 4 may be represented by one of the following Formulas 4-1 to 4-13.

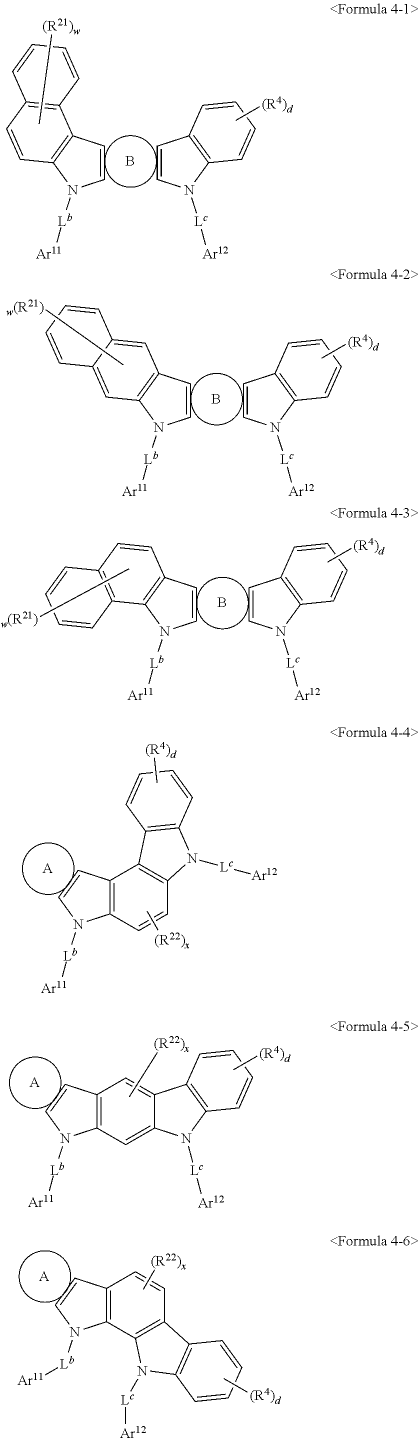

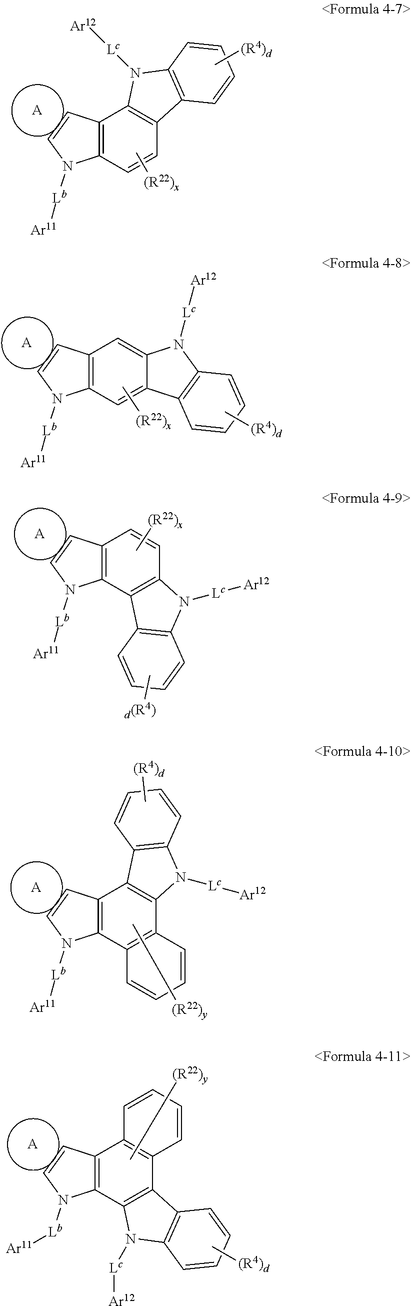

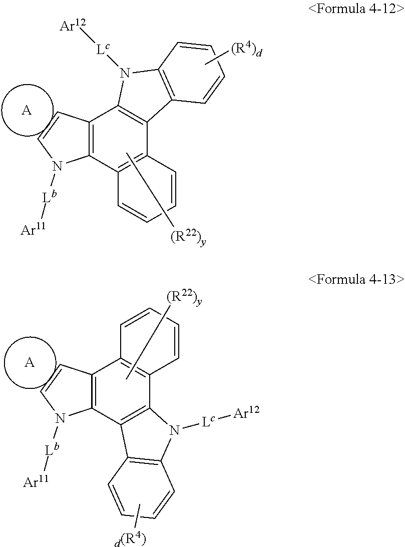

In Formula 4-1 to Formula 4-3, A ring, B ring, L^{b}, L^{c}, Ar¹¹, Ar¹², R⁴, d are the same as defined for Formula 4, R²¹ and R²² are each the same as R₁ defined in Formula 4. w is an integer of 0 to 6, x is an integer of 0 to 2, y is an integer of 0 to 4, and when each of these is an integer of 2 or more, each of R²¹, each of R²² are the same as or different from each other, and adjacent groups may be bonded to each other to form a ring.

Formula 5 may be represented by the following Formula 5-1.

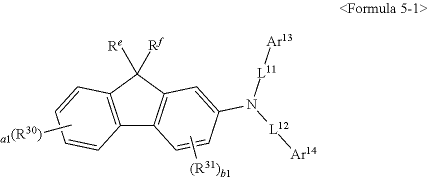

In Formula 5-1, R³⁰, R³¹, a1, b1, R^{e}, R^{f}, L¹¹, L¹², Ar¹³, Ar¹⁴ are the same as defined for Formula 5.

Formula 6 may be represented by one of the following Formulas 6-1 to 6-3.

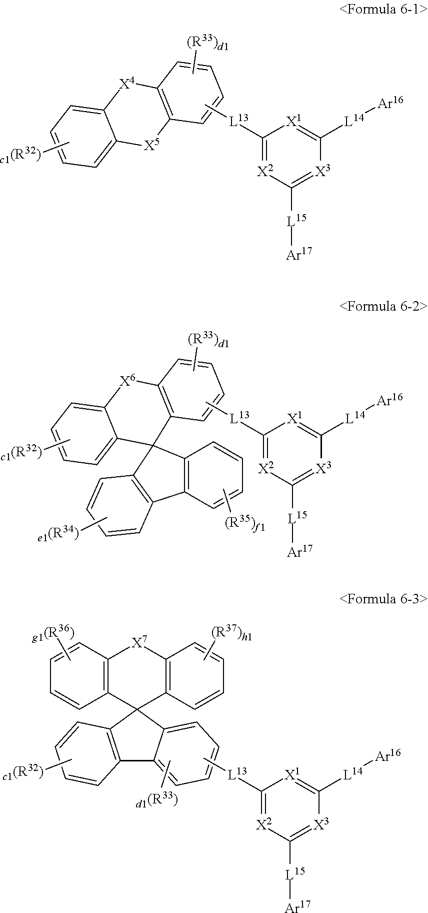

In Formula 6-1 to Formula 6-3, X¹ to X³, L¹³ to L¹⁵, Ar¹⁶, Ar¹⁷ are the same as defined for Formula 6.

X⁴ and a X⁵ are each independently a single bond, O, S, C(R₂₁)(R₂₂) or N(R₂₃), and at least one of X⁴ and X⁵ is not a single bond. X⁶ and X⁷ is a single bond, O, S, C(R₂₁)(R₂₂) or N(R₂₃).

R³² to R³⁷, R₂₁ and R₂₂ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group, and adjacent groups may be bonded to each other to form a ring, and R²¹ and R²² may be bonded to each other to form a ring.

c1, e1, f1, g1 and h1 are each an integer of 0 to 4, d1 is an integer of 0 to 3, and when each of these is an integer of 2 or more, each of R³², each of R³³, each of R³⁴, each of R³⁵, each of R³⁶, each of R³⁷ are the same as or different from each other.

R₂₃ is selected from the group consisting of a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group.

Specifically, compound represented by Formula 1 may be one of the following compounds, but there is no limitation thereto.

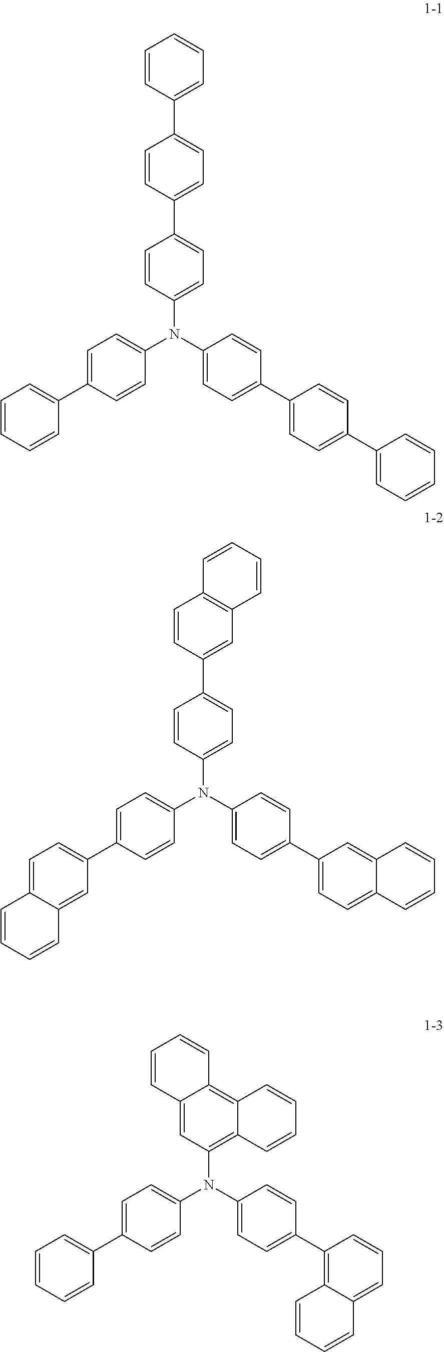 [SMILES: c1ccc(-c2ccc(-c3ccc(N(c4ccc(-c5ccccc5)cc4)c4ccc(-c5ccc(-c6ccccc6)cc5)cc4)cc3)cc2)cc1 ; c1ccc2cc(-c3ccc(N(c4ccc(-c5ccc6ccccc6c5)cc4)c4ccc(-c5ccc6ccccc6c5)cc4)cc3)ccc2c1 ; c1ccc(-c2ccc(N(c3ccc(-c4cccc5ccccc45)cc3)c3cc4ccccc4c4ccccc34)cc2)cc1]

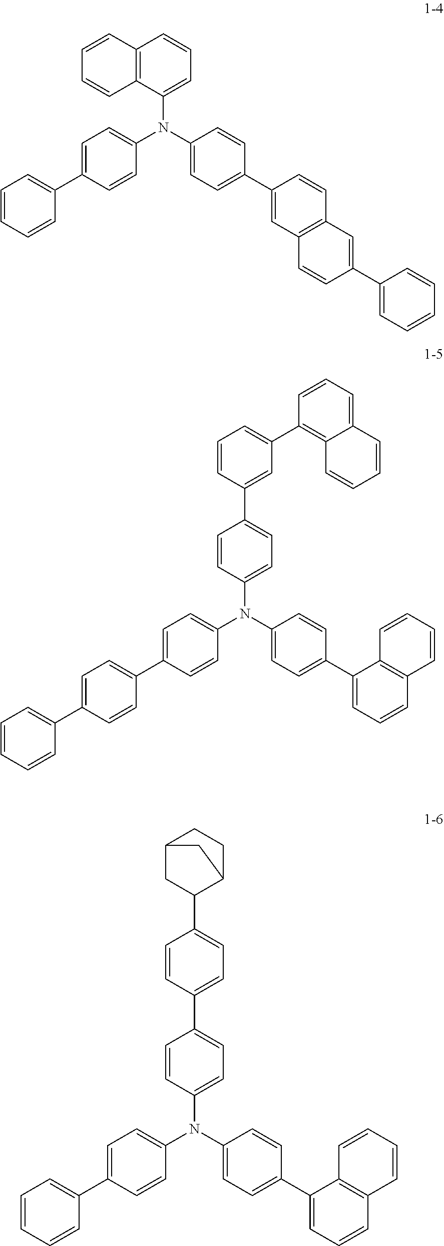 [SMILES: c1ccc(-c2ccc(N(c3ccc(-c4ccc5cc(-c6ccccc6)ccc5c4)cc3)c3cccc4ccccc34)cc2)cc1 ; c1ccc(-c2ccc(-c3ccc(N(c4ccc(-c5cccc(-c6cccc7ccccc67)c5)cc4)c4ccc(-c5cccc6ccccc56)cc4)cc3)cc2)cc1 ; c1ccc(-c2ccc(N(c3ccc(-c4ccc(C5CC6CCC5C6)cc4)cc3)c3ccc(-c4cccc5ccccc45)cc3)cc2)cc1]

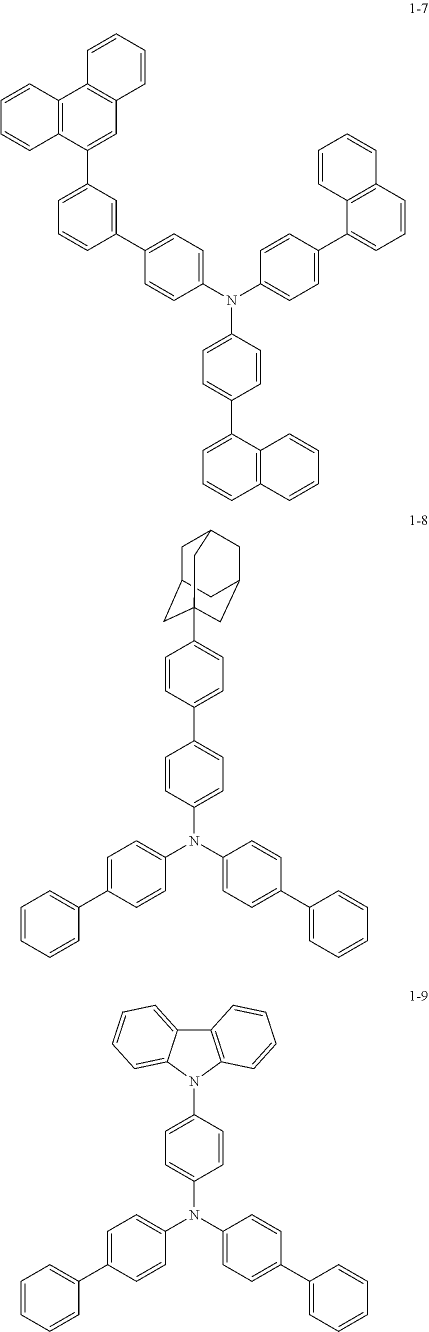

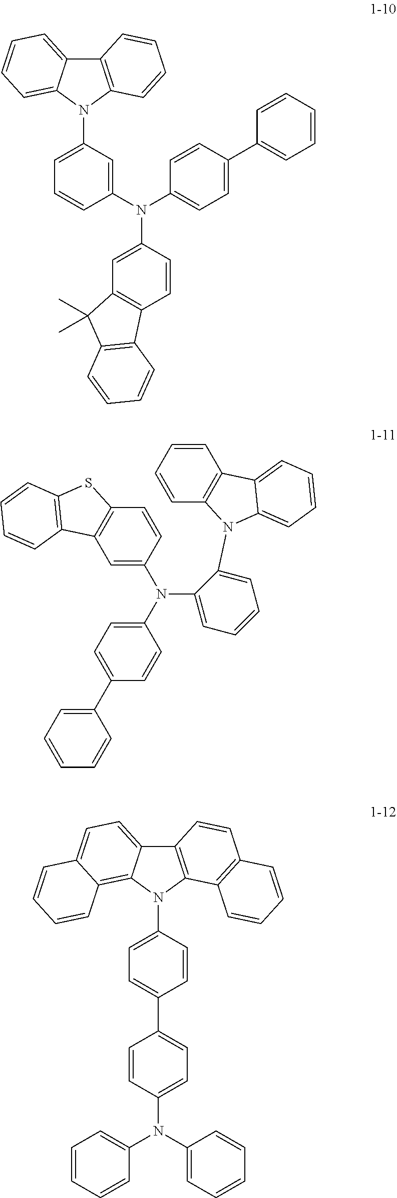 [SMILES: CC1(C)c2ccccc2-c2ccc(N(c3ccc(-c4ccccc4)cc3)c3cccc(-n4c5ccccc5c5ccccc54)c3)cc21 ; c1ccc(-c2ccc(N(c3ccc4sc5ccccc5c4c3)c3ccccc3-n3c4ccccc4c4ccccc43)cc2)cc1 ; c1ccc(N(c2ccccc2)c2ccc(-c3ccc(-n4c5c6ccccc6ccc5c5ccc6ccccc6c54)cc3)cc2)cc1]

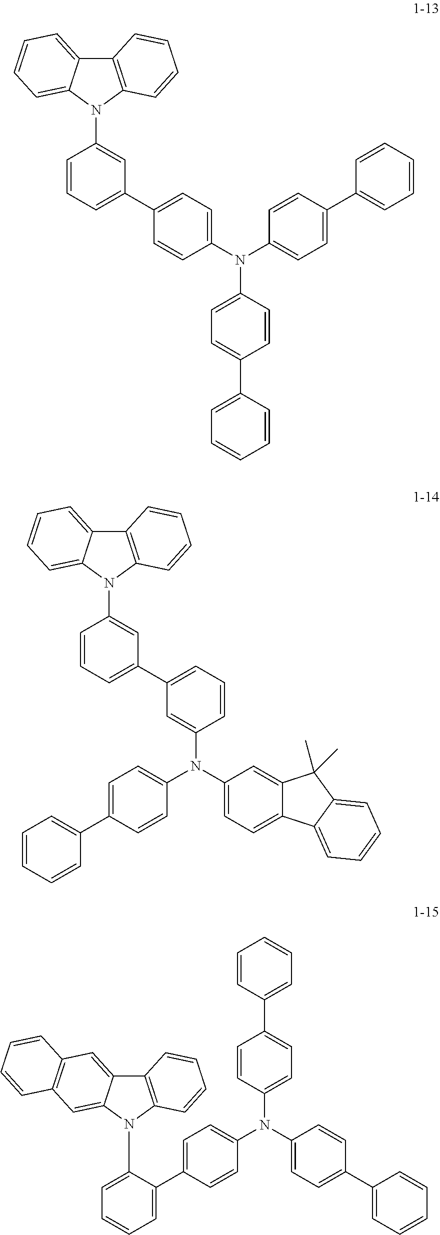 [SMILES: c1ccc(-c2ccc(N(c3ccc(-c4ccccc4)cc3)c3ccc(-c4cccc(-n5c6ccccc6c6ccccc65)c4)cc3)cc2)cc1 ; CC1(C)c2ccccc2-c2ccc(N(c3ccc(-c4ccccc4)cc3)c3cccc(-c4cccc(-n5c6ccccc6c6ccccc65)c4)c3)cc21 ; c1ccc(-c2ccc(N(c3ccc(-c4ccccc4)cc3)c3ccc(-c4ccccc4-n4c5ccccc5c5cc6ccccc6cc54)cc3)cc2)cc1]

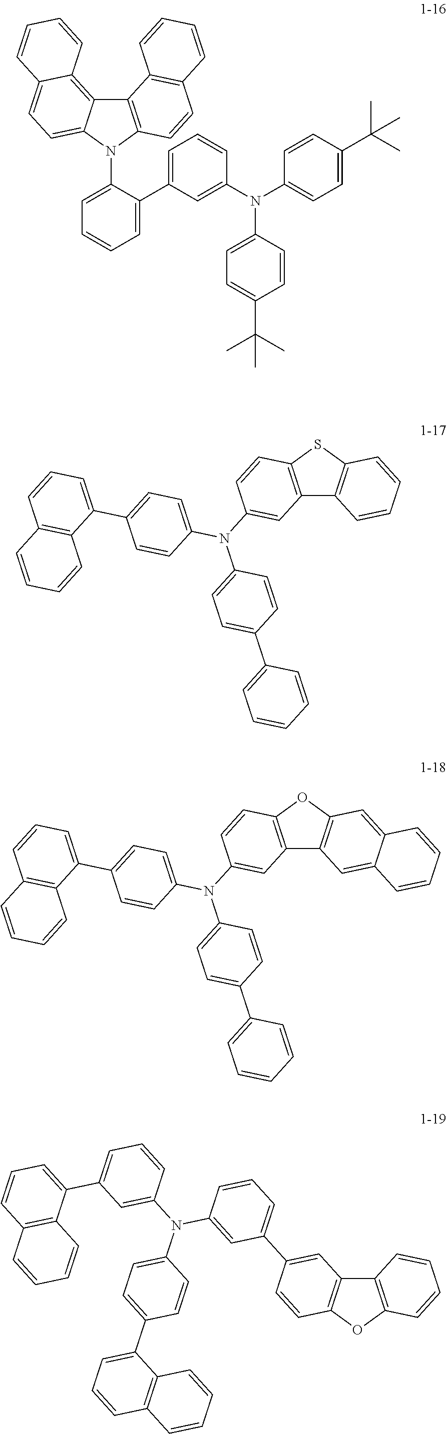 [SMILES: CC(C)(C)c1ccc(N(c2ccc(C(C)(C)C)cc2)c2cccc(-c3ccccc3-n3c4ccc5ccccc5c4c4c5ccccc5ccc43)c2)cc1 ; c1ccc(-c2ccc(N(c3ccc(-c4cccc5ccccc45)cc3)c3ccc4sc5ccccc5c4c3)cc2)cc1 ; c1ccc(-c2ccc(N(c3ccc(-c4cccc5ccccc45)cc3)c3ccc4oc5cc6ccccc6cc5c4c3)cc2)cc1 ; c1cc(-c2ccc3oc4ccccc4c3c2)cc(N(c2ccc(-c3cccc4ccccc34)cc2)c2cccc(-c3cccc4ccccc34)c2)c1]

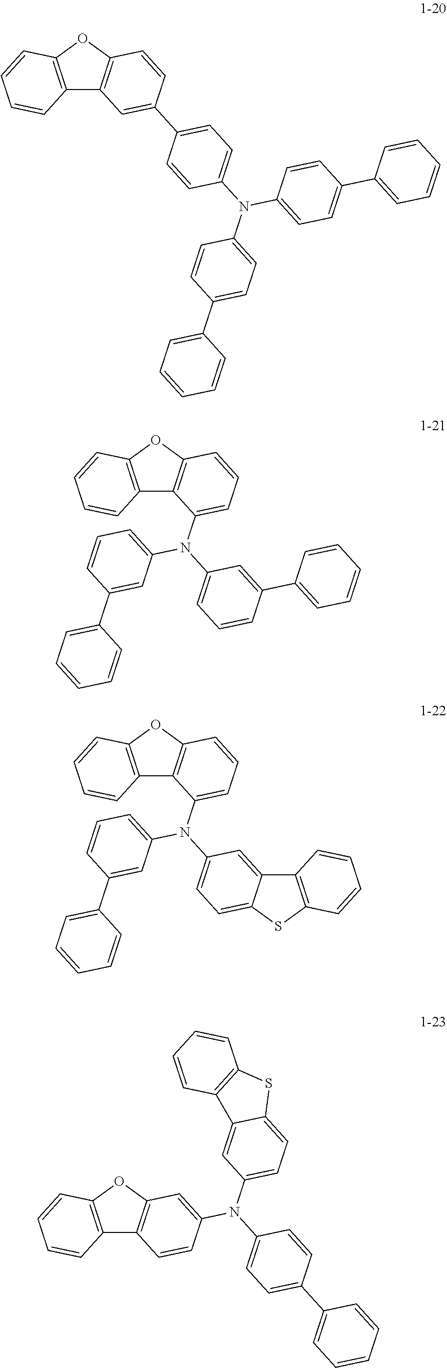 [SMILES: c1ccc(-c2ccc(N(c3ccc(-c4ccccc4)cc3)c3ccc(-c4ccc5oc6ccccc6c5c4)cc3)cc2)cc1 ; c1ccc(-c2cccc(N(c3cccc(-c4ccccc4)c3)c3cccc4oc5ccccc5c34)c2)cc1 ; c1ccc(-c2cccc(N(c3ccc4sc5ccccc5c4c3)c3cccc4oc5ccccc5c34)c2)cc1 ; c1ccc(-c2ccc(N(c3ccc4c(c3)oc3ccccc34)c3ccc4sc5ccccc5c4c3)cc2)cc1]

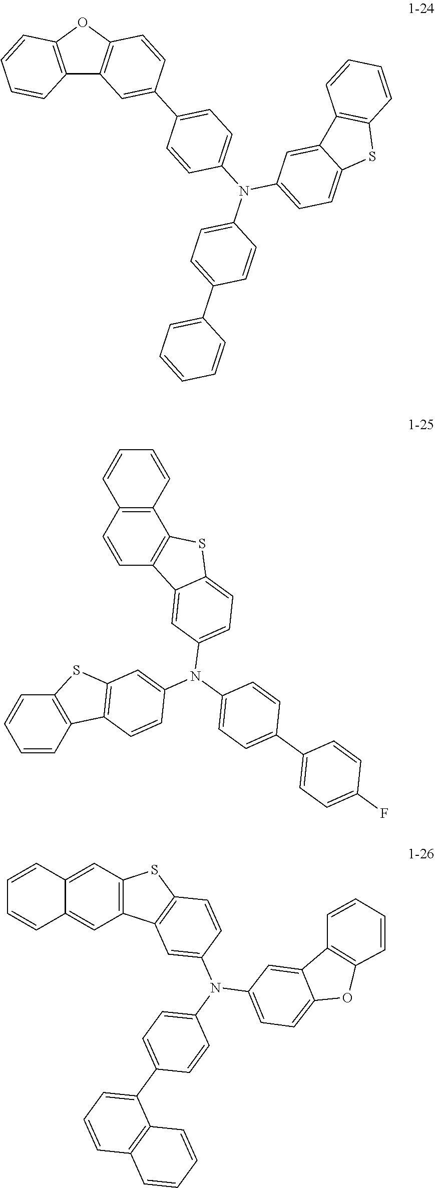 [SMILES: c1ccc(-c2ccc(N(c3ccc(-c4ccc5oc6ccccc6c5c4)cc3)c3ccc4sc5ccccc5c4c3)cc2)cc1 ; Fc1ccc(-c2ccc(N(c3ccc4c(c3)sc3ccccc34)c3ccc4sc5c6ccccc6ccc5c4c3)cc2)cc1 ; c1ccc2cc3c(cc2c1)sc1ccc(N(c2ccc(-c4cccc5ccccc45)cc2)c2ccc4oc5ccccc5c4c2)cc13]

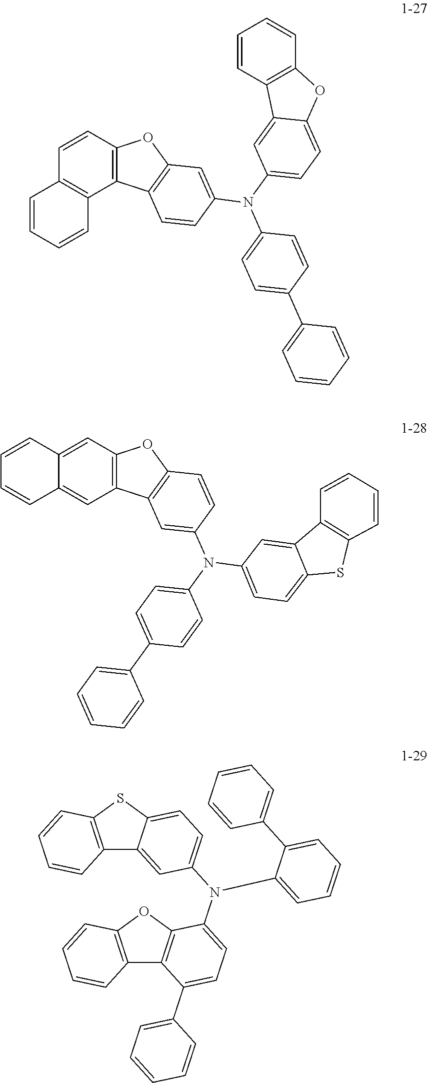 [SMILES: c1ccc(-c2ccc(N(c3ccc4c(c3)oc3ccc5ccccc5c34)c3ccc4oc5ccccc5c4c3)cc2)cc1 ; c1ccc(-c2ccc(N(c3ccc4oc5cc6ccccc6cc5c4c3)c3ccc4sc5ccccc5c4c3)cc2)cc1 ; c1ccc(-c2ccccc2N(c2ccc3sc4ccccc4c3c2)c2ccc(-c3ccccc3)c3c2oc2ccccc23)cc1]

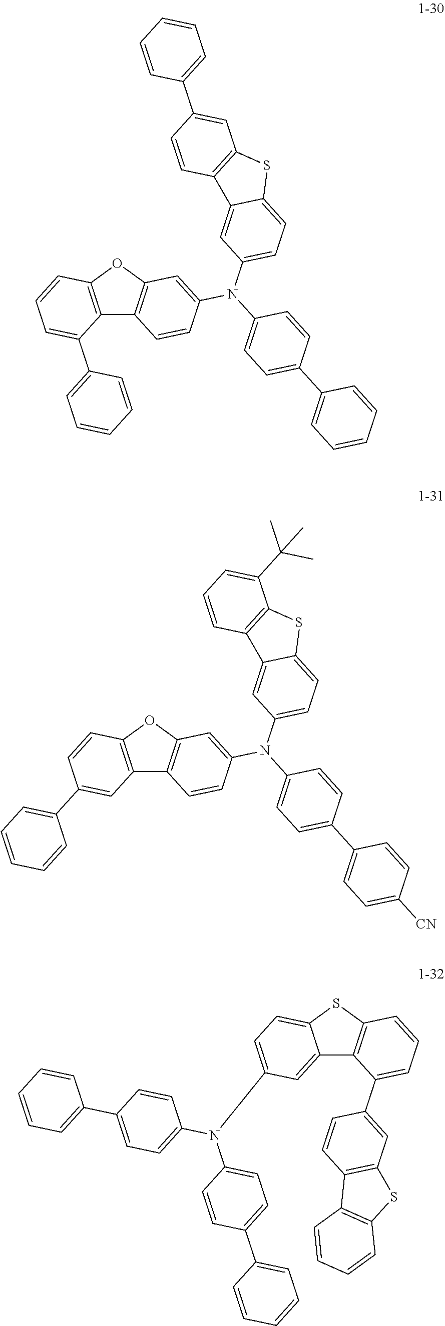 [SMILES: c1ccc(-c2ccc(N(c3ccc4c(c3)oc3cccc(-c5ccccc5)c34)c3ccc4sc5cc(-c6ccccc6)ccc5c4c3)cc2)cc1 ; CC(C)(C)c1cccc2c1sc1ccc(N(c3ccc(-c4ccc(C#N)cc4)cc3)c3ccc4c(c3)oc3ccc(-c5ccccc5)cc34)cc12 ; c1ccc(-c2ccc(N(c3ccc(-c4ccccc4)cc3)c3ccc4sc5cccc(-c6ccc7c(c6)sc6ccccc67)c5c4c3)cc2)cc1]

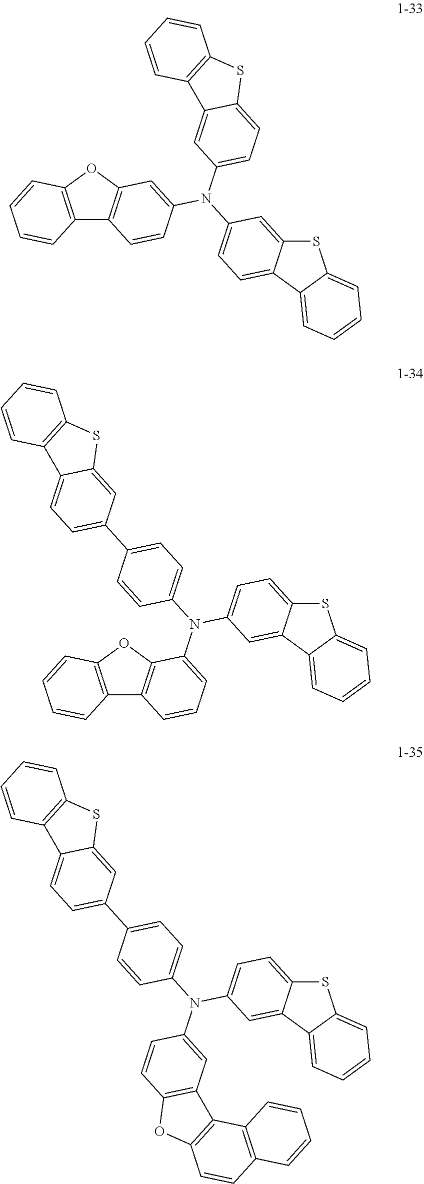 [SMILES: c1ccc2c(c1)oc1cc(N(c3ccc4c(c3)sc3ccccc34)c3ccc4sc5ccccc5c4c3)ccc12 ; c1ccc2c(c1)oc1c(N(c3ccc(-c4ccc5c(c4)sc4ccccc45)cc3)c3ccc4sc5ccccc5c4c3)cccc12 ; c1ccc2c(c1)ccc1oc3ccc(N(c4ccc(-c5ccc6c(c5)sc5ccccc56)cc4)c4ccc5sc6ccccc6c5c4)cc3c12]

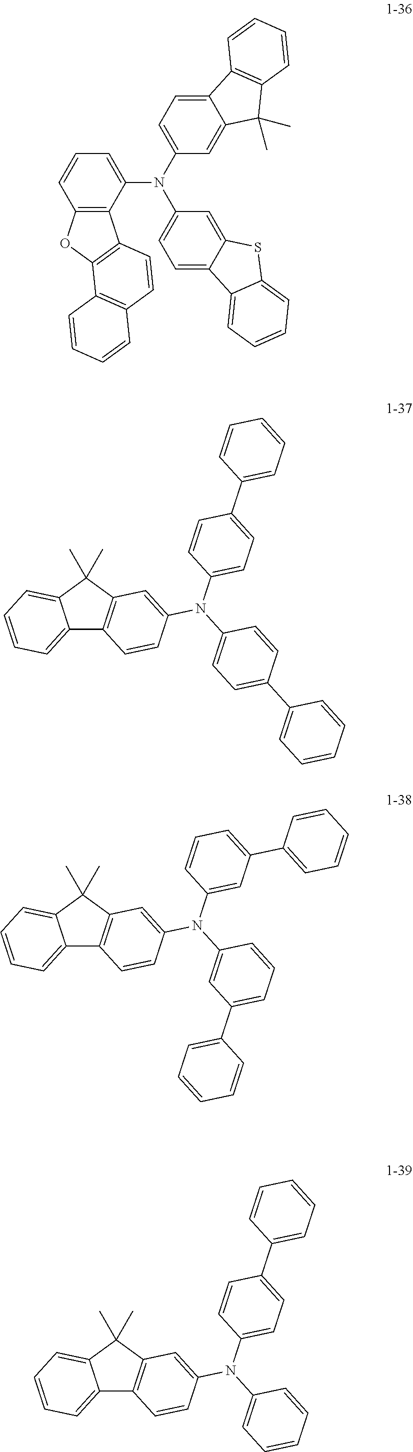 [SMILES: CC1(C)c2ccccc2-c2ccc(N(c3ccc4c(c3)sc3ccccc34)c3cccc4oc5c6ccccc6ccc5c34)cc21 ; CC1(C)c2ccccc2-c2ccc(N(c3ccc(-c4ccccc4)cc3)c3ccc(-c4ccccc4)cc3)cc21 ; CC1(C)c2ccccc2-c2ccc(N(c3cccc(-c4ccccc4)c3)c3cccc(-c4ccccc4)c3)cc21 ; CC1(C)c2ccccc2-c2ccc(N(c3ccccc3)c3ccc(-c4ccccc4)cc3)cc21]

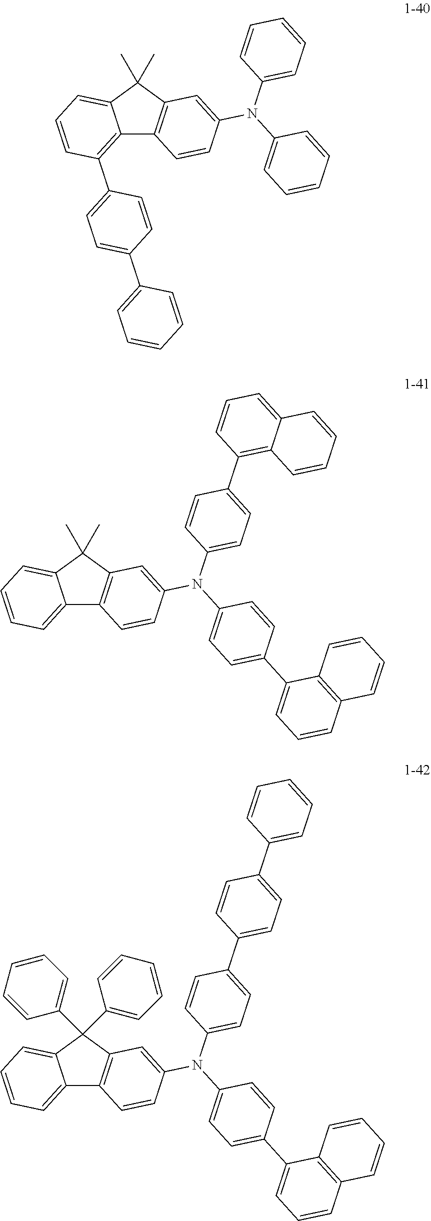

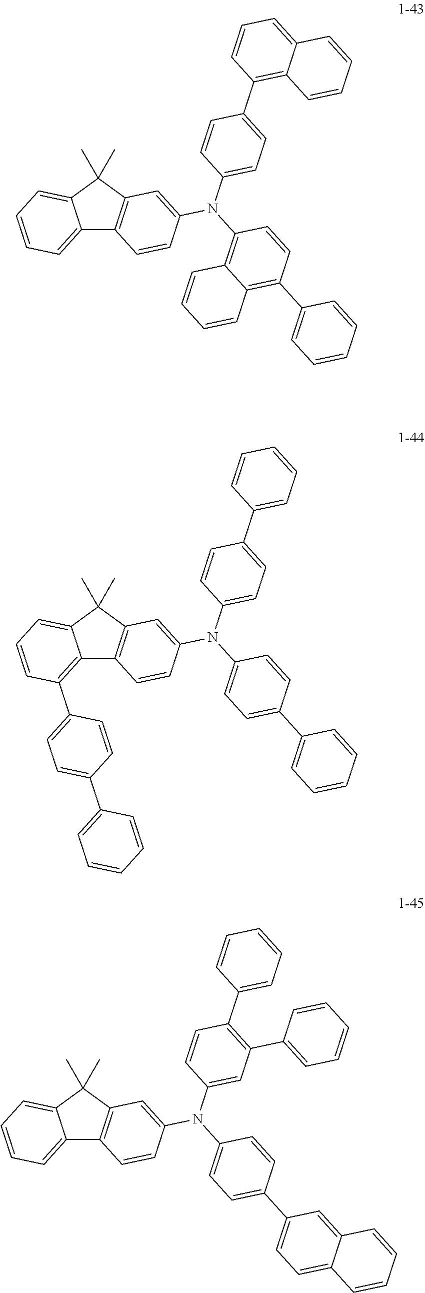 [SMILES: CC1(C)c2ccccc2-c2ccc(N(c3ccc(-c4cccc5ccccc45)cc3)c3ccc(-c4ccccc4)c4ccccc34)cc21 ; CC1(C)c2cc(N(c3ccc(-c4ccccc4)cc3)c3ccc(-c4ccccc4)cc3)ccc2-c2c(-c3ccc(-c4ccccc4)cc3)cccc21 ; CC1(C)c2ccccc2-c2ccc(N(c3ccc(-c4ccc5ccccc5c4)cc3)c3ccc(-c4ccccc4)c(-c4ccccc4)c3)cc21]

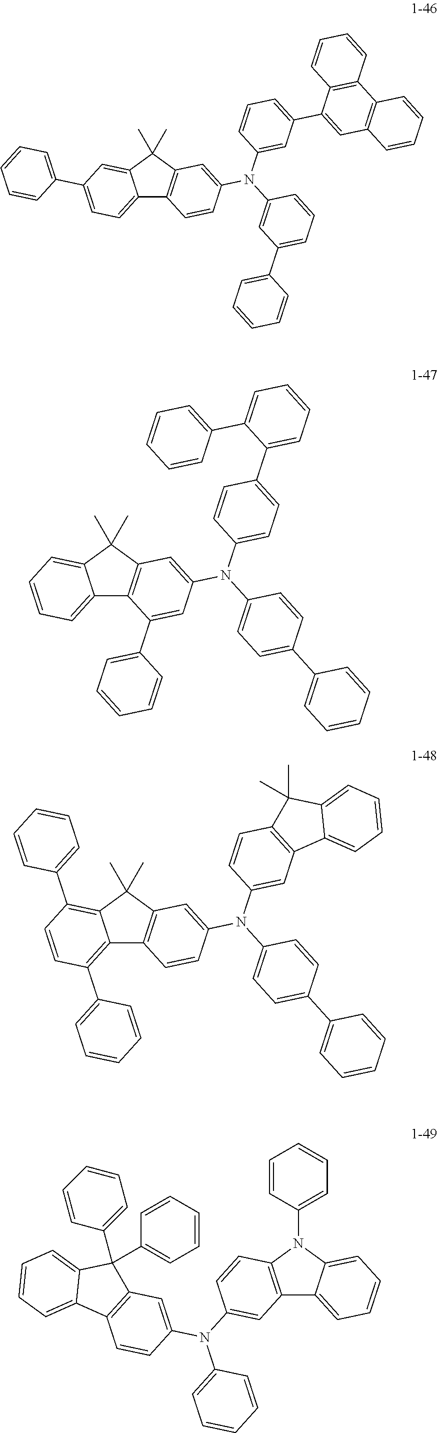 [SMILES: CC1(C)c2cc(-c3ccccc3)ccc2-c2ccc(N(c3cccc(-c4ccccc4)c3)c3cccc(-c4cc5ccccc5c5ccccc45)c3)cc21 ; CC1(C)c2ccccc2-c2c(-c3ccccc3)cc(N(c3ccc(-c4ccccc4)cc3)c3ccc(-c4ccccc4-c4ccccc4)cc3)cc21 ; CC1(C)c2ccccc2-c2cc(N(c3ccc(-c4ccccc4)cc3)c3ccc4c(c3)C(C)(C)c3c(-c5ccccc5)ccc(-c5ccccc5)c3-4)ccc21 ; c1ccc(N(c2ccc3c(c2)C(c2ccccc2)(c2ccccc2)c2ccccc2-3)c2ccc3c(c2)c2ccccc2n3-c2ccccc2)cc1]

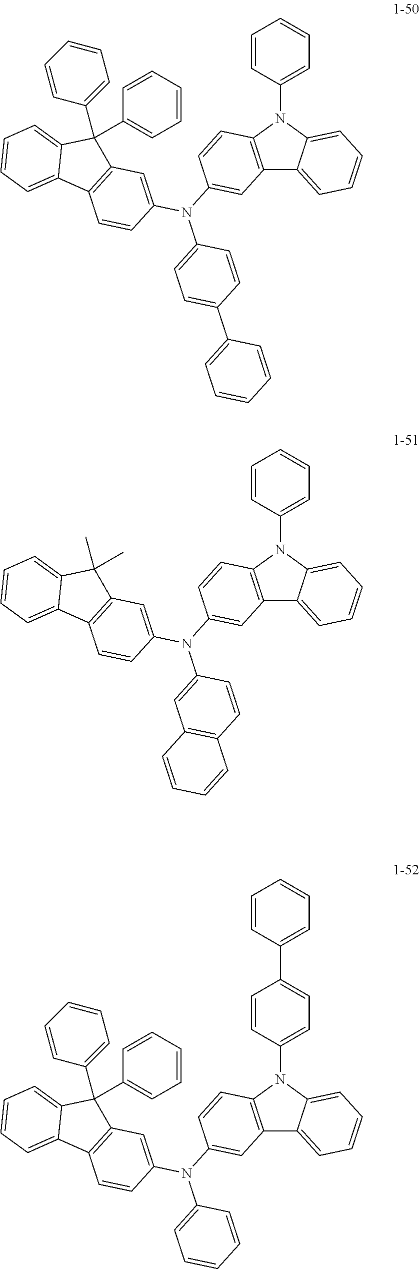 [SMILES: c1ccc(-c2ccc(N(c3ccc4c(c3)C(c3ccccc3)(c3ccccc3)c3ccccc3-4)c3ccc4c(c3)c3ccccc3n4-c3ccccc3)cc2)cc1 ; CC1(C)c2ccccc2-c2ccc(N(c3ccc4ccccc4c3)c3ccc4c(c3)c3ccccc3n4-c3ccccc3)cc21 ; c1ccc(-c2ccc(-n3c4ccccc4c4cc(N(c5ccccc5)c5ccc6c(c5)C(c5ccccc5)(c5ccccc5)c5ccccc5-6)ccc43)cc2)cc1]

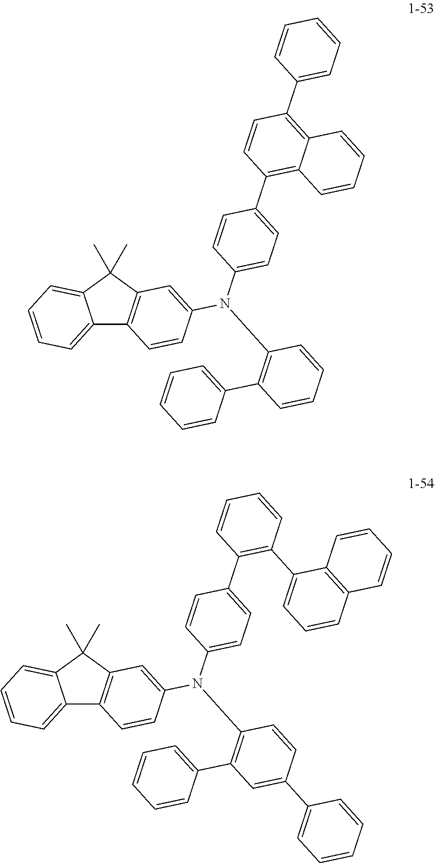 [SMILES: CC1(C)c2ccccc2-c2ccc(N(c3ccc(-c4ccc(-c5ccccc5)c5ccccc45)cc3)c3ccccc3-c3ccccc3)cc21 ; CC1(C)c2ccccc2-c2ccc(N(c3ccc(-c4ccccc4-c4cccc5ccccc45)cc3)c3ccc(-c4ccccc4)cc3-c3ccccc3)cc21]

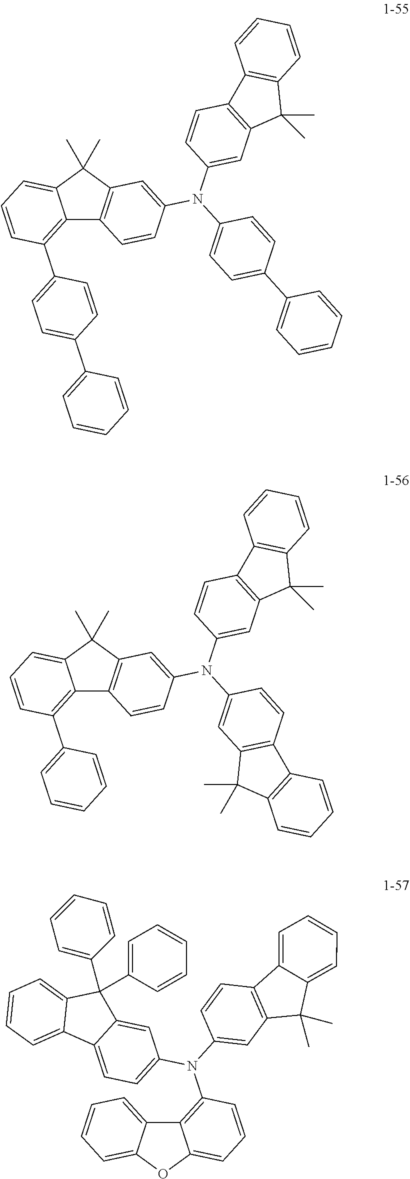 [SMILES: CC1(C)c2ccccc2-c2ccc(N(c3ccc(-c4ccccc4)cc3)c3ccc4c(c3)C(C)(C)c3cccc(-c5ccc(-c6ccccc6)cc5)c3-4)cc21 ; CC1(C)c2ccccc2-c2ccc(N(c3ccc4c(c3)C(C)(C)c3ccccc3-4)c3ccc4c(c3)C(C)(C)c3cccc(-c5ccccc5)c3-4)cc21 ; CC1(C)c2ccccc2-c2ccc(N(c3ccc4c(c3)C(c3ccccc3)(c3ccccc3)c3ccccc3-4)c3cccc4oc5ccccc5c34)cc21]

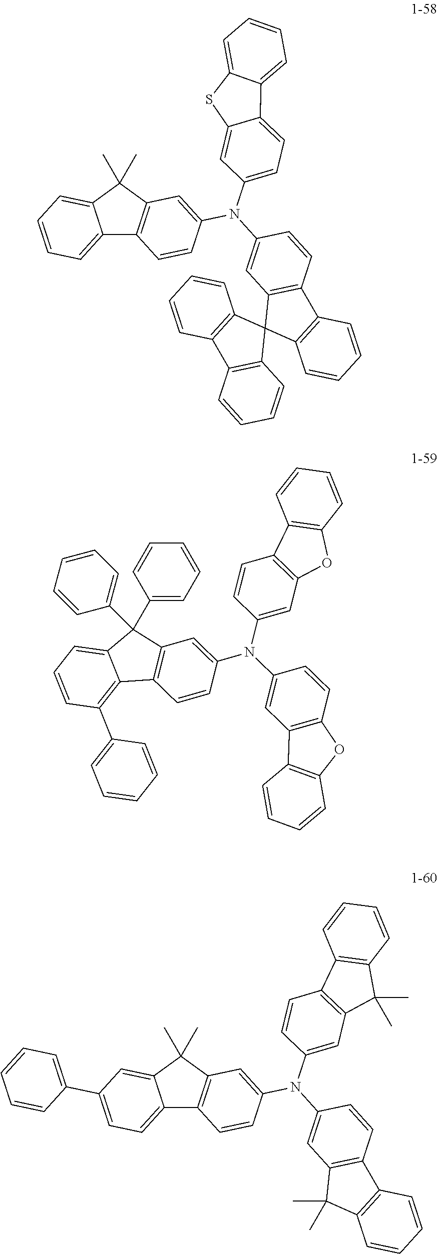 [SMILES: CC1(C)c2ccccc2-c2ccc(N(c3ccc4c(c3)C3(c5ccccc5-c5ccccc53)c3ccccc3-4)c3ccc4c(c3)sc3ccccc34)cc21 ; c1ccc(-c2cccc3c2-c2ccc(N(c4ccc5c(c4)oc4ccccc45)c4ccc5oc6ccccc6c5c4)cc2C3(c2ccccc2)c2ccccc2)cc1 ; CC1(C)c2ccccc2-c2ccc(N(c3ccc4c(c3)C(C)(C)c3ccccc3-4)c3ccc4c(c3)C(C)(C)c3cc(-c5ccccc5)ccc3-4)cc21]

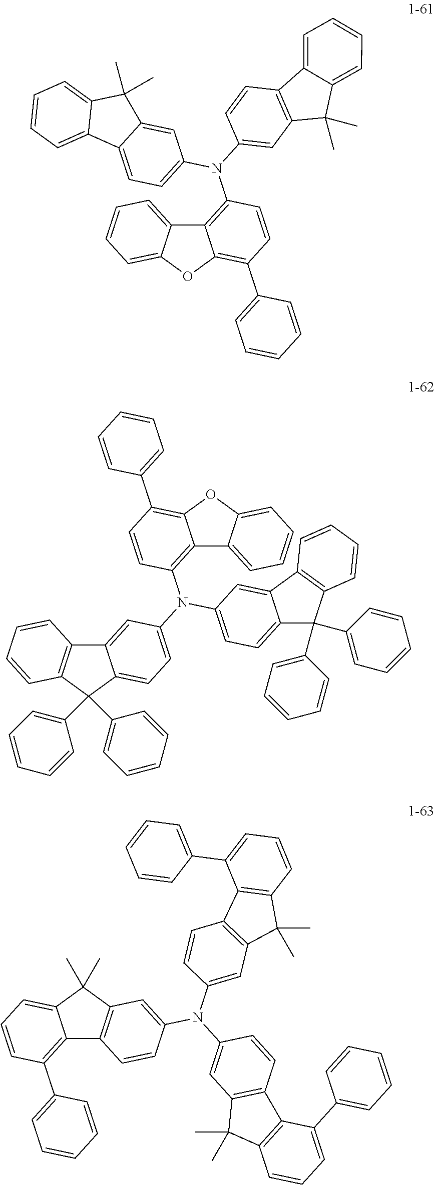 [SMILES: CC1(C)c2ccccc2-c2ccc(N(c3ccc4c(c3)C(C)(C)c3ccccc3-4)c3ccc(-c4ccccc4)c4oc5ccccc5c34)cc21 ; c1ccc(-c2ccc(N(c3ccc4c(c3)-c3ccccc3C4(c3ccccc3)c3ccccc3)c3ccc4c(c3)-c3ccccc3C4(c3ccccc3)c3ccccc3)c3c2oc2ccccc23)cc1 ; CC1(C)c2cc(N(c3ccc4c(c3)C(C)(C)c3cccc(-c5ccccc5)c3-4)c3ccc4c(c3)C(C)(C)c3cccc(-c5ccccc5)c3-4)ccc2-c2c(-c3ccccc3)cccc21]

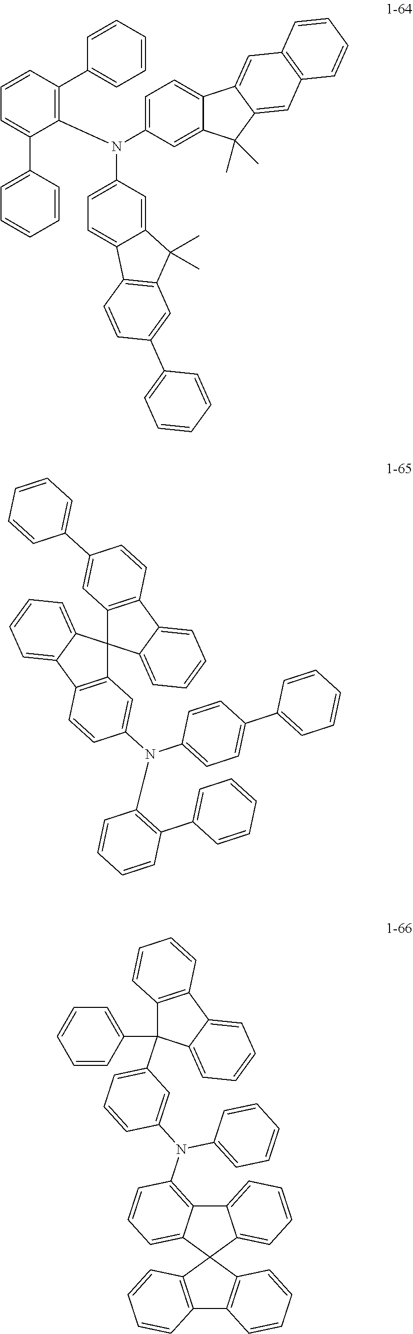 [SMILES: CC1(C)c2cc(-c3ccccc3)ccc2-c2ccc(N(c3ccc4c(c3)C(C)(C)c3cc5ccccc5cc3-4)c3c(-c4ccccc4)cccc3-c3ccccc3)cc21 ; c1ccc(-c2ccc(N(c3ccc4c(c3)C3(c5ccccc5-c5ccc(-c6ccccc6)cc53)c3ccccc3-4)c3ccccc3-c3ccccc3)cc2)cc1 ; c1ccc(N(c2cccc(C3(c4ccccc4)c4ccccc4-c4ccccc43)c2)c2cccc3c2-c2ccccc2C32c3ccccc3-c3ccccc32)cc1]

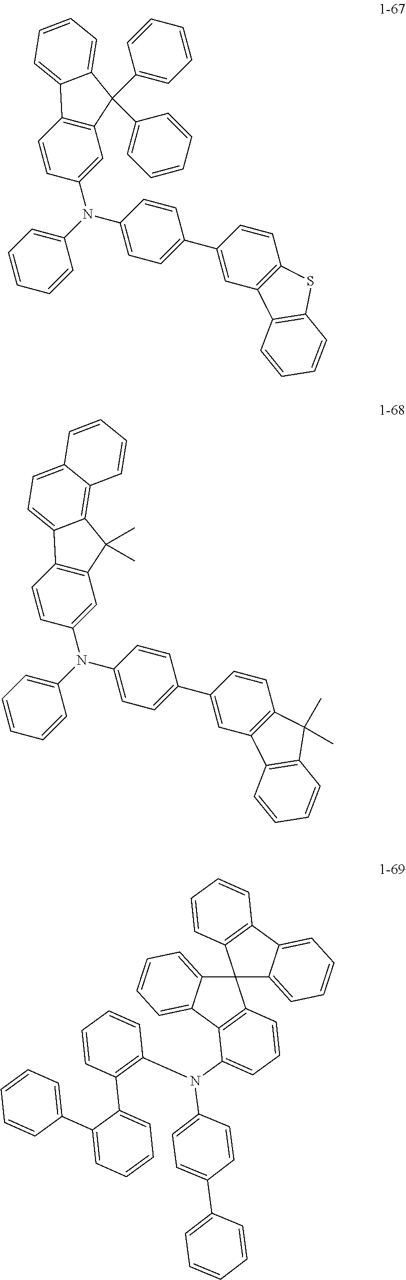 [SMILES: c1ccc(N(c2ccc(-c3ccc4sc5ccccc5c4c3)cc2)c2ccc3c(c2)C(c2ccccc2)(c2ccccc2)c2ccccc2-3)cc1 ; CC1(C)c2ccccc2-c2cc(-c3ccc(N(c4ccccc4)c4ccc5c(c4)C(C)(C)c4c-5ccc5ccccc45)cc3)ccc21 ; c1ccc(-c2ccc(N(c3ccccc3-c3ccccc3-c3ccccc3)c3cccc4c3-c3ccccc3C43c4ccccc4-c4ccccc43)cc2)cc1]

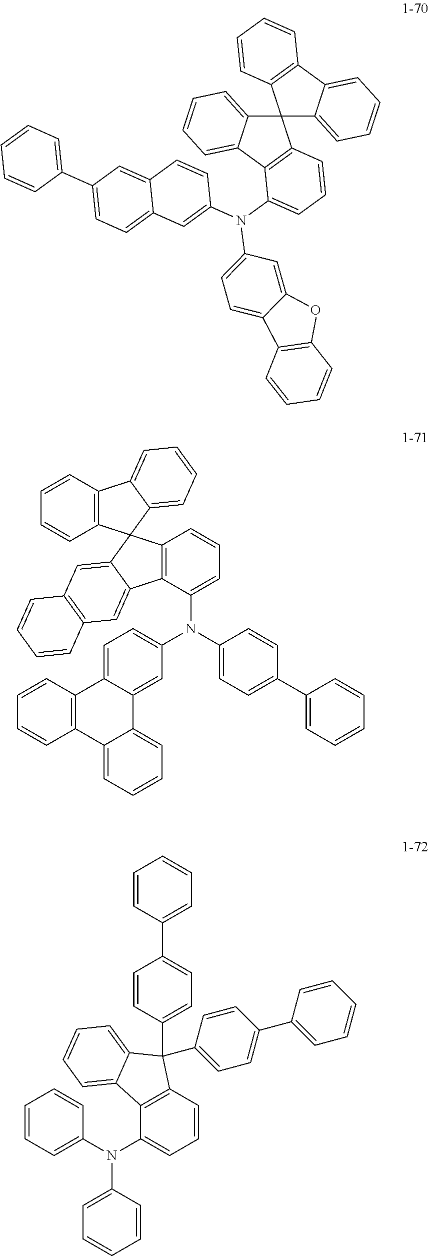 [SMILES: c1ccc(-c2ccc3cc(N(c4ccc5c(c4)oc4ccccc45)c4cccc5c4-c4ccccc4C54c5ccccc5-c5ccccc54)ccc3c2)cc1 ; c1ccc(-c2ccc(N(c3ccc4c5ccccc5c5ccccc5c4c3)c3cccc4c3-c3cc5ccccc5cc3C43c4ccccc4-c4ccccc43)cc2)cc1 ; c1ccc(-c2ccc(C3(c4ccc(-c5ccccc5)cc4)c4ccccc4-c4c(N(c5ccccc5)c5ccccc5)cccc43)cc2)cc1]

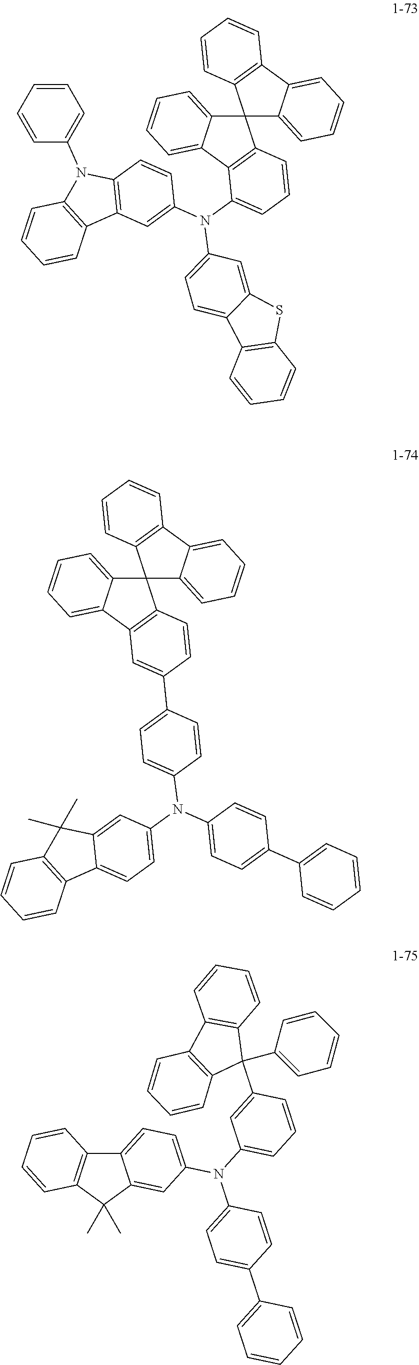 [SMILES: c1ccc(-n2c3ccccc3c3cc(N(c4ccc5c(c4)sc4ccccc45)c4cccc5c4-c4ccccc4C54c5ccccc5-c5ccccc54)ccc32)cc1 ; CC1(C)c2ccccc2-c2ccc(N(c3ccc(-c4ccccc4)cc3)c3ccc(-c4ccc5c(c4)-c4ccccc4C54c5ccccc5-c5ccccc54)cc3)cc21 ; CC1(C)c2ccccc2-c2ccc(N(c3ccc(-c4ccccc4)cc3)c3cccc(C4(c5ccccc5)c5ccccc5-c5ccccc54)c3)cc21]

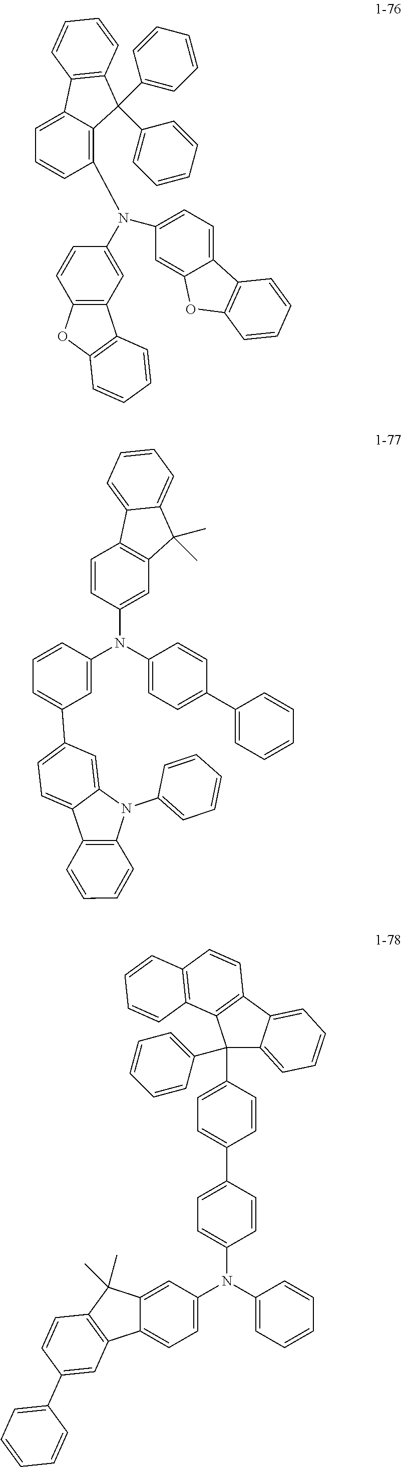 [SMILES: c1ccc(C2(c3ccccc3)c3ccccc3-c3cccc(N(c4ccc5c(c4)oc4ccccc45)c4ccc5oc6ccccc6c5c4)c32)cc1 ; CC1(C)c2ccccc2-c2ccc(N(c3ccc(-c4ccccc4)cc3)c3cccc(-c4ccc5c6ccccc6n(-c6ccccc6)c5c4)c3)cc21 ; CC1(C)c2ccc(-c3ccccc3)cc2-c2ccc(N(c3ccccc3)c3ccc(-c4ccc(C5(c6ccccc6)c6ccccc6-c6ccc7ccccc7c65)cc4)cc3)cc21]

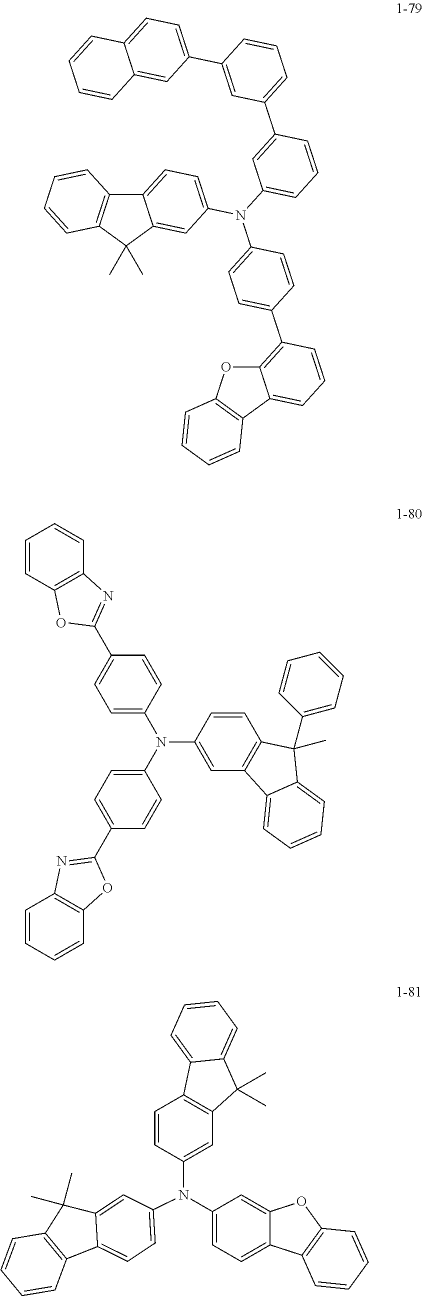 [SMILES: CC1(C)c2ccccc2-c2ccc(N(c3ccc(-c4cccc5c4oc4ccccc45)cc3)c3cccc(-c4cccc(-c5ccc6ccccc6c5)c4)c3)cc21 ; CC1(c2ccccc2)c2ccccc2-c2cc(N(c3ccc(-c4nc5ccccc5o4)cc3)c3ccc(-c4nc5ccccc5o4)cc3)ccc21 ; CC1(C)c2ccccc2-c2ccc(N(c3ccc4c(c3)C(C)(C)c3ccccc3-4)c3ccc4c(c3)oc3ccccc34)cc21]

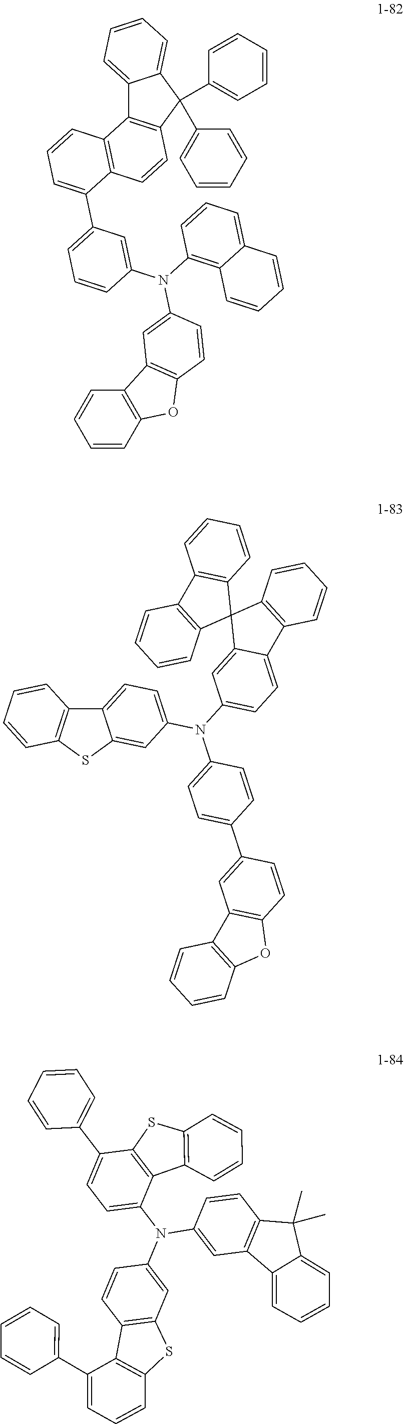 [SMILES: c1ccc(C2(c3ccccc3)c3ccccc3-c3c2ccc2c(-c4cccc(N(c5ccc6oc7ccccc7c6c5)c5cccc6ccccc56)c4)cccc32)cc1 ; c1ccc2c(c1)-c1ccccc1C21c2ccccc2-c2ccc(N(c3ccc(-c4ccc5oc6ccccc6c5c4)cc3)c3ccc4c(c3)sc3ccccc34)cc21 ; CC1(C)c2ccccc2-c2cc(N(c3ccc4c(c3)sc3cccc(-c5ccccc5)c34)c3ccc(-c4ccccc4)c4sc5ccccc5c34)ccc21]

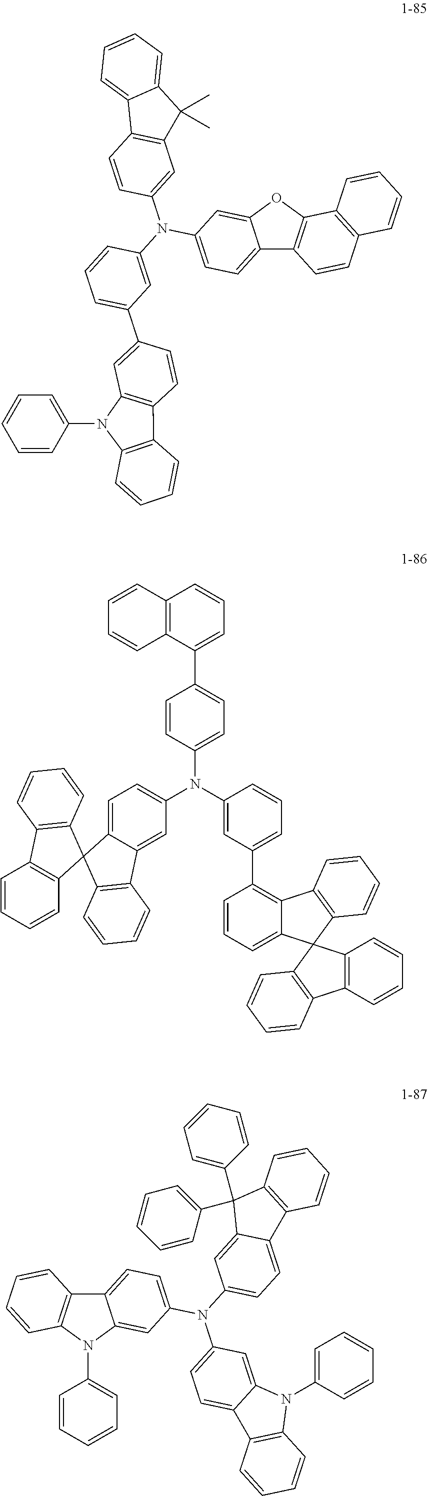 [SMILES: CC1(C)c2ccccc2-c2ccc(N(c3cccc(-c4ccc5c6ccccc6n(-c6ccccc6)c5c4)c3)c3ccc4c(c3)oc3c5ccccc5ccc43)cc21 ; c1cc(-c2cccc3c2-c2ccccc2C32c3ccccc3-c3ccccc32)cc(N(c2ccc(-c3cccc4ccccc34)cc2)c2ccc3c(c2)-c2ccccc2C32c3ccccc3-c3ccccc32)c1 ; c1ccc(-n2c3ccccc3c3ccc(N(c4ccc5c(c4)C(c4ccccc4)(c4ccccc4)c4ccccc4-5)c4ccc5c6ccccc6n(-c6ccccc6)c5c4)cc32)cc1]

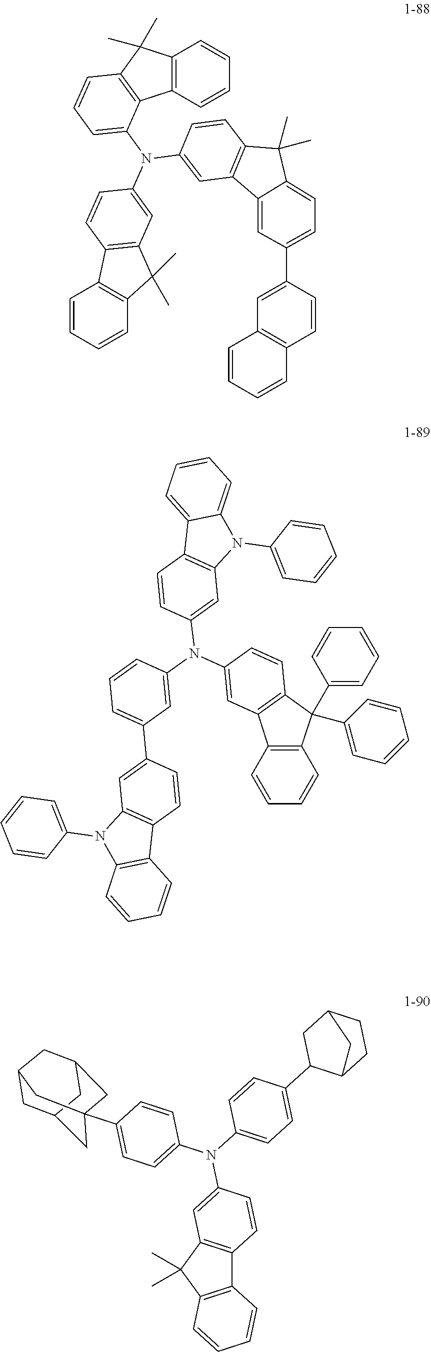 [SMILES: CC1(C)c2ccc(-c3ccc4ccccc4c3)cc2-c2cc(N(c3ccc4c(c3)C(C)(C)c3ccccc3-4)c3cccc4c3-c3ccccc3C4(C)C)ccc21 ; c1ccc(-n2c3ccccc3c3ccc(-c4cccc(N(c5ccc6c(c5)-c5ccccc5C6(c5ccccc5)c5ccccc5)c5ccc6c7ccccc7n(-c7ccccc7)c6c5)c4)cc32)cc1 ; CC1(C)c2ccccc2-c2ccc(N(c3ccc(C4CC5CCC4C5)cc3)c3ccc(C45CC6CC(CC(C6)C4)C5)cc3)cc21]

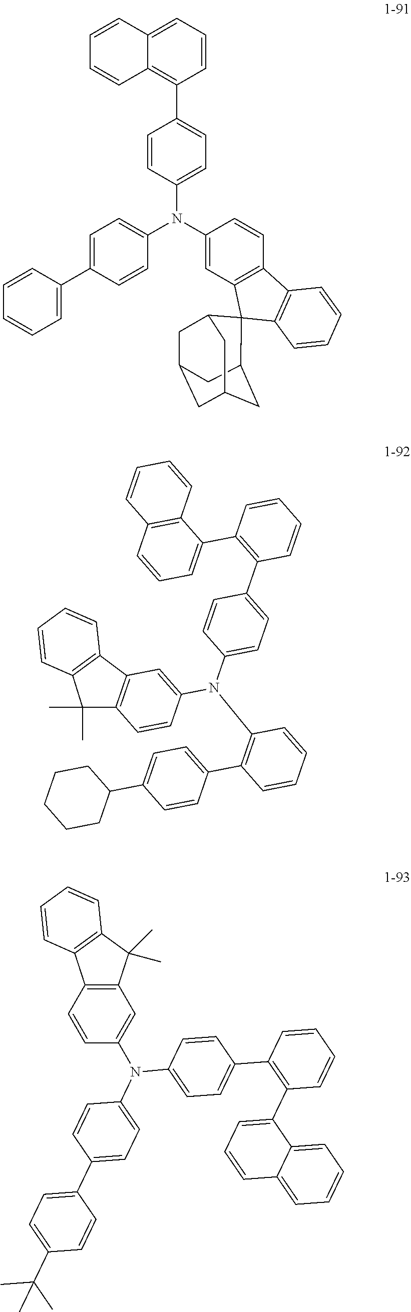 [SMILES: c1ccc(-c2ccc(N(c3ccc(-c4cccc5ccccc45)cc3)c3ccc4c(c3)C3(c5ccccc5-4)C4CC5CC(C4)CC3C5)cc2)cc1 ; CC1(C)c2ccccc2-c2cc(N(c3ccc(-c4ccccc4-c4cccc5ccccc45)cc3)c3ccccc3-c3ccc(C4CCCCC4)cc3)ccc21 ; CC(C)(C)c1ccc(-c2ccc(N(c3ccc(-c4ccccc4-c4cccc5ccccc45)cc3)c3ccc4c(c3)C(C)(C)c3ccccc3-4)cc2)cc1]

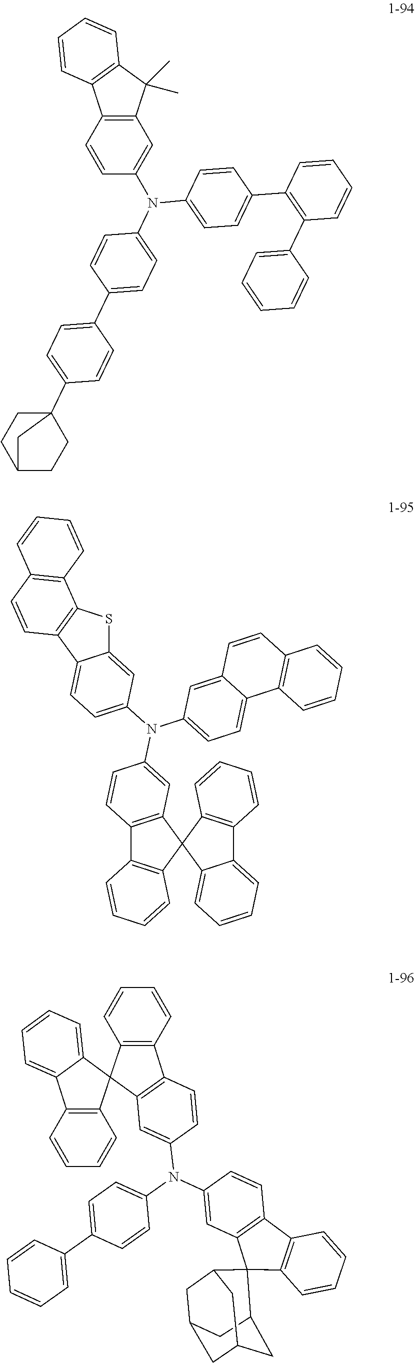 [SMILES: CC1(C)c2ccccc2-c2ccc(N(c3ccc(-c4ccc(C56CCC(CC5)C6)cc4)cc3)c3ccc(-c4ccccc4-c4ccccc4)cc3)cc21 ; c1ccc2c(c1)-c1ccccc1C21c2ccccc2-c2ccc(N(c3ccc4c(ccc5ccccc54)c3)c3ccc4c(c3)sc3c5ccccc5ccc43)cc21 ; c1ccc(-c2ccc(N(c3ccc4c(c3)C3(c5ccccc5-c5ccccc53)c3ccccc3-4)c3ccc4c(c3)C3(c5ccccc5-4)C4CC5CC(C4)CC3C5)cc2)cc1]

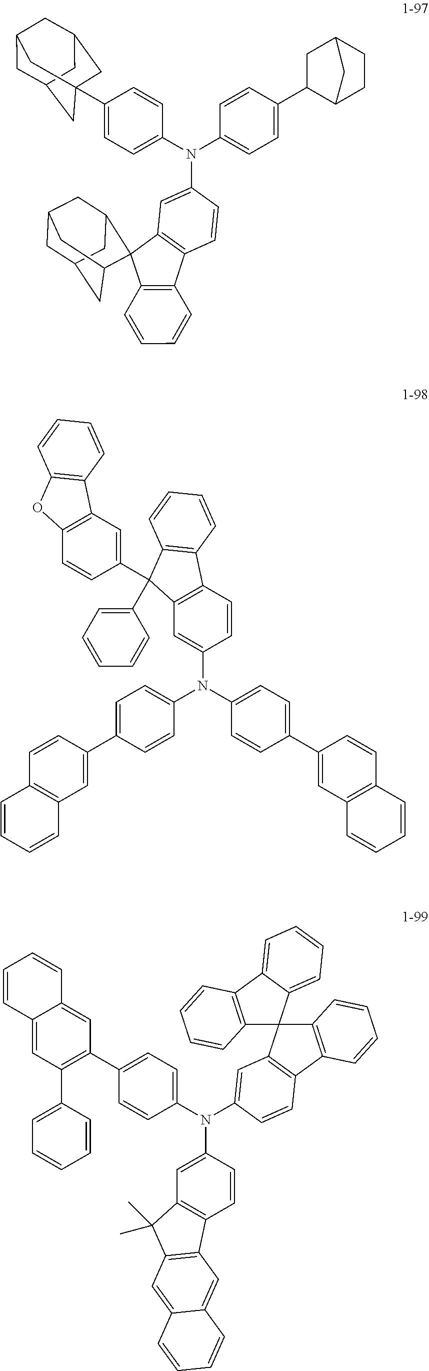 [SMILES: c1ccc2c(c1)-c1ccc(N(c3ccc(C4CC5CCC4C5)cc3)c3ccc(C45CC6CC(CC(C6)C4)C5)cc3)cc1C21C2CC3CC(C2)CC1C3 ; c1ccc(C2(c3ccc4oc5ccccc5c4c3)c3ccccc3-c3ccc(N(c4ccc(-c5ccc6ccccc6c5)cc4)c4ccc(-c5ccc6ccccc6c5)cc4)cc32)cc1 ; CC1(C)c2cc(N(c3ccc(-c4cc5ccccc5cc4-c4ccccc4)cc3)c3ccc4c(c3)C3(c5ccccc5-c5ccccc53)c3ccccc3-4)ccc2-c2cc3ccccc3cc21]

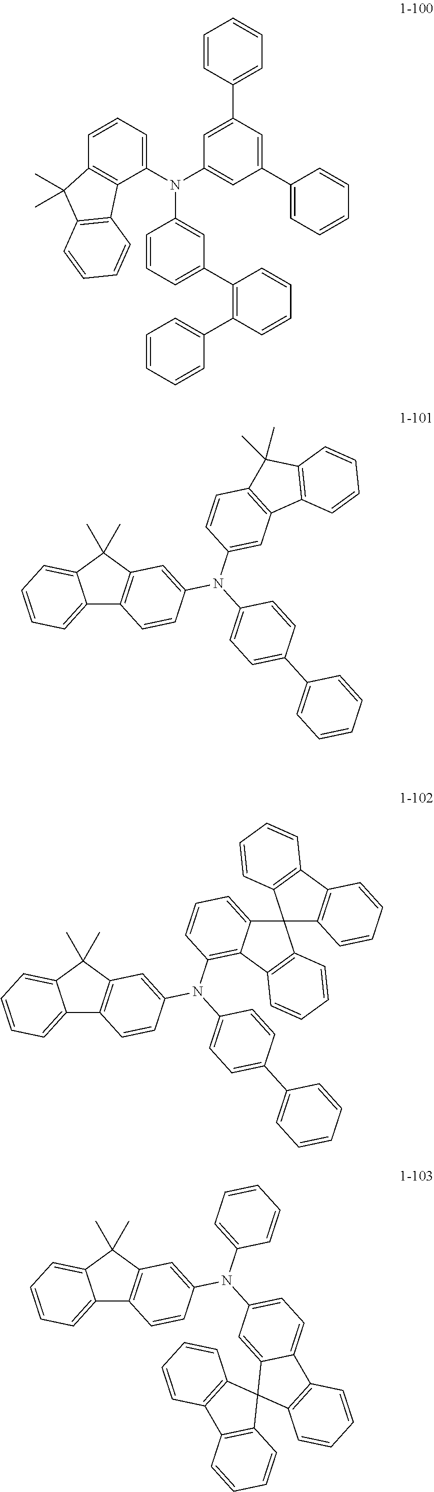 [SMILES: CC1(C)c2ccccc2-c2c(N(c3cc(-c4ccccc4)cc(-c4ccccc4)c3)c3cccc(-c4ccccc4-c4ccccc4)c3)cccc21 ; CC1(C)c2ccccc2-c2cc(N(c3ccc(-c4ccccc4)cc3)c3ccc4c(c3)C(C)(C)c3ccccc3-4)ccc21 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccccc3)c3ccc4c(c3)C3(c5ccccc5-c5ccccc53)c3ccccc3-4)cc21]

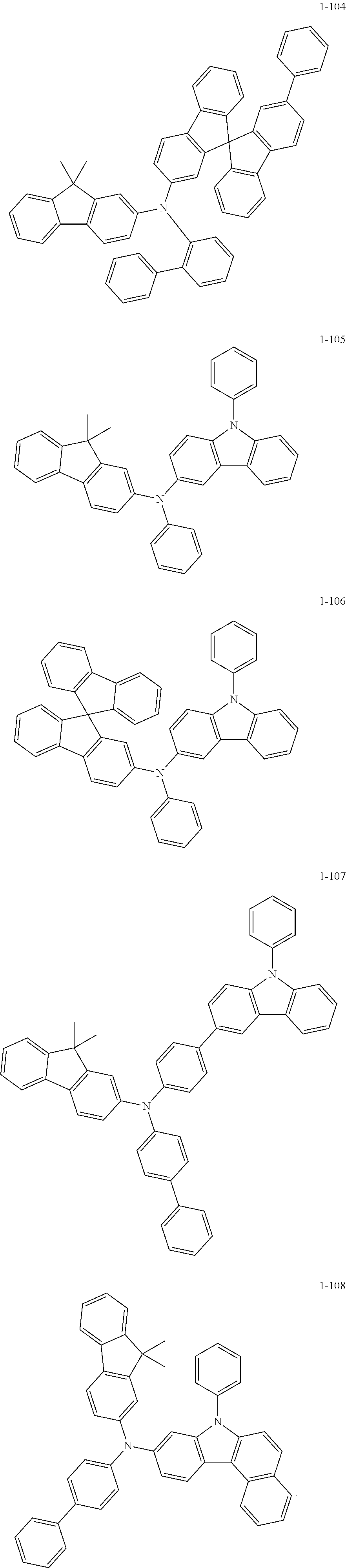 [SMILES: CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21 ; CC1(C)c2ccccc2-c2ccc(N(c3ccccc3)c3ccc4c(c3)c3ccccc3n4-c3ccccc3)cc21 ; c1ccc(N(c2ccc3c(c2)C2(c4ccccc4-c4ccccc42)c2ccccc2-3)c2ccc3c(c2)c2ccccc2n3-c2ccccc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c5c6ccccc6ccc5n(-c5ccccc5)c4c3)cc21]

Specifically, compound represented by Formula 2 may be one of the following compounds, but there is no limitation thereto.

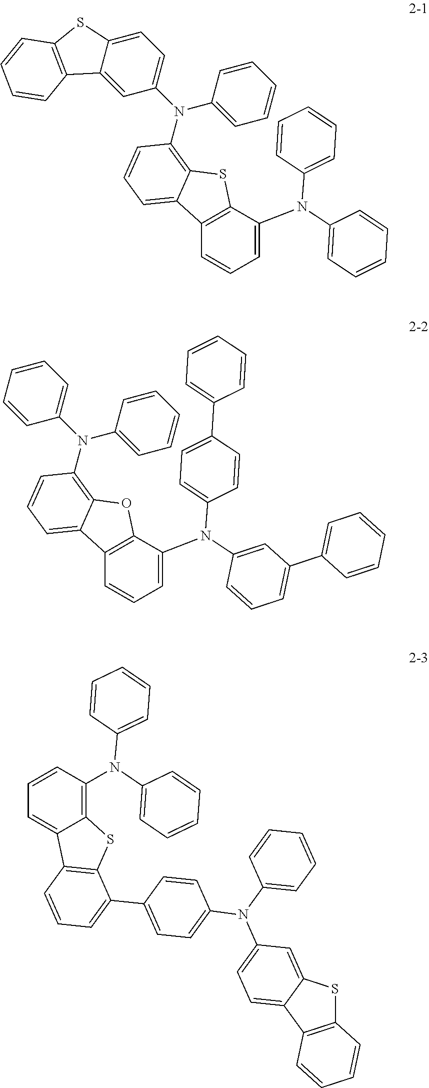 [SMILES: c1ccc(N(c2ccccc2)c2cccc3c2sc2c(N(c4ccccc4)c4ccc5sc6ccccc6c5c4)cccc23)cc1 ; c1ccc(-c2ccc(N(c3cccc(-c4ccccc4)c3)c3cccc4c3oc3c(N(c5ccccc5)c5ccccc5)cccc34)cc2)cc1 ; c1ccc(N(c2ccc(-c3cccc4c3sc3c(N(c5ccccc5)c5ccccc5)cccc34)cc2)c2ccc3c(c2)sc2ccccc23)cc1]

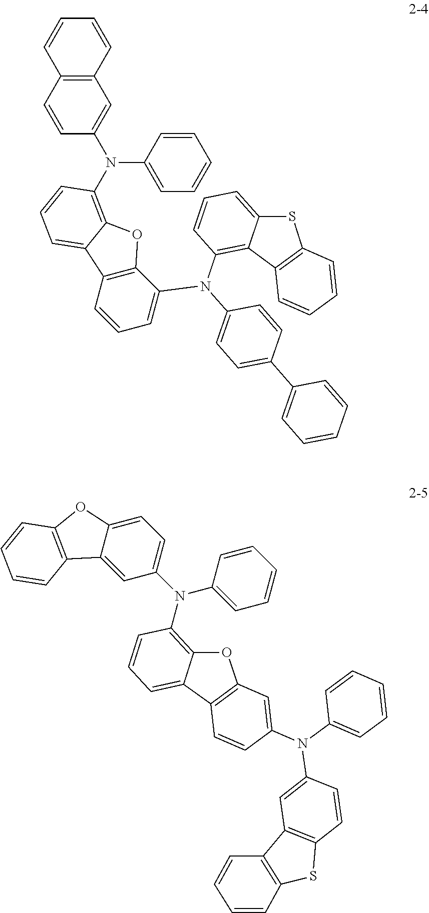 [SMILES: c1ccc(-c2ccc(N(c3cccc4c3oc3c(N(c5ccccc5)c5ccc6ccccc6c5)cccc34)c3cccc4sc5ccccc5c34)cc2)cc1 ; c1ccc(N(c2ccc3c(c2)oc2c(N(c4ccccc4)c4ccc5oc6ccccc6c5c4)cccc23)c2ccc3sc4ccccc4c3c2)cc1]

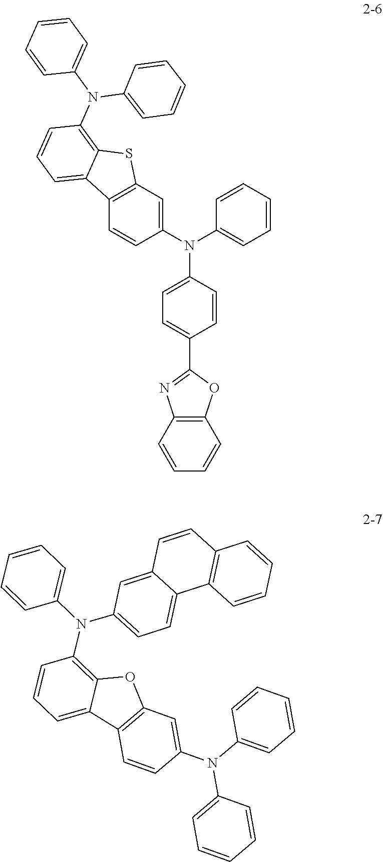 [SMILES: c1ccc(N(c2ccc(-c3nc4ccccc4o3)cc2)c2ccc3c(c2)sc2c(N(c4ccccc4)c4ccccc4)cccc23)cc1 ; c1ccc(N(c2ccccc2)c2ccc3c(c2)oc2c(N(c4ccccc4)c4ccc5c(ccc6ccccc65)c4)cccc23)cc1]

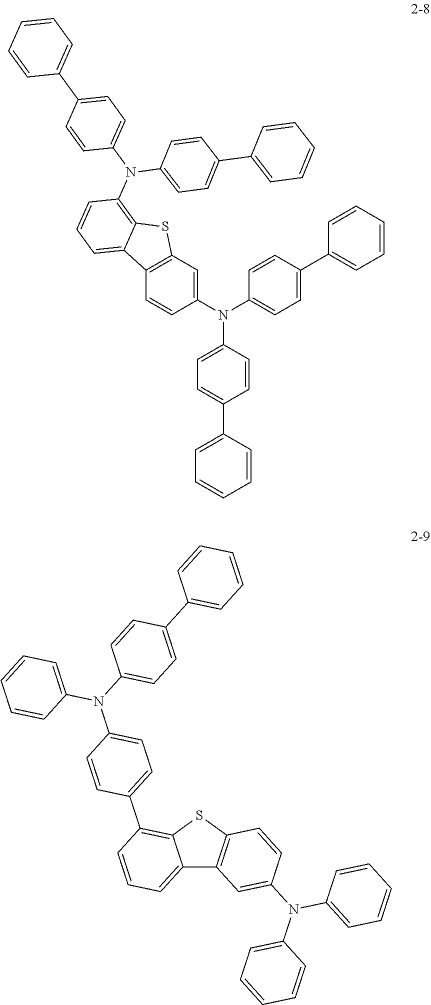 [SMILES: c1ccc(-c2ccc(N(c3ccc(-c4ccccc4)cc3)c3ccc4c(c3)sc3c(N(c5ccc(-c6ccccc6)cc5)c5ccc(-c6ccccc6)cc5)cccc34)cc2)cc1 ; c1ccc(-c2ccc(N(c3ccccc3)c3ccc(-c4cccc5c4sc4ccc(N(c6ccccc6)c6ccccc6)cc45)cc3)cc2)cc1]

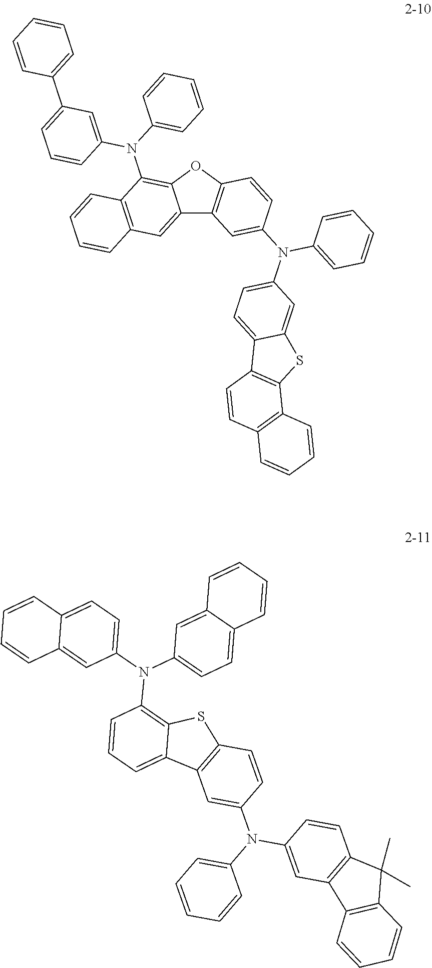 [SMILES: c1ccc(-c2cccc(N(c3ccccc3)c3c4ccccc4cc4c3oc3ccc(N(c5ccccc5)c5ccc6c(c5)sc5c7ccccc7ccc65)cc34)c2)cc1 ; CC1(C)c2ccccc2-c2cc(N(c3ccccc3)c3ccc4sc5c(N(c6ccc7ccccc7c6)c6ccc7ccccc7c6)cccc5c4c3)ccc21]

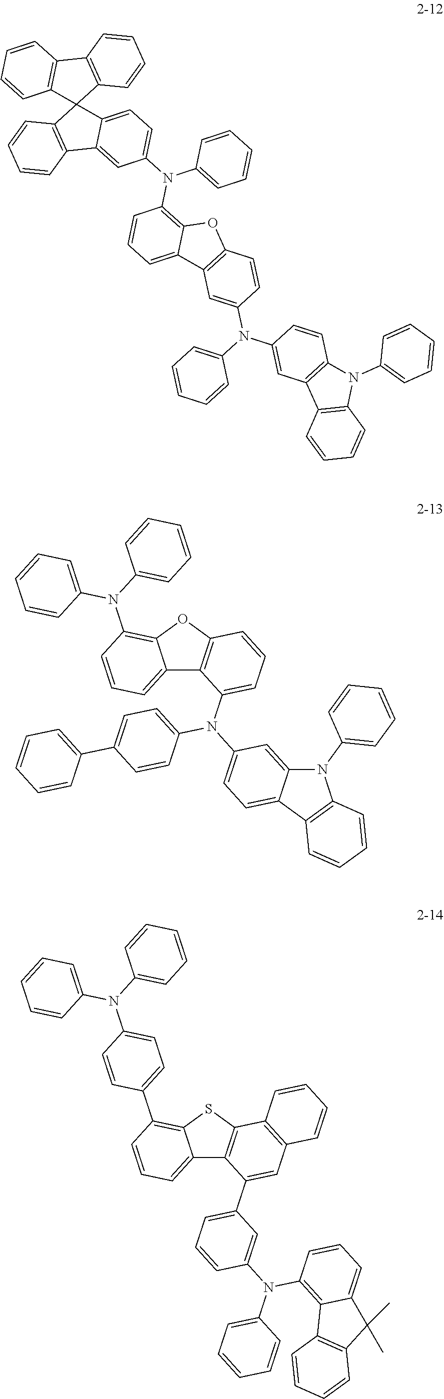 [SMILES: c1ccc(N(c2ccc3oc4c(N(c5ccccc5)c5ccc6c(c5)-c5ccccc5C65c6ccccc6-c6ccccc65)cccc4c3c2)c2ccc3c(c2)c2ccccc2n3-c2ccccc2)cc1 ; c1ccc(-c2ccc(N(c3ccc4c5ccccc5n(-c5ccccc5)c4c3)c3cccc4oc5c(N(c6ccccc6)c6ccccc6)cccc5c34)cc2)cc1 ; CC1(C)c2ccccc2-c2c(N(c3ccccc3)c3cccc(-c4cc5ccccc5c5sc6c(-c7ccc(N(c8ccccc8)c8ccccc8)cc7)cccc6c45)c3)cccc21]

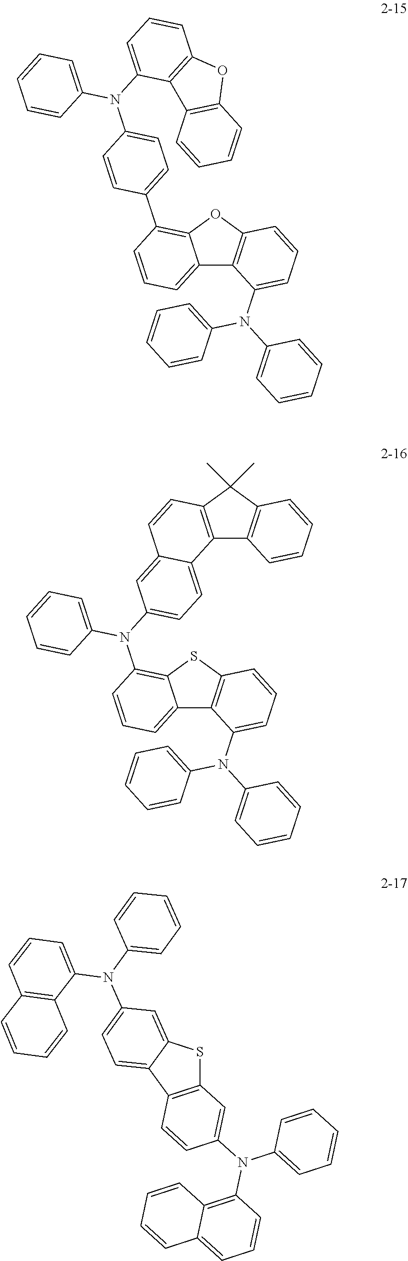 [SMILES: c1ccc(N(c2ccc(-c3cccc4c3oc3cccc(N(c5ccccc5)c5ccccc5)c34)cc2)c2cccc3oc4ccccc4c23)cc1 ; CC1(C)c2ccccc2-c2c1ccc1cc(N(c3ccccc3)c3cccc4c3sc3cccc(N(c5ccccc5)c5ccccc5)c34)ccc21 ; c1ccc(N(c2ccc3c(c2)sc2cc(N(c4ccccc4)c4cccc5ccccc45)ccc23)c2cccc3ccccc23)cc1]

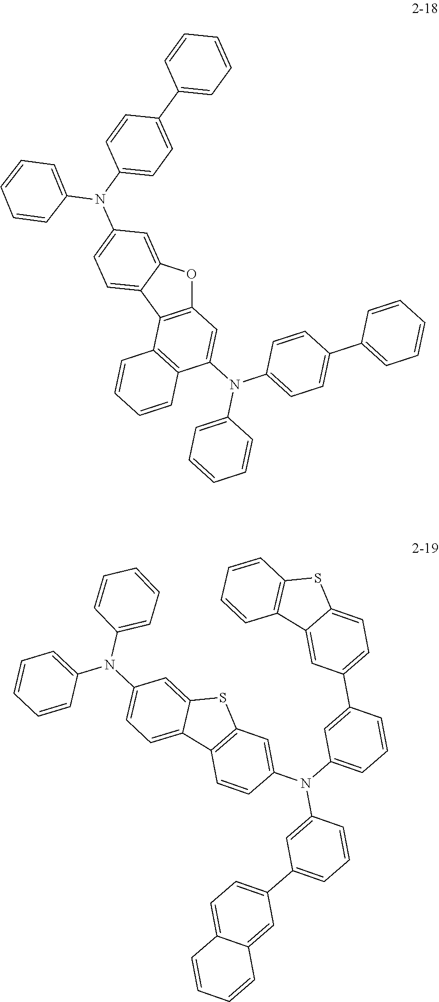 [SMILES: c1ccc(-c2ccc(N(c3ccccc3)c3ccc4c(c3)oc3cc(N(c5ccccc5)c5ccc(-c6ccccc6)cc5)c5ccccc5c34)cc2)cc1 ; c1ccc(N(c2ccccc2)c2ccc3c(c2)sc2cc(N(c4cccc(-c5ccc6ccccc6c5)c4)c4cccc(-c5ccc6sc7ccccc7c6c5)c4)ccc23)cc1]

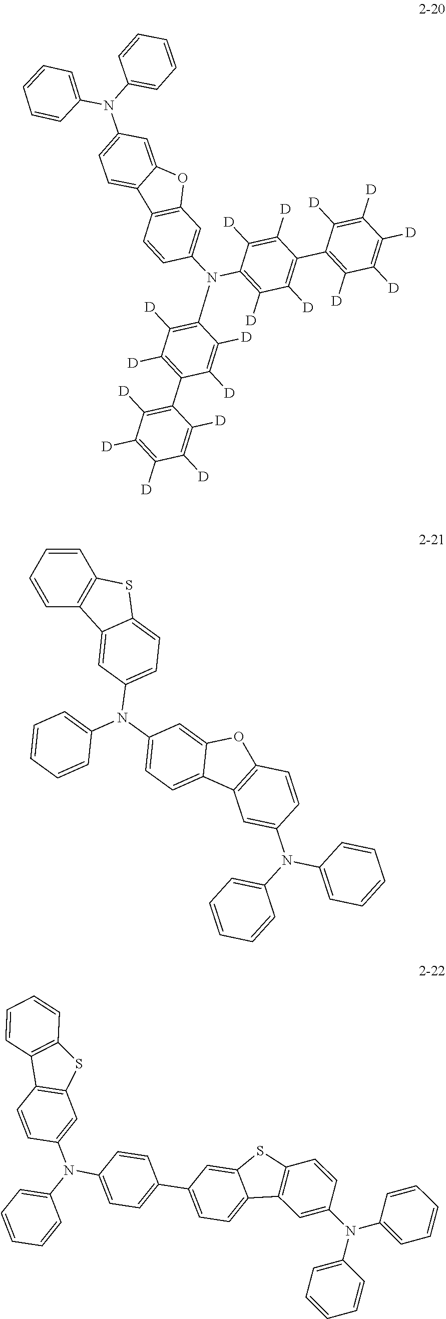 [SMILES: [2H]c1c([2H])c([2H])c(-c2c([2H])c([2H])c(N(c3ccc4c(c3)oc3cc(N(c5ccccc5)c5ccccc5)ccc34)c3c([2H])c([2H])c(-c4c([2H])c([2H])c([2H])c([2H])c4[2H])c([2H])c3[2H])c([2H])c2[2H])c([2H])c1[2H] ; c1ccc(N(c2ccccc2)c2ccc3oc4cc(N(c5ccccc5)c5ccc6sc7ccccc7c6c5)ccc4c3c2)cc1 ; c1ccc(N(c2ccc(-c3ccc4c(c3)sc3ccc(N(c5ccccc5)c5ccccc5)cc34)cc2)c2ccc3c(c2)sc2ccccc23)cc1]

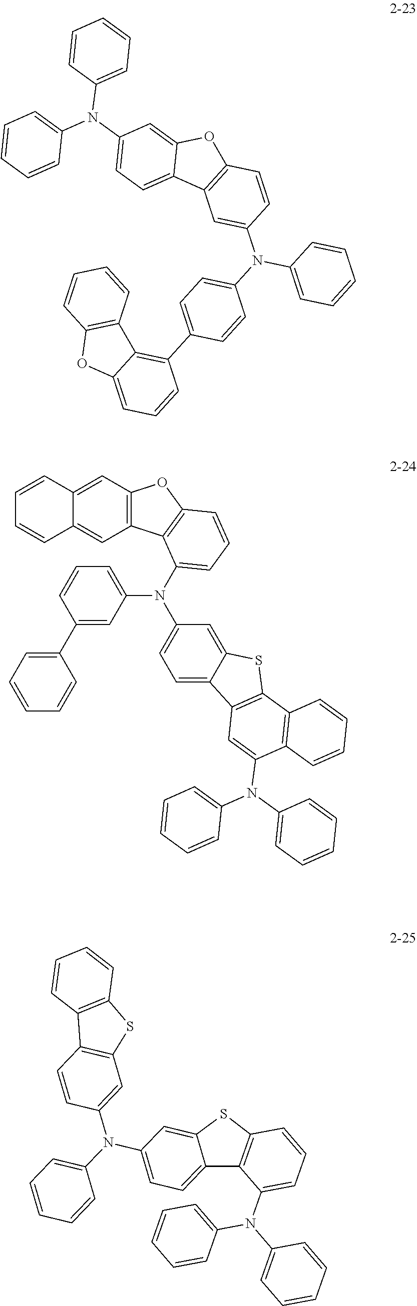 [SMILES: c1ccc(N(c2ccccc2)c2ccc3c(c2)oc2ccc(N(c4ccccc4)c4ccc(-c5cccc6oc7ccccc7c56)cc4)cc23)cc1 ; c1ccc(-c2cccc(N(c3ccc4c(c3)sc3c5ccccc5c(N(c5ccccc5)c5ccccc5)cc43)c3cccc4oc5cc6ccccc6cc5c34)c2)cc1 ; c1ccc(N(c2ccc3c(c2)sc2ccccc23)c2ccc3c(c2)sc2cccc(N(c4ccccc4)c4ccccc4)c23)cc1]

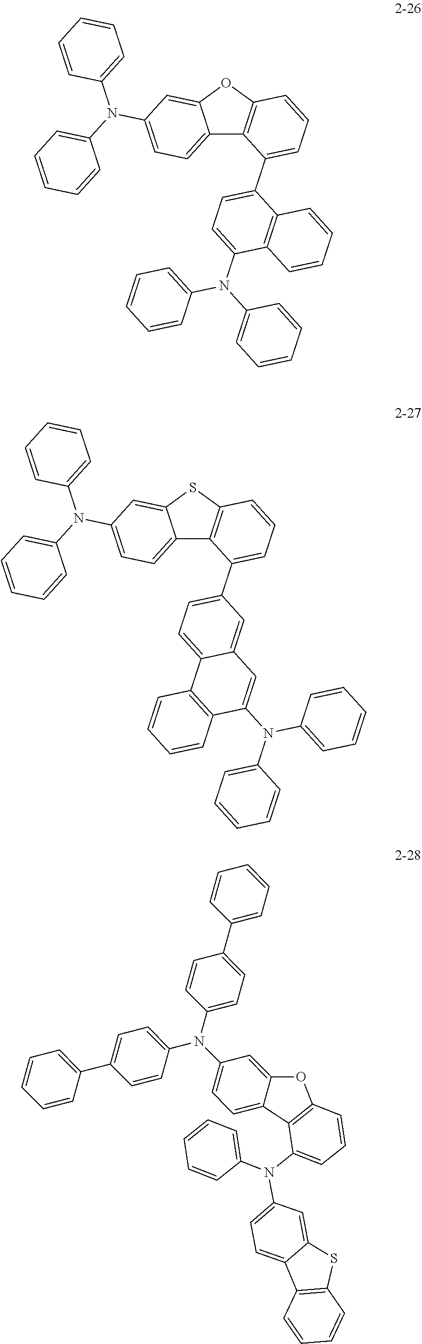

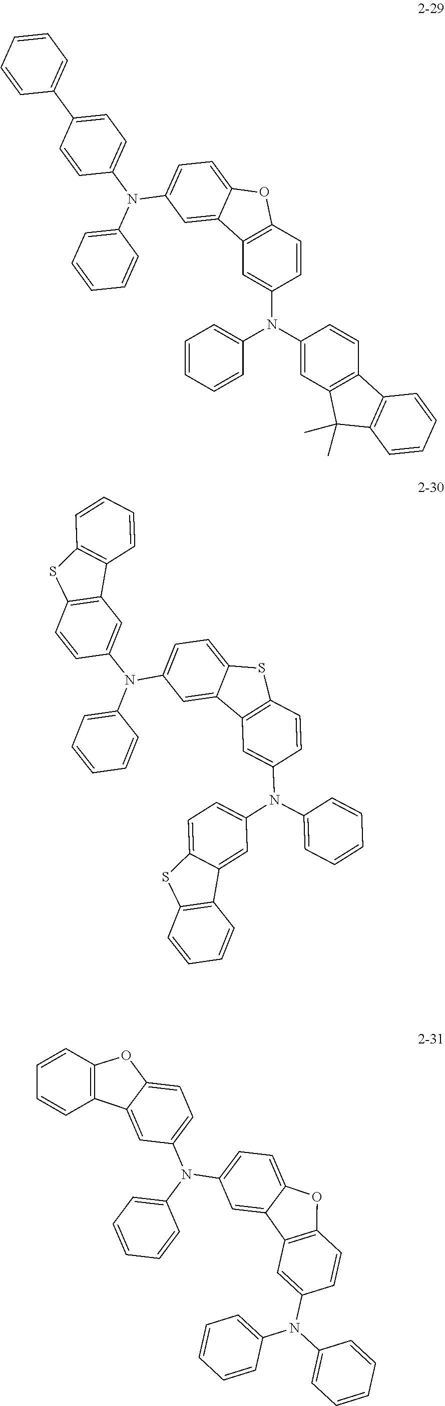 [SMILES: CC1(C)c2ccccc2-c2ccc(N(c3ccccc3)c3ccc4oc5ccc(N(c6ccccc6)c6ccc(-c7ccccc7)cc6)cc5c4c3)cc21 ; c1ccc(N(c2ccc3sc4ccccc4c3c2)c2ccc3sc4ccc(N(c5ccccc5)c5ccc6sc7ccccc7c6c5)cc4c3c2)cc1 ; c1ccc(N(c2ccccc2)c2ccc3oc4ccc(N(c5ccccc5)c5ccc6oc7ccccc7c6c5)cc4c3c2)cc1]

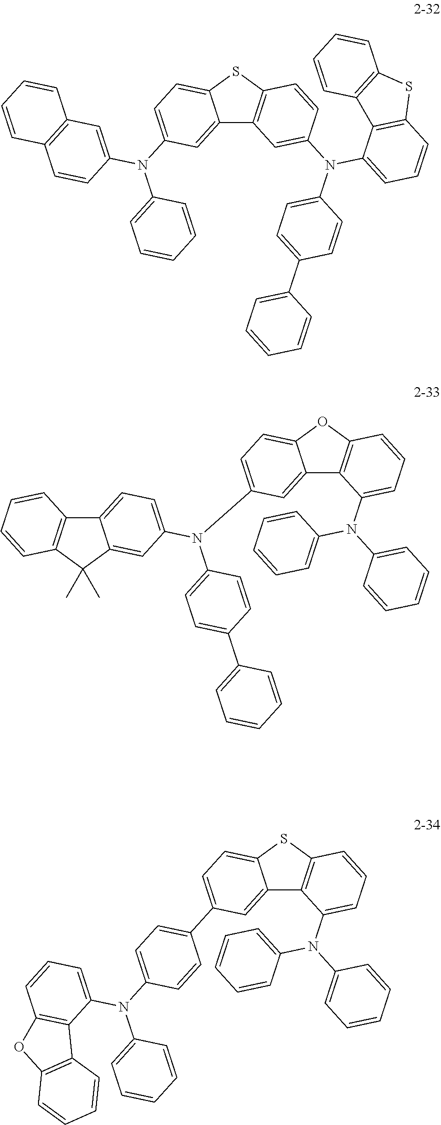 [SMILES: c1ccc(-c2ccc(N(c3ccc4sc5ccc(N(c6ccccc6)c6ccc7ccccc7c6)cc5c4c3)c3cccc4sc5ccccc5c34)cc2)cc1 ; CC1(C)c2ccccc2-c2ccc(N(c3ccc(-c4ccccc4)cc3)c3ccc4oc5cccc(N(c6ccccc6)c6ccccc6)c5c4c3)cc21 ; c1ccc(N(c2ccc(-c3ccc4sc5cccc(N(c6ccccc6)c6ccccc6)c5c4c3)cc2)c2cccc3oc4ccccc4c23)cc1]

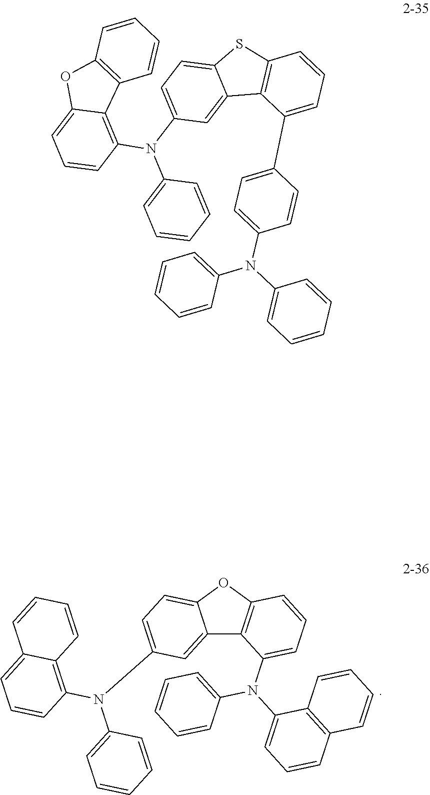 [SMILES: c1ccc(N(c2ccccc2)c2ccc(-c3cccc4sc5ccc(N(c6ccccc6)c6cccc7oc8ccccc8c67)cc5c34)cc2)cc1 ; c1ccc(N(c2ccc3oc4cccc(N(c5ccccc5)c5cccc6ccccc56)c4c3c2)c2cccc3ccccc23)cc1]

Specifically, compound represented by Formula 3 may be one of the following compounds, but there is no limitation thereto.

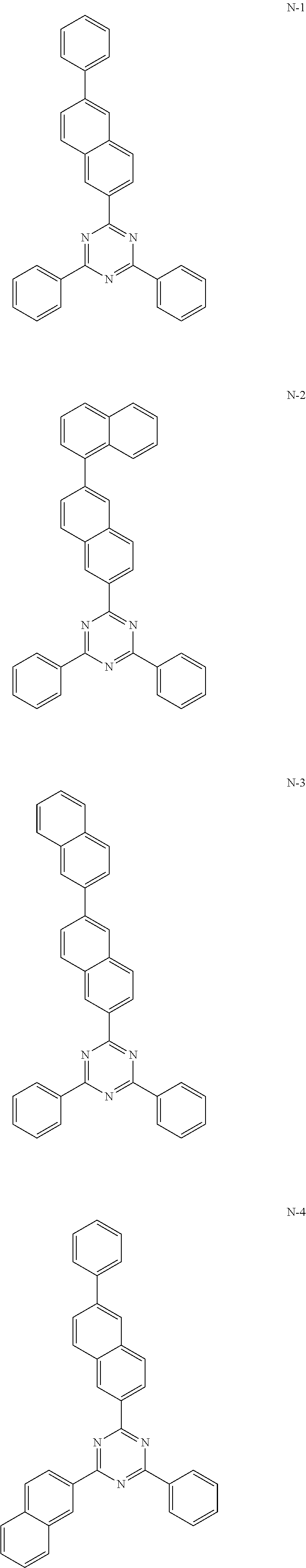 [SMILES: c1ccc(-c2ccc3cc(-c4nc(-c5ccccc5)nc(-c5ccccc5)n4)ccc3c2)cc1 ; c1ccc(-c2nc(-c3ccccc3)nc(-c3ccc4cc(-c5cccc6ccccc56)ccc4c3)n2)cc1 ; c1ccc(-c2nc(-c3ccccc3)nc(-c3ccc4cc(-c5ccc6ccccc6c5)ccc4c3)n2)cc1 ; c1ccc(-c2ccc3cc(-c4nc(-c5ccccc5)nc(-c5ccc6ccccc6c5)n4)ccc3c2)cc1]

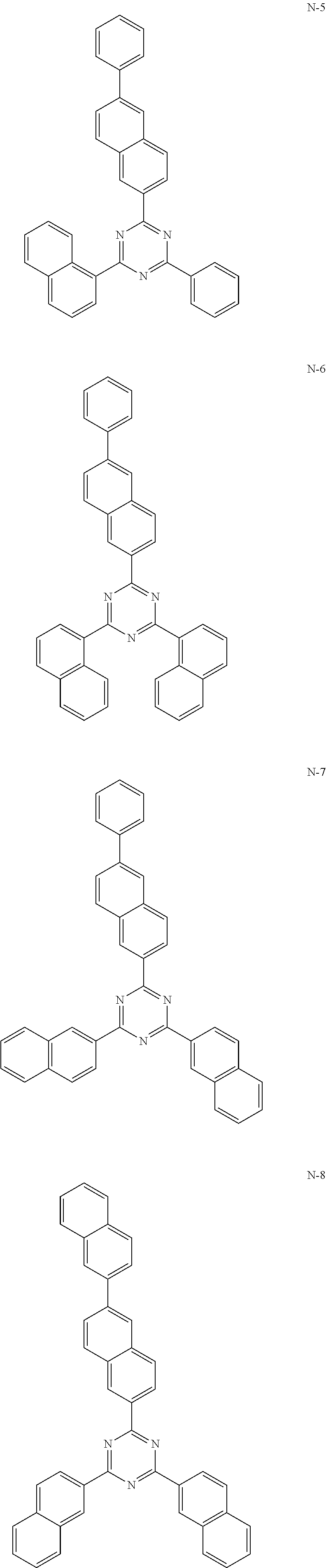 [SMILES: c1ccc(-c2ccc3cc(-c4nc(-c5ccccc5)nc(-c5cccc6ccccc56)n4)ccc3c2)cc1 ; c1ccc(-c2ccc3cc(-c4nc(-c5cccc6ccccc56)nc(-c5cccc6ccccc56)n4)ccc3c2)cc1 ; c1ccc(-c2ccc3cc(-c4nc(-c5ccc6ccccc6c5)nc(-c5ccc6ccccc6c5)n4)ccc3c2)cc1 ; c1ccc2cc(-c3ccc4cc(-c5nc(-c6ccc7ccccc7c6)nc(-c6ccc7ccccc7c6)n5)ccc4c3)ccc2c1]

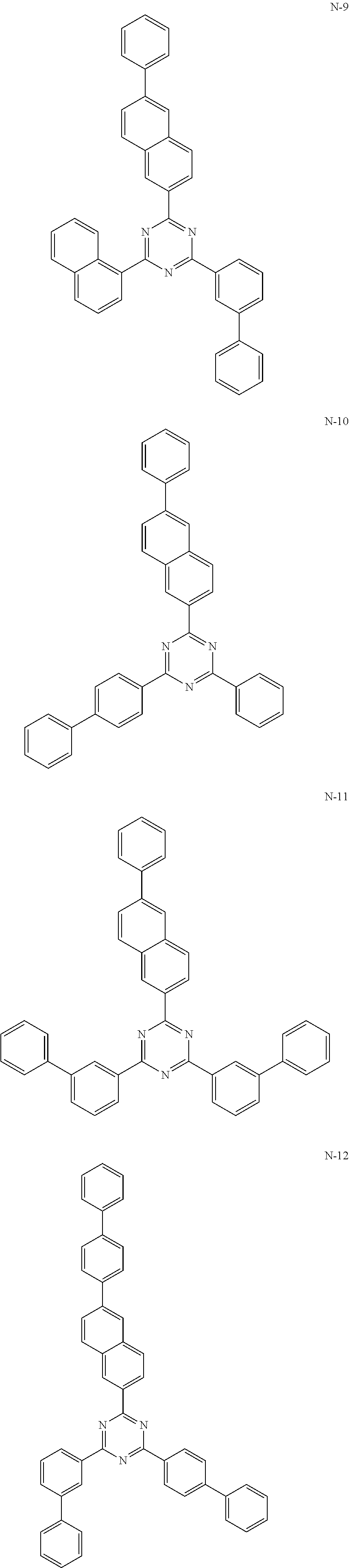 [SMILES: c1ccc(-c2cccc(-c3nc(-c4ccc5cc(-c6ccccc6)ccc5c4)nc(-c4cccc5ccccc45)n3)c2)cc1 ; c1ccc(-c2ccc(-c3nc(-c4ccccc4)nc(-c4ccc5cc(-c6ccccc6)ccc5c4)n3)cc2)cc1 ; c1ccc(-c2cccc(-c3nc(-c4cccc(-c5ccccc5)c4)nc(-c4ccc5cc(-c6ccccc6)ccc5c4)n3)c2)cc1 ; c1ccc(-c2ccc(-c3ccc4cc(-c5nc(-c6ccc(-c7ccccc7)cc6)nc(-c6cccc(-c7ccccc7)c6)n5)ccc4c3)cc2)cc1]

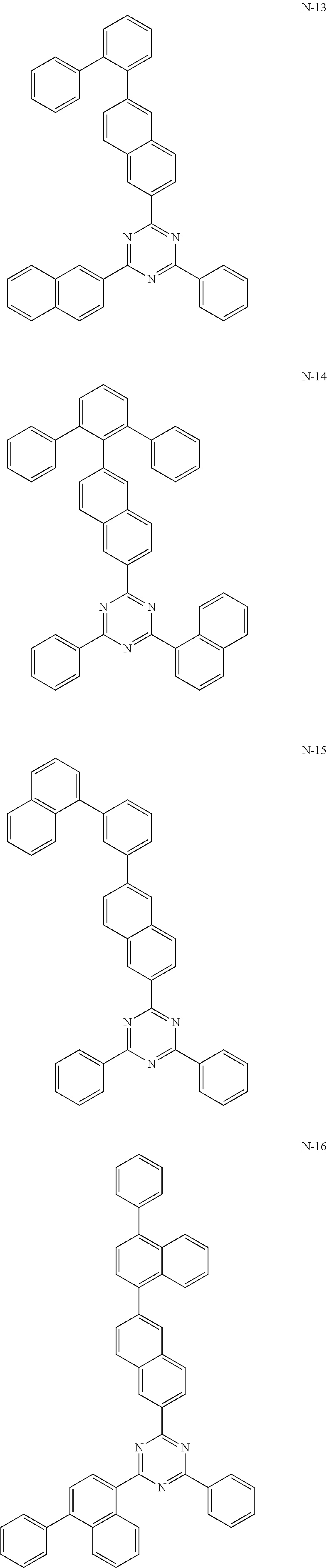 [SMILES: c1ccc(-c2nc(-c3ccc4ccccc4c3)nc(-c3ccc4cc(-c5ccccc5-c5ccccc5)ccc4c3)n2)cc1 ; c1ccc(-c2nc(-c3ccc4cc(-c5c(-c6ccccc6)cccc5-c5ccccc5)ccc4c3)nc(-c3cccc4ccccc34)n2)cc1 ; c1ccc(-c2nc(-c3ccccc3)nc(-c3ccc4cc(-c5cccc(-c6cccc7ccccc67)c5)ccc4c3)n2)cc1 ; c1ccc(-c2nc(-c3ccc4cc(-c5ccc(-c6ccccc6)c6ccccc56)ccc4c3)nc(-c3ccc(-c4ccccc4)c4ccccc34)n2)cc1]

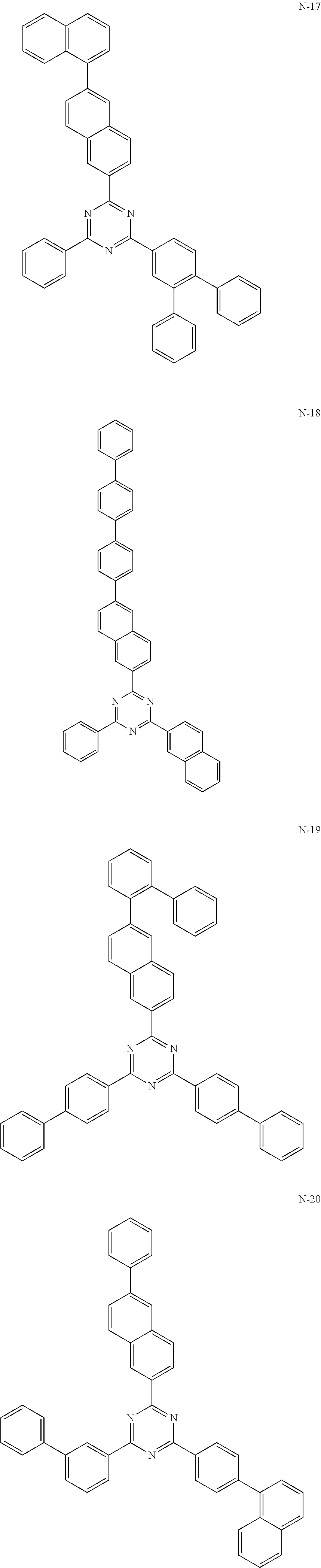 [SMILES: c1ccc(-c2nc(-c3ccc(-c4ccccc4)c(-c4ccccc4)c3)nc(-c3ccc4cc(-c5cccc6ccccc56)ccc4c3)n2)cc1 ; c1ccc(-c2ccc(-c3ccc(-c4ccc5cc(-c6nc(-c7ccccc7)nc(-c7ccc8ccccc8c7)n6)ccc5c4)cc3)cc2)cc1 ; c1ccc(-c2ccc(-c3nc(-c4ccc(-c5ccccc5)cc4)nc(-c4ccc5cc(-c6ccccc6-c6ccccc6)ccc5c4)n3)cc2)cc1 ; c1ccc(-c2cccc(-c3nc(-c4ccc(-c5cccc6ccccc56)cc4)nc(-c4ccc5cc(-c6ccccc6)ccc5c4)n3)c2)cc1]

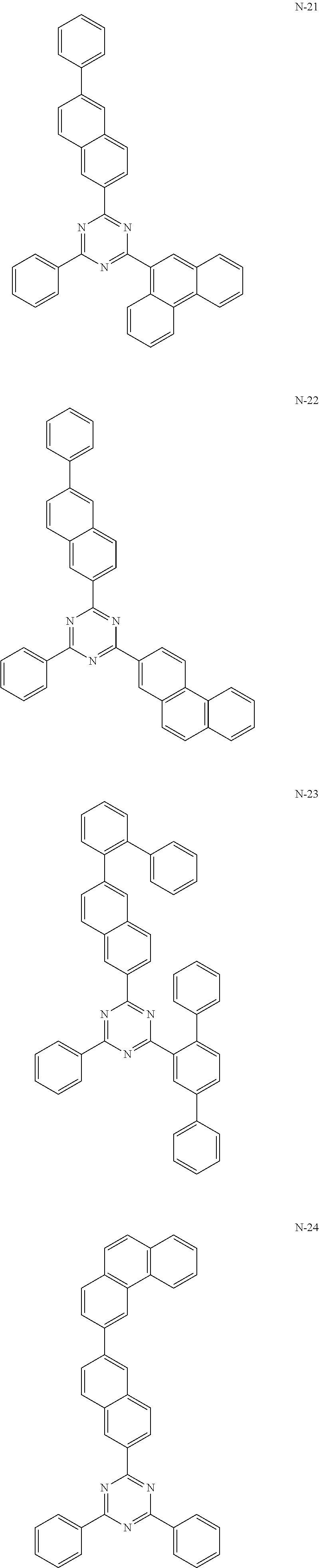 [SMILES: c1ccc(-c2ccc3cc(-c4nc(-c5ccccc5)nc(-c5cc6ccccc6c6ccccc56)n4)ccc3c2)cc1 ; c1ccc(-c2ccc3cc(-c4nc(-c5ccccc5)nc(-c5ccc6c(ccc7ccccc76)c5)n4)ccc3c2)cc1 ; c1ccc(-c2ccc(-c3ccccc3)c(-c3nc(-c4ccccc4)nc(-c4ccc5cc(-c6ccccc6-c6ccccc6)ccc5c4)n3)c2)cc1 ; c1ccc(-c2nc(-c3ccccc3)nc(-c3ccc4cc(-c5ccc6ccc7ccccc7c6c5)ccc4c3)n2)cc1]

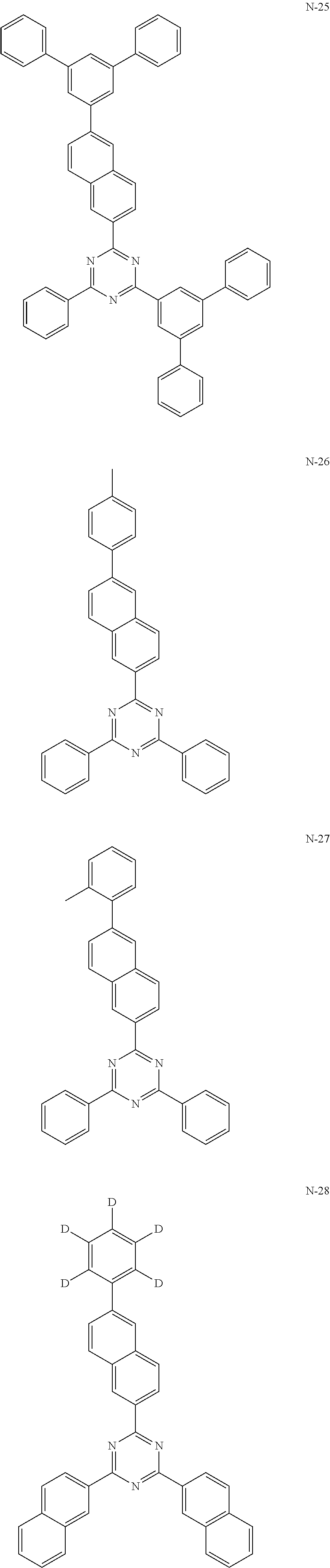 [SMILES: c1ccc(-c2cc(-c3ccccc3)cc(-c3ccc4cc(-c5nc(-c6ccccc6)nc(-c6cc(-c7ccccc7)cc(-c7ccccc7)c6)n5)ccc4c3)c2)cc1 ; Cc1ccc(-c2ccc3cc(-c4nc(-c5ccccc5)nc(-c5ccccc5)n4)ccc3c2)cc1 ; Cc1ccccc1-c1ccc2cc(-c3nc(-c4ccccc4)nc(-c4ccccc4)n3)ccc2c1 ; [2H]c1c([2H])c([2H])c(-c2ccc3cc(-c4nc(-c5ccc6ccccc6c5)nc(-c5ccc6ccccc6c5)n4)ccc3c2)c([2H])c1[2H]]

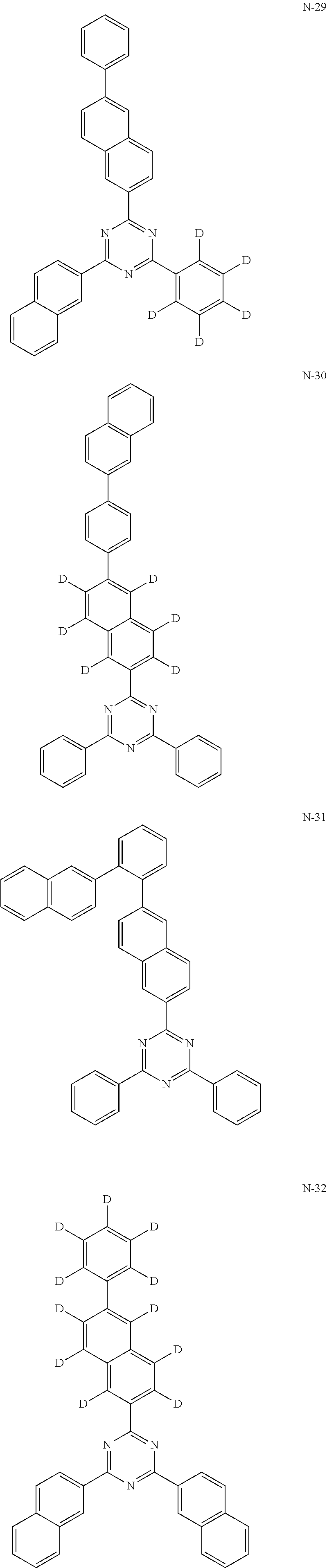 [SMILES: [2H]c1c([2H])c([2H])c(-c2nc(-c3ccc4ccccc4c3)nc(-c3ccc4cc(-c5ccccc5)ccc4c3)n2)c([2H])c1[2H] ; [2H]c1c(-c2nc(-c3ccccc3)nc(-c3ccccc3)n2)c([2H])c2c([2H])c([2H])c(-c3ccc(-c4ccc5ccccc5c4)cc3)c([2H])c2c1[2H] ; c1ccc(-c2nc(-c3ccccc3)nc(-c3ccc4cc(-c5ccccc5-c5ccc6ccccc6c5)ccc4c3)n2)cc1 ; [2H]c1c([2H])c([2H])c(-c2c([2H])c([2H])c3c([2H])c(-c4nc(-c5ccc6ccccc6c5)nc(-c5ccc6ccccc6c5)n4)c([2H])c([2H])c3c2[2H])c([2H])c1[2H]]

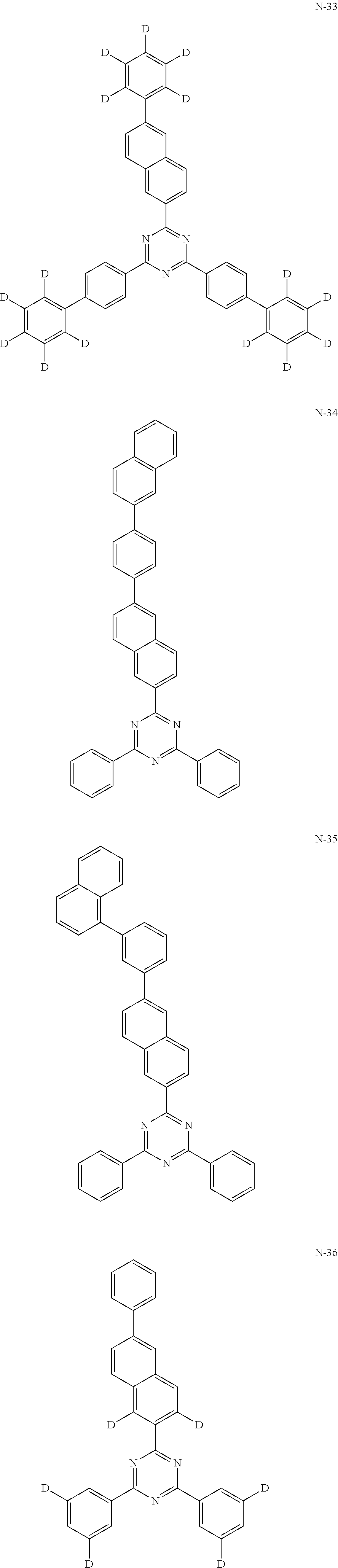 [SMILES: [2H]c1c([2H])c([2H])c(-c2ccc(-c3nc(-c4ccc(-c5c([2H])c([2H])c([2H])c([2H])c5[2H])cc4)nc(-c4ccc5cc(-c6c([2H])c([2H])c([2H])c([2H])c6[2H])ccc5c4)n3)cc2)c([2H])c1[2H] ; c1ccc(-c2nc(-c3ccccc3)nc(-c3ccc4cc(-c5ccc(-c6ccc7ccccc7c6)cc5)ccc4c3)n2)cc1 ; c1ccc(-c2nc(-c3ccccc3)nc(-c3ccc4cc(-c5cccc(-c6cccc7ccccc67)c5)ccc4c3)n2)cc1 ; [2H]c1cc([2H])cc(-c2nc(-c3cc([2H])cc([2H])c3)nc(-c3c([2H])cc4cc(-c5ccccc5)ccc4c3[2H])n2)c1]

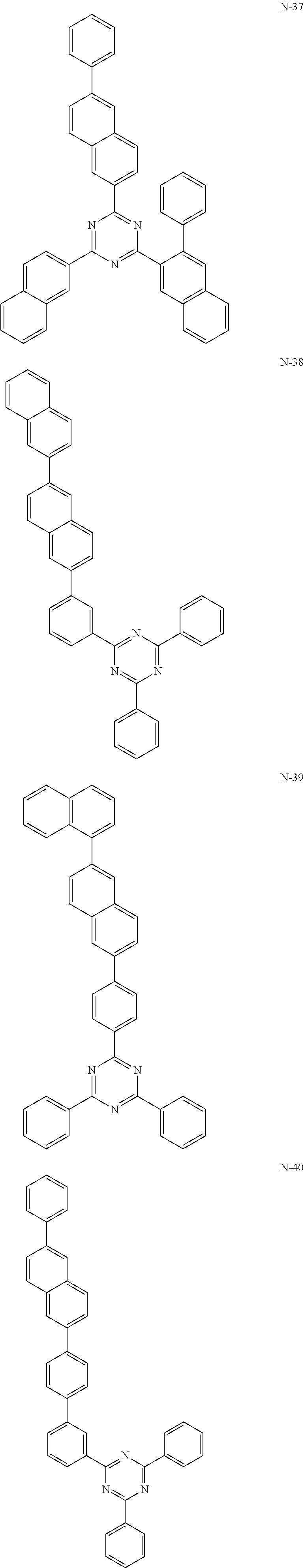

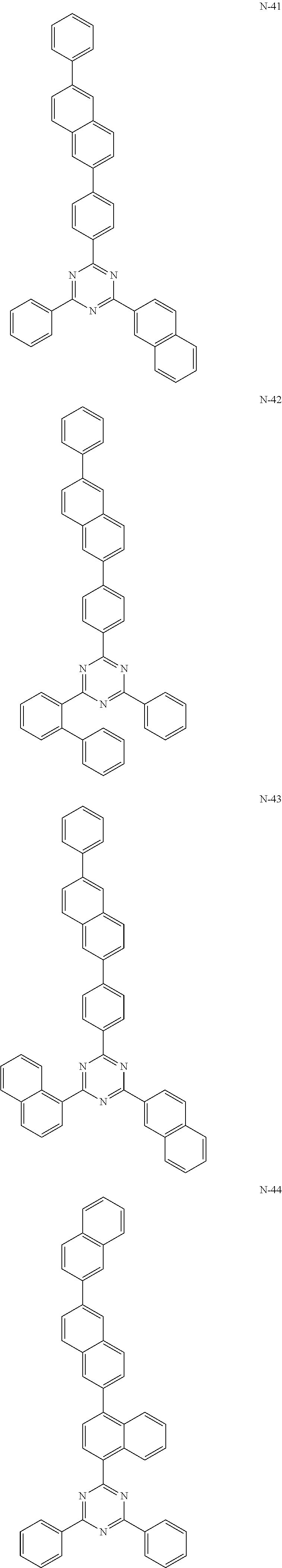 [SMILES: c1ccc(-c2ccc3cc(-c4ccc(-c5nc(-c6ccccc6)nc(-c6ccc7ccccc7c6)n5)cc4)ccc3c2)cc1 ; c1ccc(-c2ccc3cc(-c4ccc(-c5nc(-c6ccccc6)nc(-c6ccccc6-c6ccccc6)n5)cc4)ccc3c2)cc1 ; c1ccc(-c2ccc3cc(-c4ccc(-c5nc(-c6ccc7ccccc7c6)nc(-c6cccc7ccccc67)n5)cc4)ccc3c2)cc1 ; c1ccc(-c2nc(-c3ccccc3)nc(-c3ccc(-c4ccc5cc(-c6ccc7ccccc7c6)ccc5c4)c4ccccc34)n2)cc1]

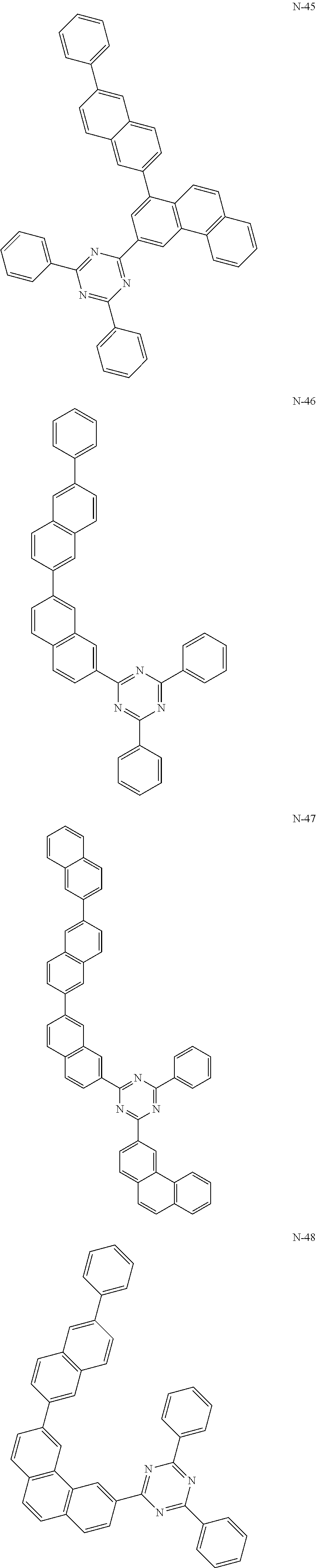 [SMILES: c1ccc(-c2ccc3cc(-c4cc(-c5nc(-c6ccccc6)nc(-c6ccccc6)n5)cc5c4ccc4ccccc45)ccc3c2)cc1 ; c1ccc(-c2ccc3cc(-c4ccc5ccc(-c6nc(-c7ccccc7)nc(-c7ccccc7)n6)cc5c4)ccc3c2)cc1 ; c1ccc(-c2nc(-c3ccc4ccc(-c5ccc6cc(-c7ccc8ccccc8c7)ccc6c5)cc4c3)nc(-c3ccc4ccc5ccccc5c4c3)n2)cc1 ; c1ccc(-c2ccc3cc(-c4ccc5ccc6ccc(-c7nc(-c8ccccc8)nc(-c8ccccc8)n7)cc6c5c4)ccc3c2)cc1]

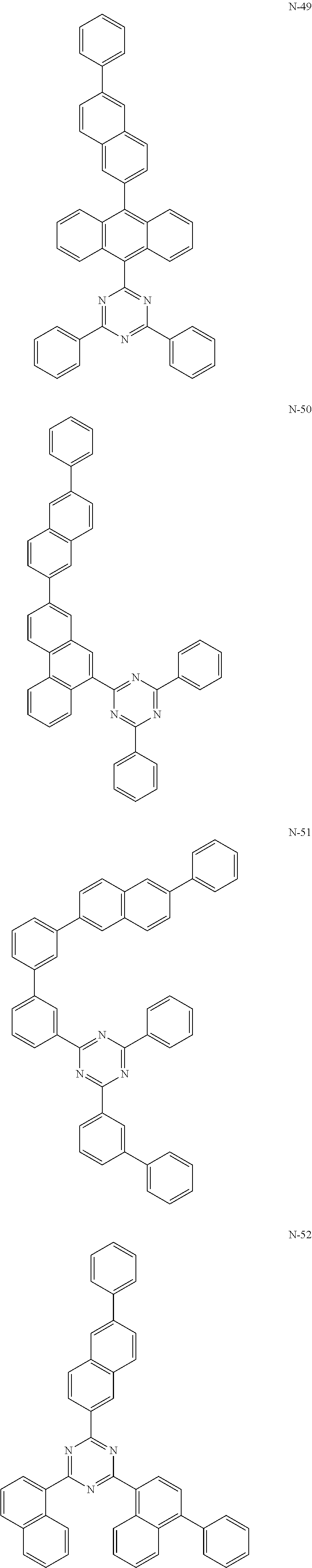 [SMILES: c1ccc(-c2ccc3cc(-c4c5ccccc5c(-c5nc(-c6ccccc6)nc(-c6ccccc6)n5)c5ccccc45)ccc3c2)cc1 ; c1ccc(-c2ccc3cc(-c4ccc5c(c4)cc(-c4nc(-c6ccccc6)nc(-c6ccccc6)n4)c4ccccc45)ccc3c2)cc1 ; c1ccc(-c2cccc(-c3nc(-c4ccccc4)nc(-c4cccc(-c5cccc(-c6ccc7cc(-c8ccccc8)ccc7c6)c5)c4)n3)c2)cc1 ; c1ccc(-c2ccc3cc(-c4nc(-c5cccc6ccccc56)nc(-c5ccc(-c6ccccc6)c6ccccc56)n4)ccc3c2)cc1]

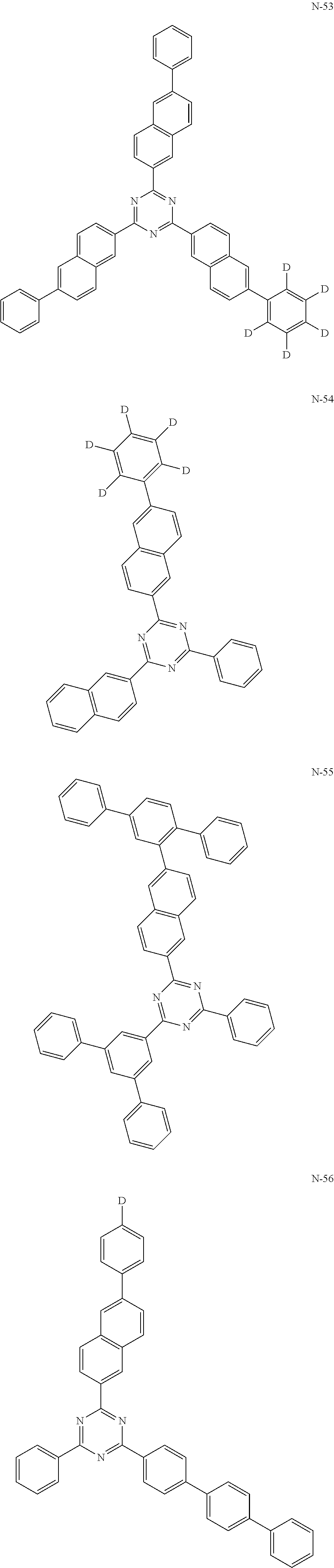 [SMILES: [2H]c1c([2H])c([2H])c(-c2ccc3cc(-c4nc(-c5ccc6cc(-c7ccccc7)ccc6c5)nc(-c5ccc6cc(-c7ccccc7)ccc6c5)n4)ccc3c2)c([2H])c1[2H] ; [2H]c1c([2H])c([2H])c(-c2ccc3cc(-c4nc(-c5ccccc5)nc(-c5ccc6ccccc6c5)n4)ccc3c2)c([2H])c1[2H] ; c1ccc(-c2cc(-c3ccccc3)cc(-c3nc(-c4ccccc4)nc(-c4ccc5cc(-c6cc(-c7ccccc7)ccc6-c6ccccc6)ccc5c4)n3)c2)cc1 ; [2H]c1ccc(-c2ccc3cc(-c4nc(-c5ccccc5)nc(-c5ccc(-c6ccc(-c7ccccc7)cc6)cc5)n4)ccc3c2)cc1]

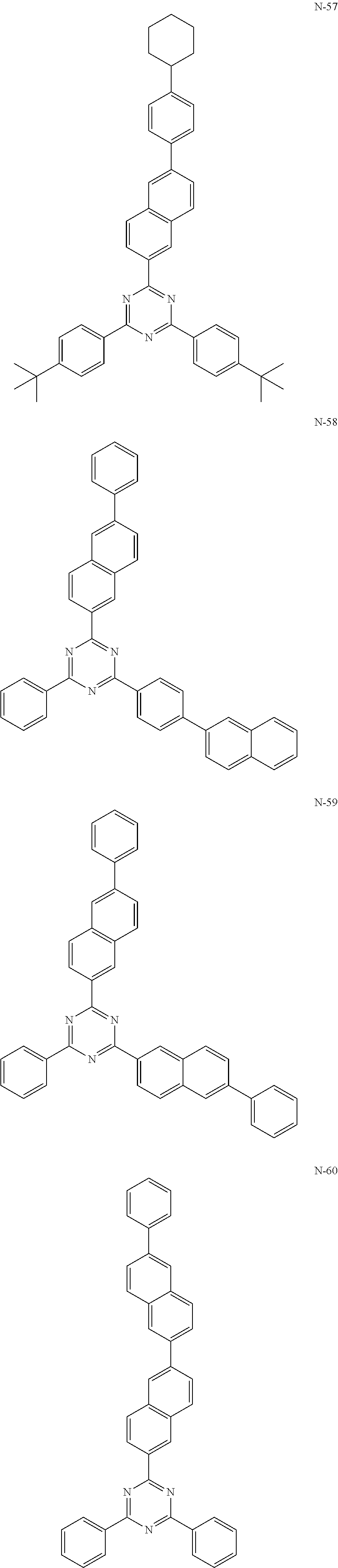 [SMILES: CC(C)(C)c1ccc(-c2nc(-c3ccc(C(C)(C)C)cc3)nc(-c3ccc4cc(-c5ccc(C6CCCCC6)cc5)ccc4c3)n2)cc1 ; c1ccc(-c2ccc3cc(-c4nc(-c5ccccc5)nc(-c5ccc(-c6ccc7ccccc7c6)cc5)n4)ccc3c2)cc1 ; c1ccc(-c2ccc3cc(-c4nc(-c5ccccc5)nc(-c5ccc6cc(-c7ccccc7)ccc6c5)n4)ccc3c2)cc1 ; c1ccc(-c2ccc3cc(-c4ccc5cc(-c6nc(-c7ccccc7)nc(-c7ccccc7)n6)ccc5c4)ccc3c2)cc1]

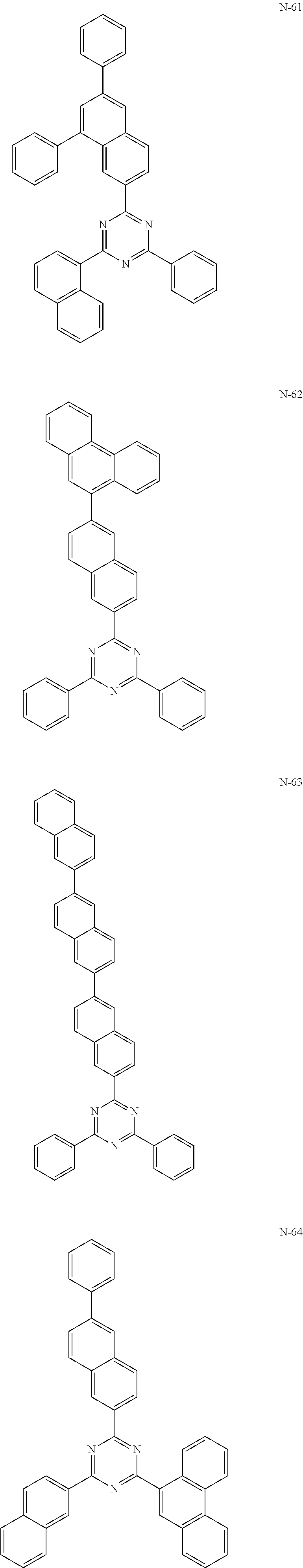 [SMILES: c1ccc(-c2cc(-c3ccccc3)c3cc(-c4nc(-c5ccccc5)nc(-c5cccc6ccccc56)n4)ccc3c2)cc1 ; c1ccc(-c2nc(-c3ccccc3)nc(-c3ccc4cc(-c5cc6ccccc6c6ccccc56)ccc4c3)n2)cc1 ; c1ccc(-c2nc(-c3ccccc3)nc(-c3ccc4cc(-c5ccc6cc(-c7ccc8ccccc8c7)ccc6c5)ccc4c3)n2)cc1 ; c1ccc(-c2ccc3cc(-c4nc(-c5ccc6ccccc6c5)nc(-c5cc6ccccc6c6ccccc56)n4)ccc3c2)cc1]

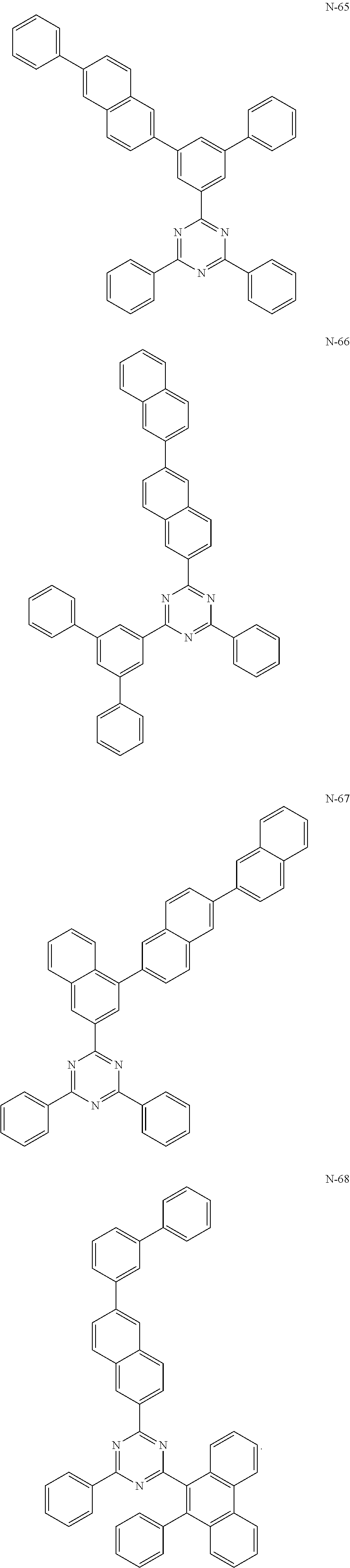

Specifically, compound represented by Formula 4 may be one of the following compounds, but there is no limitation thereto.

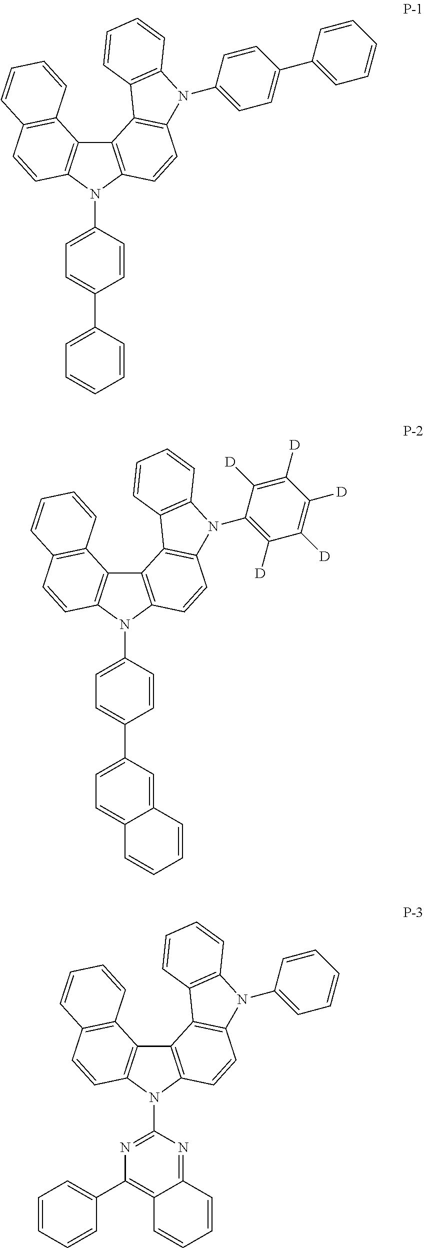 [SMILES: c1ccc(-c2ccc(-n3c4ccccc4c4c5c6c7ccccc7ccc6n(-c6ccc(-c7ccccc7)cc6)c5ccc43)cc2)cc1 ; [2H]c1c([2H])c([2H])c(-n2c3ccccc3c3c4c5c6ccccc6ccc5n(-c5ccc(-c6ccc7ccccc7c6)cc5)c4ccc32)c([2H])c1[2H] ; c1ccc(-c2nc(-n3c4ccc5ccccc5c4c4c5c6ccccc6n(-c6ccccc6)c5ccc43)nc3ccccc23)cc1]

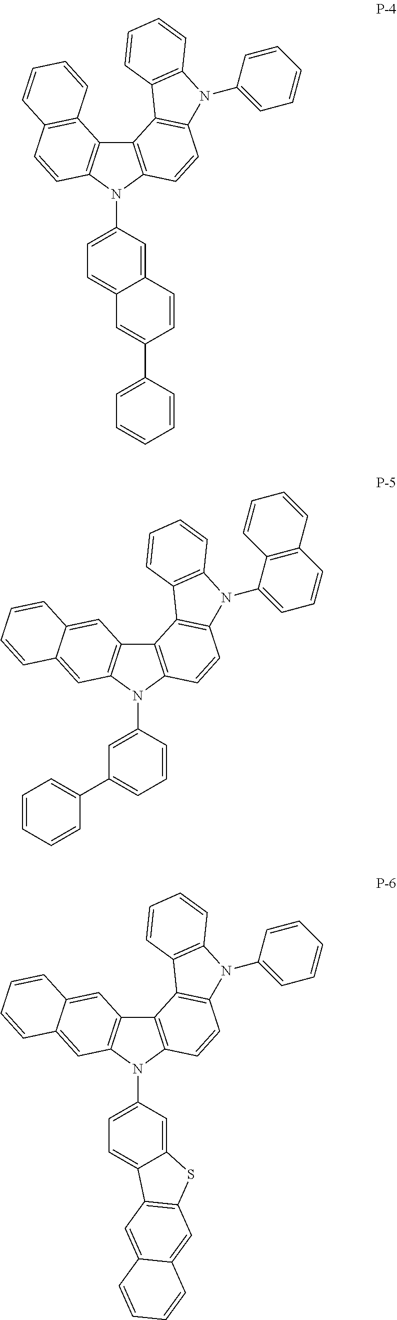 [SMILES: c1ccc(-c2ccc3cc(-n4c5ccc6ccccc6c5c5c6c7ccccc7n(-c7ccccc7)c6ccc54)ccc3c2)cc1 ; c1ccc(-c2cccc(-n3c4cc5ccccc5cc4c4c5c6ccccc6n(-c6cccc7ccccc67)c5ccc43)c2)cc1 ; c1ccc(-n2c3ccccc3c3c4c5cc6ccccc6cc5n(-c5ccc6c(c5)sc5cc7ccccc7cc56)c4ccc32)cc1]

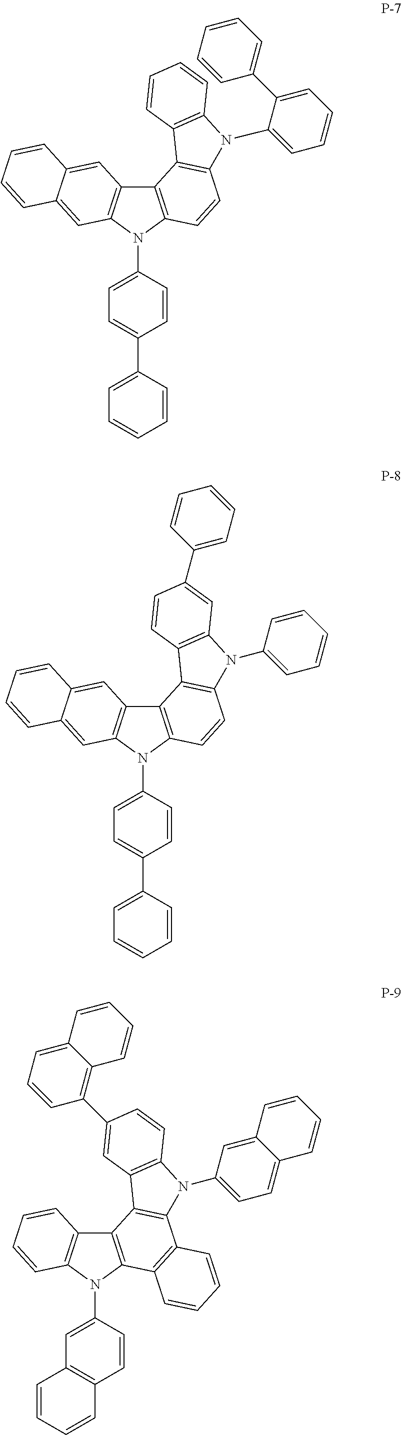 [SMILES: c1ccc(-c2ccc(-n3c4cc5ccccc5cc4c4c5c6ccccc6n(-c6ccccc6-c6ccccc6)c5ccc43)cc2)cc1 ; c1ccc(-c2ccc(-n3c4cc5ccccc5cc4c4c5c6ccc(-c7ccccc7)cc6n(-c6ccccc6)c5ccc43)cc2)cc1 ; c1ccc2cc(-n3c4ccccc4c4c5c6cc(-c7cccc8ccccc78)ccc6n(-c6ccc7ccccc7c6)c5c5ccccc5c43)ccc2c1]

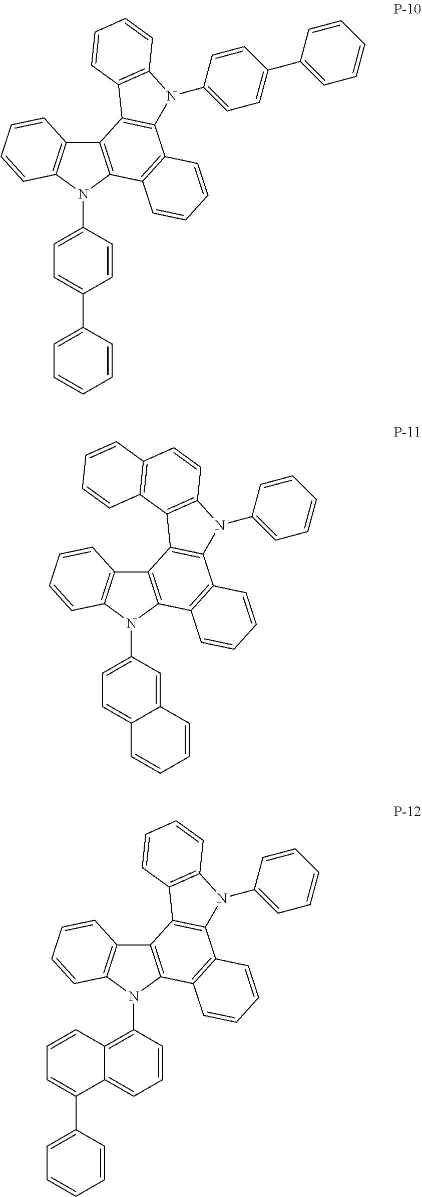 [SMILES: c1ccc(-c2ccc(-n3c4ccccc4c4c5c6ccccc6n(-c6ccc(-c7ccccc7)cc6)c5c5ccccc5c43)cc2)cc1 ; c1ccc(-n2c3ccc4ccccc4c3c3c4c5ccccc5n(-c5ccc6ccccc6c5)c4c4ccccc4c32)cc1 ; c1ccc(-c2cccc3c(-n4c5ccccc5c5c6c7ccccc7n(-c7ccccc7)c6c6ccccc6c54)cccc23)cc1]

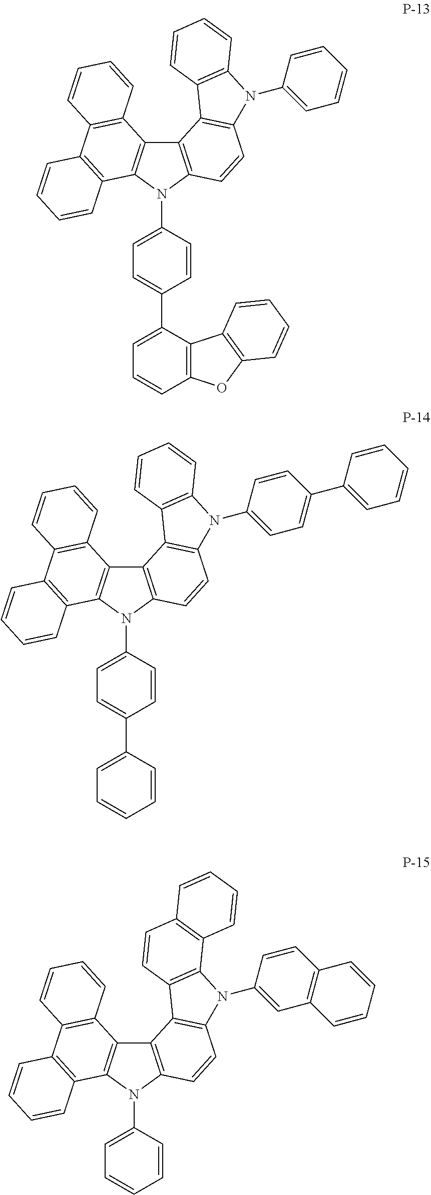 [SMILES: c1ccc(-n2c3ccccc3c3c4c5c6ccccc6c6ccccc6c5n(-c5ccc(-c6cccc7oc8ccccc8c67)cc5)c4ccc32)cc1 ; c1ccc(-c2ccc(-n3c4ccccc4c4c5c6c7ccccc7c7ccccc7c6n(-c6ccc(-c7ccccc7)cc6)c5ccc43)cc2)cc1 ; c1ccc(-n2c3ccc4c(c5ccc6ccccc6c5n4-c4ccc5ccccc5c4)c3c3c4ccccc4c4ccccc4c32)cc1]

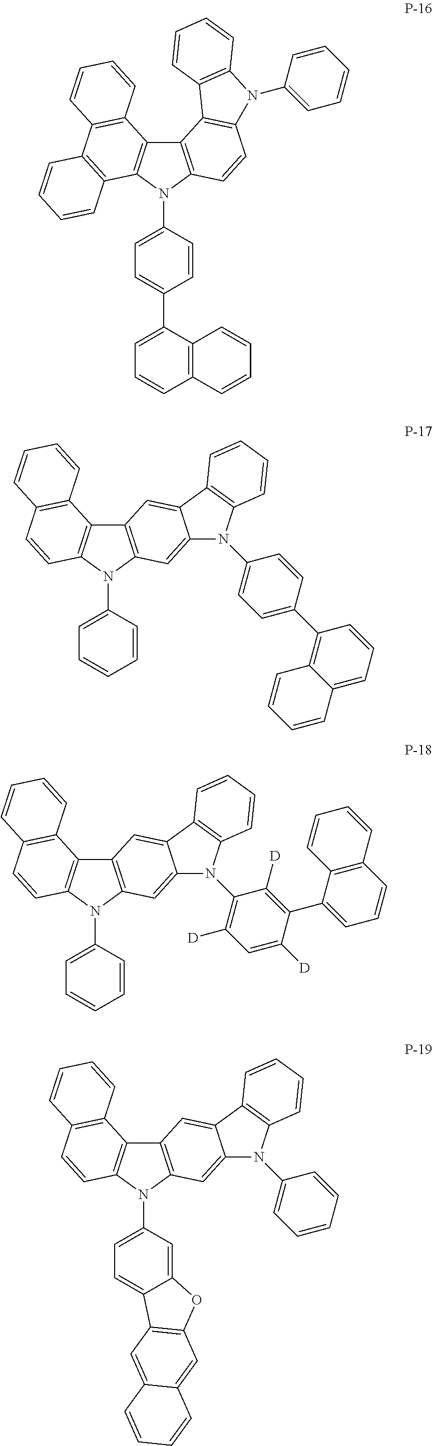 [SMILES: c1ccc(-n2c3ccccc3c3c4c5c6ccccc6c6ccccc6c5n(-c5ccc(-c6cccc7ccccc67)cc5)c4ccc32)cc1 ; c1ccc(-n2c3cc4c(cc3c3c5ccccc5ccc32)c2ccccc2n4-c2ccc(-c3cccc4ccccc34)cc2)cc1 ; [2H]c1cc([2H])c(-n2c3ccccc3c3cc4c5c6ccccc6ccc5n(-c5ccccc5)c4cc32)c([2H])c1-c1cccc2ccccc12 ; c1ccc(-n2c3ccccc3c3cc4c5c6ccccc6ccc5n(-c5ccc6c(c5)oc5cc7ccccc7cc56)c4cc32)cc1]

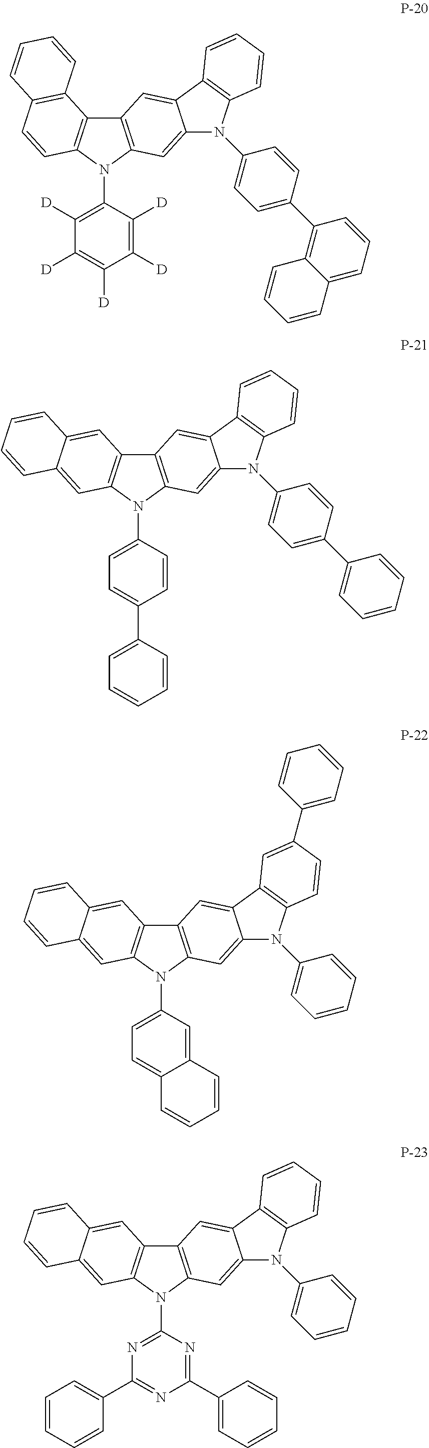 [SMILES: [2H]c1c([2H])c([2H])c(-n2c3cc4c(cc3c3c5ccccc5ccc32)c2ccccc2n4-c2ccc(-c3cccc4ccccc34)cc2)c([2H])c1[2H] ; c1ccc(-c2ccc(-n3c4ccccc4c4cc5c6cc7ccccc7cc6n(-c6ccc(-c7ccccc7)cc6)c5cc43)cc2)cc1 ; c1ccc(-c2ccc3c(c2)c2cc4c5cc6ccccc6cc5n(-c5ccc6ccccc6c5)c4cc2n3-c2ccccc2)cc1 ; c1ccc(-c2nc(-c3ccccc3)nc(-n3c4cc5ccccc5cc4c4cc5c6ccccc6n(-c6ccccc6)c5cc43)n2)cc1]

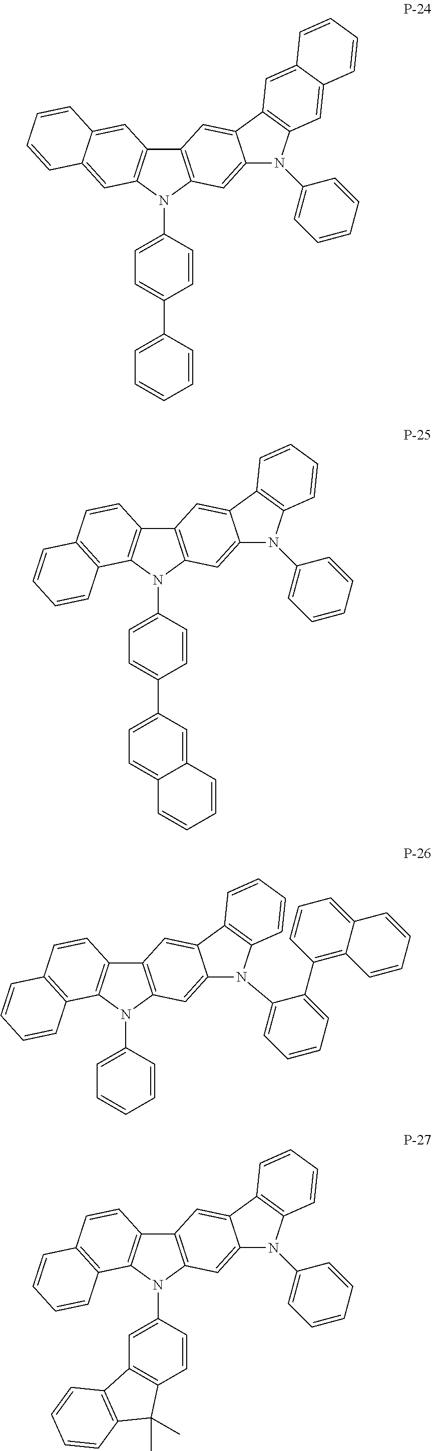 [SMILES: c1ccc(-c2ccc(-n3c4cc5ccccc5cc4c4cc5c6cc7ccccc7cc6n(-c6ccccc6)c5cc43)cc2)cc1 ; c1ccc(-n2c3ccccc3c3cc4c5ccc6ccccc6c5n(-c5ccc(-c6ccc7ccccc7c6)cc5)c4cc32)cc1 ; c1ccc(-n2c3cc4c(cc3c3ccc5ccccc5c32)c2ccccc2n4-c2ccccc2-c2cccc3ccccc23)cc1 ; CC1(C)c2ccccc2-c2cc(-n3c4cc5c(cc4c4ccc6ccccc6c43)c3ccccc3n5-c3ccccc3)ccc21]

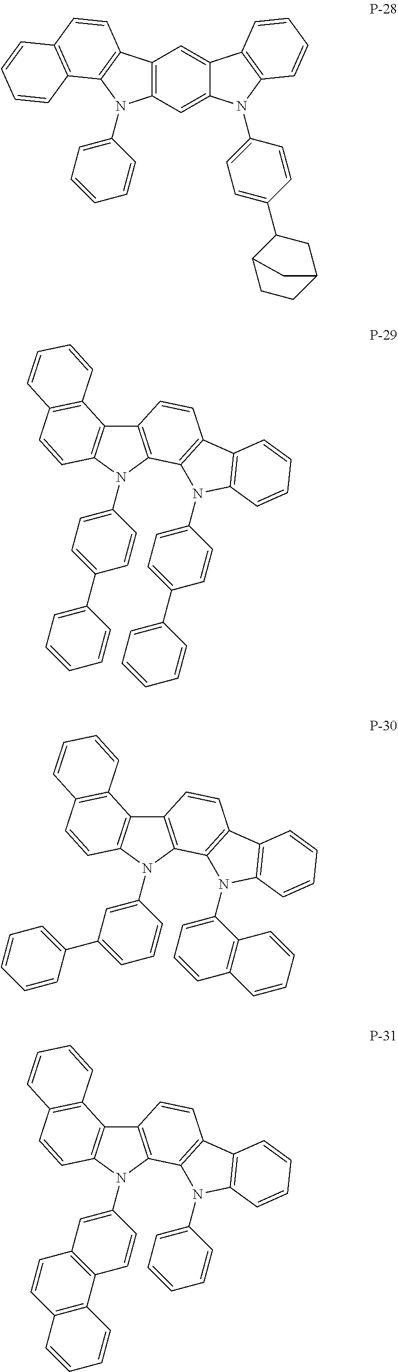 [SMILES: c1ccc(-n2c3cc4c(cc3c3ccc5ccccc5c32)c2ccccc2n4-c2ccc(C3CC4CCC3C4)cc2)cc1 ; c1ccc(-c2ccc(-n3c4ccccc4c4ccc5c6c7ccccc7ccc6n(-c6ccc(-c7ccccc7)cc6)c5c43)cc2)cc1 ; c1ccc(-c2cccc(-n3c4ccc5ccccc5c4c4ccc5c6ccccc6n(-c6cccc7ccccc67)c5c43)c2)cc1 ; c1ccc(-n2c3ccccc3c3ccc4c5c6ccccc6ccc5n(-c5ccc6c(ccc7ccccc76)c5)c4c32)cc1]

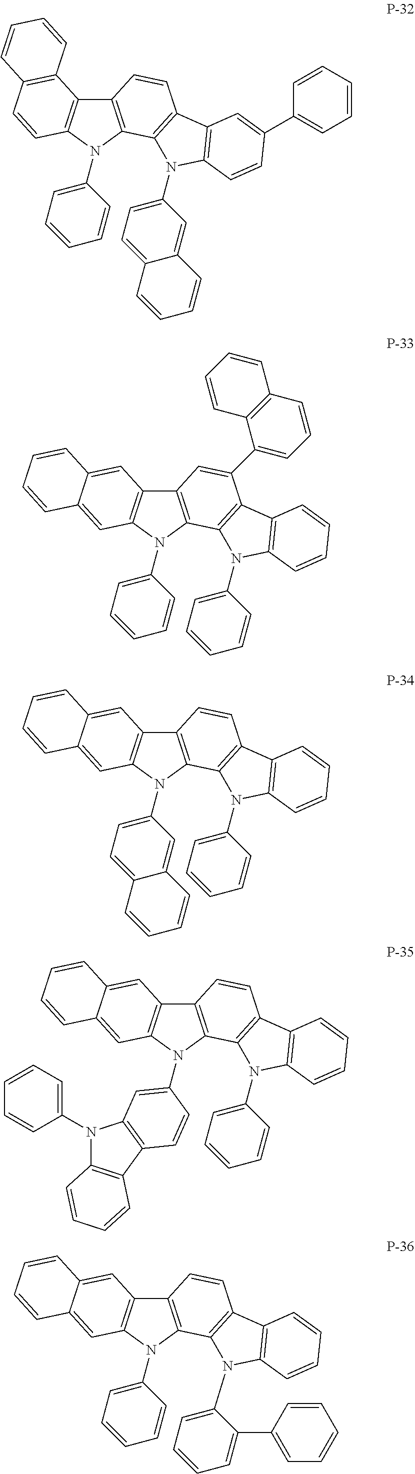

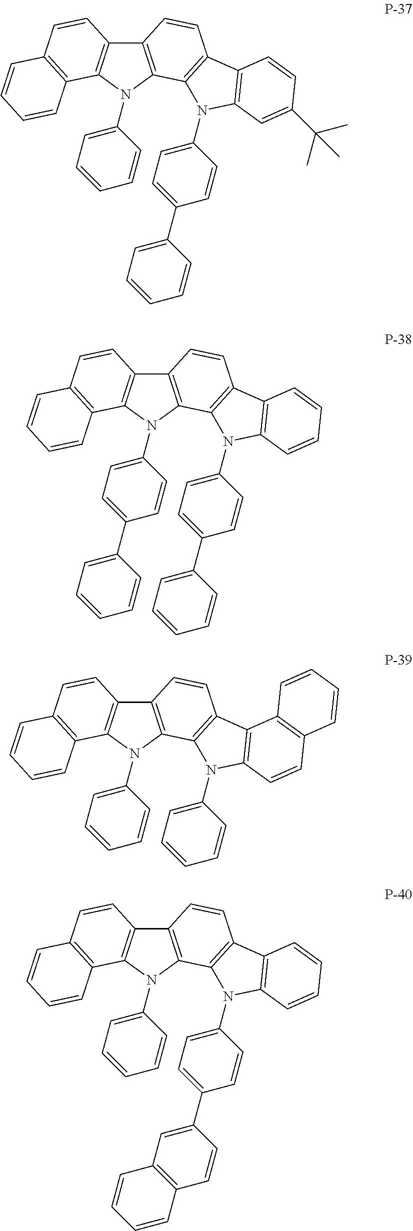

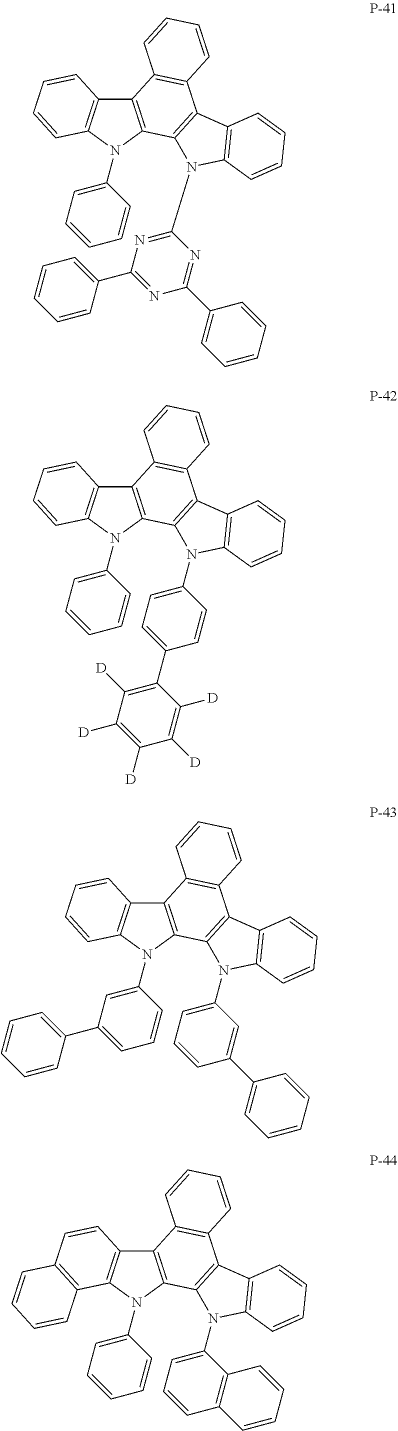 [SMILES: c1ccc(-c2nc(-c3ccccc3)nc(-n3c4ccccc4c4c5ccccc5c5c6ccccc6n(-c6ccccc6)c5c43)n2)cc1 ; [2H]c1c([2H])c([2H])c(-c2ccc(-n3c4ccccc4c4c5ccccc5c5c6ccccc6n(-c6ccccc6)c5c43)cc2)c([2H])c1[2H] ; c1ccc(-c2cccc(-n3c4ccccc4c4c5ccccc5c5c6ccccc6n(-c6cccc(-c7ccccc7)c6)c5c43)c2)cc1 ; c1ccc(-n2c3c4ccccc4ccc3c3c4ccccc4c4c5ccccc5n(-c5cccc6ccccc56)c4c32)cc1]

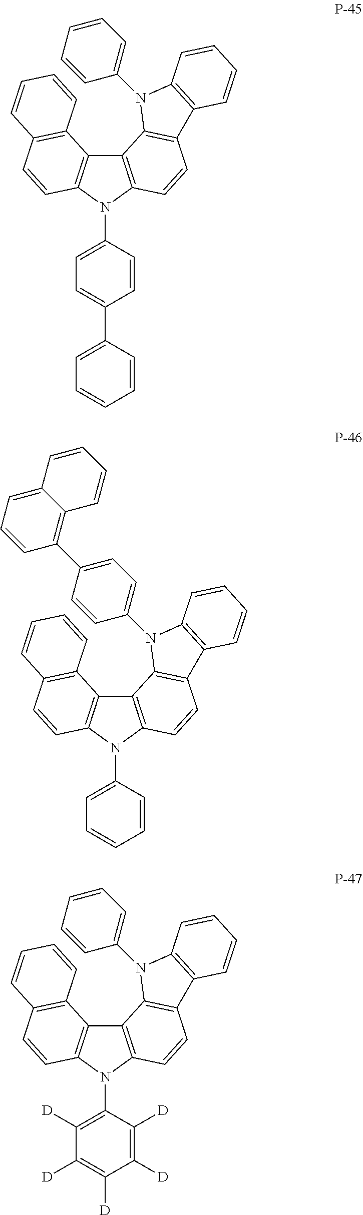

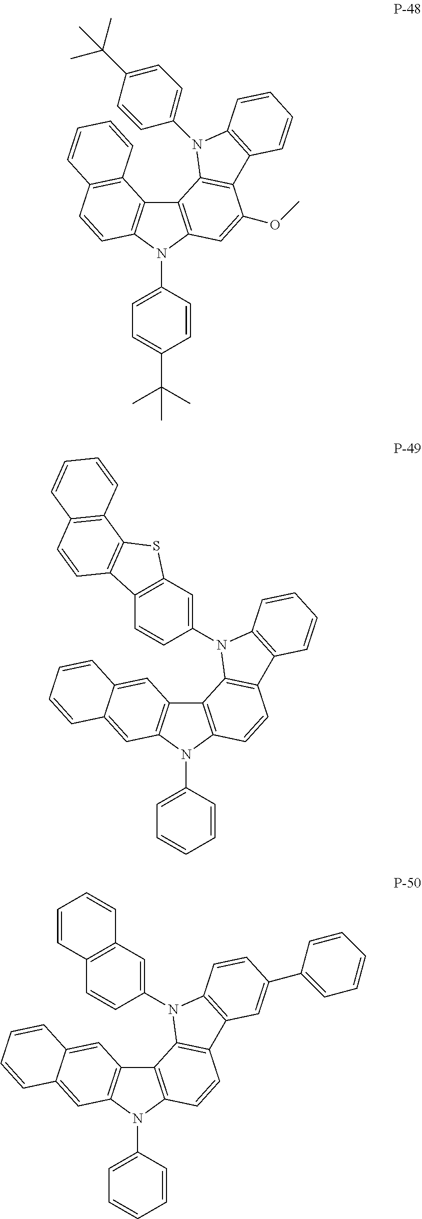 [SMILES: COc1cc2c(c3c4ccccc4ccc3n2-c2ccc(C(C)(C)C)cc2)c2c1c1ccccc1n2-c1ccc(C(C)(C)C)cc1 ; c1ccc(-n2c3cc4ccccc4cc3c3c2ccc2c4ccccc4n(-c4ccc5c(c4)sc4c6ccccc6ccc54)c23)cc1 ; c1ccc(-c2ccc3c(c2)c2ccc4c(c5cc6ccccc6cc5n4-c4ccccc4)c2n3-c2ccc3ccccc3c2)cc1]

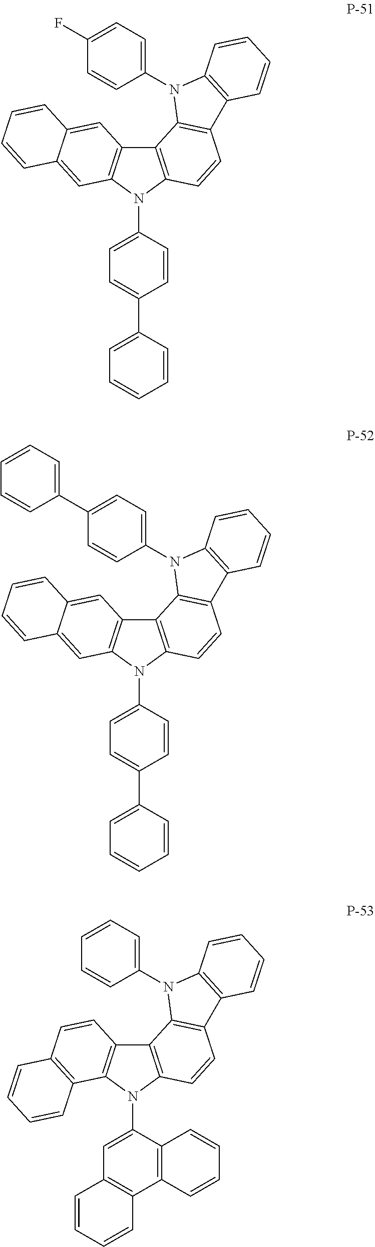 [SMILES: Fc1ccc(-n2c3ccccc3c3ccc4c(c5cc6ccccc6cc5n4-c4ccc(-c5ccccc5)cc4)c32)cc1 ; c1ccc(-c2ccc(-n3c4cc5ccccc5cc4c4c3ccc3c5ccccc5n(-c5ccc(-c6ccccc6)cc5)c34)cc2)cc1 ; c1ccc(-n2c3ccccc3c3ccc4c(c5ccc6ccccc6c5n4-c4cc5ccccc5c5ccccc45)c32)cc1]

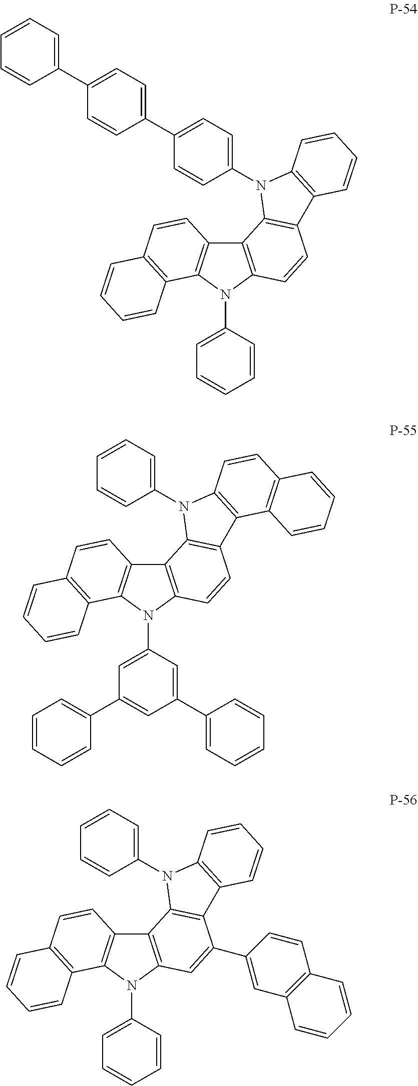 [SMILES: c1ccc(-c2ccc(-c3ccc(-n4c5ccccc5c5ccc6c(c7ccc8ccccc8c7n6-c6ccccc6)c54)cc3)cc2)cc1 ; c1ccc(-c2cc(-c3ccccc3)cc(-n3c4ccc5c6c7ccccc7ccc6n(-c6ccccc6)c5c4c4ccc5ccccc5c43)c2)cc1 ; c1ccc(-n2c3cc(-c4ccc5ccccc5c4)c4c5ccccc5n(-c5ccccc5)c4c3c3ccc4ccccc4c32)cc1]

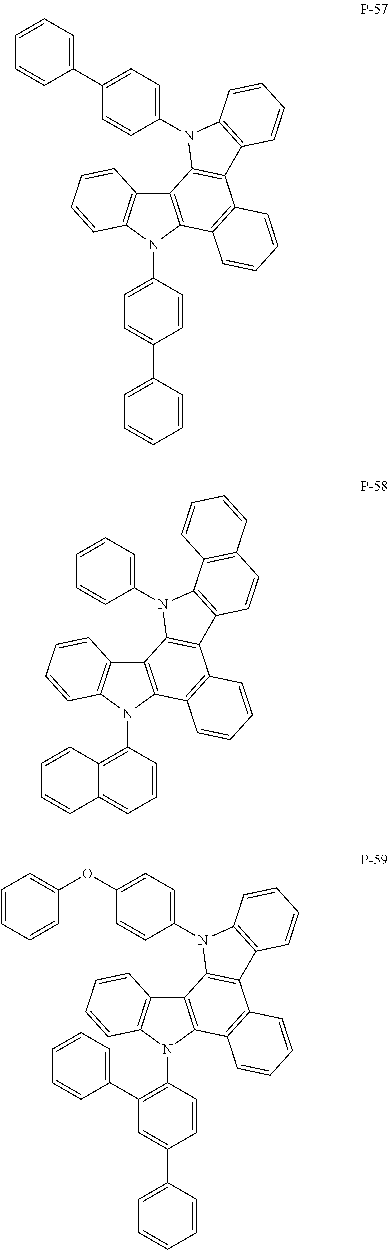 [SMILES: c1ccc(-c2ccc(-n3c4ccccc4c4c3c3ccccc3c3c5ccccc5n(-c5ccc(-c6ccccc6)cc5)c34)cc2)cc1 ; c1ccc(-n2c3c4ccccc4ccc3c3c4ccccc4c4c(c5ccccc5n4-c4cccc5ccccc45)c32)cc1 ; c1ccc(Oc2ccc(-n3c4ccccc4c4c5ccccc5c5c(c6ccccc6n5-c5ccc(-c6ccccc6)cc5-c5ccccc5)c43)cc2)cc1]

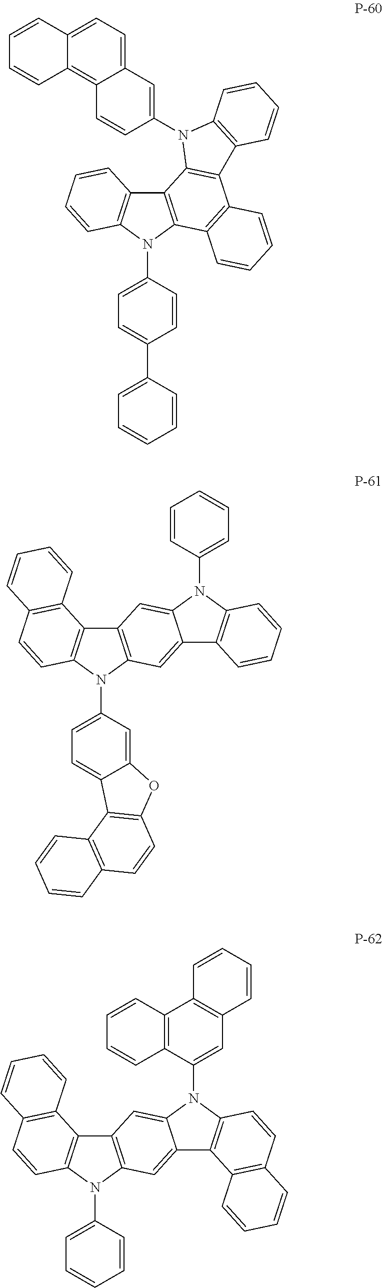 [SMILES: c1ccc(-c2ccc(-n3c4ccccc4c4c3c3ccccc3c3c5ccccc5n(-c5ccc6c(ccc7ccccc76)c5)c34)cc2)cc1 ; c1ccc(-n2c3ccccc3c3cc4c(cc32)c2c3ccccc3ccc2n4-c2ccc3c(c2)oc2ccc4ccccc4c23)cc1 ; c1ccc(-n2c3cc4c5c6ccccc6ccc5n(-c5cc6ccccc6c6ccccc56)c4cc3c3c4ccccc4ccc32)cc1]

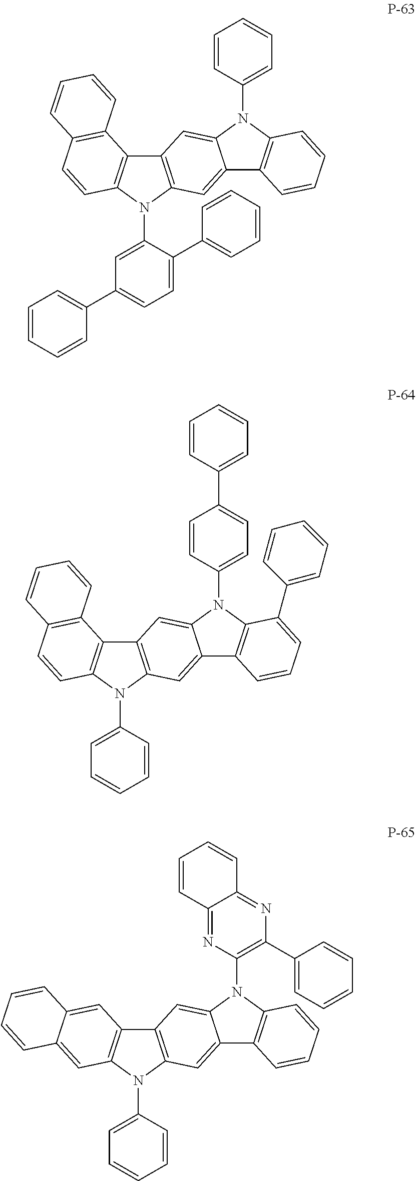 [SMILES: c1ccc(-c2ccc(-c3ccccc3)c(-n3c4cc5c6ccccc6n(-c6ccccc6)c5cc4c4c5ccccc5ccc43)c2)cc1 ; c1ccc(-c2ccc(-n3c4cc5c6c7ccccc7ccc6n(-c6ccccc6)c5cc4c4cccc(-c5ccccc5)c43)cc2)cc1 ; c1ccc(-c2nc3ccccc3nc2-n2c3ccccc3c3cc4c(cc32)c2cc3ccccc3cc2n4-c2ccccc2)cc1]

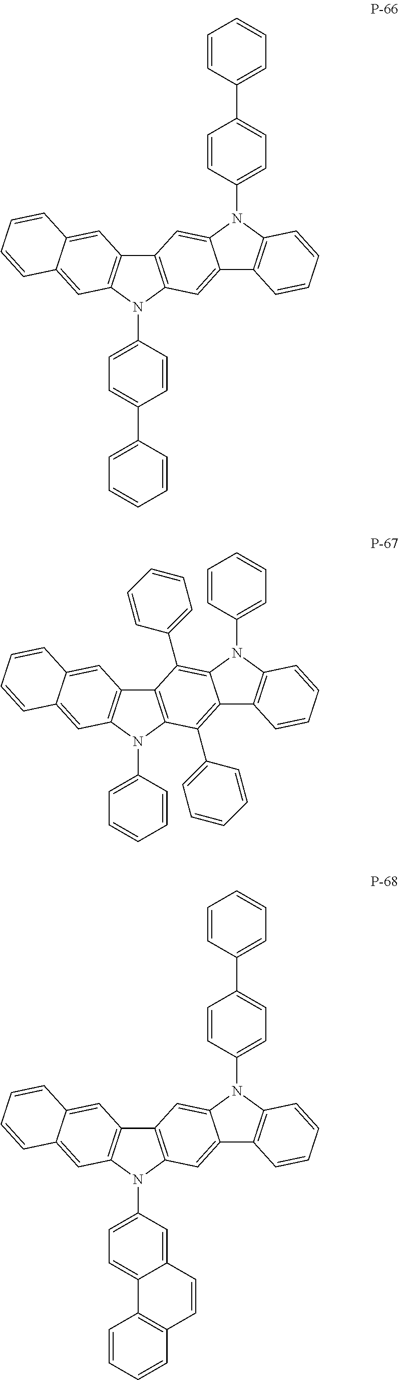 [SMILES: c1ccc(-c2ccc(-n3c4ccccc4c4cc5c(cc43)c3cc4ccccc4cc3n5-c3ccc(-c4ccccc4)cc3)cc2)cc1 ; c1ccc(-c2c3c4cc5ccccc5cc4n(-c4ccccc4)c3c(-c3ccccc3)c3c4ccccc4n(-c4ccccc4)c23)cc1 ; c1ccc(-c2ccc(-n3c4ccccc4c4cc5c(cc43)c3cc4ccccc4cc3n5-c3ccc4c(ccc5ccccc54)c3)cc2)cc1]

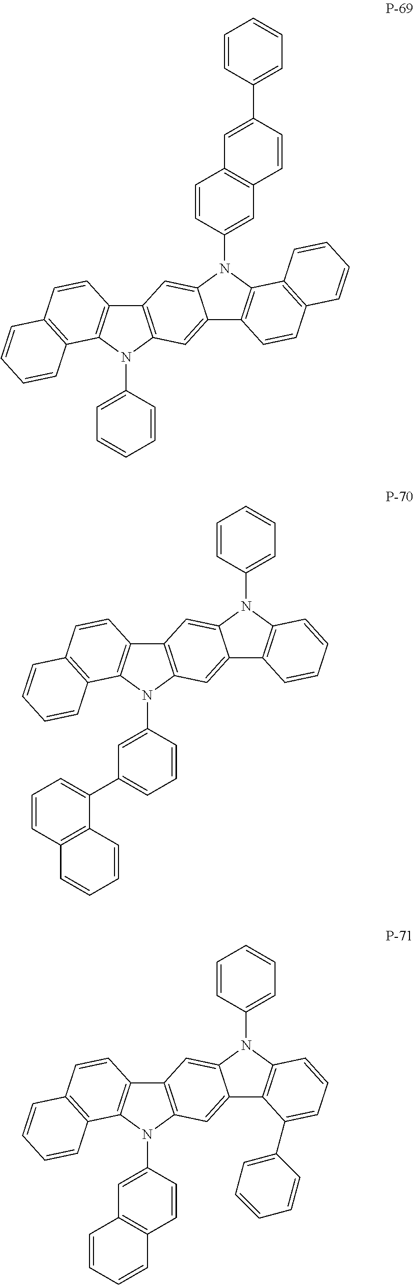 [SMILES: c1ccc(-c2ccc3cc(-n4c5cc6c7ccc8ccccc8c7n(-c7ccccc7)c6cc5c5ccc6ccccc6c54)ccc3c2)cc1 ; c1ccc(-n2c3ccccc3c3cc4c(cc32)c2ccc3ccccc3c2n4-c2cccc(-c3cccc4ccccc34)c2)cc1 ; c1ccc(-c2cccc3c2c2cc4c(cc2n3-c2ccccc2)c2ccc3ccccc3c2n4-c2ccc3ccccc3c2)cc1]

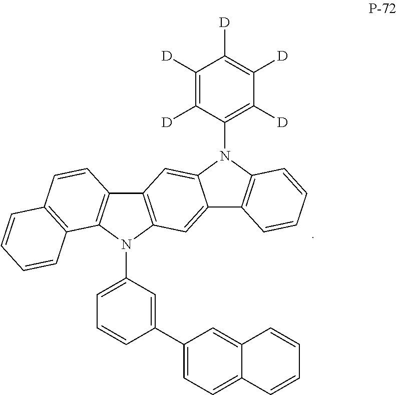 [SMILES: [2H]c1c([2H])c([2H])c(-n2c3ccccc3c3cc4c(cc32)c2ccc3ccccc3c2n4-c2cccc(-c3ccc4ccccc4c3)c2)c([2H])c1[2H]]

Specifically, compound represented by Formula 5 may be one of the compounds 1-37 to 1-60, 1-75, 1-77, 1-81, 1-85, 1-87, 1-90, 1-91, 1-93, 1-94, 1-96, 1-97, 1-101 to 1-108, but there is no limitation thereto.

Specifically, compound represented by Formula 6 may be one of the following compounds, but there is no limitation thereto.

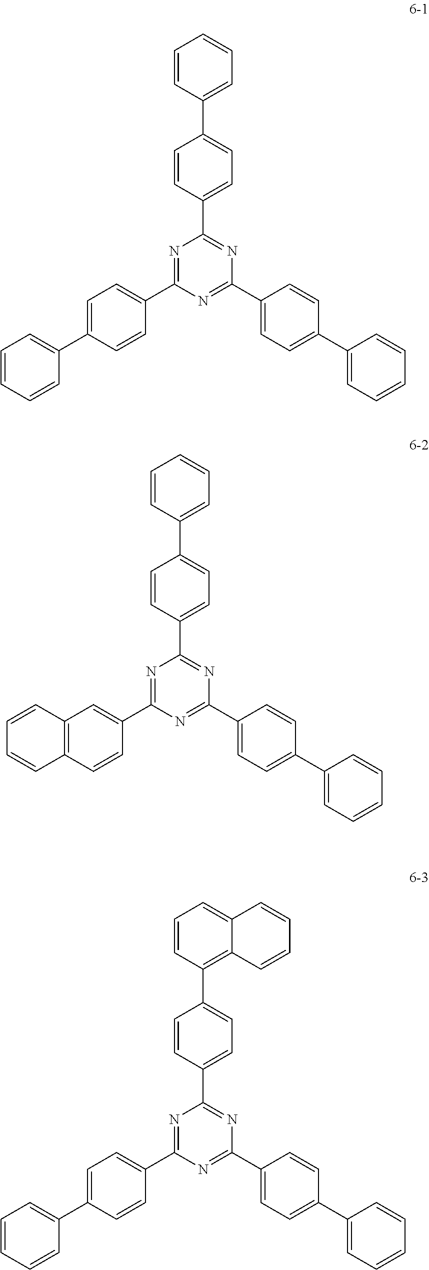 [SMILES: c1ccc(-c2ccc(-c3nc(-c4ccc(-c5ccccc5)cc4)nc(-c4ccc(-c5ccccc5)cc4)n3)cc2)cc1 ; c1ccc(-c2ccc(-c3nc(-c4ccc(-c5ccccc5)cc4)nc(-c4ccc5ccccc5c4)n3)cc2)cc1 ; c1ccc(-c2ccc(-c3nc(-c4ccc(-c5ccccc5)cc4)nc(-c4ccc(-c5cccc6ccccc56)cc4)n3)cc2)cc1]

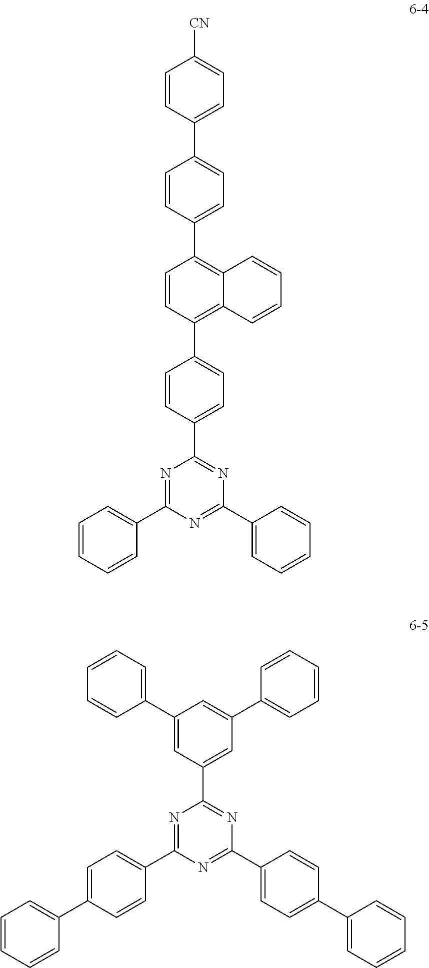 [SMILES: N#Cc1ccc(-c2ccc(-c3ccc(-c4ccc(-c5nc(-c6ccccc6)nc(-c6ccccc6)n5)cc4)c4ccccc34)cc2)cc1 ; c1ccc(-c2ccc(-c3nc(-c4ccc(-c5ccccc5)cc4)nc(-c4cc(-c5ccccc5)cc(-c5ccccc5)c4)n3)cc2)cc1]

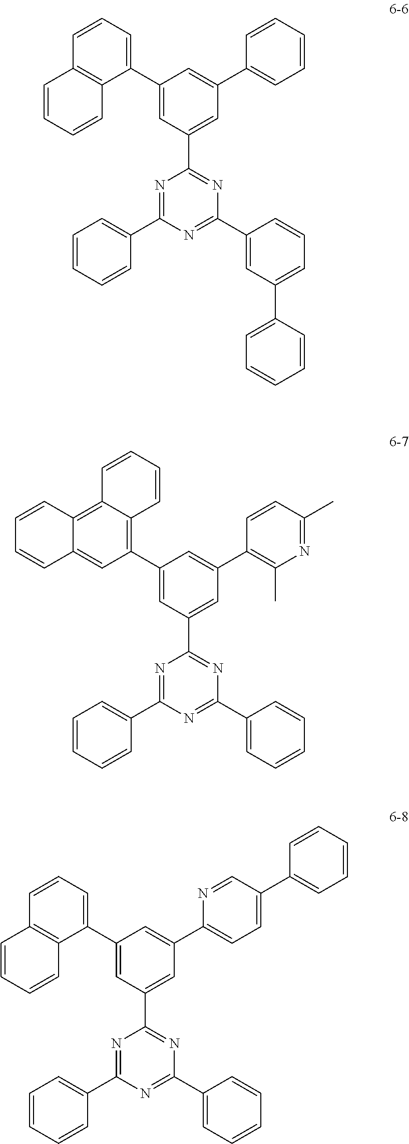 [SMILES: c1ccc(-c2cccc(-c3nc(-c4ccccc4)nc(-c4cc(-c5ccccc5)cc(-c5cccc6ccccc56)c4)n3)c2)cc1 ; Cc1ccc(-c2cc(-c3nc(-c4ccccc4)nc(-c4ccccc4)n3)cc(-c3cc4ccccc4c4ccccc34)c2)c(C)n1 ; c1ccc(-c2ccc(-c3cc(-c4nc(-c5ccccc5)nc(-c5ccccc5)n4)cc(-c4cccc5ccccc45)c3)nc2)cc1]

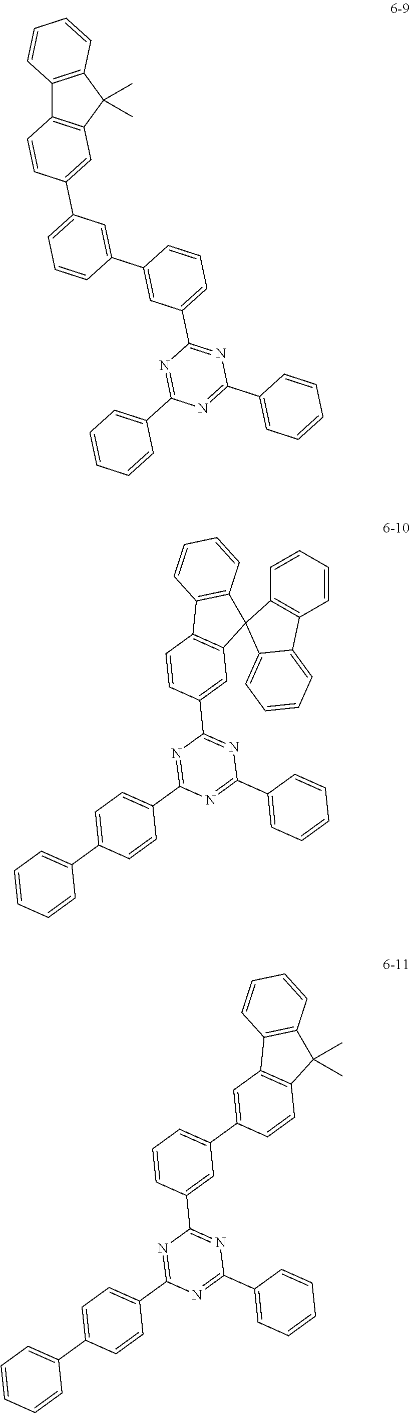 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3nc(-c4ccccc4)nc(-c4ccc5c(c4)C4(c6ccccc6-c6ccccc64)c4ccccc4-5)n3)cc2)cc1 ; CC1(C)c2ccccc2-c2cc(-c3cccc(-c4nc(-c5ccccc5)nc(-c5ccc(-c6ccccc6)cc5)n4)c3)ccc21]

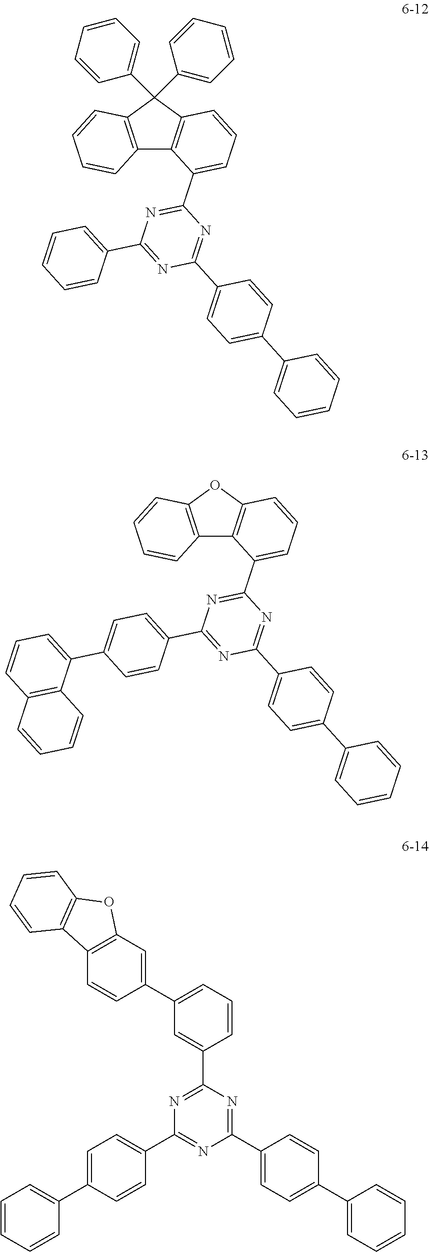 [SMILES: c1ccc(-c2ccc(-c3nc(-c4ccccc4)nc(-c4cccc5c4-c4ccccc4C5(c4ccccc4)c4ccccc4)n3)cc2)cc1 ; c1ccc(-c2ccc(-c3nc(-c4ccc(-c5cccc6ccccc56)cc4)nc(-c4cccc5oc6ccccc6c45)n3)cc2)cc1 ; c1ccc(-c2ccc(-c3nc(-c4ccc(-c5ccccc5)cc4)nc(-c4cccc(-c5ccc6c(c5)oc5ccccc56)c4)n3)cc2)cc1]

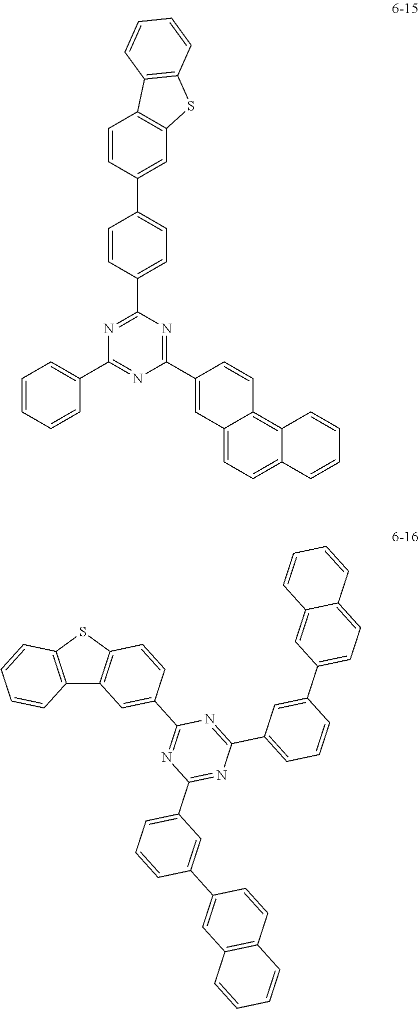 [SMILES: c1ccc(-c2nc(-c3ccc(-c4ccc5c(c4)sc4ccccc45)cc3)nc(-c3ccc4c(ccc5ccccc54)c3)n2)cc1 ; c1cc(-c2ccc3ccccc3c2)cc(-c2nc(-c3cccc(-c4ccc5ccccc5c4)c3)nc(-c3ccc4sc5ccccc5c4c3)n2)c1]

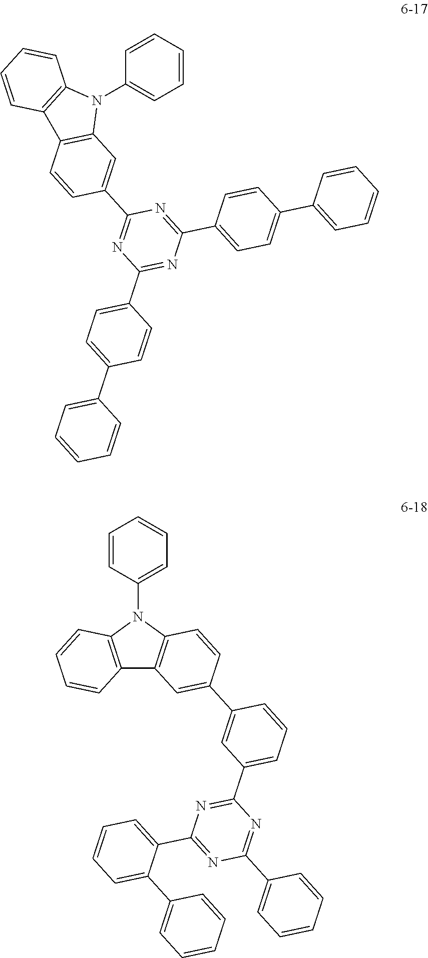 [SMILES: c1ccc(-c2ccc(-c3nc(-c4ccc(-c5ccccc5)cc4)nc(-c4ccc5c6ccccc6n(-c6ccccc6)c5c4)n3)cc2)cc1 ; c1ccc(-c2nc(-c3cccc(-c4ccc5c(c4)c4ccccc4n5-c4ccccc4)c3)nc(-c3ccccc3-c3ccccc3)n2)cc1]

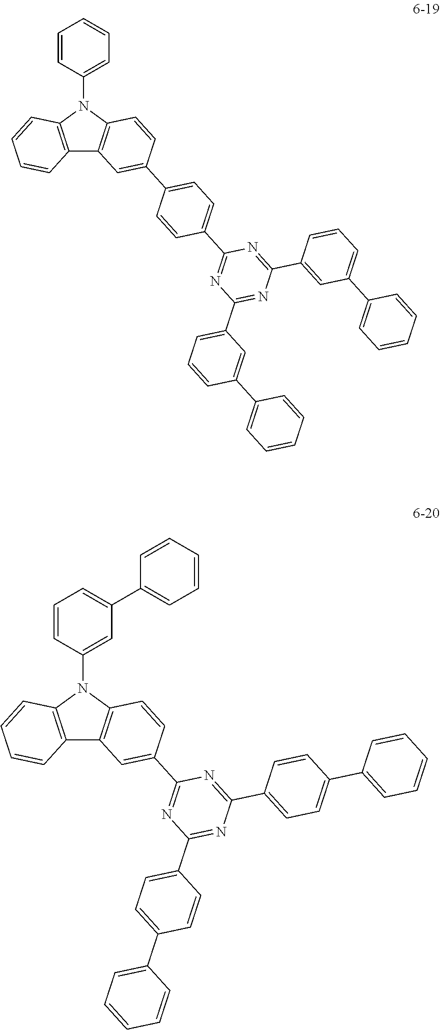 [SMILES: c1ccc(-c2cccc(-c3nc(-c4ccc(-c5ccc6c(c5)c5ccccc5n6-c5ccccc5)cc4)nc(-c4cccc(-c5ccccc5)c4)n3)c2)cc1 ; c1ccc(-c2ccc(-c3nc(-c4ccc(-c5ccccc5)cc4)nc(-c4ccc5c(c4)c4ccccc4n5-c4cccc(-c5ccccc5)c4)n3)cc2)cc1]

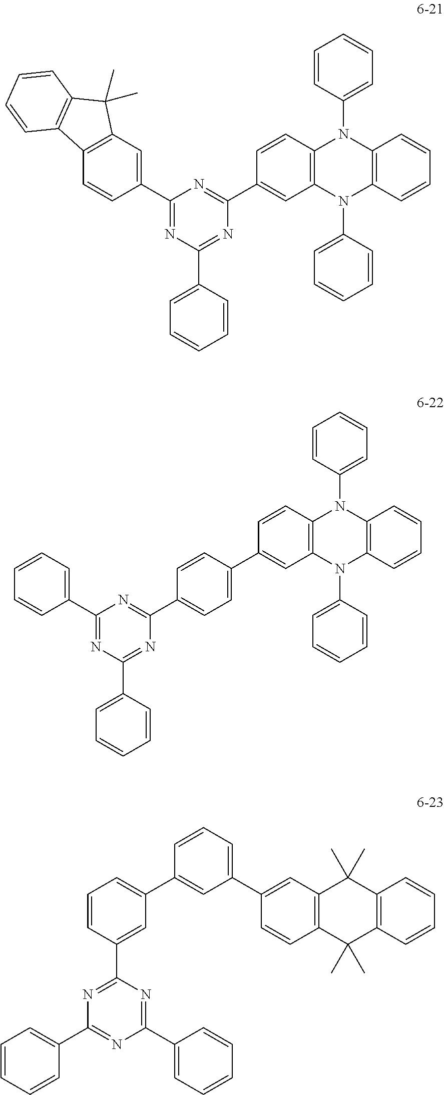 [SMILES: CC1(C)c2ccccc2-c2ccc(-c3nc(-c4ccccc4)nc(-c4ccc5c(c4)N(c4ccccc4)c4ccccc4N5c4ccccc4)n3)cc21 ; c1ccc(-c2nc(-c3ccccc3)nc(-c3ccc(-c4ccc5c(c4)N(c4ccccc4)c4ccccc4N5c4ccccc4)cc3)n2)cc1 ; CC1(C)c2ccccc2C(C)(C)c2cc(-c3cccc(-c4cccc(-c5nc(-c6ccccc6)nc(-c6ccccc6)n5)c4)c3)ccc21]

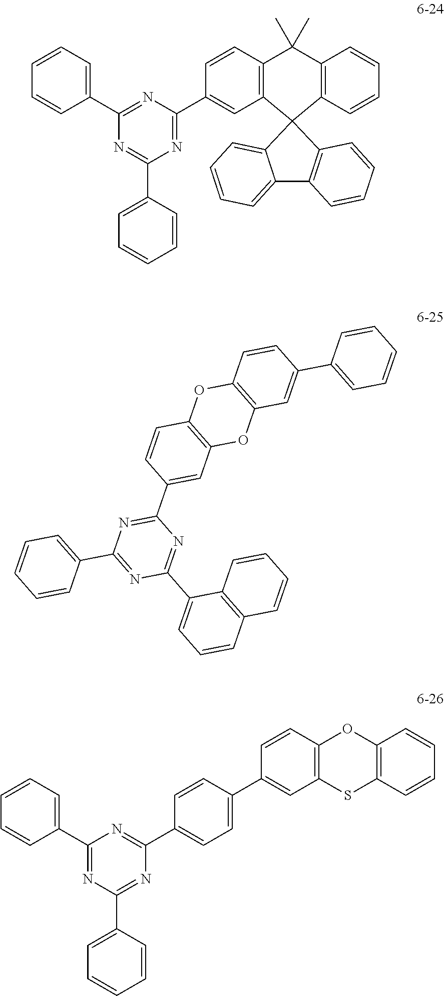 [SMILES: CC1(C)c2ccccc2C2(c3ccccc3-c3ccccc32)c2cc(-c3nc(-c4ccccc4)nc(-c4ccccc4)n3)ccc21 ; c1ccc(-c2ccc3c(c2)Oc2cc(-c4nc(-c5ccccc5)nc(-c5cccc6ccccc56)n4)ccc2O3)cc1 ; c1ccc(-c2nc(-c3ccccc3)nc(-c3ccc(-c4ccc5c(c4)Sc4ccccc4O5)cc3)n2)cc1]

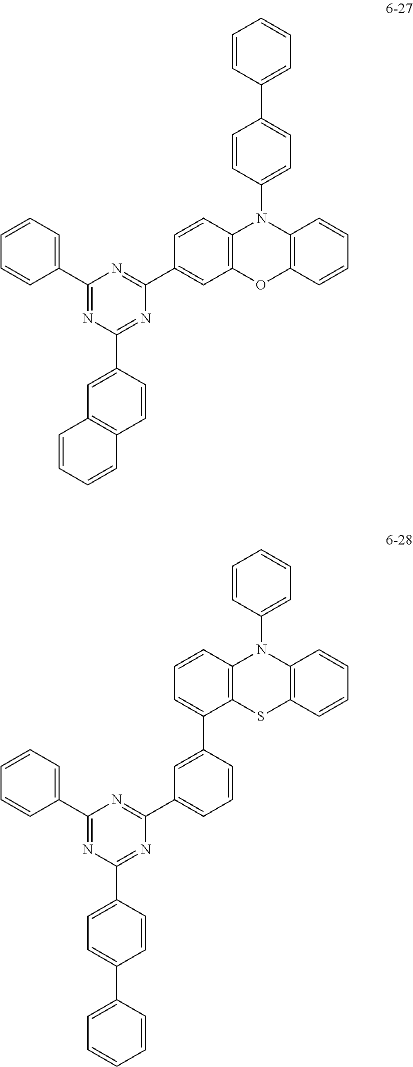 [SMILES: c1ccc(-c2ccc(N3c4ccccc4Oc4cc(-c5nc(-c6ccccc6)nc(-c6ccc7ccccc7c6)n5)ccc43)cc2)cc1 ; c1ccc(-c2ccc(-c3nc(-c4ccccc4)nc(-c4cccc(-c5cccc6c5Sc5ccccc5N6c5ccccc5)c4)n3)cc2)cc1]

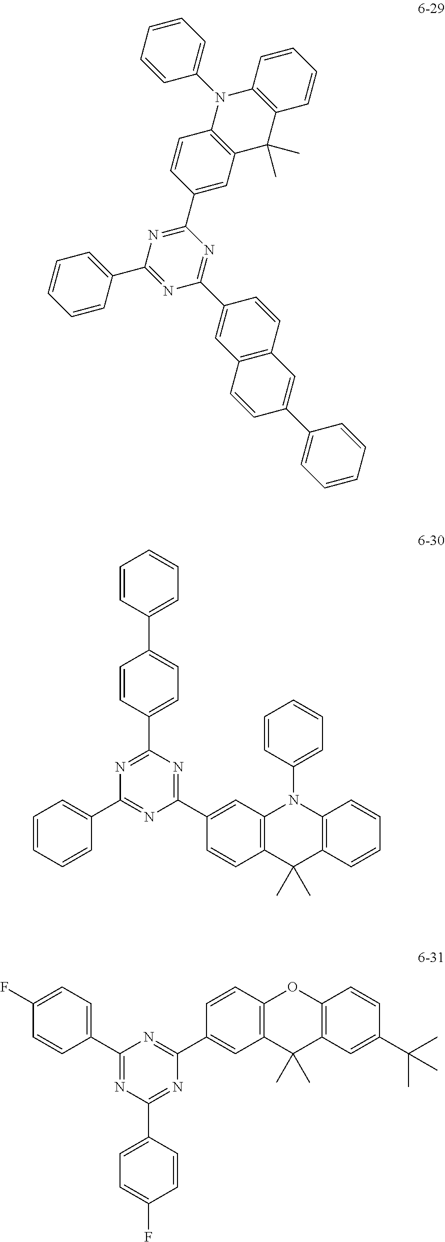 [SMILES: CC1(C)c2ccccc2N(c2ccccc2)c2ccc(-c3nc(-c4ccccc4)nc(-c4ccc5cc(-c6ccccc6)ccc5c4)n3)cc21 ; CC1(C)c2ccccc2N(c2ccccc2)c2cc(-c3nc(-c4ccccc4)nc(-c4ccc(-c5ccccc5)cc4)n3)ccc21 ; CC(C)(C)c1ccc2c(c1)C(C)(C)c1cc(-c3nc(-c4ccc(F)cc4)nc(-c4ccc(F)cc4)n3)ccc1O2]

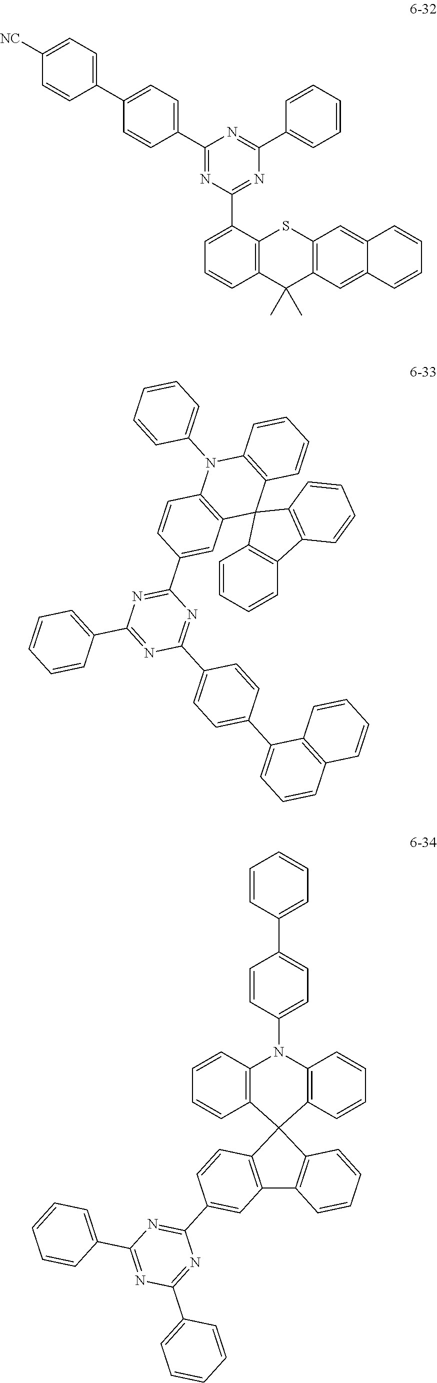 [SMILES: CC1(C)c2cc3ccccc3cc2Sc2c(-c3nc(-c4ccccc4)nc(-c4ccc(-c5ccc(C#N)cc5)cc4)n3)cccc21 ; c1ccc(-c2nc(-c3ccc(-c4cccc5ccccc45)cc3)nc(-c3ccc4c(c3)C3(c5ccccc5-c5ccccc53)c3ccccc3N4c3ccccc3)n2)cc1 ; c1ccc(-c2ccc(N3c4ccccc4C4(c5ccccc5-c5cc(-c6nc(-c7ccccc7)nc(-c7ccccc7)n6)ccc54)c4ccccc43)cc2)cc1]

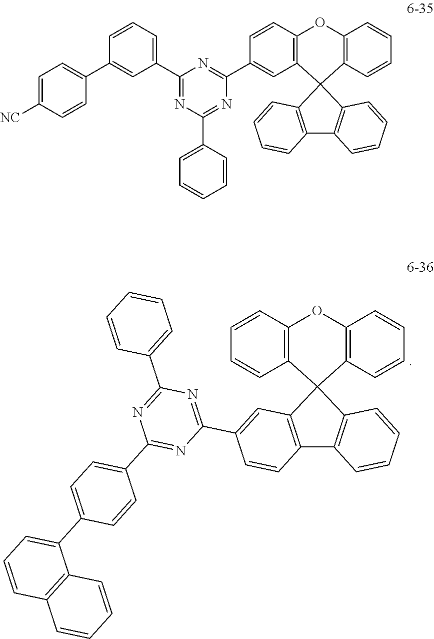 [SMILES: N#Cc1ccc(-c2cccc(-c3nc(-c4ccccc4)nc(-c4ccc5c(c4)C4(c6ccccc6O5)c5ccccc5-c5ccccc54)n3)c2)cc1 ; c1ccc(-c2nc(-c3ccc(-c4cccc5ccccc45)cc3)nc(-c3ccc4c(c3)C3(c5ccccc5Oc5ccccc53)c3ccccc3-4)n2)cc1]

Hereinafter, the synthesis examples of compound represented by Formulas 1 to 6 according to the present invention, and preparation methods of an organic electric element will be described in detail by way of examples. However, the present invention is not limited to the following examples.

### [Synthesis Example 1] Synthesis Example of Formula 1

Compound (final product 1) represented by Formula 1 according to the present invention can be synthesized as shown in Reaction Scheme 1 below, but is not limited thereto.

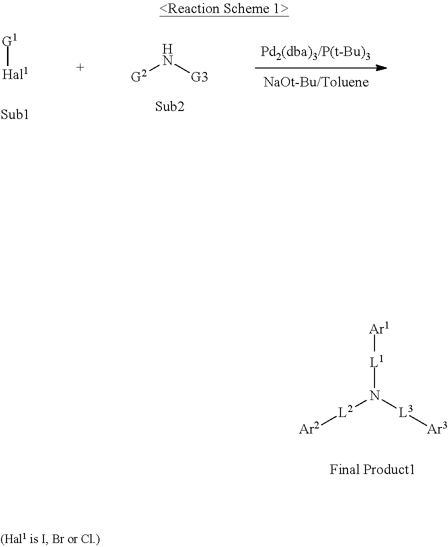

### Exemplary Compounds of Sub1

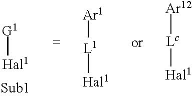

Compounds belonging to Sub 1 may be, but not limited to, the following compounds, and Table 1 shows FD-MS (Field Desorption-Mass Spectrometry) values of the following compounds.

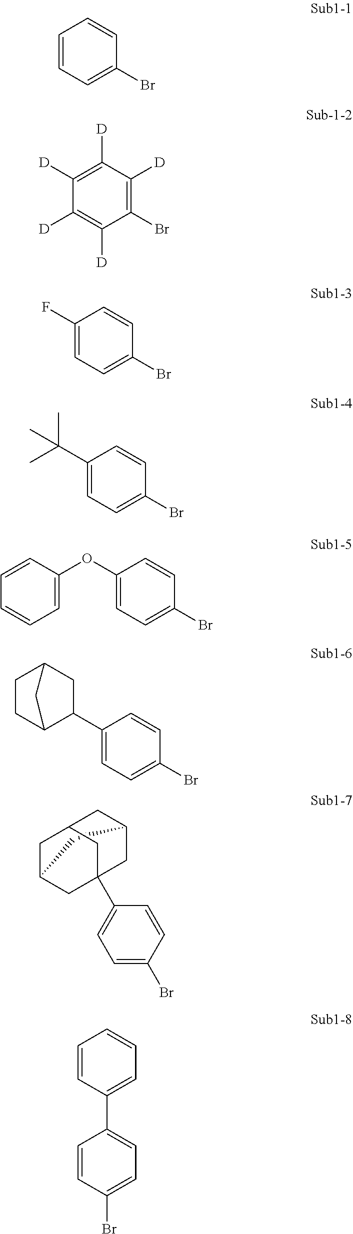

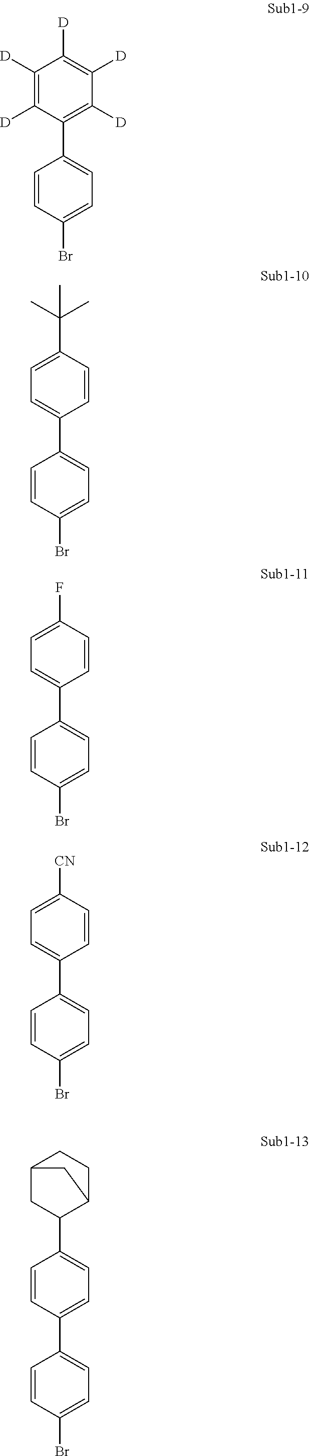

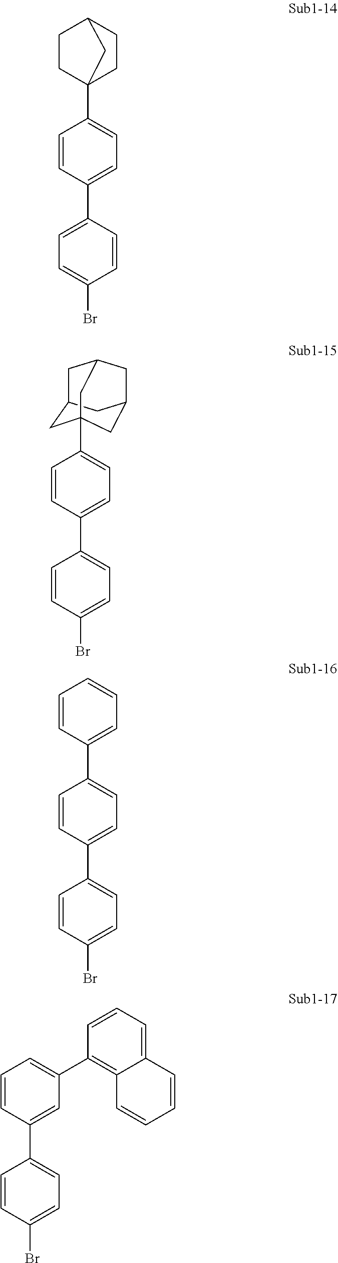

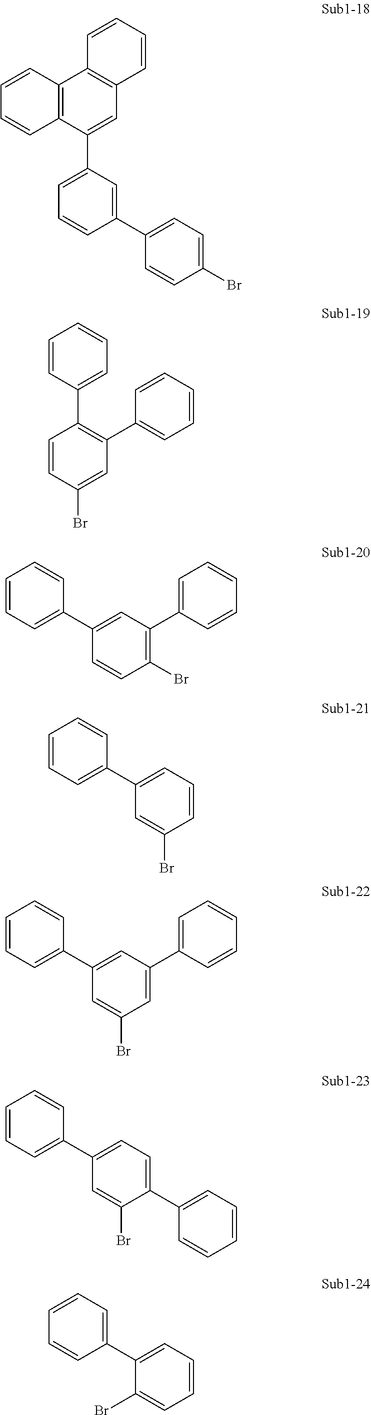

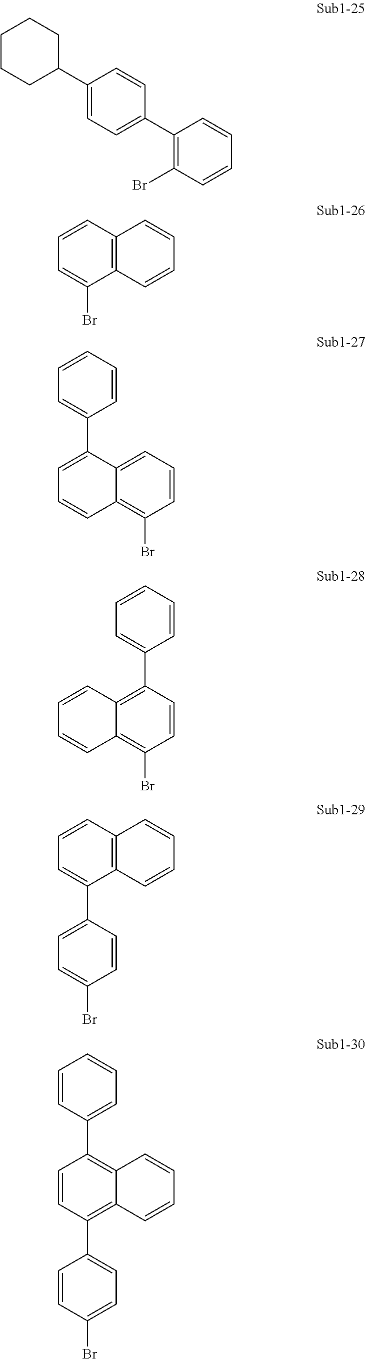

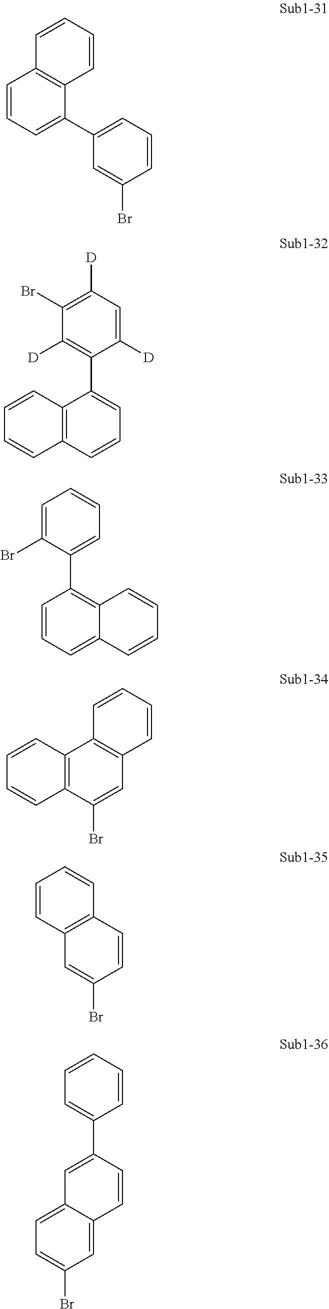

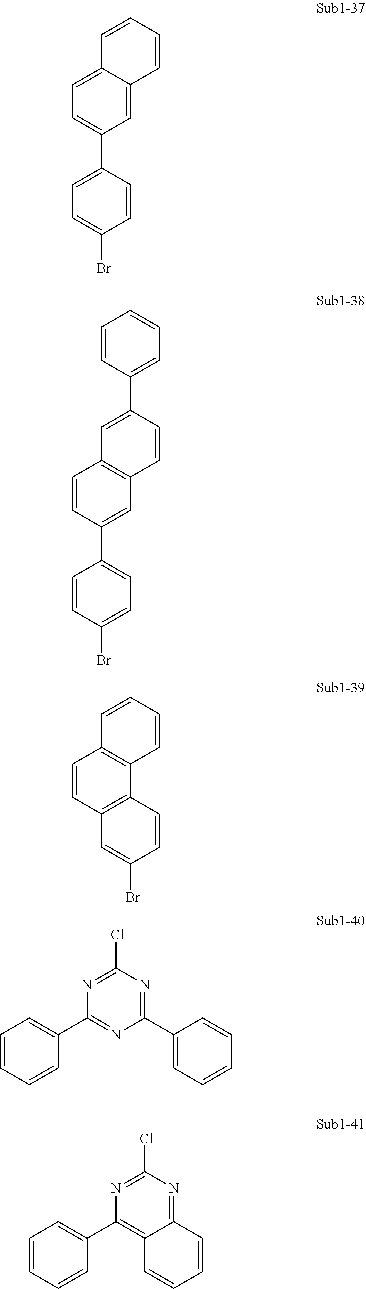

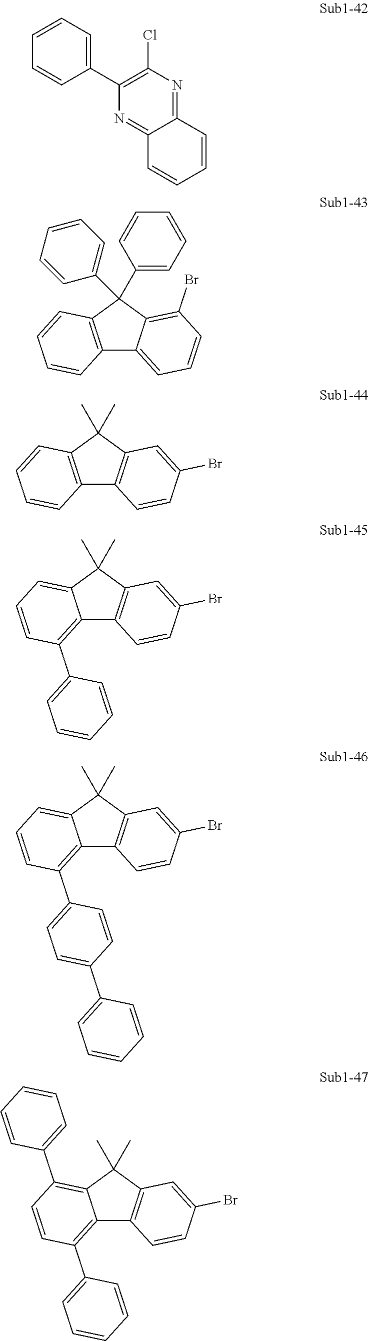

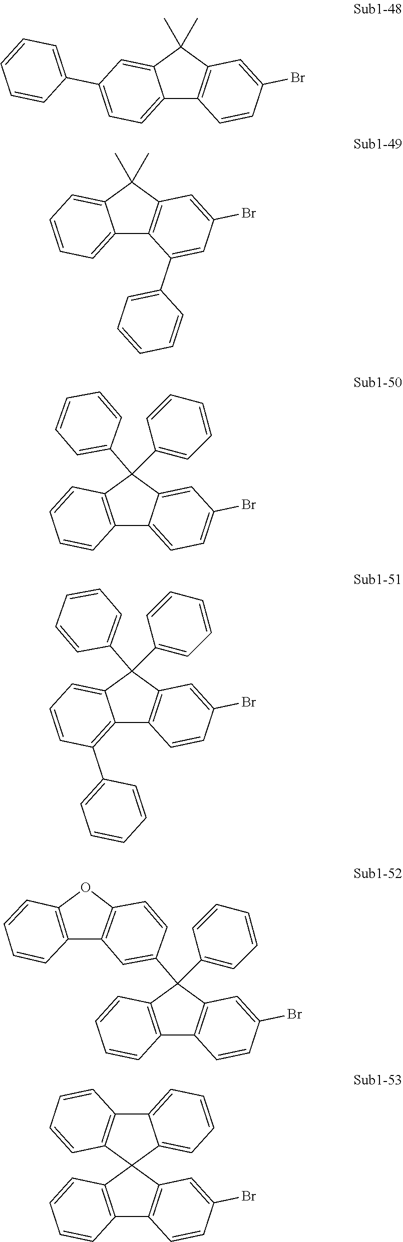

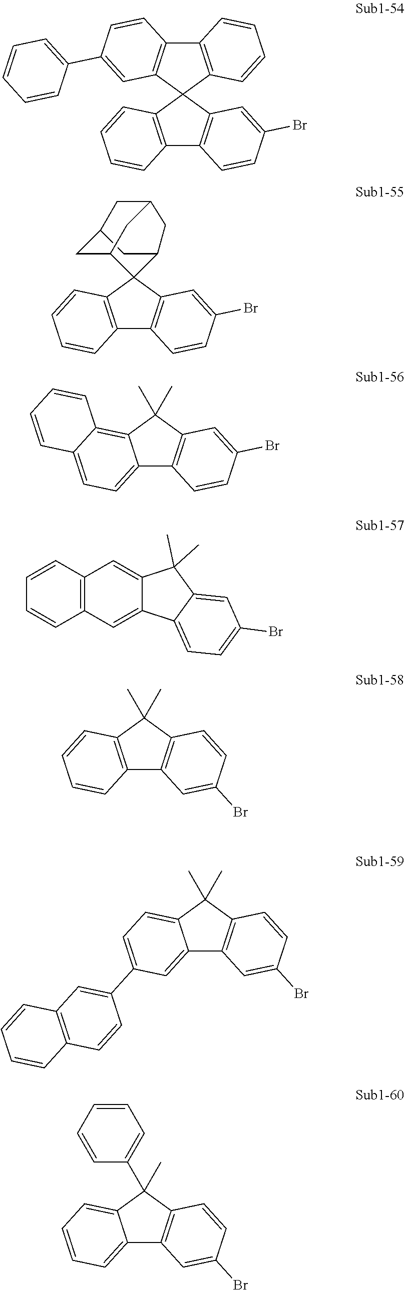

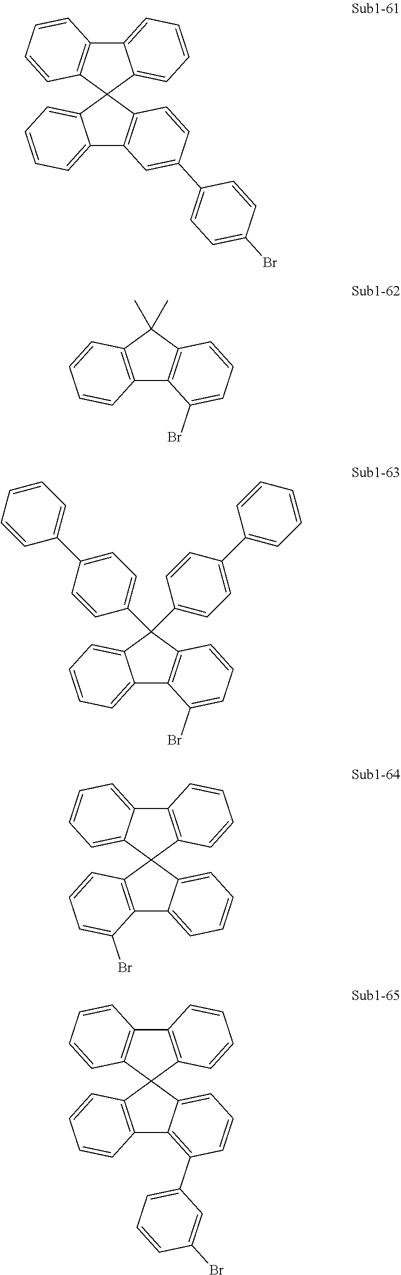

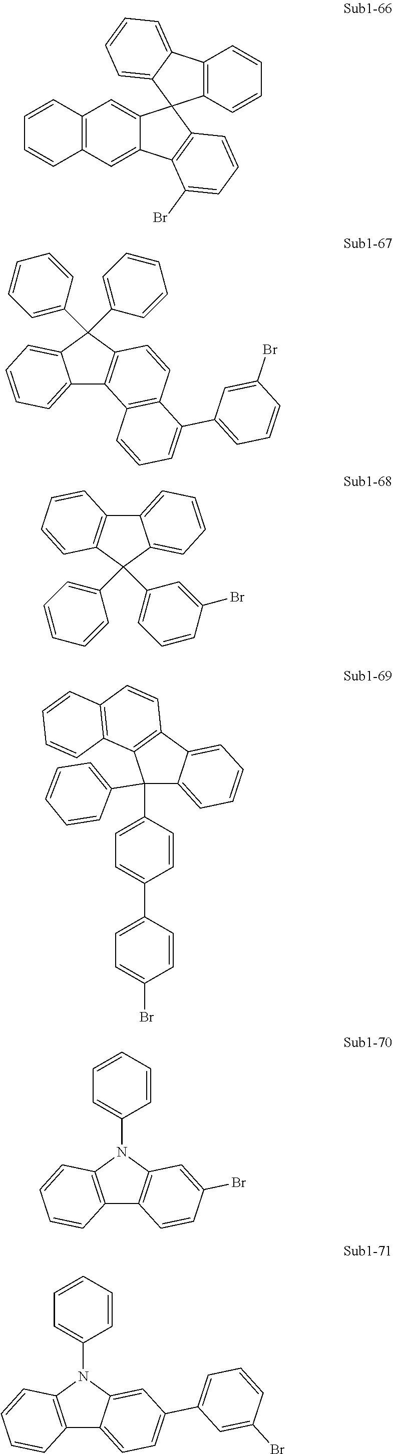

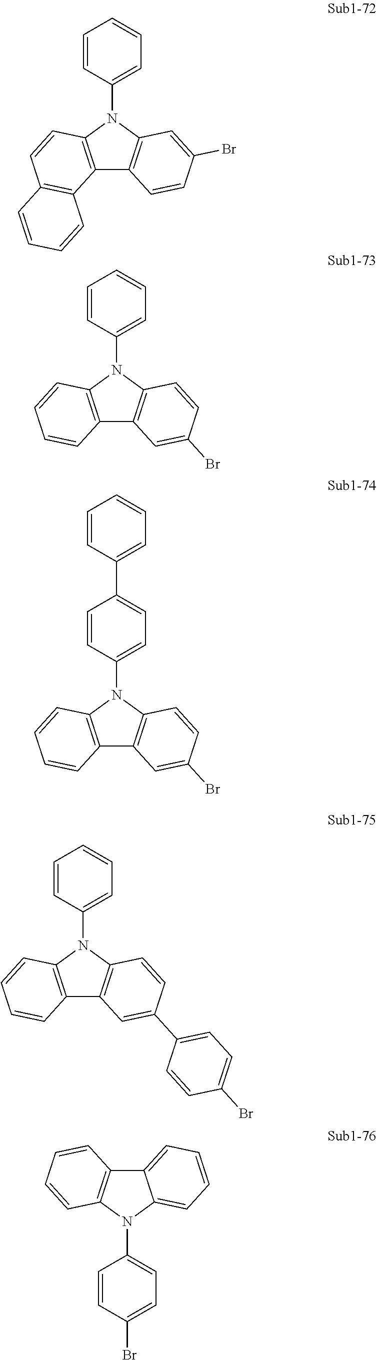

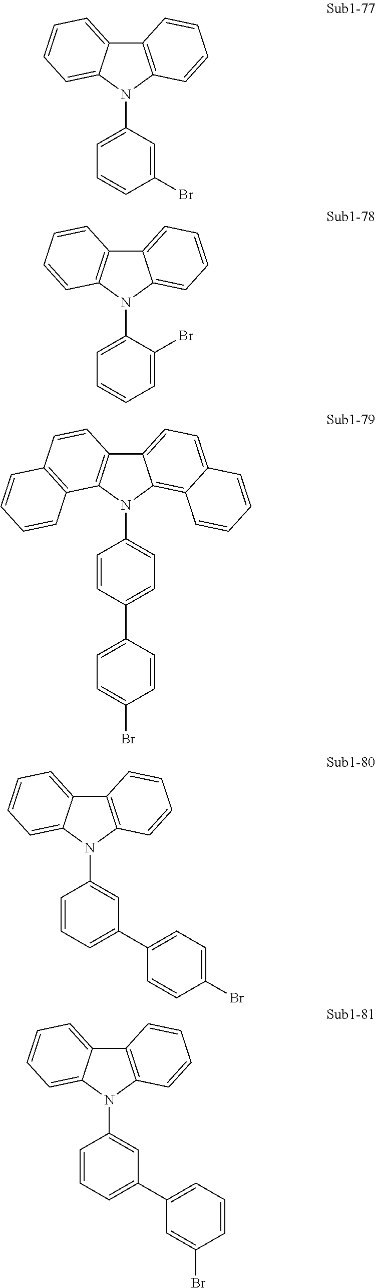

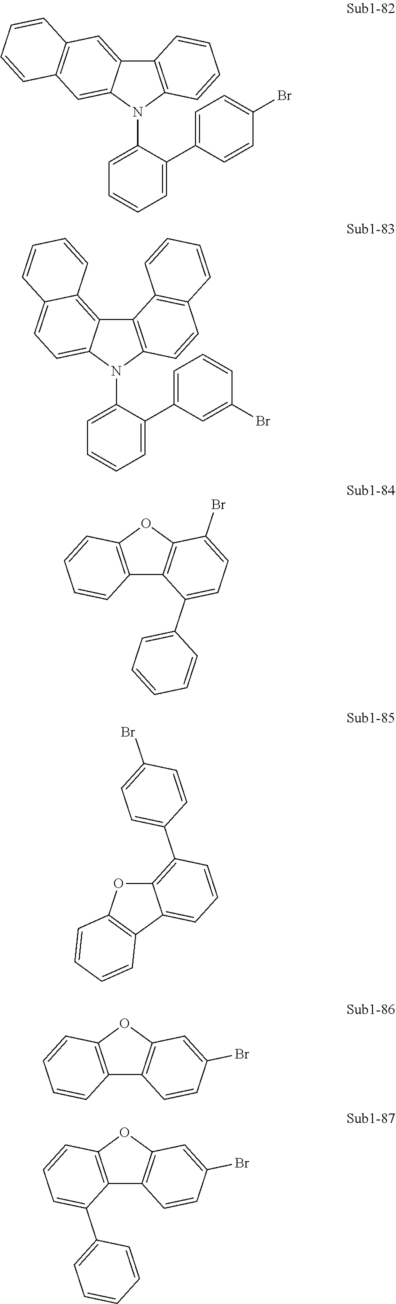

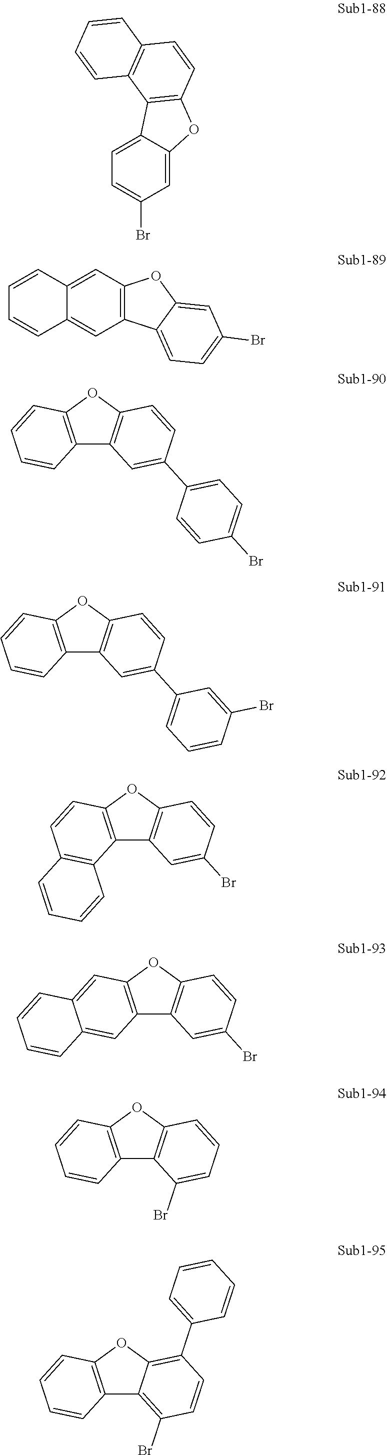

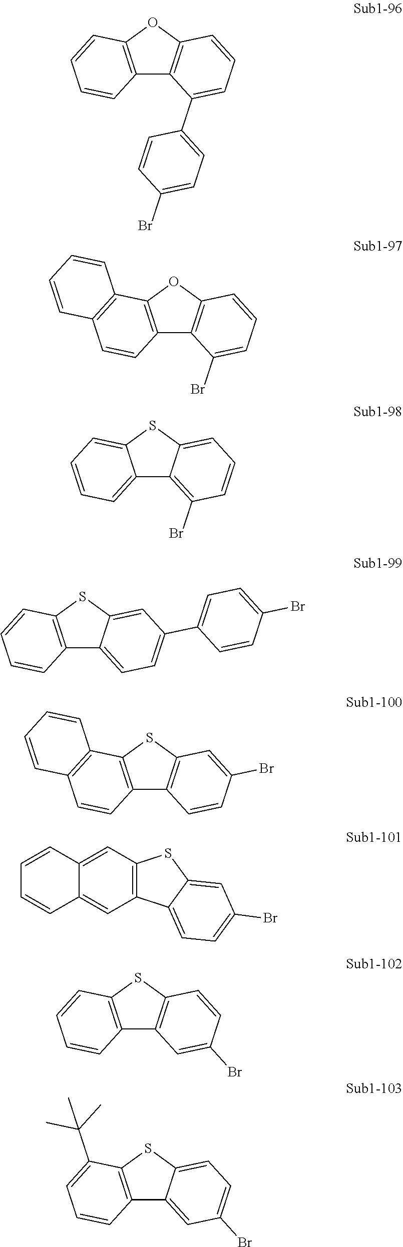

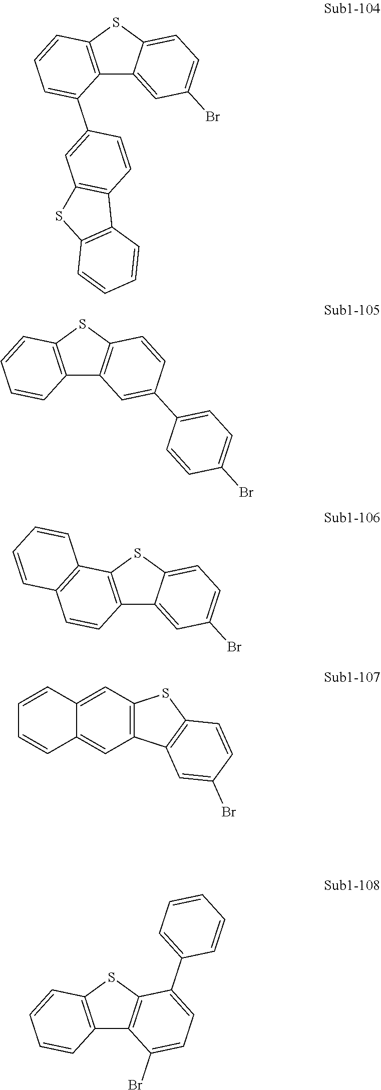

TABLE 1

| Compound | FD-MS | Compound | FD-MS |
|---|---|---|---|
| Sub1-1 | m/z = 155.96(C₆H₅Br = 157.01) | Sub1-2 | m/z = 160.99(C₆D₅Br = 162.04) |
| Sub1-3 | m/z = 173.95(C₆H₄BrF = 175) | Sub1-4 | m/z = 212.02(C₁₀H₁₃Br = 213.12) |
| Sub1-5 | m/z = 247.98(C₁₂H₉BrO = 249.11) | Sub1-6 | m/z = 250.04(C₁₃H₁₅Br = 251.17) |
| Sub1-7 | m/z = 290.07(C₁₆H₁₉Br = 291.23) | Sub1-8 | m/z = 231.99(C₁₂H₉Br = 233.11) |
| Sub1-9 | m/z = 237.02(C₁₂H₄D₅Br = 238.14) | Sub1-10 | m/z = 288.05(C₁₆H₁₇Br = 289.22) |
| Sub1-11 | m/z = 249.98(C₁₂H₈BrF = 251.1) | Sub1-12 | m/z = 256.98(C₁₃H₈BrN = 258.12) |
| Sub1-13 | m/z = 326.07(C₁₉H₁₉Br = 327.27) | Sub1-14 | m/z = 326.07(C₁₉H₁₉Br = 327.27) |
| Sub1-15 | m/z = 366.1(C₂₂H₂₃Br = 367.33) | Sub1-16 | m/z = 308.02(C₁₈H₁₃Br = 309.21) |
| Sub1-17 | m/z = 358.04(C₂₂H₁₅Br = 359.27) | Sub1-18 | m/z = 408.05(C₂₆H₁₇Br = 409.33) |
| Sub1-19 | m/z = 308.02(C₁₈H₁₃Br = 309.21) | Sub1-20 | m/z = 308.02(C₁₈H₁₃Br = 309.21) |
| Sub1-21 | m/z = 231.99(C₁₂H₉Br = 233.11) | Sub1-22 | m/z = 308.02(C₁₈H₁₃Br = 309.21) |
| Sub1-23 | m/z = 308.02(C₁₈H₁₃Br = 309.21) | Sub1-24 | m/z = 231.99(C₁₂H₉Br = 233.11) |
| Sub1-25 | m/z = 314.07(C₁₈H₁₉Br = 315.25) | Sub1-26 | m/z = 205.97(C₁₀H₇Br = 207.07) |
| Sub1-27 | m/z = 282(C₁₆H₁₁Br = 283.17) | Sub1-28 | m/z = 282(C₁₆H₁₁Br = 283.17) |
| Sub1-29 | m/z = 282(C₁₆H₁₁Br = 283.17) | Sub1-30 | m/z = 358.04(C₂₂H₁₅Br = 359.27) |
| Sub1-31 | m/z = 282(C₁₆H₁₁Br = 283.17) | Sub1-32 | m/z = 285.02(C₁₆H₈D₃Br = 286.19) |
| Sub1-33 | m/z = 282(C₁₆H₁₁Br = 283.17) | Sub1-34 | m/z = 255.99(C₁₄H₉Br = 257.13) |
| Sub1-35 | m/z = 205.97(C₁₀H₇Br = 207.07) | Sub1-36 | m/z = 282(C₁₆H₁₁Br = 283.17) |
| Sub1-37 | m/z = 282(C₁₆H₁₁Br = 283.17) | Sub1-38 | m/z = 358.04(C₂₂H₁₅Br = 359.27) |
| Sub1-39 | m/z = 255.99(C₁₄H₉Br = 257.13) | Sub1-40 | m/z = 267.06(C₁₅H₁₀ClN₃ = 267.72) |
| Sub1-41 | m/z = 240.05(C₁₄H₉ClN₂ = 240.69) | Sub1-42 | m/z = 240.05(C₁₄H₉ClN₂ = 240.69) |
| Sub1-43 | m/z = 396.05(C₂₅H₁₇Br = 397.32) | Sub1-44 | m/z = 272.02(C₁₅H₁₃Br = 273.17) |
| Sub1-45 | m/z = 348.05(C₂₁H₁₇Br = 349.27) | Sub1-46 | m/z = 424.08(C₂₇H₂₁Br = 425.37) |
| Sub1-47 | m/z = 424.08(C₂₇H₂₁Br = 425.37) | Sub1-48 | m/z = 348.05(C₂₁H₁₇Br = 349.27) |
| Sub1-49 | m/z = 348.05(C₂₁H₁₇Br = 349.27) | Sub1-50 | m/z = 396.05(C₂₅H₁₇Br = 397.32) |
| Sub1-51 | m/z = 472.08(C₃₁H₂₁Br = 473.41) | Sub1-52 | m/z = 486.06(C₃₁H₁₉BrO = 487.4) |
| Sub1-53 | m/z = 394.04(C₂₅H₁₅Br = 395.3) | Sub1-54 | m/z = 470.07(C₃₁H₁₉Br = 471.4) |
| Sub1-55 | m/z = 364.08(C₂₂H₂₁Br = 365.31) | Sub1-56 | m/z = 322.04(C₁₉H₁₅Br = 323.23) |
| Sub1-57 | m/z = 322.04(C₁₉H₁₅Br = 323.23) | Sub1-58 | m/z = 272.02(C₁₅H₁₃Br = 273.17) |
| Sub1-59 | m/z = 398.07(C₂₅H₁₉Br = 399.33) | Sub1-60 | m/z = 334.04(C₂₀H₁₅Br = 335.24) |
| Sub1-61 | m/z = 470.07(C₃₁H₁₉Br = 471.4) | Sub1-62 | m/z = 272.02(C₁₅H₁₃Br = 273.17) |
| Sub1-63 | m/z = 548.11(C₃₇H₂₅Br = 549.51) | Sub1-64 | m/z = 394.04(C₂₅H₁₅Br = 395.3) |
| Sub1-65 | m/z = 470.07(C₃₁H₁₉Br = 471.4) | Sub1-66 | m/z = 444.05(C₂₉H₁₇Br = 445.36) |
| Sub1-67 | m/z = 522.1(C₃₅H₂₃Br = 523.47) | Sub1-68 | m/z = 396.05(C₂₅H₁₇Br = 397.32) |
| Sub1-69 | m/z = 522.1(C₃₅H₂₃Br = 523.47) | Sub1-70 | m/z = 321.02(C₁₈H₁₂BrN = 322.21) |
| Sub1-71 | m/z = 397.05(C₂₄H₁₆BrN = 398.3) | Sub1-72 | m/z = 371.03(C₂₂H₁₄BrN = 372.27) |
| Sub1-73 | m/z = 321.02(C₁₈H₁₂BrN = 322.21) | Sub1-74 | m/z = 397.05(C₂₄H₁₆BrN = 398.3) |
| Sub1-75 | m/z = 397.05(C₂₄H₁₆BrN = 398.3) | Sub1-76 | m/z = 321.02(C₁₈H₁₂BrN = 322.21) |
| Sub1-77 | m/z = 321.02(C₁₈H₁₂BrN = 322.21) | Sub1-78 | m/z = 321.02(C₁₈H₁₂BrN = 322.21) |
| Sub1-79 | m/z = 497.08(C₃₂H₂₀BrN = 498.42) | Sub1-80 | m/z = 397.05(C₂₄H₁₆BrN = 398.3) |
| Sub1-81 | m/z = 397.05(C₂₄H₁₆BrN = 398.3) | Sub1-82 | m/z = 447.06(C₂₈H₁₈BrN = 448.36) |
| Sub1-83 | m/z = 497.08(C₃₂H₂₀BrN = 498.42) | Sub1-84 | m/z = 322(C₁₈H₁₁BrO = 323.19) |
| Sub1-85 | m/z = 322(C₁₈H₁₁BrO = 323.19) | Sub1-86 | m/z = 245.97(C₁₂H₇BrO = 247.09) |
| Sub1-87 | m/z = 322(C₁₈H₁₁BrO = 323.19) | Sub1-88 | m/z = 295.98(C₁₆H₉BrO = 297.15) |
| Sub1-89 | m/z = 295.98(C₁₆H₉BrO = 297.15) | Sub1-90 | m/z = 322(C₁₈H₁₁BrO = 323.19) |
| Sub1-91 | m/z = 322(C₁₈H₁₁BrO = 323.19) | Sub1-92 | m/z = 295.98(C₁₆H₉BrO = 297.15) |
| Sub1-93 | m/z = 295.98(C₁₆H₉BrO = 297.15) | Sub1-94 | m/z = 245.97(C₁₂H₇BrO = 247.09) |
| Sub1-95 | m/z = 322(C₁₈H₁₁BrO = 323.19) | Sub1-96 | m/z = 322(C₁₈H₁₁BrO = 323.19) |
| Sub1-97 | m/z = 295.98(C₁₆H₉BrO = 297.15) | Sub1-98 | m/z = 261.95(C₁₂H₇BrS = 263.15) |
| Sub1-99 | m/z = 337.98(C₁₈H₁₁BrS = 339.25) | Sub1-100 | m/z = 311.96(C₁₆H₉BrS = 313.21) |
| Sub1-101 | m/z = 311.96(C₁₆H₉BrS = 313.21) | Sub1-102 | m/z = 261.95(C₁₂H₇BrS = 263.15) |
| Sub1-103 | m/z = 318.01(C₁₆H₁₅BrS = 319.26) | Sub1-104 | m/z = 443.96(C₂₄H₁₃BrS₂ = 445.39) |
| Sub1-105 | m/z = 337.98(C₁₈H₁₁BrS = 339.25) | Sub1-106 | m/z = 311.96(C₁₆H₉BrS = 313.21) |
| Sub1-107 | m/z = 311.96(C₁₆H₉BrS = 313.21) | Sub1-108 | m/z = 337.98(C₁₈H₁₁BrS = 339.25) |

### Exemplary Compounds of Sub2

Sub 2 of Reaction Scheme 1 may be synthesized (disclosed in the applicant's Korean Patent No. 10-1251451 (issued dated Apr. 5, 2013)) by the reaction route of Scheme 2, but is not limited thereto.

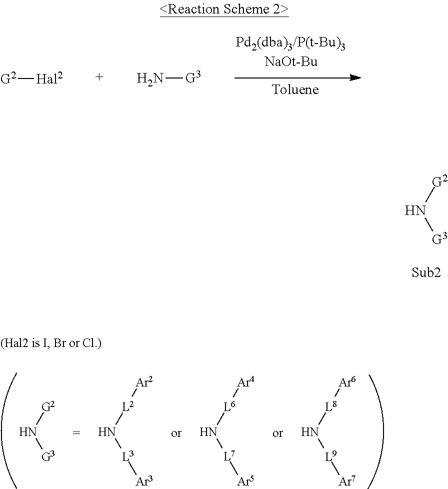

Compounds belonging to Sub 2 may be, but not limited to, the following compounds, and Table 2 shows FD-MS values of the following compounds.

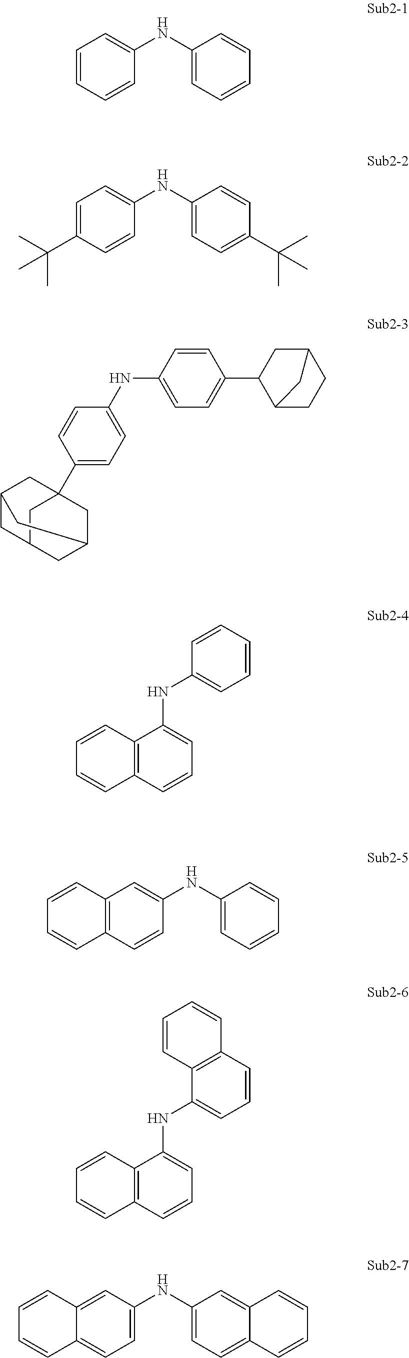

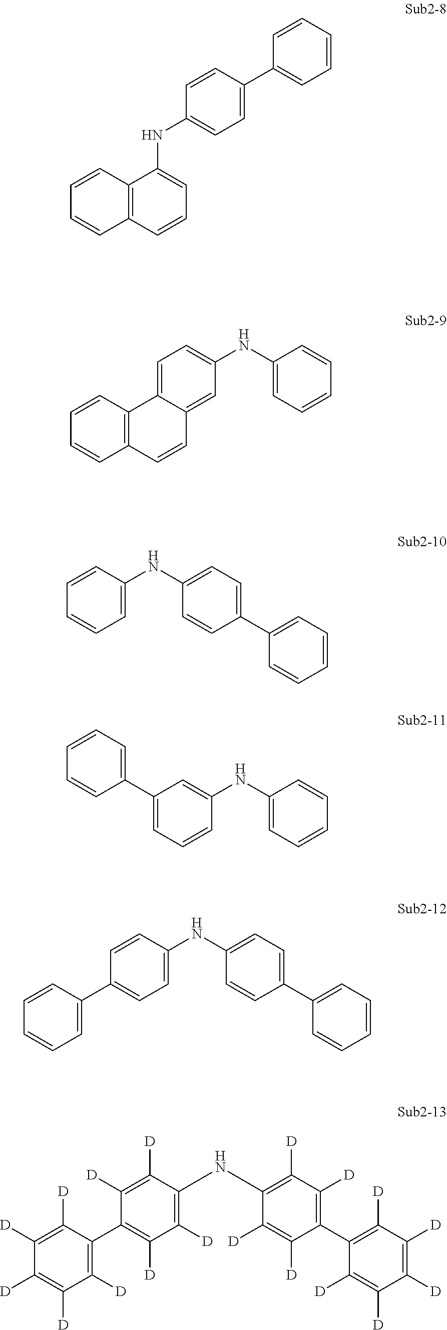 [SMILES: c1ccc(-c2ccc(Nc3cccc4ccccc34)cc2)cc1 ; c1ccc(Nc2ccc3c(ccc4ccccc43)c2)cc1 ; c1ccc(Nc2ccc(-c3ccccc3)cc2)cc1 ; c1ccc(Nc2cccc(-c3ccccc3)c2)cc1 ; c1ccc(-c2ccc(Nc3ccc(-c4ccccc4)cc3)cc2)cc1 ; [2H]c1c([2H])c([2H])c(-c2c([2H])c([2H])c(Nc3c([2H])c([2H])c(-c4c([2H])c([2H])c([2H])c([2H])c4[2H])c([2H])c3[2H])c([2H])c2[2H])c([2H])c1[2H]]

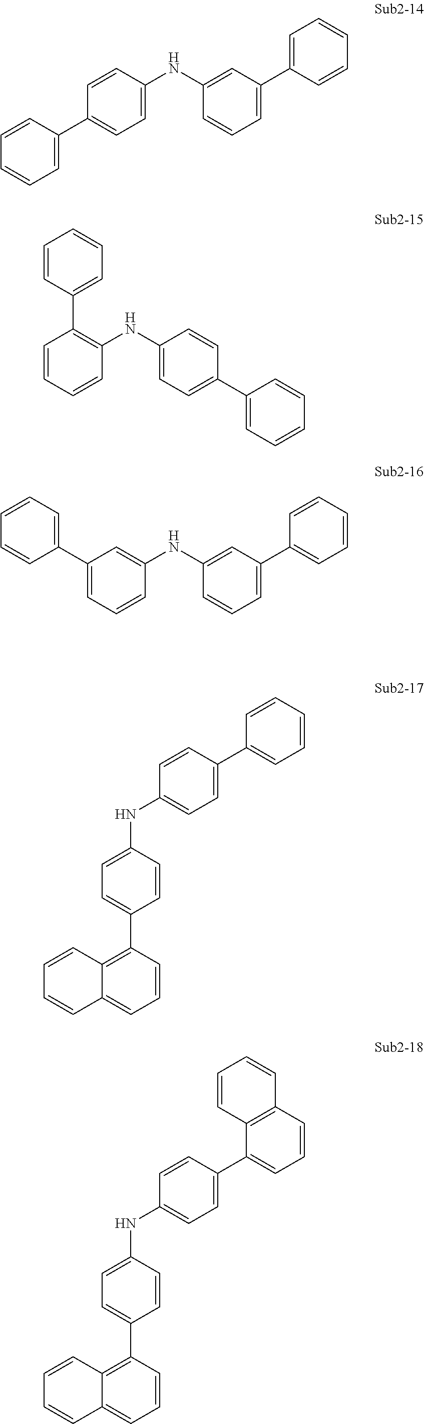 [SMILES: c1ccc(-c2ccc(Nc3cccc(-c4ccccc4)c3)cc2)cc1 ; c1ccc(-c2ccc(Nc3ccccc3-c3ccccc3)cc2)cc1 ; c1ccc(-c2cccc(Nc3cccc(-c4ccccc4)c3)c2)cc1 ; c1ccc(-c2ccc(Nc3ccc(-c4cccc5ccccc45)cc3)cc2)cc1 ; c1ccc2c(-c3ccc(Nc4ccc(-c5cccc6ccccc56)cc4)cc3)cccc2c1]

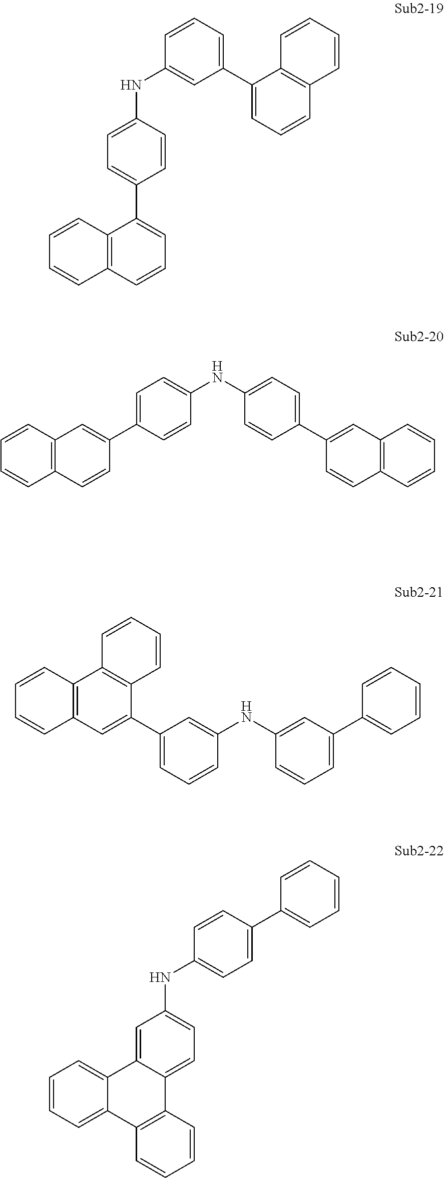 [SMILES: c1cc(Nc2ccc(-c3cccc4ccccc34)cc2)cc(-c2cccc3ccccc23)c1 ; c1ccc2cc(-c3ccc(Nc4ccc(-c5ccc6ccccc6c5)cc4)cc3)ccc2c1 ; c1ccc(-c2cccc(Nc3cccc(-c4cc5ccccc5c5ccccc45)c3)c2)cc1 ; c1ccc(-c2ccc(Nc3ccc4c5ccccc5c5ccccc5c4c3)cc2)cc1]

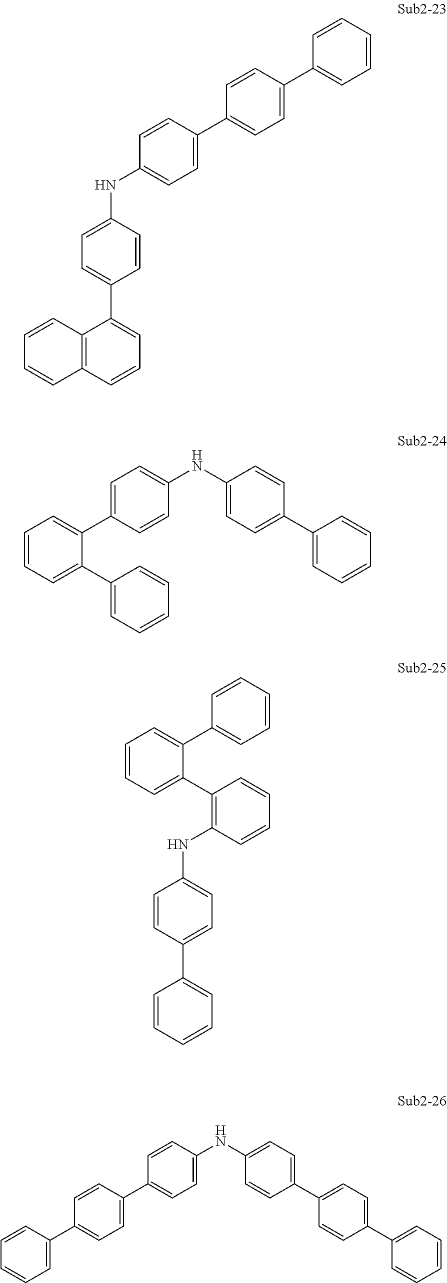 [SMILES: c1ccc(-c2ccc(-c3ccc(Nc4ccc(-c5cccc6ccccc56)cc4)cc3)cc2)cc1 ; c1ccc(-c2ccc(Nc3ccc(-c4ccccc4-c4ccccc4)cc3)cc2)cc1 ; c1ccc(-c2ccc(Nc3ccccc3-c3ccccc3-c3ccccc3)cc2)cc1 ; c1ccc(-c2ccc(-c3ccc(Nc4ccc(-c5ccc(-c6ccccc6)cc5)cc4)cc3)cc2)cc1]

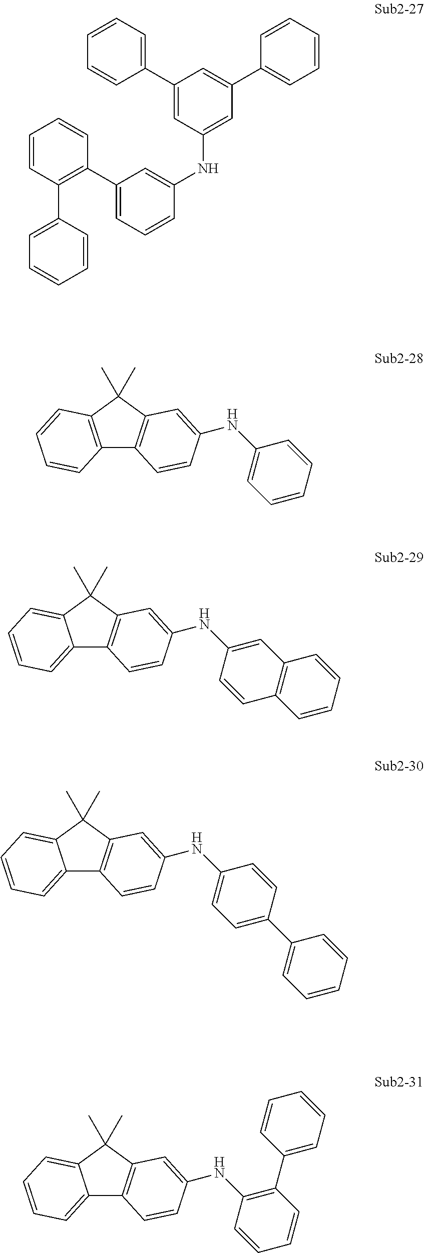 [SMILES: c1ccc(-c2cc(Nc3cccc(-c4ccccc4-c4ccccc4)c3)cc(-c3ccccc3)c2)cc1 ; CC1(C)c2ccccc2-c2ccc(Nc3ccccc3)cc21 ; CC1(C)c2ccccc2-c2ccc(Nc3ccc4ccccc4c3)cc21 ; CC1(C)c2ccccc2-c2ccc(Nc3ccc(-c4ccccc4)cc3)cc21 ; CC1(C)c2ccccc2-c2ccc(Nc3ccccc3-c3ccccc3)cc21]

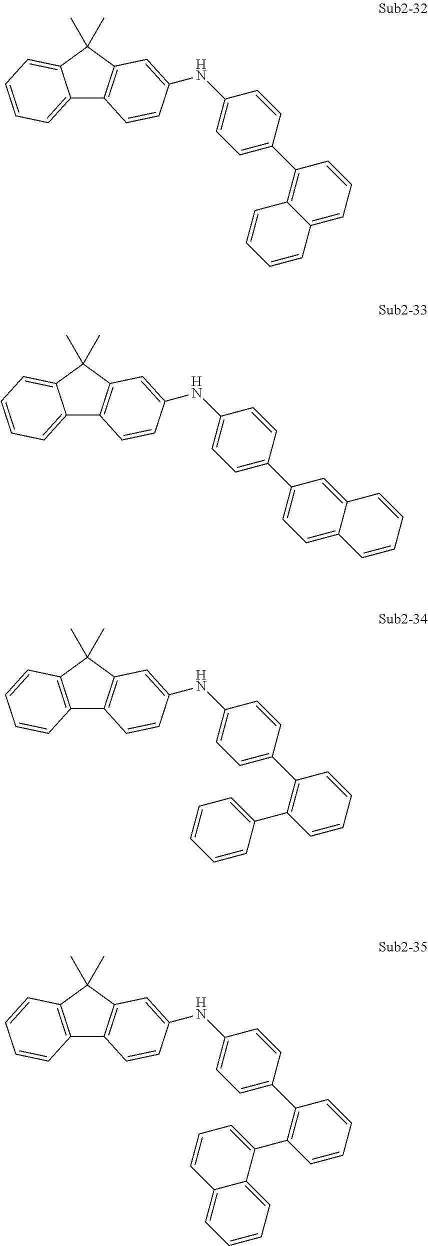 [SMILES: CC1(C)c2ccccc2-c2ccc(Nc3ccc(-c4cccc5ccccc45)cc3)cc21 ; CC1(C)c2ccccc2-c2ccc(Nc3ccc(-c4ccc5ccccc5c4)cc3)cc21 ; CC1(C)c2ccccc2-c2ccc(Nc3ccc(-c4ccccc4-c4ccccc4)cc3)cc21 ; CC1(C)c2ccccc2-c2ccc(Nc3ccc(-c4ccccc4-c4cccc5ccccc45)cc3)cc21]

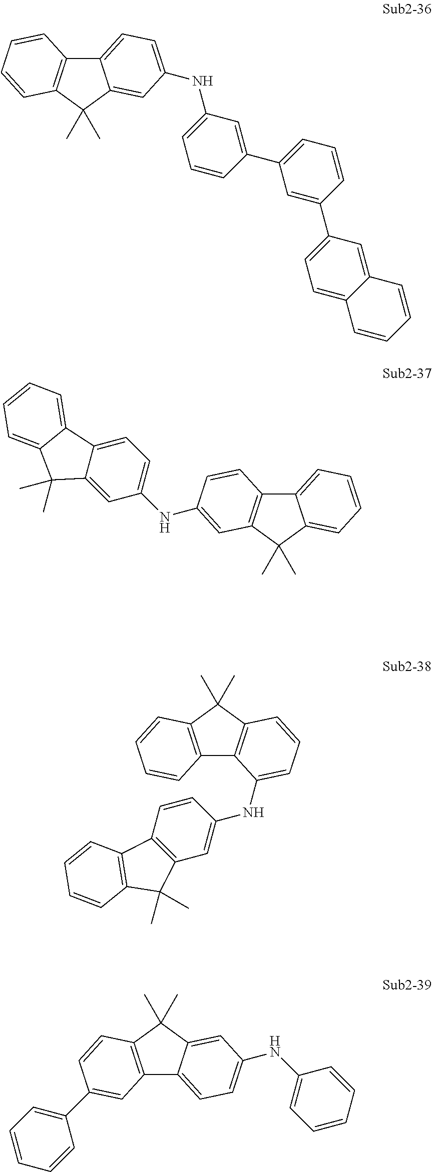 [SMILES: CC1(C)c2ccccc2-c2ccc(Nc3cccc(-c4cccc(-c5ccc6ccccc6c5)c4)c3)cc21 ; CC1(C)c2ccccc2-c2ccc(Nc3ccc4c(c3)C(C)(C)c3ccccc3-4)cc21 ; CC1(C)c2ccccc2-c2ccc(Nc3cccc4c3-c3ccccc3C4(C)C)cc21 ; CC1(C)c2ccc(-c3ccccc3)cc2-c2ccc(Nc3ccccc3)cc21]

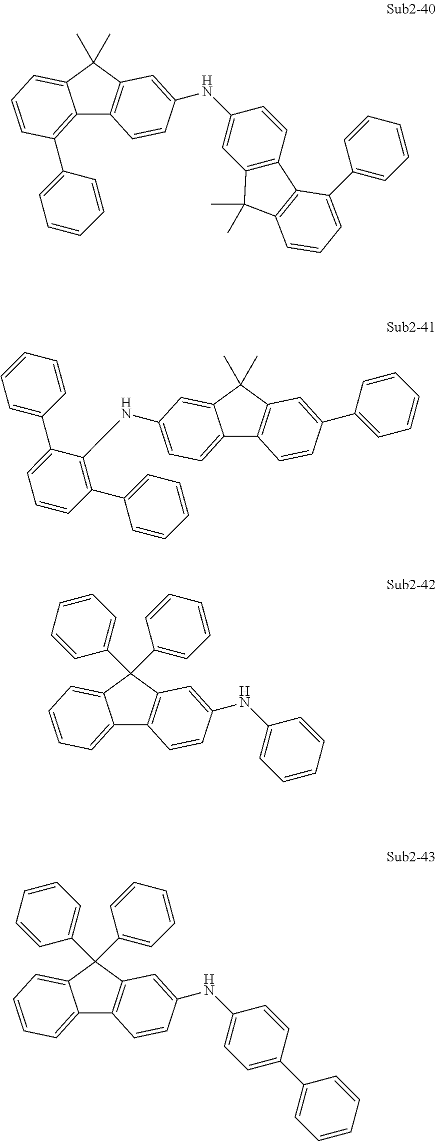 [SMILES: CC1(C)c2cc(Nc3ccc4c(c3)C(C)(C)c3cccc(-c5ccccc5)c3-4)ccc2-c2c(-c3ccccc3)cccc21 ; CC1(C)c2cc(Nc3c(-c4ccccc4)cccc3-c3ccccc3)ccc2-c2ccc(-c3ccccc3)cc21 ; c1ccc(Nc2ccc3c(c2)C(c2ccccc2)(c2ccccc2)c2ccccc2-3)cc1 ; c1ccc(-c2ccc(Nc3ccc4c(c3)C(c3ccccc3)(c3ccccc3)c3ccccc3-4)cc2)cc1]

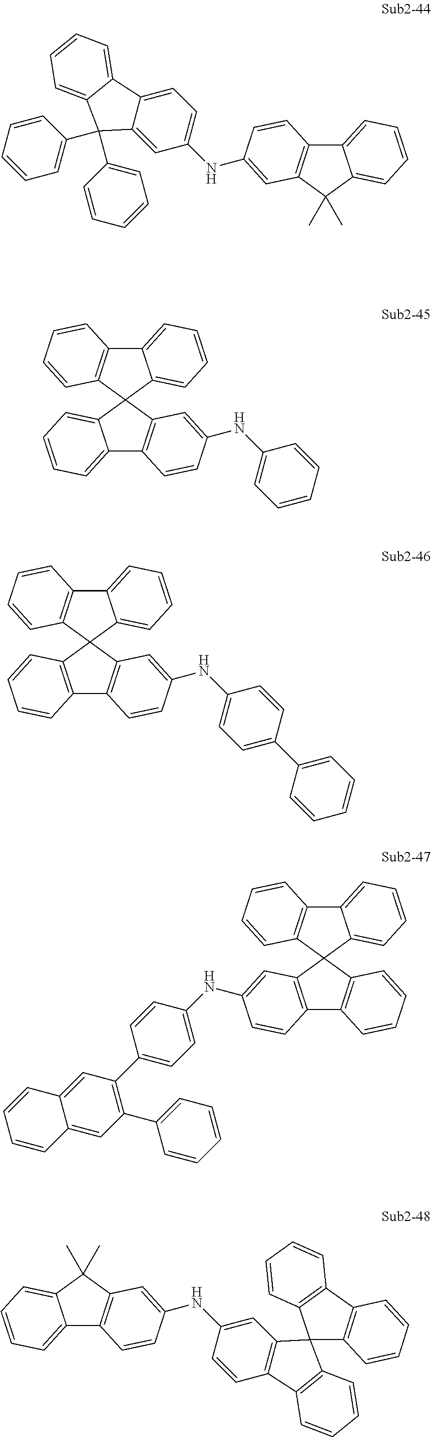 [SMILES: CC1(C)c2ccccc2-c2ccc(Nc3ccc4c(c3)C(c3ccccc3)(c3ccccc3)c3ccccc3-4)cc21 ; c1ccc(Nc2ccc3c(c2)C2(c4ccccc4-c4ccccc42)c2ccccc2-3)cc1 ; c1ccc(-c2ccc(Nc3ccc4c(c3)C3(c5ccccc5-c5ccccc53)c3ccccc3-4)cc2)cc1 ; c1ccc(-c2cc3ccccc3cc2-c2ccc(Nc3ccc4c(c3)C3(c5ccccc5-c5ccccc53)c3ccccc3-4)cc2)cc1 ; CC1(C)c2ccccc2-c2ccc(Nc3ccc4c(c3)C3(c5ccccc5-c5ccccc53)c3ccccc3-4)cc21]

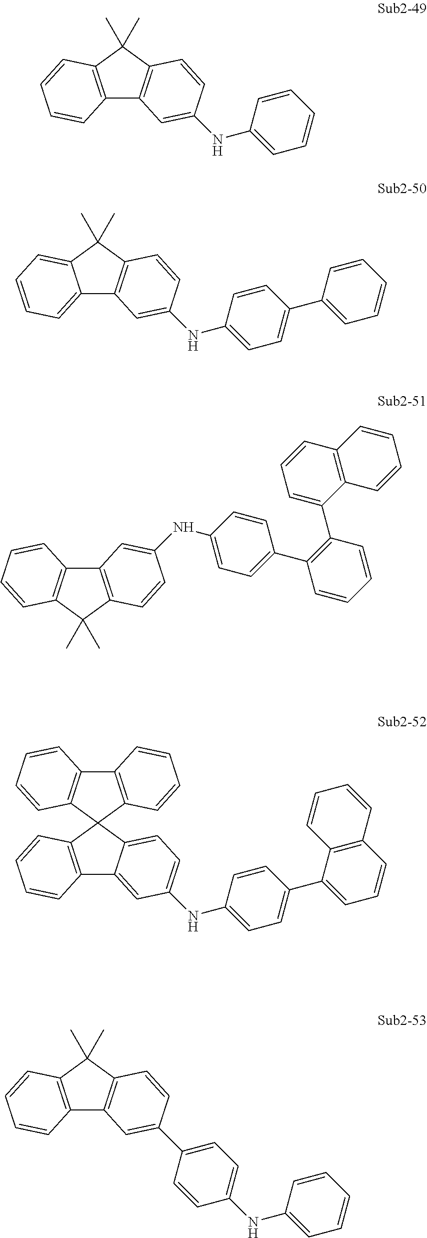 [SMILES: CC1(C)c2ccccc2-c2cc(Nc3ccccc3)ccc21 ; CC1(C)c2ccccc2-c2cc(Nc3ccc(-c4ccccc4)cc3)ccc21 ; CC1(C)c2ccccc2-c2cc(Nc3ccc(-c4ccccc4-c4cccc5ccccc45)cc3)ccc21 ; c1ccc2c(c1)-c1ccccc1C21c2ccccc2-c2cc(Nc3ccc(-c4cccc5ccccc45)cc3)ccc21 ; CC1(C)c2ccccc2-c2cc(-c3ccc(Nc4ccccc4)cc3)ccc21]

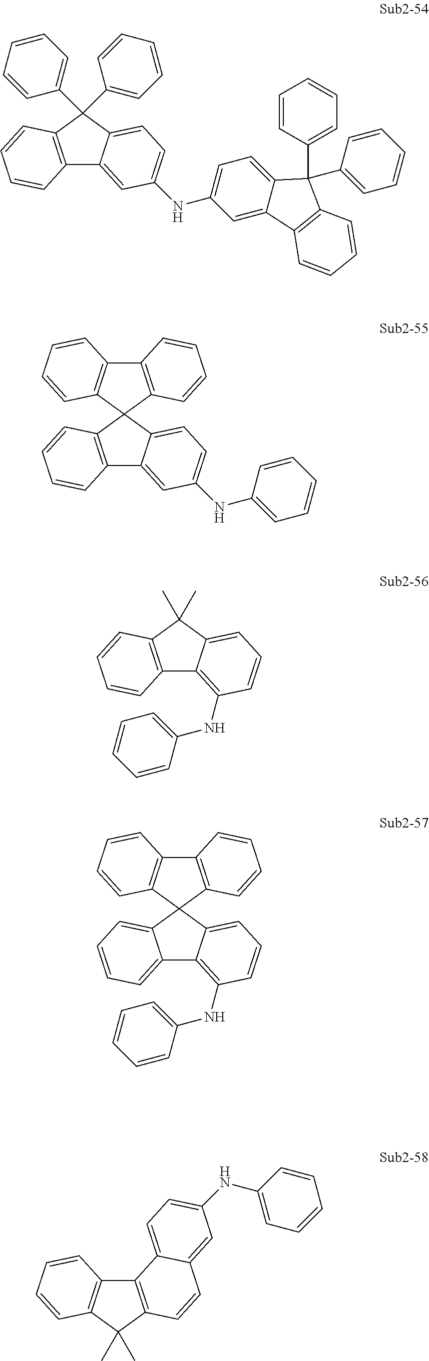 [SMILES: c1ccc(C2(c3ccccc3)c3ccccc3-c3cc(Nc4ccc5c(c4)-c4ccccc4C5(c4ccccc4)c4ccccc4)ccc32)cc1 ; c1ccc(Nc2ccc3c(c2)-c2ccccc2C32c3ccccc3-c3ccccc32)cc1 ; CC1(C)c2ccccc2-c2c(Nc3ccccc3)cccc21 ; c1ccc(Nc2cccc3c2-c2ccccc2C32c3ccccc3-c3ccccc32)cc1 ; CC1(C)c2ccccc2-c2c1ccc1cc(Nc3ccccc3)ccc21]

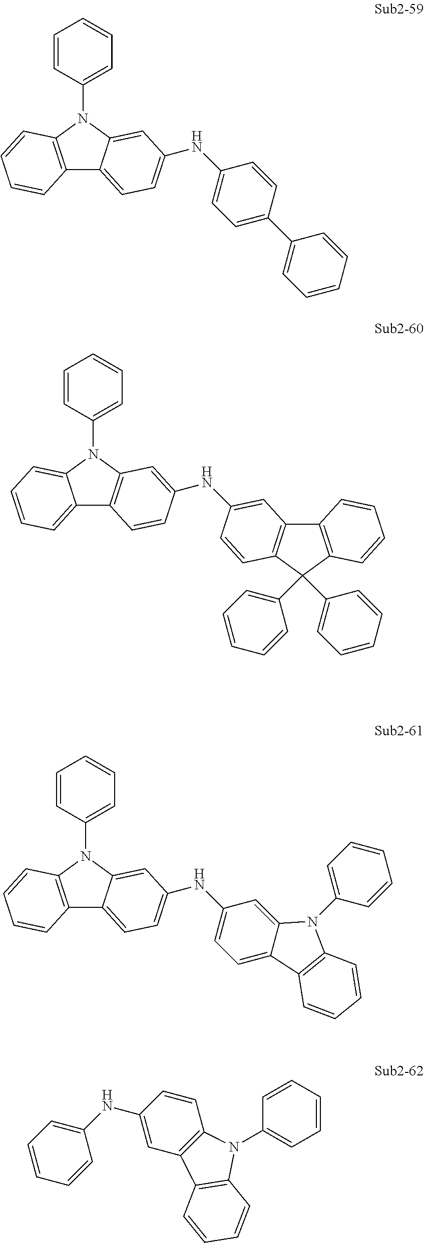 [SMILES: c1ccc(-c2ccc(Nc3ccc4c5ccccc5n(-c5ccccc5)c4c3)cc2)cc1 ; c1ccc(-n2c3ccccc3c3ccc(Nc4ccc5c(c4)-c4ccccc4C5(c4ccccc4)c4ccccc4)cc32)cc1 ; c1ccc(-n2c3ccccc3c3ccc(Nc4ccc5c6ccccc6n(-c6ccccc6)c5c4)cc32)cc1 ; c1ccc(Nc2ccc3c(c2)c2ccccc2n3-c2ccccc2)cc1]

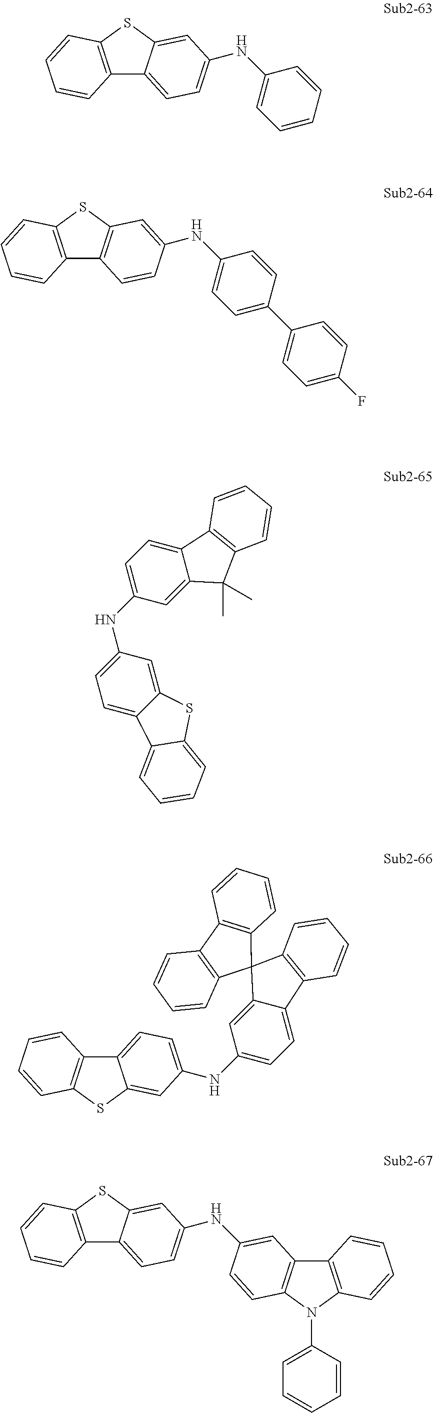 [SMILES: c1ccc(Nc2ccc3c(c2)sc2ccccc23)cc1 ; Fc1ccc(-c2ccc(Nc3ccc4c(c3)sc3ccccc34)cc2)cc1 ; CC1(C)c2ccccc2-c2ccc(Nc3ccc4c(c3)sc3ccccc34)cc21 ; c1ccc2c(c1)-c1ccccc1C21c2ccccc2-c2ccc(Nc3ccc4c(c3)sc3ccccc34)cc21 ; c1ccc(-n2c3ccccc3c3cc(Nc4ccc5c(c4)sc4ccccc45)ccc32)cc1]

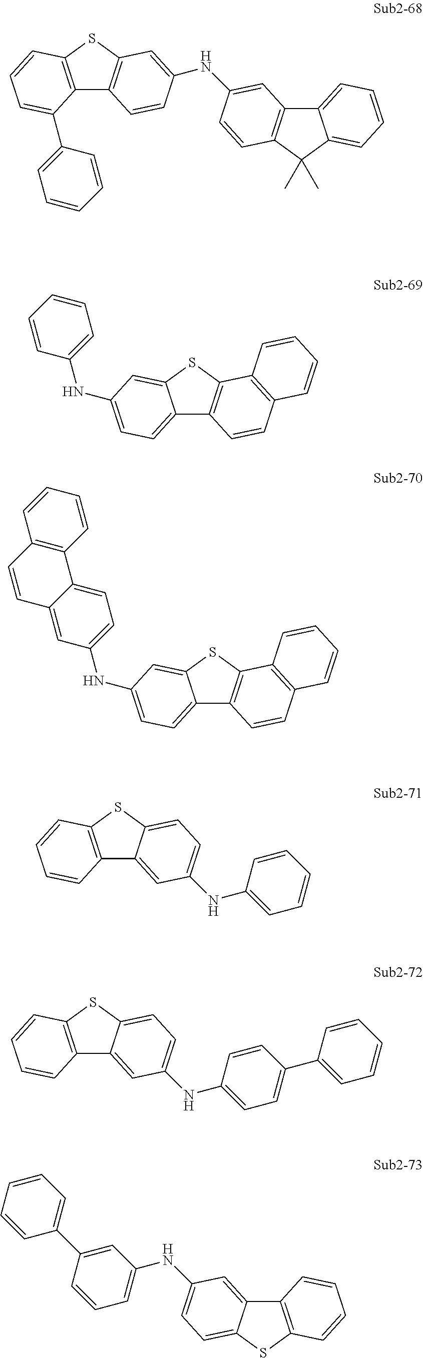 [SMILES: CC1(C)c2ccccc2-c2cc(Nc3ccc4c(c3)sc3cccc(-c5ccccc5)c34)ccc21 ; c1ccc(Nc2ccc3c(c2)sc2c4ccccc4ccc32)cc1 ; c1ccc2c(c1)ccc1cc(Nc3ccc4c(c3)sc3c5ccccc5ccc43)ccc12 ; c1ccc(Nc2ccc3sc4ccccc4c3c2)cc1 ; c1ccc(-c2ccc(Nc3ccc4sc5ccccc5c4c3)cc2)cc1 ; c1ccc(-c2cccc(Nc3ccc4sc5ccccc5c4c3)c2)cc1]

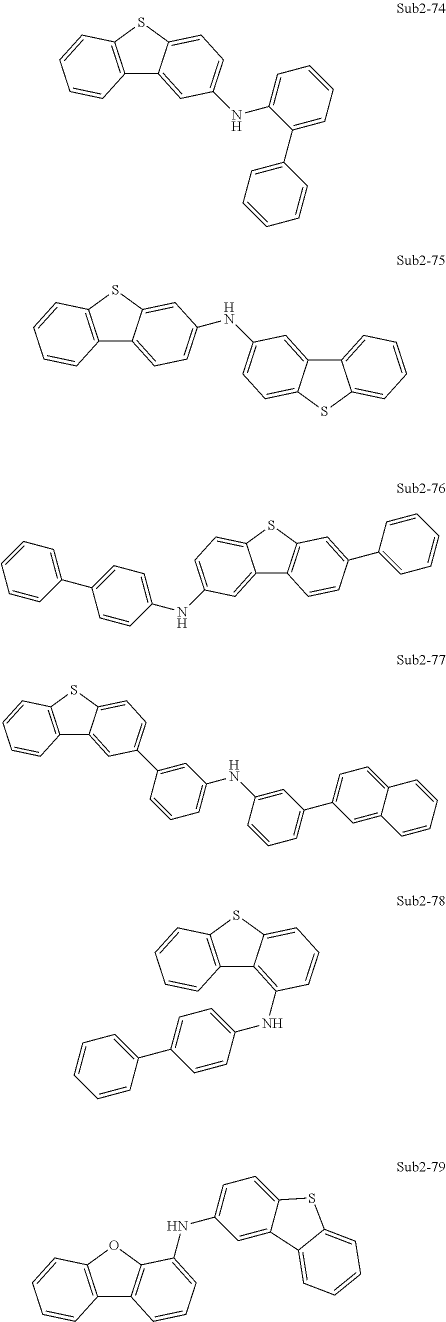 [SMILES: c1ccc(-c2ccccc2Nc2ccc3sc4ccccc4c3c2)cc1 ; c1ccc2c(c1)sc1cc(Nc3ccc4sc5ccccc5c4c3)ccc12 ; c1ccc(-c2ccc(Nc3ccc4sc5cc(-c6ccccc6)ccc5c4c3)cc2)cc1 ; c1cc(Nc2cccc(-c3ccc4sc5ccccc5c4c3)c2)cc(-c2ccc3ccccc3c2)c1 ; c1ccc(-c2ccc(Nc3cccc4sc5ccccc5c34)cc2)cc1 ; c1ccc2c(c1)oc1c(Nc3ccc4sc5ccccc5c4c3)cccc12]

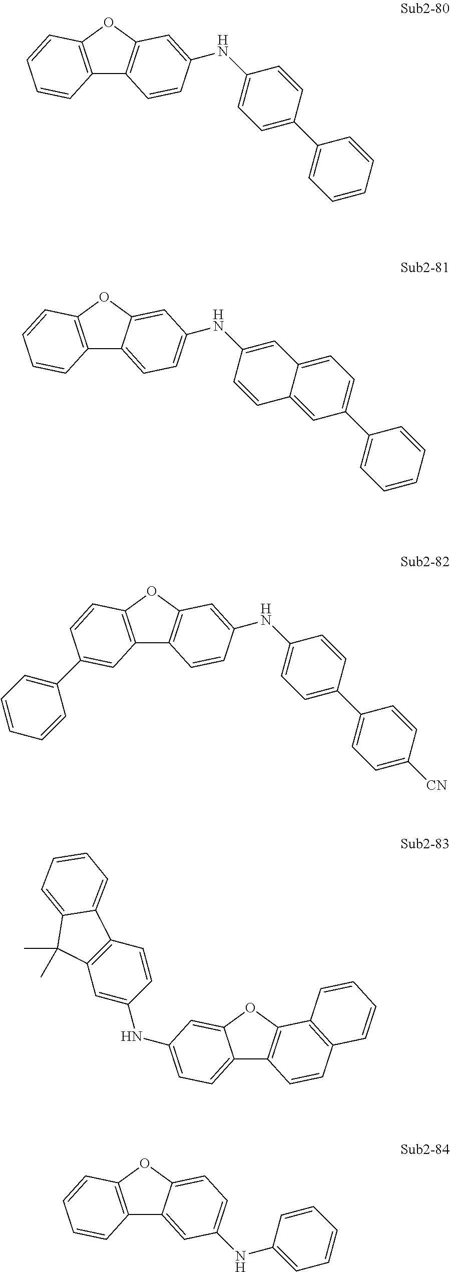 [SMILES: c1ccc(-c2ccc(Nc3ccc4c(c3)oc3ccccc34)cc2)cc1 ; c1ccc(-c2ccc3cc(Nc4ccc5c(c4)oc4ccccc45)ccc3c2)cc1 ; N#Cc1ccc(-c2ccc(Nc3ccc4c(c3)oc3ccc(-c5ccccc5)cc34)cc2)cc1 ; CC1(C)c2ccccc2-c2ccc(Nc3ccc4c(c3)oc3c5ccccc5ccc43)cc21 ; c1ccc(Nc2ccc3oc4ccccc4c3c2)cc1]

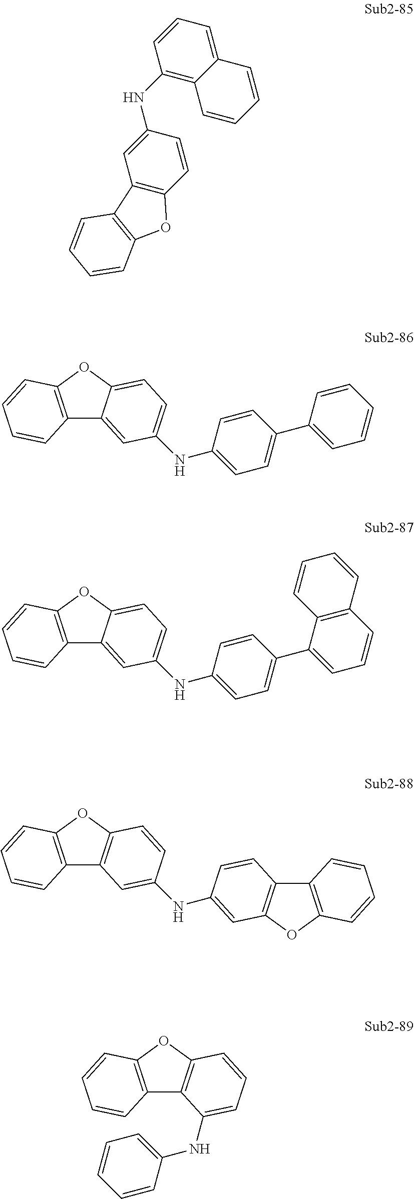 [SMILES: c1ccc2c(Nc3ccc4oc5ccccc5c4c3)cccc2c1 ; c1ccc(-c2ccc(Nc3ccc4oc5ccccc5c4c3)cc2)cc1 ; c1ccc2c(-c3ccc(Nc4ccc5oc6ccccc6c5c4)cc3)cccc2c1 ; c1ccc2c(c1)oc1cc(Nc3ccc4oc5ccccc5c4c3)ccc12 ; c1ccc(Nc2cccc3oc4ccccc4c23)cc1]

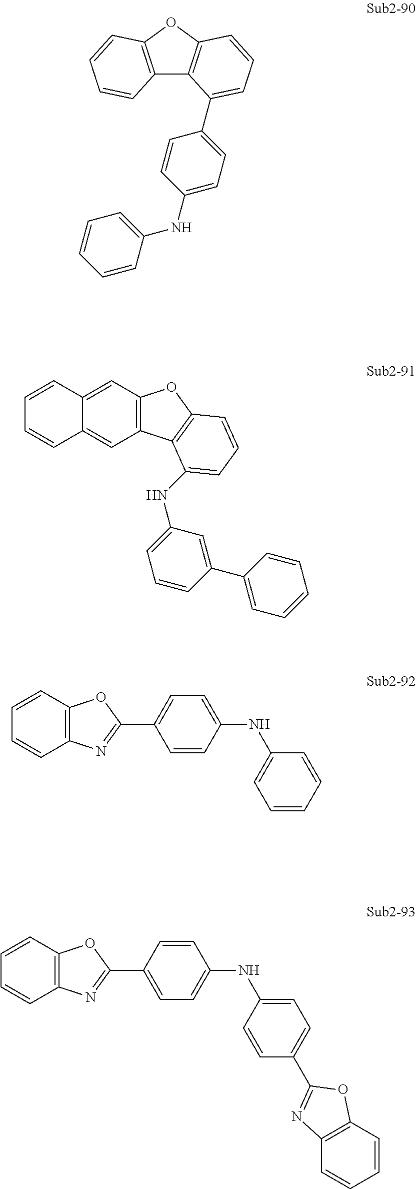 [SMILES: c1ccc(Nc2ccc(-c3cccc4oc5ccccc5c34)cc2)cc1 ; c1ccc(-c2cccc(Nc3cccc4oc5cc6ccccc6cc5c34)c2)cc1 ; c1ccc(Nc2ccc(-c3nc4ccccc4o3)cc2)cc1 ; c1ccc2oc(-c3ccc(Nc4ccc(-c5nc6ccccc6o5)cc4)cc3)nc2c1]

TABLE 2

| Compound | FD-MS | Compound | FD-MS |
|---|---|---|---|
| Sub2-1 | m/z = 169.09(C₁₂H₁₁N = 169.23) | Sub2-2 | m/z = 169.09(C₁₂H₁₁N = 169.23) |
| Sub2-3 | m/z = 397.28(C₂₉H₃₅N = 397.61) | Sub2-4 | m/z = 219.1(C₁₆H₁₃N = 219.29) |
| Sub2-5 | m/z = 219.1(C₁₆H₁₃N = 219.29) | Sub2-6 | m/z = 269.12(C₂₀H₁₅N = 269.35) |
| Sub2-7 | m/z = 269.12(C₂₀H₁₅N = 269.35) | Sub2-8 | m/z = 295.14(C₂₂H₁₇N = 295.39) |
| Sub2-9 | m/z = 269.12(C₂₀H₁₅N = 269.35) | Sub2-10 | m/z = 245.12(C₁₈H₁₅N = 245.33) |
| Sub2-11 | m/z = 245.12(C₁₈H₁₅N = 245.33) | Sub2-12 | m/z = 321.15(C₂₄H₁₉N = 321.42) |
| Sub2-13 | m/z = 339.26(C₂₄HD₁₈N = 339.53) | Sub2-14 | m/z = 321.15(C₂₄H₁₉N = 321.42) |
| Sub2-15 | m/z = 321.15(C₂₄H₁₉N = 321.42) | Sub2-16 | m/z = 321.15(C₂₄H₁₉N = 321.42) |
| Sub2-17 | m/z = 371.17(C₂₈H₂₁N = 371.48) | Sub2-18 | m/z = 421.18(C₃₂H₂₃N = 421.54) |
| Sub2-19 | m/z = 421.18(C₃₂H₂₃N = 421.54) | Sub2-20 | m/z = 421.18(C₃₂H₂₃N = 421.54) |
| Sub2-21 | m/z = 421.18(C₃₂H₂₃N = 421.54) | Sub2-22 | m/z = 395.17(C₃₀H₂₁N = 395.51) |
| Sub2-23 | m/z = 447.2(C₃₄H₂₅N = 447.58) | Sub2-24 | m/z = 397.18(C₃₀H₂₃N = 397.52) |
| Sub2-25 | m/z = 397.18(C₃₀H₂₃N = 397.52) | Sub2-26 | m/z = 473.21(C₃₆H₂₇N = 473.62) |
| Sub2-27 | m/z = 473.21(C₃₆H₂₇N = 473.62) | Sub2-28 | m/z = 285.15(C₂₁H₁₉N = 285.39) |
| Sub2-29 | m/z = 335.17(C₂₅H₂₁N = 335.45) | Sub2-30 | m/z = 361.18(C₂₇H₂₃N = 361.49) |
| Sub2-31 | m/z = 361.18(C₂₇H₂₃N = 361.49) | Sub2-32 | m/z = 411.2(C₃₁H₂₅N = 411.55) |
| Sub2-33 | m/z = 411.2(C₃₁H₂₅N = 411.55) | Sub2-34 | m/z = 437.21(C₃₃H₂₇N = 437.59) |
| Sub2-35 | m/z = 487.23(C₃₇H₂₉N = 487.65) | Sub2-36 | m/z = 487.23(C₃₇H₂₉N = 487.65) |
| Sub2-37 | m/z = 401.21(C₃₀H₂₇N = 401.55) | Sub2-38 | m/z = 401.21(C₃₀H₂₇N = 401.55) |
| Sub2-39 | m/z = 361.18(C₂₇H₂₃N = 361.49) | Sub2-40 | m/z = 553.28(C₄₂H₃₅N = 553.75) |
| Sub2-41 | m/z = 513.25(C₃₉H₃₁N = 513.68) | Sub2-42 | m/z = 409.18(C₃₁H₂₃N = 409.53) |
| Sub2-43 | m/z = 485.21(C₃₇H₂₇N = 485.63) | Sub2-44 | m/z = 525.25(C₄₀H₃₁N = 525.7) |
| Sub2-45 | m/z = 407.17(C₃₁H₂₁N = 407.52) | Sub2-46 | m/z = 483.2(C₃₇H₂₅N = 483.61) |
| Sub2-47 | m/z = 609.25(C₄₇H₃₁N = 609.77) | Sub2-48 | m/z = 523.23(C₄₀H₂₉N = 523.68) |
| Sub2-49 | m/z = 285.15(C₂₁H₁₉N = 285.39) | Sub2-50 | m/z = 361.18(C₂₇H₂₃N = 361.49) |
| Sub2-51 | m/z = 487.23(C₃₇H₂₉N = 487.65) | Sub2-52 | m/z = 533.21(C₄₁H₂₇N = 533.67) |
| Sub2-53 | m/z = 361.18(C₂₇H₂₃N = 361.49) | Sub2-54 | m/z = 649.28(C₅₀H₃₅N = 649.84) |
| Sub2-55 | m/z = 407.17(C₃₁H₂₁N = 407.52) | Sub2-56 | m/z = 285.15(C₂₁H₁₉N = 285.39) |
| Sub2-57 | m/z = 407.17(C₃₁H₂₁N = 407.52) | Sub2-58 | m/z = 335.17(C₂₅H₂₁N = 335.45) |
| Sub2-59 | m/z = 410.18(C₃₀H₂₂N₂ = 410.52) | Sub2-60 | m/z = 574.24(C₄₃H₃₀N₂ = 574.73) |
| Sub2-61 | m/z = 499.2(C₃₆H₂₅N₃ = 499.62) | Sub2-62 | m/z = 334.15(C₂₄H₁₈N₂ = 334.42) |
| Sub2-63 | m/z = 275.08(C₁₈H₁₃NS = 275.37) | Sub2-64 | m/z = 369.1(C₂₄H₁₆FNS = 369.46) |
| Sub2-65 | m/z = 391.14(C₂₇H₂₁NS = 391.53) | Sub2-66 | m/z = 513.16(C₃₇H₂₃NS = 513.66) |
| Sub2-67 | m/z = 440.13(C₃₀H₂₀N₂S = 440.56) | Sub2-68 | m/z = 467.17(C₃₃H₂₅NS = 467.63) |
| Sub2-69 | m/z = 325.09(C₂₂H₁₅NS = 325.43) | Sub2-70 | m/z = 425.12(C₃₀H₁₉NS = 425.55) |
| Sub2-71 | m/z = 275.08(C₁₈H₁₃NS = 275.37) | Sub2-72 | m/z = 351.11(C₂₄H₁₇NS = 351.47) |
| Sub2-73 | m/z = 351.11(C₂₄H₁₇NS = 351.47) | Sub2-74 | m/z = 351.11(C₂₄H₁₇NS = 351.47) |
| Sub2-75 | m/z = 381.06(C₂₄H₁₅NS₂ = 381.51) | Sub2-76 | m/z = 427.14(C₃₀H₂₁NS = 427.57) |
| Sub2-77 | m/z = 477.16(C₃₄H₂₃NS = 477.63) | Sub2-78 | m/z = 351.11(C₂₄H₁₇NS = 351.47) |
| Sub2-79 | m/z = 365.09(C₂₄H₁₅NOS = 365.45) | Sub2-80 | m/z = 335.13(C₂₄H₁₇NO = 335.41) |
| Sub2-81 | m/z = 385.15(G₂₈H₁₉NO = 385.47) | Sub2-82 | m/z = 436.16(C₃₁H₂₀N₂O = 436.51) |
| Sub2-83 | m/z = 425.18(C₃₁H₂₃NO = 425.53) | Sub2-84 | m/z = 259.1(C₁₈H₁₃NO = 259.31) |
| Sub2-85 | m/z = 309.12(C₂₂H₁₅NO = 309.37) | Sub2-86 | m/z = 335.13(C₂₄H₁₇NO = 335.41) |
| Sub2-87 | m/z = 385.15(C₂₈H₁₉NO = 385.47) | Sub2-88 | m/z = 349.11(C₂₄H₁₅NO₂ = 349.39) |
| Sub2-89 | m/z = 259.1(C₁₈H₁₃NO = 259.31) | Sub2-90 | m/z = 335.13(C₂₄H₁₇NO = 335.41) |
| Sub2-91 | m/z = 385.15(C₂₈H₁₉NO = 385.47) | Sub2-92 | m/z = 286.11(C₁₉H₁₄N₂O = 286.33) |
| Sub2-93 | m/z = 403.13(C₂₆H₁₇N₃O₂ = 403.44) | | |

### Synthesis Example of the Final Compound

### 1. Synthesis Example of 1-7

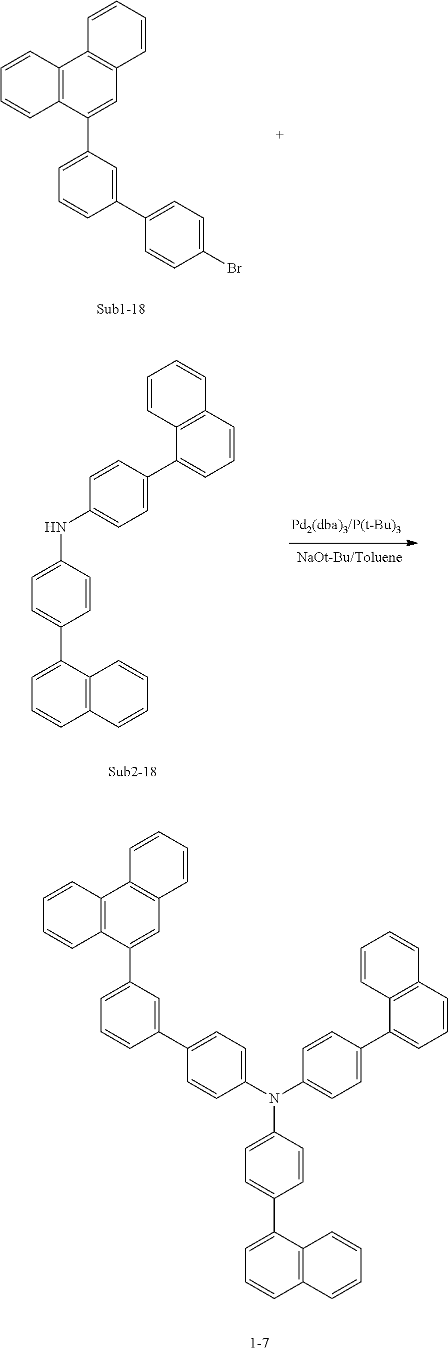 [SMILES: Brc1ccc(-c2cccc(-c3cc4ccccc4c4ccccc34)c2)cc1 ; c1ccc2c(-c3ccc(Nc4ccc(-c5cccc6ccccc56)cc4)cc3)cccc2c1 ; c1cc(-c2ccc(N(c3ccc(-c4cccc5ccccc45)cc3)c3ccc(-c4cccc5ccccc45)cc3)cc2)cc(-c2cc3ccccc3c3ccccc23)c1]

After dissolving Sub1-18 (10.0 g, 24.4 mmol) in toluene (122 mL), Sub2-18 (10.3 g, 24.4 mmol), Pd₂(dba)₃ (0.67 g, 0.73 mmol), P(t-Bu)₃ (0.30 g, 1.47 mmol) and NaOt-Bu (4.7 g, 48.9 mmol) are added thereto and the reaction is carried out at 80° C. When the reaction is completed, the reaction product is extracted with CH₂Cl₂ and water, and then the organic layer is dried with MgSO₄ and concentrated. Then, the concentrate is separated through a silica gel column and recrystallized to obtain 13.2 g (yield: 72%) of the product.

### 2. Synthesis Example of 1-13

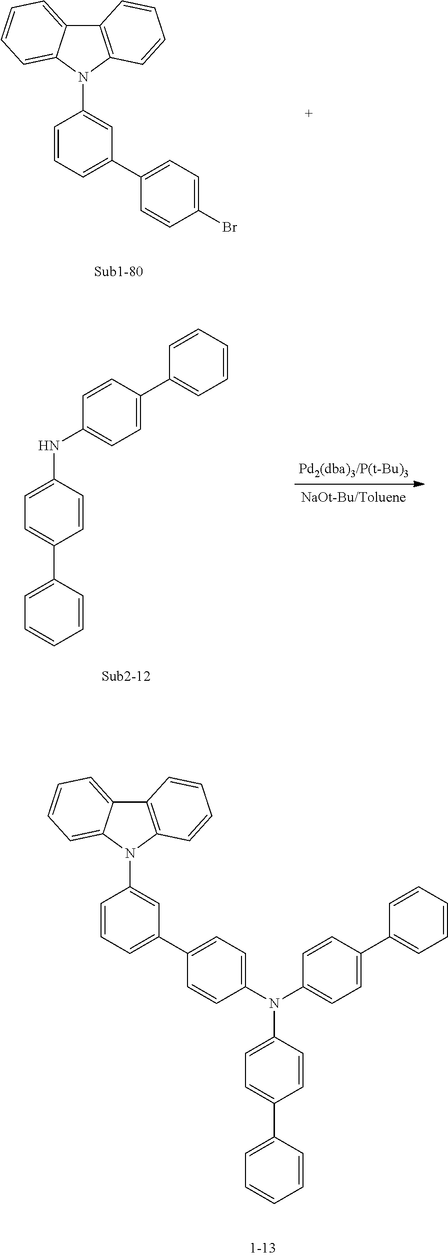 [SMILES: Brc1ccc(-c2cccc(-n3c4ccccc4c4ccccc43)c2)cc1 ; c1ccc(-c2ccc(Nc3ccc(-c4ccccc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

After dissolving Sub1-80 (10.0 g, 25.1 mmol) in toluene (126 mL), Sub2-12 (8.1 g, 25.1 mmol), Pd₂(dba)₃ (0.69 g, 0.75 mmol), P(t-Bu)₃ (0.30 g, 1.51 mmol), NaOt-Bu (4.8 g, 50.2 mmol) are added thereto, and the synthesis is carried out in the same manner as the synthesis of 1-7 to obtain 12.5 g (yield: 78%) of product.

### 3. Synthesis Example of 1-28

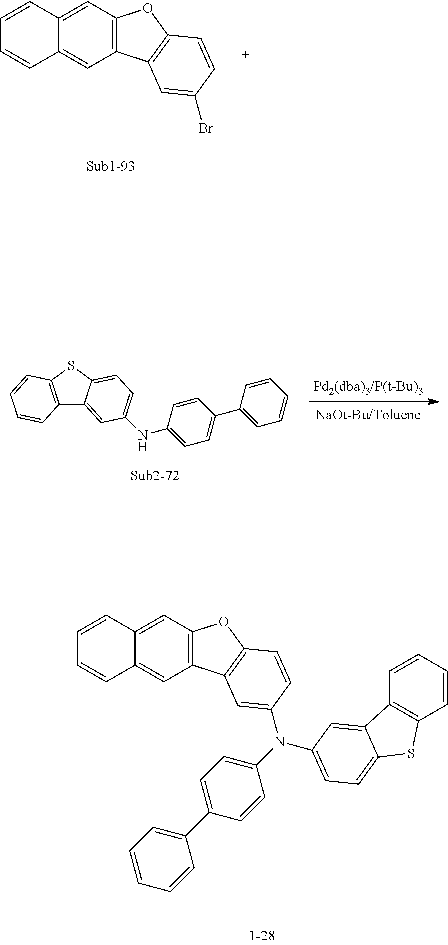 [SMILES: Brc1ccc2oc3cc4ccccc4cc3c2c1 ; c1ccc(-c2ccc(Nc3ccc4sc5ccccc5c4c3)cc2)cc1 ; c1ccc(-c2ccc(N(c3ccc4oc5cc6ccccc6cc5c4c3)c3ccc4sc5ccccc5c4c3)cc2)cc1]

After dissolving Sub1-93 (10.0 g, 33.7 mmol) in toluene (168 mL), Sub2-72 (11.8 g, 33.7 mmol), Pd₂(dba)₃ (0.92 g, 1.01 mmol), P(t-Bu)₃ (0.41 g, 2.02 mmol), NaOt-Bu (6.5 g, 67.3 mmol) are added thereto, and the synthesis is carried out in the same manner as the synthesis of 1-7 to obtain 15.1 g (yield: 79%) of product.

### 4. Synthesis Example of 1-32

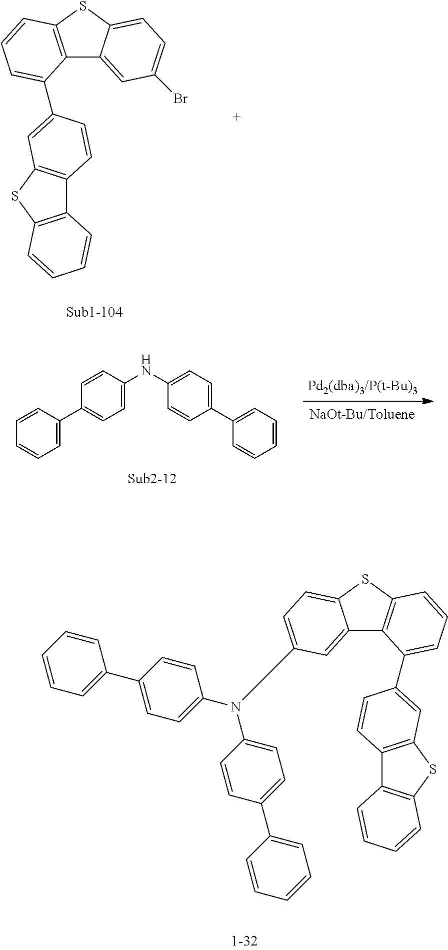 [SMILES: Brc1ccc2sc3cccc(-c4ccc5c(c4)sc4ccccc45)c3c2c1 ; c1ccc(-c2ccc(Nc3ccc(-c4ccccc4)cc3)cc2)cc1 ; c1ccc(-c2ccc(N(c3ccc(-c4ccccc4)cc3)c3ccc4sc5cccc(-c6ccc7c(c6)sc6ccccc67)c5c4c3)cc2)cc1]

After dissolving Sub1-104 (10.0 g, 22.5 mmol) in toluene (112 mL), Sub2-12 (7.2 g, 22.5 mmol), Pd₂(dba)₃ (0.62 g, 0.67 mmol), P(t-Bu)₃ (0.27 g, 1.35 mmol), NaOt-Bu (4.3 g, 44.9 mmol) are added thereto, and the synthesis is carried out in the same manner as the synthesis of 1-7 to obtain 11.4 g (yield: 74%) of product.

### 5. Synthesis Example of 1-49

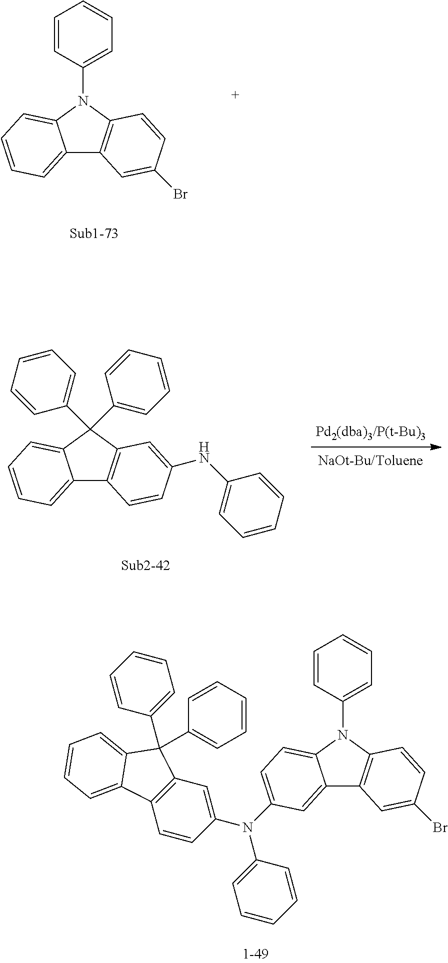 [SMILES: Brc1ccc2c(c1)c1ccccc1n2-c1ccccc1 ; c1ccc(Nc2ccc3c(c2)C(c2ccccc2)(c2ccccc2)c2ccccc2-3)cc1 ; Brc1ccc2c(c1)c1cc(N(c3ccccc3)c3ccc4c(c3)C(c3ccccc3)(c3ccccc3)c3ccccc3-4)ccc1n2-c1ccccc1]

After dissolving Sub1-73 (10.0 g, 31.0 mmol) in toluene (155 mL), Sub2-42 (12.7 g, 31.0 mmol), Pd₂(dba)₃ (0.85 g, 0.93 mmol), P(t-Bu)₃ (0.38 g, 1.86 mmol), NaOt-Bu (6.0 g, 62.1 mmol) are added thereto, and the synthesis is carried out in the same manner as the synthesis of 1-7 to obtain 14.3 g (yield: 71%) of product.

### 6. Synthesis Example of 1-104

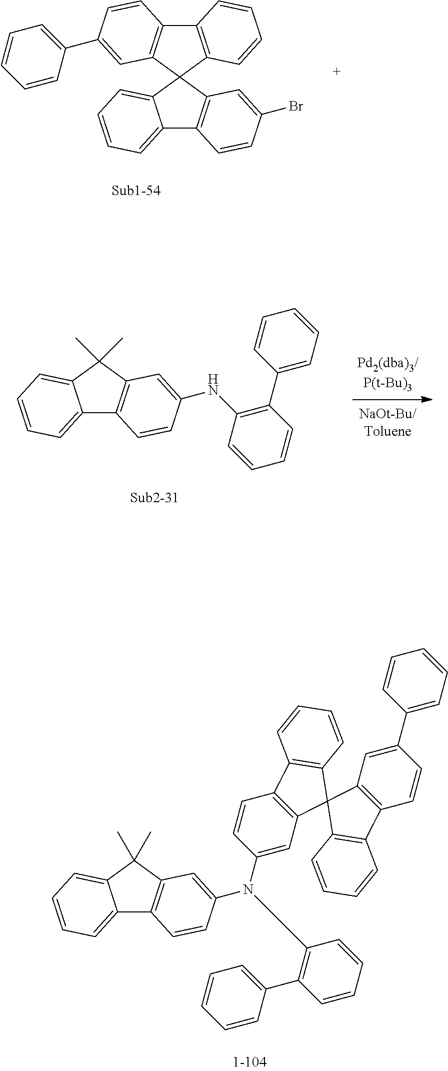 [SMILES: Brc1ccc2c(c1)C1(c3ccccc3-2)c2ccccc2-c2ccc(-c3ccccc3)cc21 ; CC1(C)c2ccccc2-c2ccc(Nc3ccccc3-c3ccccc3)cc21 ; CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21]

After dissolving Sub1-54 (10.0 g, 21.2 mmol) in toluene (106 mL), Sub2-31 (7.7 g, 21.2 mmol), Pd₂(dba)₃ (0.58 g, 0.64 mmol), P(t-Bu)₃ (0.26 g, 1.27 mmol), NaOt-Bu (4.1 g, 42.4 mmol) are added thereto, and the synthesis is carried out in the same manner as the synthesis of 1-7 to obtain 10.4 g (yield: 65%) of product.

The FD-MS values of the compounds 1-1 to 1-108 of the present invention prepared according to the above synthesis examples are shown in Table 3 below.

TABLE 3

| Compound | FD-MS | Compound | FD-MS |
|---|---|---|---|
| 1-1 | m/z = 625.28(C₄₈H₃₅N = 625.82) | 1-2 | m/z = 623.26(C₄₈H₃₃N = 623.8) |
| 1-3 | m/z = 547.23(C₄₂H₂₉N = 547.7) | 1-4 | m/z = 573.25(C₄₄H₃₁N = 573.74) |
| 1-5 | m/z = 725.31(C₅₆H₃₉N = 725.94) | 1-6 | m/z = 617.31(C₄₇H₃₉N = 617.84) |
| 1-7 | m/z = 749.31(C₅₈H₃₉N = 749.96) | 1-8 | m/z = 607.32(C₄₆H₄₁N = 607.84) |
| 1-9 | m/z = 562.24(C₄₂H₃₀N₂ = 562.72) | 1-10 | m/z = 602.27(C₄₅H₃₄N₂ = 602.78) |
| 1-11 | m/z = 592.2(C₄₂H₂₈N₂S = 592.76) | 1-12 | m/z = 586.24(C₄₄H₃₀N₂ = 586.74) |
| 1-13 | m/z = 638.27(C₄₈H₃₄N₂ = 638.81) | 1-14 | m/z = 678.3(C₅₁H₃₈N₂ = 678.88) |
| 1-15 | m/z = 688.29(C₅₂H₃₆N₂ = 688.87) | 1-16 | m/z = 698.37(C₅₂H₄₆N₂ = 698.95) |
| 1-17 | m/z = 553.19(C₄₀H₂₇NS = 553.72) | 1-18 | m/z = 587.22(C₄₄H₂₉NO = 587.72) |
| 1-19 | m/z = 663.26(C₅₀H₃₃NO = 663.82) | 1-20 | m/z = 563.22(C₄₂H₂₉NO = 563.7) |
| 1-21 | m/z = 487.19(C₃₆H₂₅NO = 487.6) | 1-22 | m/z = 517.15(C₃₆H₂₃NOS = 517.65) |
| 1-23 | m/z = 517.15(C₃₆H₂₃NOS = 517.65) | 1-24 | m/z = 593.18(C₄₂H₂₇NOS = 593.74) |
| 1-25 | m/z = 601.13(C₄₀H₂₄FNS₂ = 601.76) | 1-26 | m/z = 617.18(C₄₄H₂₇NOS = 617.77) |
| 1-27 | m/z = 551.19(C₄₀H₂₅NO₂ = 551.65) | 1-28 | m/z = 567.17(C₄₀H₂₅NOS = 567.71) |
| 1-29 | m/z = 593.18(C₄₂H₂₇NOS = 593.74) | 1-30 | m/z = 669.21(C₄₈H₃₁NOS = 669.84) |
| 1-31 | m/z = 674.24(C₄₇H₃₄N₂OS = 674.86) | 1-32 | m/z = 685.19(C₄₈H₃₁NS₂ = 685.9) |
| 1-33 | m/z = 547.11(C₃₆H₂₁NOS₂ = 547.69) | 1-34 | m/z = 623.14(C₄₂H₂₅NOS₂ = 623.79) |
| 1-35 | m/z = 597.12(C₄₀H₂₃NOS₂ = 597.75) | 1-36 | m/z = 607.2(C₄₃H₂₉NOS = 607.77) |
| 1-37 | m/z = 513.25(C₃₉H₃₁N = 513.68) | 1-38 | m/z = 513.25(C₃₉H₃₁N = 513.68) |
| 1-39 | m/z = 437.21(C₃₃H₂₇N = 437.59) | 1-40 | m/z = 513.25(C₃₉H₃₁N = 513.68) |
| 1-41 | m/z = 613.28(C₄₇H₃₅N = 613.8) | 1-42 | m/z = 763.32(C₅₉H₄₁N = 763.98) |
| 1-43 | m/z = 613.28(C₄₇H₃₅N = 613.8) | 1-44 | m/z = 665.31(C₅₁H₃₉N = 665.88) |
| 1-45 | m/z = 639.29(C₄₉H₃₇N = 639.84) | 1-46 | m/z = 689.31(C₅₃H₃₉N = 689.9) |
| 1-47 | m/z = 665.31(C₅₁H₃₉N = 665.88) | 1-48 | m/z = 705.34(C₅₄H₄₃N = 705.95) |
| 1-49 | m/z = 650.27(C₄₉H₃₄N₂ = 650.83) | 1-50 | m/z = 726.3(C₅₅H₃₈N₂ = 726.92) |
| 1-51 | m/z = 576.26(C₄₃H₃₂N₂ = 576.74) | 1-52 | m/z = 726.3(C₅₅H₃₈N₂ = 726.92) |
| 1-53 | m/z = 639.29(C₄₉H₃₇N = 639.84) | 1-54 | m/z = 715.32(C₅₅H₄₁N = 715.94) |
| 1-55 | m/z = 705.34(C₅₄H₄₃N = 705.95) | 1-56 | m/z = 669.34(C₅₁H₄₃N = 669.91) |
| 1-57 | m/z = 691.29(C₅₂H₃₇NO = 691.87) | 1-58 | m/z = 705.25(C₅₂H₃₅NS = 705,92) |
| 1-59 | m/z = 741.27(C₅₅H₃₅NO₂ = 741.89) | 1-60 | m/z = 669.34(C₅₁H₄₃N = 669.91) |
| 1-61 | m/z = 643.29(C₄₈H₃₇NO = 643.83) | 1-62 | m/z = 891.35(C₆₈H₄₅NO = 892.11) |
| 1-63 | m/z = 821.4(C₆₃H₅₁N = 822.11) | 1-64 | m/z = 755.36(C₅₈H₄₅N = 756.01) |
| 1-65 | m/z = 711.29(C₅₅H₃₇N = 711.91) | 1-66 | m/z = 723.29(C₅₆H₃₇N = 723.92) |
| 1-67 | m/z = 667.23(C₄₉H₃₃NS = 667.87) | 1-68 | m/z = 603.29(C₄₆H₃₇N = 603.81) |
| 1-69 | m/z = 711.29(C₅₅H₃₇N = 711.91) | 1-70 | m/z = 699.26(C₅₃H₃₃NO = 699.85) |
| 1-71 | m/z = 759.29(C₅₉H₃₇N = 759.95) | 1-72 | m/z = 637.28(C₄₉H₃₅N = 637.83) |
| 1-73 | m/z = 754.24(C₅₅H₃₄N₂S = 754.95) | 1-74 | m/z = 751.32(C₅₈H₄₁N = 751.97) |
| 1-75 | m/z = 677.31(C₅₂H₃₉N = 677.89) | 1-76 | m/z = 665.24(C₄₉H₃₁NO₂ = 665.79) |
| 1-77 | m/z = 678.3(C₅₁H₃₈N₂ = 678.88) | 1-78 | m/z = 803.36(C₆₂H₄₅N = 804.05) |
| 1-79 | m/z = 729.3(C₅₅H₃₉NO = 729.92) | 1-80 | m/z = 657.24(C₄₆H₃₁N₃O₂ = 657.77) |
| 1-81 | m/z = 567.26(C₄₂H₃₃NO = 567.73) | 1-82 | m/z = 751.29(C₅₇H₃₇NO = 751.93) |
| 1-83 | m/z = 755.23(C₅₅H₃₃NOS = 755.94) | 1-84 | m/z = 725.22(C₅₁H₃₅NS₂ = 725.97) |
| 1-85 | m/z = 742.3(C₅₅H₃₈N₂O = 742.92) | 1-86 | m/z = 923.36(C₇₂H₄₅N = 924.16) |
| 1-87 | m/z = 815.33(C₆₁H₄₁N₃ = 816.02) | 1-88 | m/z = 719.36(C₅₅H₄₅N = 719.97) |
| 1-89 | m/z = 891.36(C₆₇H₄₅N₃ = 892.12) | 1-90 | m/z = 589.37(C₄₄H₄₇N = 589.87) |
| 1-91 | m/z = 655.32(C₅₀H₄₁N = 655.89) | 1-92 | m/z = 721.37(C₅₅H₄₇N = 721.99) |
| 1-93 | m/z = 695.36(C₅₃H₄₅N = 695.95) | 1-94 | m/z = 683.36(C₅₂H₄₅N = 683.94) |
| 1-95 | m/z = 739.23(C₅₅H₃₃NS = 739.94) | 1-96 | m/z = 767.36(C₅₉H₄₅N = 768.02) |
| 1-97 | m/z = 681.43(C₅₁H₅₅N = 682.01) | 1-98 | m/z = 827.32(C₆₃H₄₁NO = 828.03) |
| 1-99 | m/z = 851.36(C₆₆H₄₅N = 852.09) | 1-100 | m/z = 665.31(C₅₁H₃₉N = 665.88) |
| 1-101 | m/z = 553.28(C₄₂H₃₅N = 553.75) | 1-102 | m/z = 675.29(C₅₂H₃₇N = 675.88) |
| 1-103 | m/z = 599.26(C₄₆H₃₃N = 599.78) | 1-104 | m/z = 751.32(C₅₈H₄₁N = 751.97) |
| 1-105 | m/z = 526.24(C₃₉H₃₀N₂ = 526.68) | 1-106 | m/z = 648.26(C₄₉H₃₂N₂ = 648.81) |
| 1-107 | m/z = 678.3(C₅₁H₃₈N₂ = 678.88) | 1-108 | m/z = 652.29(C₄₉H₃₆N₂ = 652.84) |

### [Synthesis Example 2] Synthesis Example of Formula 2

The compound represented by Formula 2 (final product 2) according to the present invention can be synthesized as shown in Reaction Scheme 3 below, but is not limited thereto.

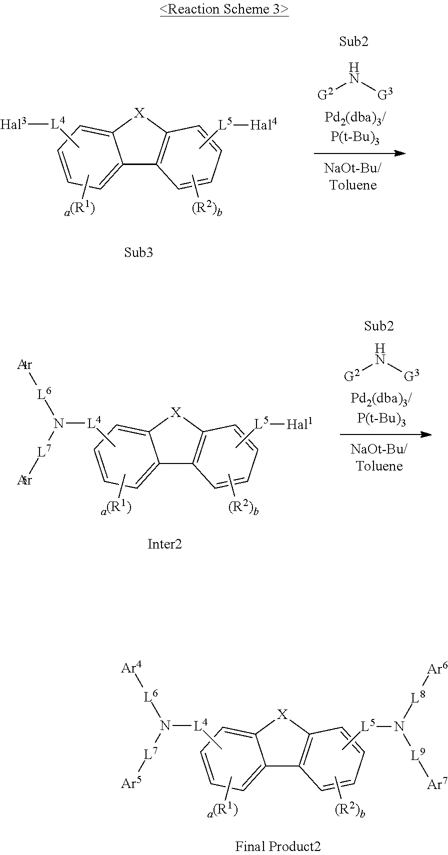

### Exemplary Compounds of Sub3

Compounds belonging to Sub 3 may be, but not limited to, the following compounds, and Table 4 shows FD-MS values of the following compounds.

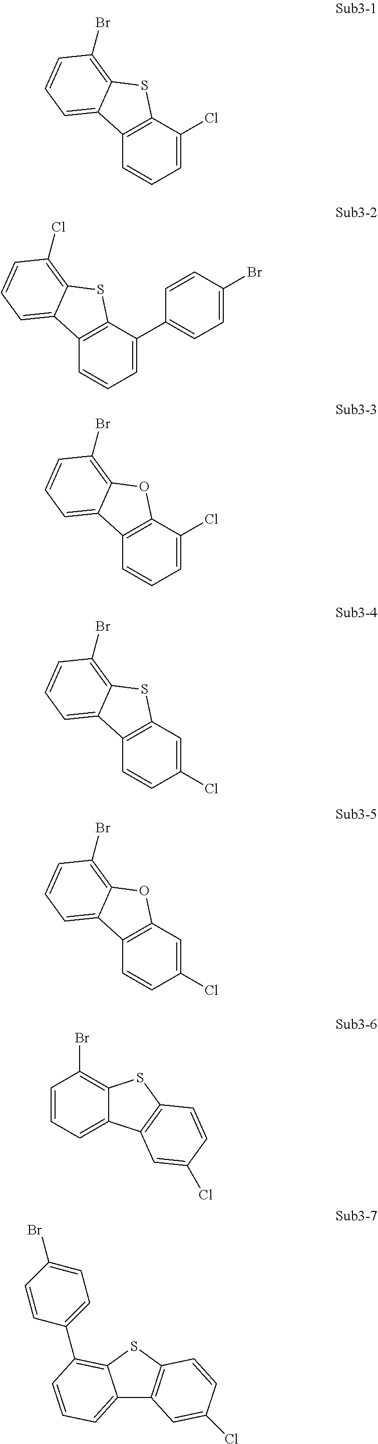

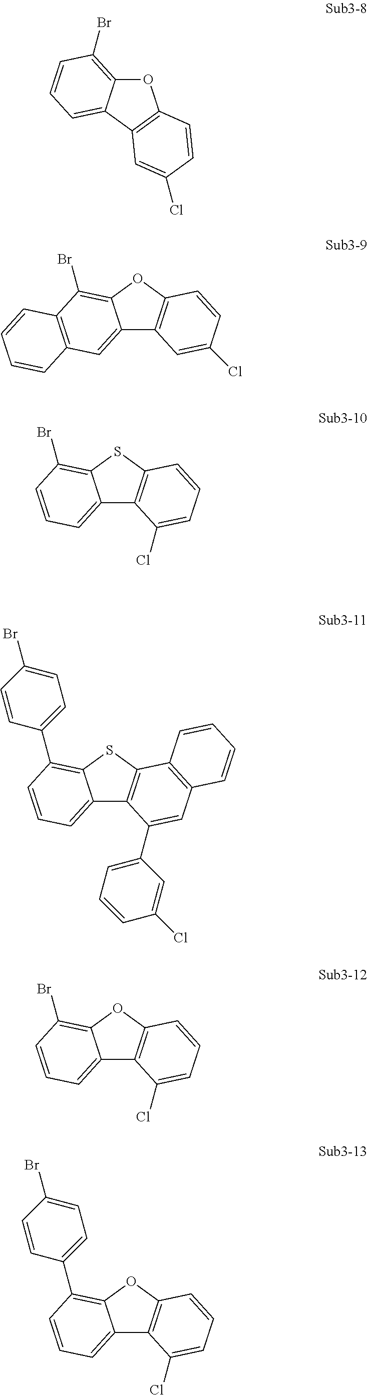 [SMILES: Clc1ccc2oc3c(Br)cccc3c2c1 ; Clc1ccc2oc3c(Br)c4ccccc4cc3c2c1 ; Clc1cccc2sc3c(Br)cccc3c12 ; Clc1cccc(-c2cc3ccccc3c3sc4c(-c5ccc(Br)cc5)cccc4c23)c1 ; Clc1cccc2oc3c(Br)cccc3c12 ; Clc1cccc2oc3c(-c4ccc(Br)cc4)cccc3c12]

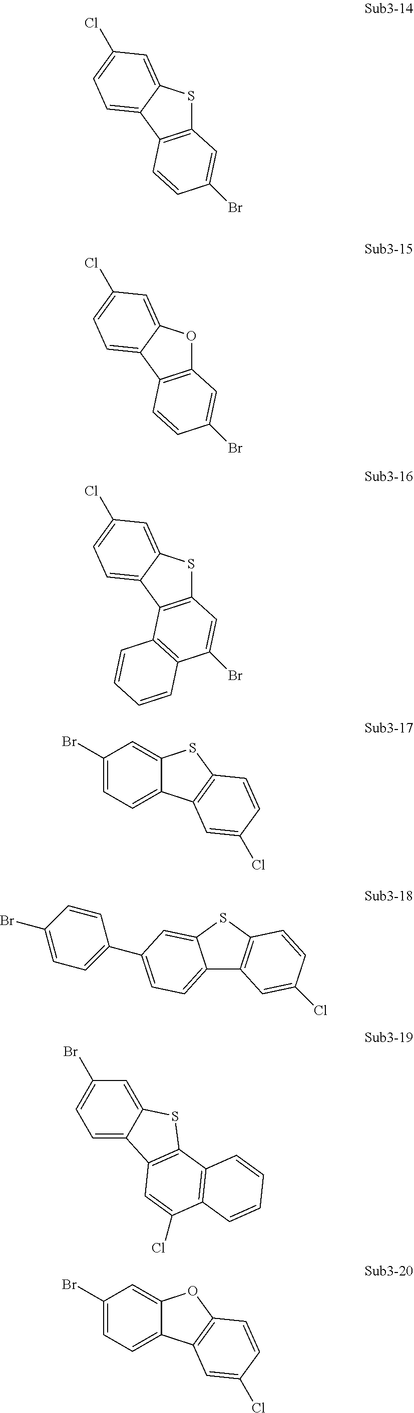

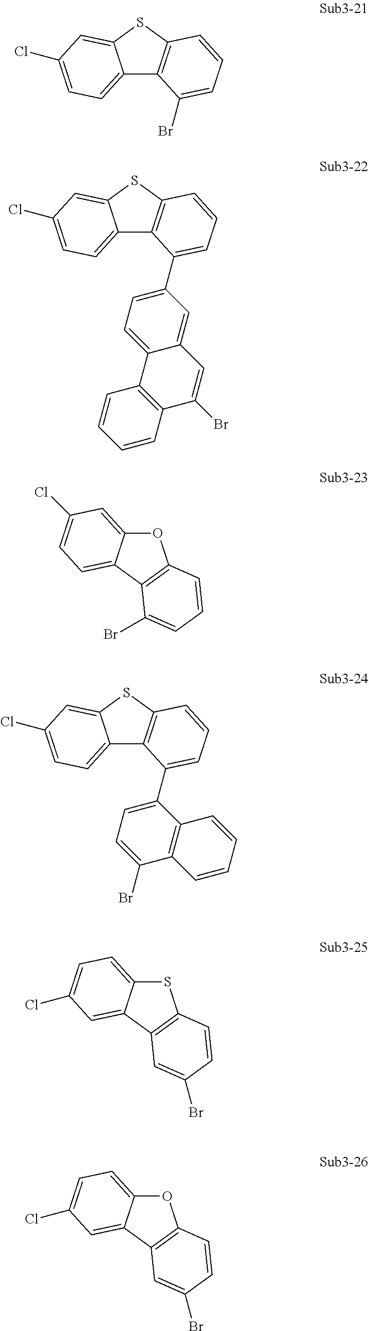 [SMILES: Clc1ccc2c(c1)sc1cccc(Br)c12 ; Clc1ccc2c(c1)sc1cccc(-c3ccc4c(c3)cc(Br)c3ccccc34)c12 ; Clc1ccc2c(c1)oc1cccc(Br)c12 ; Clc1ccc2c(c1)sc1cccc(-c3ccc(Br)c4ccccc34)c12 ; Clc1ccc2sc3ccc(Br)cc3c2c1 ; Clc1ccc2oc3ccc(Br)cc3c2c1]

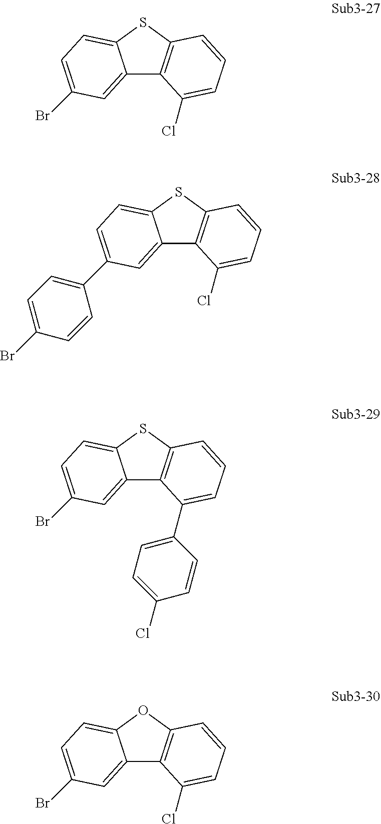 [SMILES: Clc1cccc2sc3ccc(Br)cc3c12 ; Clc1cccc2sc3ccc(-c4ccc(Br)cc4)cc3c12 ; Clc1ccc(-c2cccc3sc4ccc(Br)cc4c23)cc1 ; Clc1cccc2oc3ccc(Br)cc3c12]

TABLE 4

| Compound | FD-MS | Compound | FD-MS |
|---|---|---|---|
| Sub3-1 | m/z = 295.91(C₁₂H₆BrCIS = 297.59) | Sub3-2 | m/z = 371.94(C₁₈H₁₀BrCIS = 373.69) |
| Sub3-3 | m/z = 279.93(C₁₂H₆BrCIO = 281.53) | Sub3-4 | m/z = 295.91(C₁₂H₆BrCIS = 297.59) |
| Sub3-5 | m/z = 279.93(C₁₂H₆BrCIO = 281.53) | Sub3-6 | m/z = 295.91(C₁₂H₆BrCIS = 297.59) |
| Sub3-7 | m/z = 371.94(C₁₈H₁₀BrCIS = 373.69) | Sub3-8 | m/z = 279.93(C₁₂H₆BrCIO = 281.53) |
| Sub3-9 | m/z = 329.94(C₁₆H₈BrCIO = 331.59) | Sub3-10 | m/z = 295.91(C₁₂H₆BrCIS = 297.59) |
| Sub3-11 | m/z = 497.98(C₂₈H₁₆BrCIS = 499.85) | Sub3-12 | m/z = 279.93(C₁₂H₆BrCIO = 281.53) |
| Sub3-13 | m/z = 355.96(C₁₈H₁₀BrCIO = 357.63) | Sub3-14 | m/z = 295.91(C₁₂H₆BrCIS = 297.59) |
| Sub3-15 | m/z = 279.93(C₁₂H₆BrCIO = 281.53) | Sub3-16 | m/z = 329.94(C₁₆H₆BrCIO = 331.59) |
| Sub3-17 | m/z = 295.91(C₁₂H₆BrCIS = 297.59) | Sub3-18 | m/z = 371.94(C₁₈H₁₀BrCIS = 373.69) |
| Sub3-19 | m/z = 345.92(C₁₆H₈BrCIS = 347.65) | Sub3-20 | m/z = 279.93(C₁₂H₆BrCIO = 281.53) |
| Sub3-21 | m/z = 295.91(C₁₂H₆BrCIS = 297.59) | Sub3-22 | m/z = 471.97(C₂₆H₁₄BrCIS = 473.81) |
| Sub3-23 | m/z = 279.93(C₁₂H₆BrCIO = 281.53) | Sub3-24 | m/z = 405.98(C₂₂H₁₂BrCIO = 407.69) |
| Sub3-25 | m/z = 295.91(C₁₂H₆BrCIS = 297.59) | Sub3-26 | m/z = 279.93(C₁₂H₆BrCIO = 281.53) |
| Sub3-27 | m/z = 295.91(C₁₂H₆BrCIS = 297.59) | Sub3-28 | m/z = 371.94(C₁₈H₁₀BrCIS = 373.69) |
| Sub3-29 | m/z = 371.94(C₁₈H₁₀BrCIS = 373.69) | Sub3-30 | m/z = 279.93(C₁₂H₅BrCIO = 281.53) |

### Synthesis Example of Final Compound

### 1. Synthesis Example of 2-15

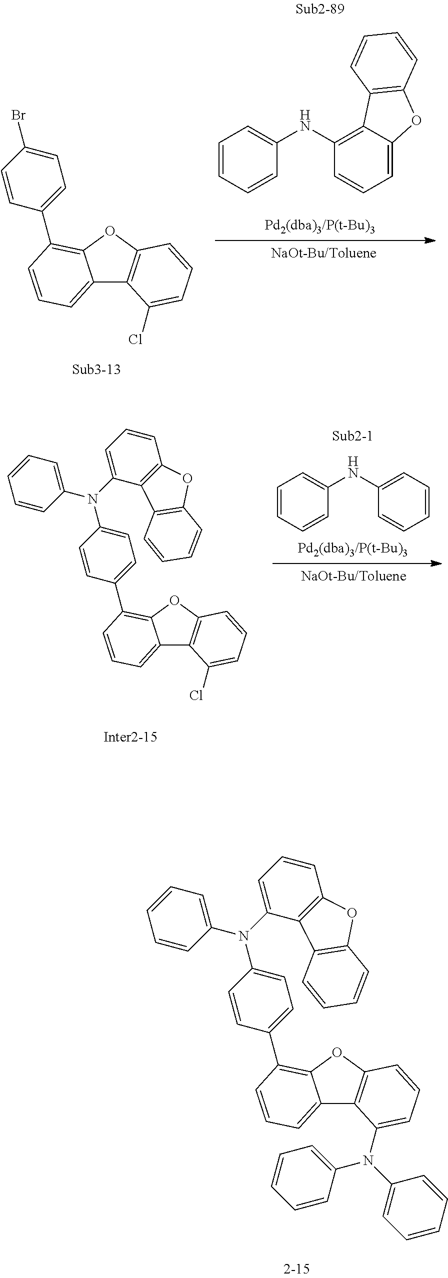 [SMILES: Clc1cccc2oc3c(-c4ccc(Br)cc4)cccc3c12 ; c1ccc(Nc2cccc3oc4ccccc4c23)cc1 ; Clc1cccc2oc3c(-c4ccc(N(c5ccccc5)c5cccc6oc7ccccc7c56)cc4)cccc3c12 ; c1ccc(Nc2ccccc2)cc1 ; c1ccc(N(c2ccc(-c3cccc4c3oc3cccc(N(c5ccccc5)c5ccccc5)c34)cc2)c2cccc3oc4ccccc4c23)cc1]

### (1) Synthesis Example of Inter2-15

After dissolving Sub3-13 (10.0 g, 28.0 mmol) in toluene (140 mL), Sub2-89 (7.3 g, 28.0 mmol), Pd₂(dba)₃ (0.77 g, 0.84 mmol), P(t-Bu)₃ (0.34 g, 1.68 mmol) and NaOt-Bu (5.4 g, 55.9 mmol) are added thereto and the reaction is carried out at 60° C. When the reaction is completed, the reaction product is extracted with CH₂Cl₂ and water, and then the organic layer is dried with MgSO₄ and concentrated. Then, the concentrate is separated through a silica gel column and recrystallized to obtain 11.5 g (yield: 77%) of the product.

### (2) Synthesis Example of 2-15

After dissolving Inter2-15 (11.5 g, 21.5 mmol) in toluene (108 mL), Sub2-1 (3.6 g, 21.5 mmol), Pd₂(dba)₃ (0.59 g, 0.65 mmol), P(t-Bu)₃ (0.26 g, 1.29 mmol), NaOt-Bu (4.1 g, 43.1 mmol) are added thereto and the reaction is carried out at 80° C. When the reaction is completed, the reaction product is extracted with CH₂Cl₂ and water, and then the organic layer is dried with MgSO₄ and concentrated. Then, the concentrate is separated through a silica gel column and recrystallized to obtain 10.1 g (yield: 70%) of the product.

### 2. Synthesis Example of 2-22

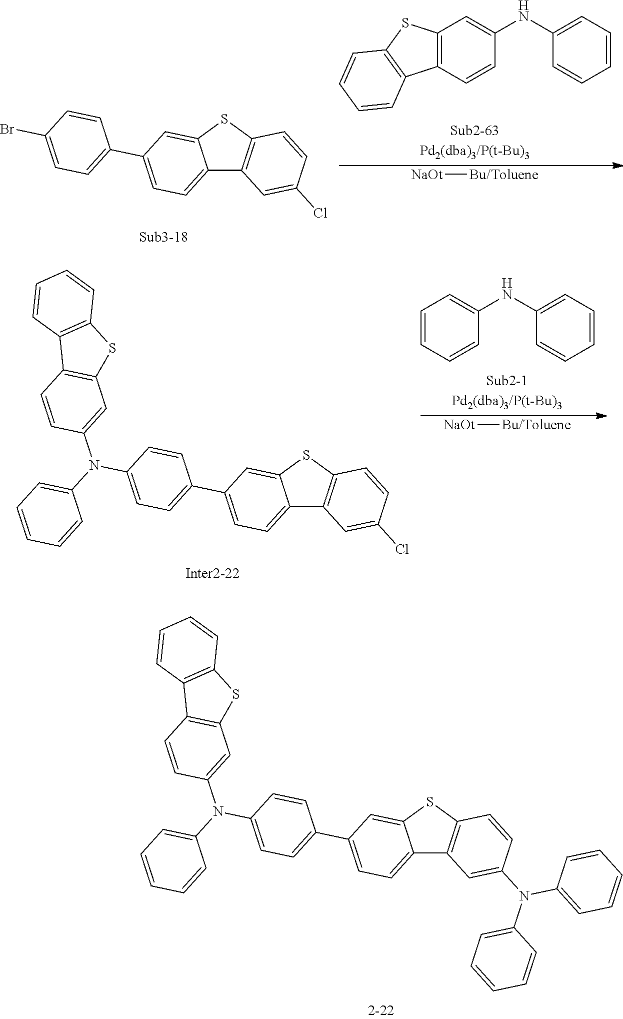

### (1) Synthesis Example of Inter2-22

After dissolving Sub3-18 (10.0 g, 26.8 mmol) in toluene (134 mL), Sub2-63 (7.4 g, 26.8 mmol), Pd₂(dba)₃ (0.74 g, 0.80 mmol), P(t-Bu)₃ (0.32 g, 1.61 mmol) and NaOt-Bu (5.1 g, 53.5 mmol) are added thereto, and the synthesis is carried out in the same manner as the synthesis of Inter2-15 to obtain 10.9 g (yield: 72%) of product.

### (2) Synthesis Example of 2-22

After dissolving Inter2-22 (10.9 g, 19.3 mmol) in toluene (96 mL), Sub2-1 (3.3 g, 19.3 mmol), Pd₂(dba)₃ (0.53 g, 0.58 mmol), P(t-Bu)₃ (0.23 g, 1.16 mmol) and NaOt-Bu (3.7 g, 38.5 mmol) are added thereto, and the synthesis is carried out in the same manner as the synthesis of 2-15 to obtain 10.8 g (yield: 80%) of product.

### 3. Synthesis Example of 2-33

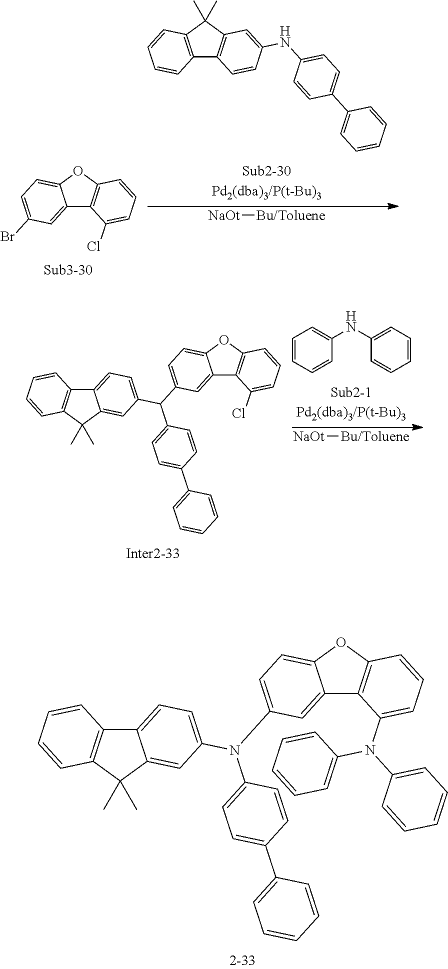

### (1) Synthesis Example of Inter2-33

After dissolving Sub3-30 (10.0 g, 35.5 mmol) in toluene (178 mL), Sub2-30 (12.8 g, 35.5 mmol), Pd₂(dba)₃ (0.98 g, 1.07 mmol), P(t-Bu)₃ (0.43 g, 2.13 mmol), NaOt-Bu (6.8 g, 71.0 mmol) are added thereto, and the synthesis is carried out in the same manner as the synthesis of Inter2-15 to obtain 14.6 g (yield: 73%) of product.

### (2) Synthesis Example of 2-33

After dissolving Inter2-33 (14.6 g, 25.9 mmol) in toluene (130 mL), Sub2-1 (4.4 g, 25.9 mmol), Pd₂(dba)₃ (0.71 g, 0.78 mmol), P(t-Bu)₃ (0.31 g, 1.56 mmol), NaOt-Bu (5.0 g, 51.9 mmol) are added thereto, and the synthesis is carried out in the same manner as the synthesis of 2-15 to obtain 12.8 g (yield: 71%) of product.

The FD-MS values of the compounds 2-1 to 2-36 of the present invention prepared according to the above synthesis examples are shown in Table 5 below.

TABLE 5

| Compound | FD-MS | Compound | FD-MS |
|---|---|---|---|
| 2-1 | m/z = 624.17(C₄₂H₂₈N₂S₂ = 624.82) | 2-2 | m/z = 654.27(C₄₈H₃₄N₂O = 654.81) |
| 2-3 | m/z = 700.2(C₄₈H₃₂N₂S₂ = 700.92) | 2-4 | m/z = 734.24(C₅₂H₃₄N₂OS = 734.92) |
| 2-5 | m/z = 698.2(C₄₈H₃₀N₂O₂S = 698.84) | 2-6 | m/z = 635.2(C₄₃H₂₈N₃OS = 635.79) |
| 2-7 | m/z = 602.24(C₄₄H₃₀N₂O = 602.74) | 2-8 | m/z = 822.31(C₆₀H₄₂N₂S = 823.07) |
| 2-9 | m/z = 670.24(C₄₈H₃₄N₂S = 670.87) | 2-10 | m/z = 784.25(C₅₆H₃₆N₂OS = 784.98) |
| 2-11 | m/z = 734.28(C₅₃H₃₈N₂S = 734.96) | 2-12 | m/z = 905.34(C₆₇H₄₃N₃O = 906.1) |
| 2-13 | m/z = 743.29(C₅₄H₃₇N₃O = 743,91) | 2-14 | m/z = 836.32(C₆₁H₄₄N₂S = 837.1) |
| 2-15 | m/z = 668.25(C₄₈H₃₂N₂O₂ = 668.8) | 2-16 | m/z = 684.26(C₄₉H₃₅N₂S = 684.9) |
| 2-17 | m/z = 618.21(C₄₄H₃₀N₂S = 618.8) | 2-18 | m/z = 704.28(C₅₂H₃₆N₂O = 704.87) |
| 2-19 | m/z = 826.25(C₅₈H₃₈N₂S₂ = 827.08) | 2-20 | m/z = 672.38(C₄₈H₁₆D₁₈N₂O = 672.92) |
| 2-21 | m/z = 608.19(C₄₂H₂₈N₂OS = 608.76) | 2-22 | m/z = 700.2(C₄₈H₃₂N₂S₂ = 700.92) |
| 2-23 | m/z = 668.25(C₄₈H₃₂N₂O₂ = 668.8) | 2-24 | m/z = 784.25(C₅₆H₃₅N₂OS = 784.98) |
| 2-25 | m/z = 624.17(C₄₂H₂₈N₂S₂ = 624.82) | 2-26 | m/z = 628.25(C₄₆H₃₂N₂O = 628.78) |
| 2-27 | m/z = 694.24(C₈₀H₃₄N₂S = 694.9) | 2-28 | m/z = 760.25(C₅₄H₃₆N₂OS = 760.96) |
| 2-29 | m/z = 694.3(C₅₁H₃₈N₂O = 694.88) | 2-30 | m/z = 730.16(C₄₈H₃₀N₂S₃ = 730.96) |
| 2-31 | m/z = 592.22(C₄₂H₂₈N₂O₂ = 592.7) | 2-32 | m/z = 750.22(C₅₂H₃₄N₂S₂ = 750.98) |
| 2-33 | m/z = 694.3(C₅₁H₃₈N₂O = 694.88) | 2-34 | m/z = 684.22(C₄₈H₃₂N₂OS = 684.86) |
| 2-35 | m/z = 684.22(C₄₈H₃₂N₂OS = 684.86) | 2-36 | m/z = 602.24(C₄₄H₃₀N₂O = 602.74) |

### [Synthesis Example 3] Synthesis Example of Formula 3

The compound represented by Formula 3 (final product 3) according to the present invention can be synthesized as shown in Reaction Scheme 4 below, but is not limited thereto.

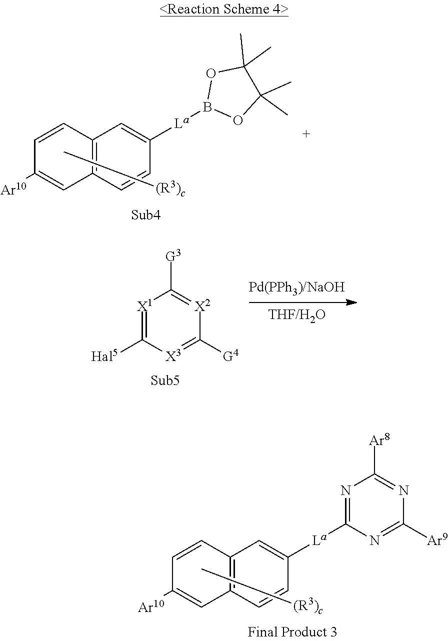

### Exemplary Compounds of Sub4

Compounds belonging to Sub 4 may be, but not limited to, the following compounds, and Table 6 shows FD-MS values of the following compounds.

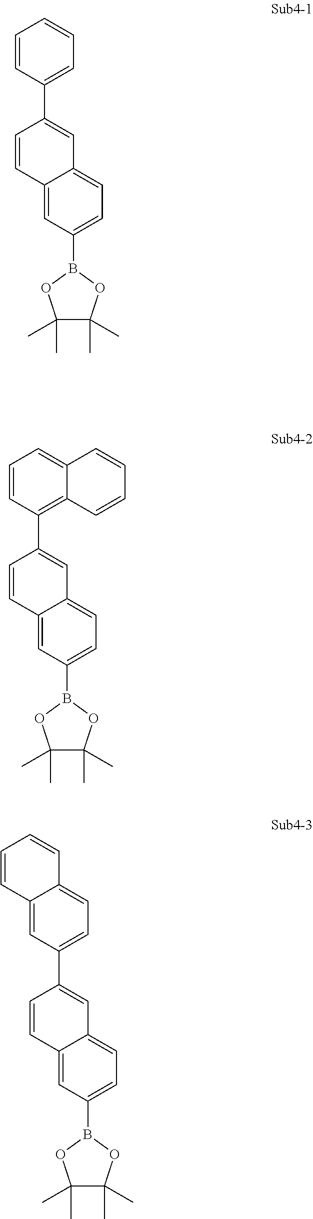 [SMILES: CC1(C)OB(c2ccc3cc(-c4ccccc4)ccc3c2)OC1(C)C ; CC1(C)OB(c2ccc3cc(-c4cccc5ccccc45)ccc3c2)OC1(C)C ; CC1(C)OB(c2ccc3cc(-c4ccc5ccccc5c4)ccc3c2)OC1(C)C]

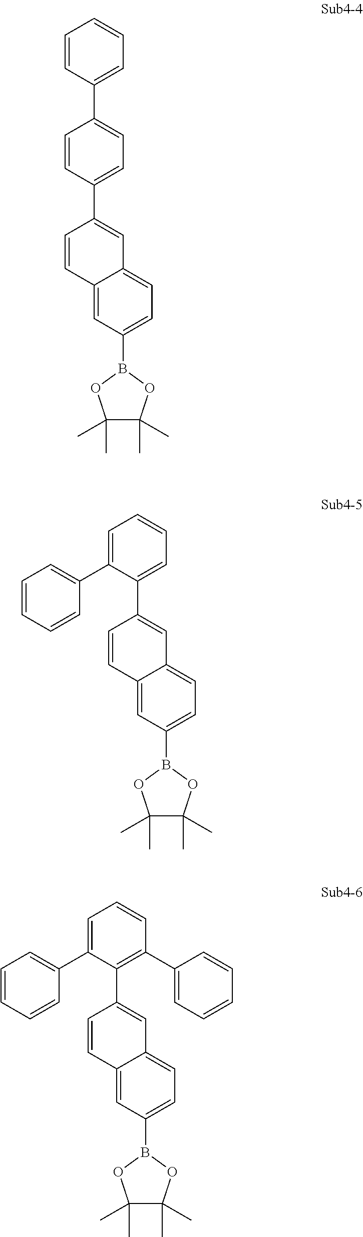 [SMILES: CC1(C)OB(c2ccc3cc(-c4ccc(-c5ccccc5)cc4)ccc3c2)OC1(C)C ; CC1(C)OB(c2ccc3cc(-c4ccccc4-c4ccccc4)ccc3c2)OC1(C)C ; CC1(C)OB(c2ccc3cc(-c4c(-c5ccccc5)cccc4-c4ccccc4)ccc3c2)OC1(C)C]

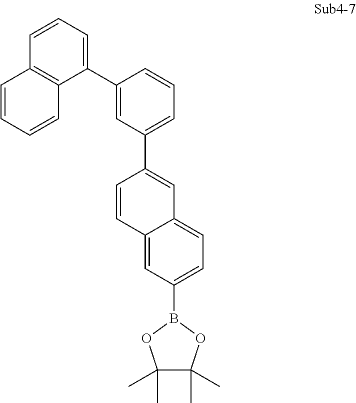 [SMILES: CC1(C)OB(c2ccc3cc(-c4cccc(-c5cccc6ccccc56)c4)ccc3c2)OC1(C)C]

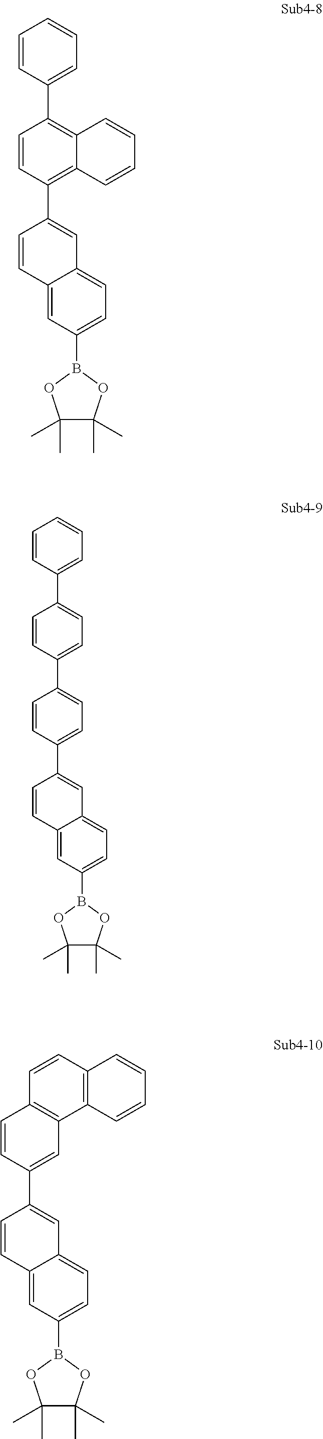 [SMILES: CC1(C)OB(c2ccc3cc(-c4ccc(-c5ccccc5)c5ccccc45)ccc3c2)OC1(C)C ; CC1(C)OB(c2ccc3cc(-c4ccc(-c5ccc(-c6ccccc6)cc5)cc4)ccc3c2)OC1(C)C ; CC1(C)OB(c2ccc3cc(-c4ccc5ccc6ccccc6c5c4)ccc3c2)OC1(C)C]

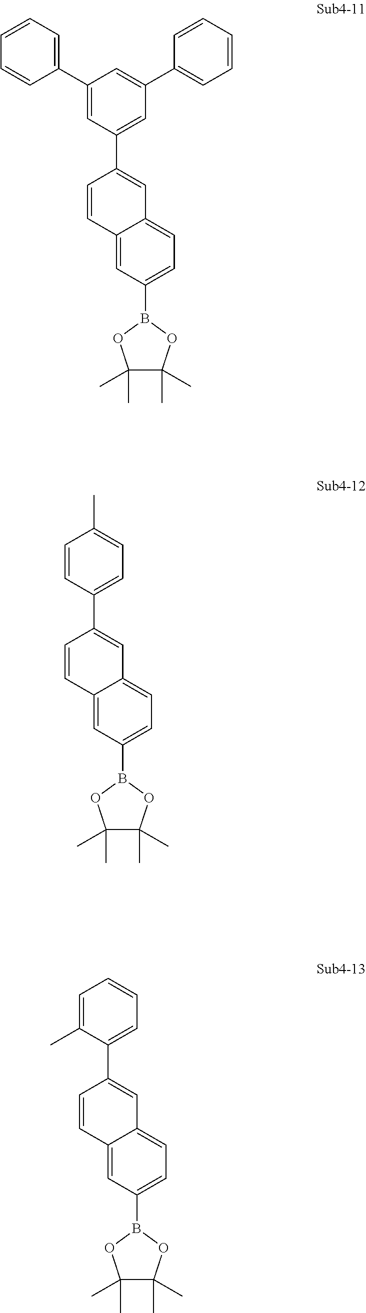

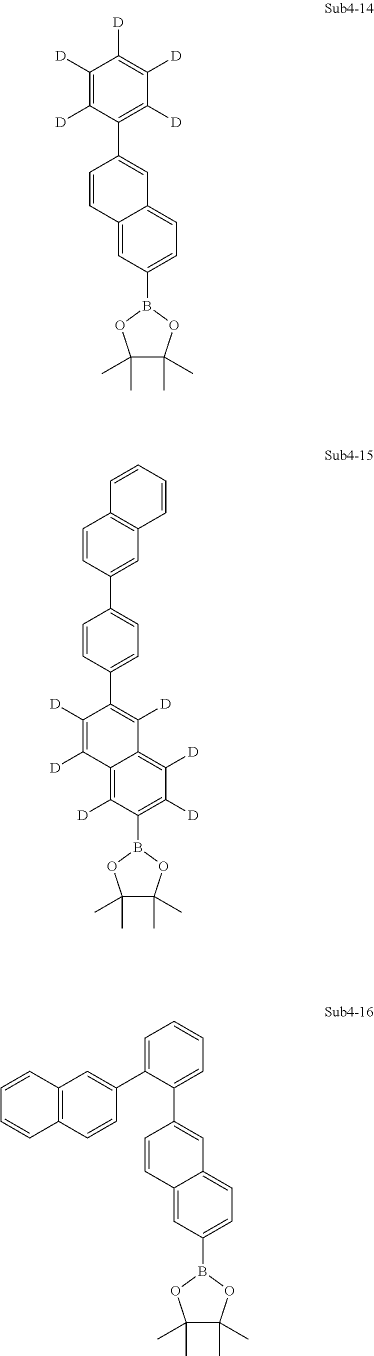 [SMILES: [2H]c1c([2H])c([2H])c(-c2ccc3cc(B4OC(C)(C)C(C)(C)O4)ccc3c2)c([2H])c1[2H] ; [2H]c1c(-c2ccc(-c3ccc4ccccc4c3)cc2)c([2H])c2c([2H])c([2H])c(B3OC(C)(C)C(C)(C)O3)c([2H])c2c1[2H] ; CC1(C)OB(c2ccc3cc(-c4ccccc4-c4ccc5ccccc5c4)ccc3c2)OC1(C)C]

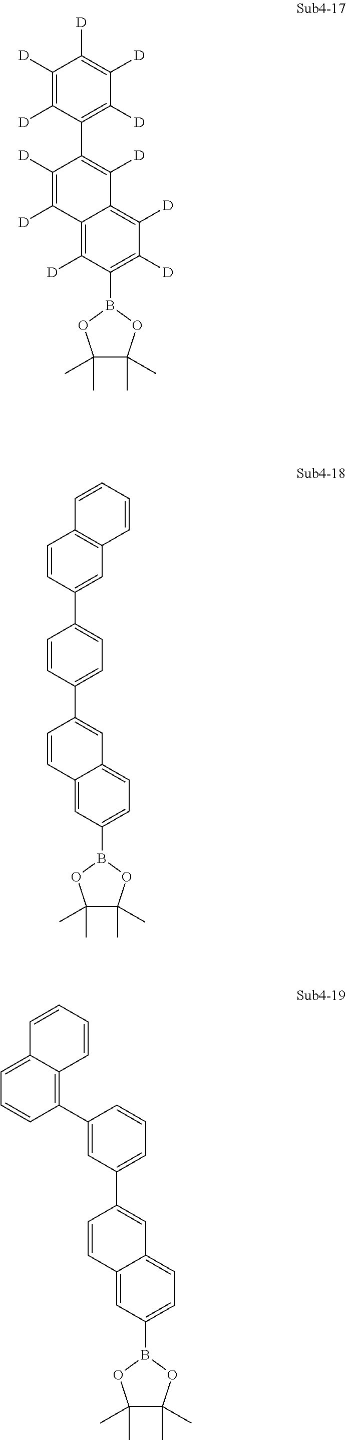 [SMILES: [2H]c1c([2H])c([2H])c(-c2c([2H])c([2H])c3c([2H])c(B4OC(C)(C)C(C)(C)O4)c([2H])c([2H])c3c2[2H])c([2H])c1[2H] ; CC1(C)OB(c2ccc3cc(-c4ccc(-c5ccc6ccccc6c5)cc4)ccc3c2)OC1(C)C ; CC1(C)OB(c2ccc3cc(-c4cccc(-c5cccc6ccccc56)c4)ccc3c2)OC1(C)C]

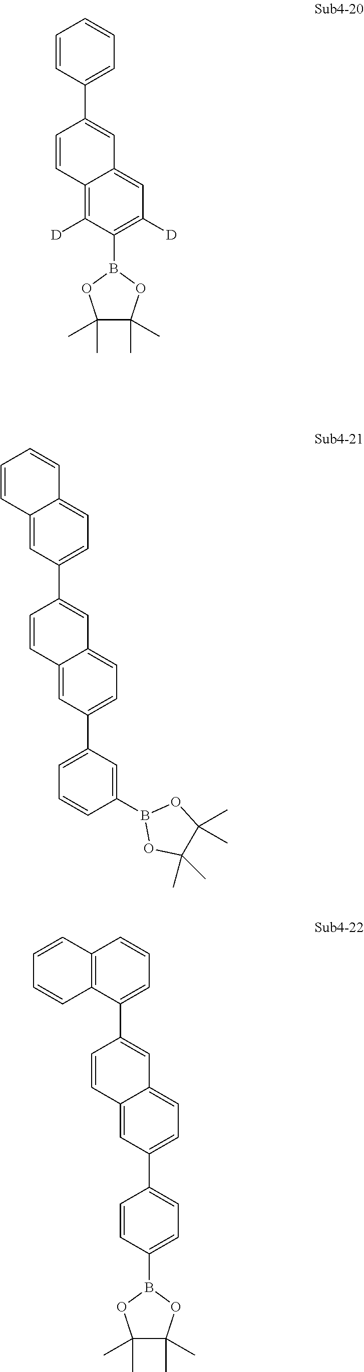 [SMILES: [2H]c1cc2cc(-c3ccccc3)ccc2c([2H])c1B1OC(C)(C)C(C)(C)O1 ; CC1(C)OB(c2cccc(-c3ccc4cc(-c5ccc6ccccc6c5)ccc4c3)c2)OC1(C)C ; CC1(C)OB(c2ccc(-c3ccc4cc(-c5cccc6ccccc56)ccc4c3)cc2)OC1(C)C]

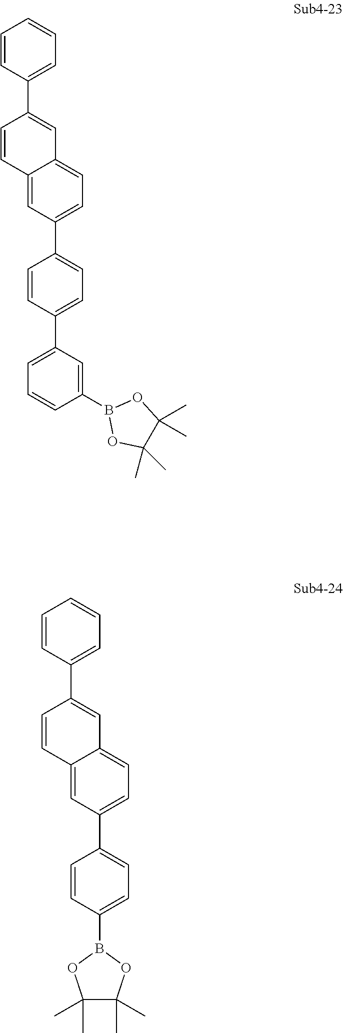 [SMILES: CC1(C)OB(c2cccc(-c3ccc(-c4ccc5cc(-c6ccccc6)ccc5c4)cc3)c2)OC1(C)C ; CC1(C)OB(c2ccc(-c3ccc4cc(-c5ccccc5)ccc4c3)cc2)OC1(C)C]

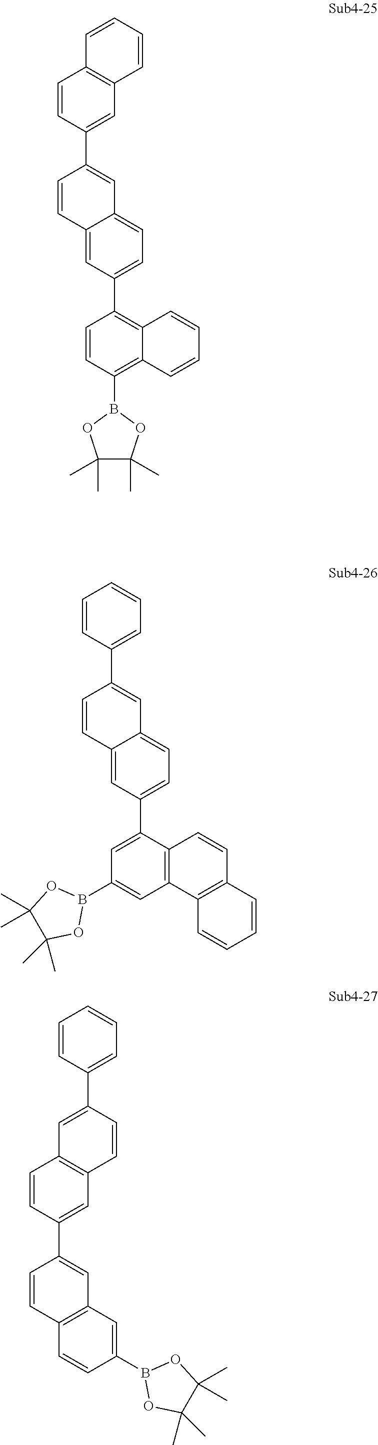 [SMILES: CC1(C)OB(c2ccc(-c3ccc4cc(-c5ccc6ccccc6c5)ccc4c3)c3ccccc23)OC1(C)C ; CC1(C)OB(c2cc(-c3ccc4cc(-c5ccccc5)ccc4c3)c3ccc4ccccc4c3c2)OC1(C)C ; CC1(C)OB(c2ccc3ccc(-c4ccc5cc(-c6ccccc6)ccc5c4)cc3c2)OC1(C)C]

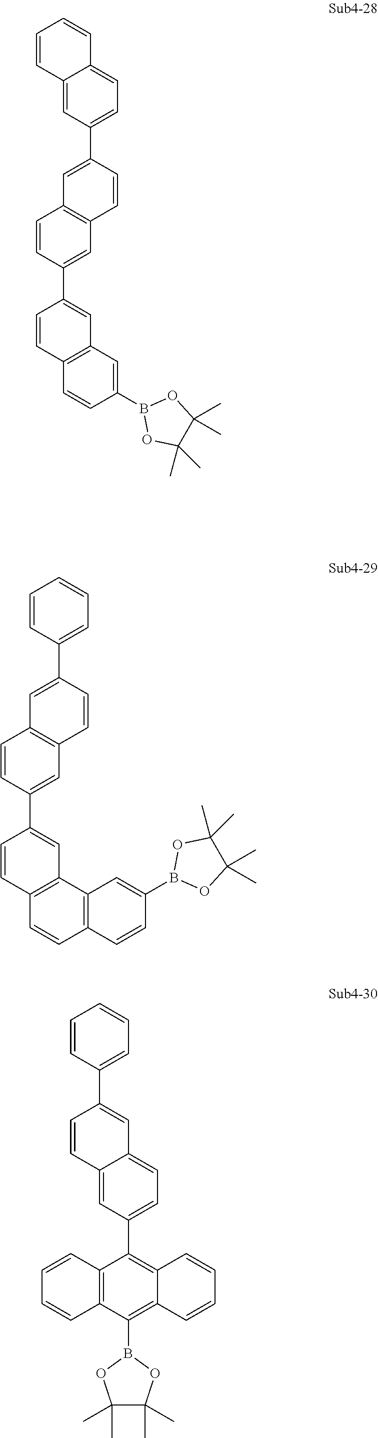 [SMILES: CC1(C)OB(c2ccc3ccc(-c4ccc5cc(-c6ccc7ccccc7c6)ccc5c4)cc3c2)OC1(C)C ; CC1(C)OB(c2ccc3ccc4ccc(-c5ccc6cc(-c7ccccc7)ccc6c5)cc4c3c2)OC1(C)C ; CC1(C)OB(c2c3ccccc3c(-c3ccc4cc(-c5ccccc5)ccc4c3)c3ccccc23)OC1(C)C]

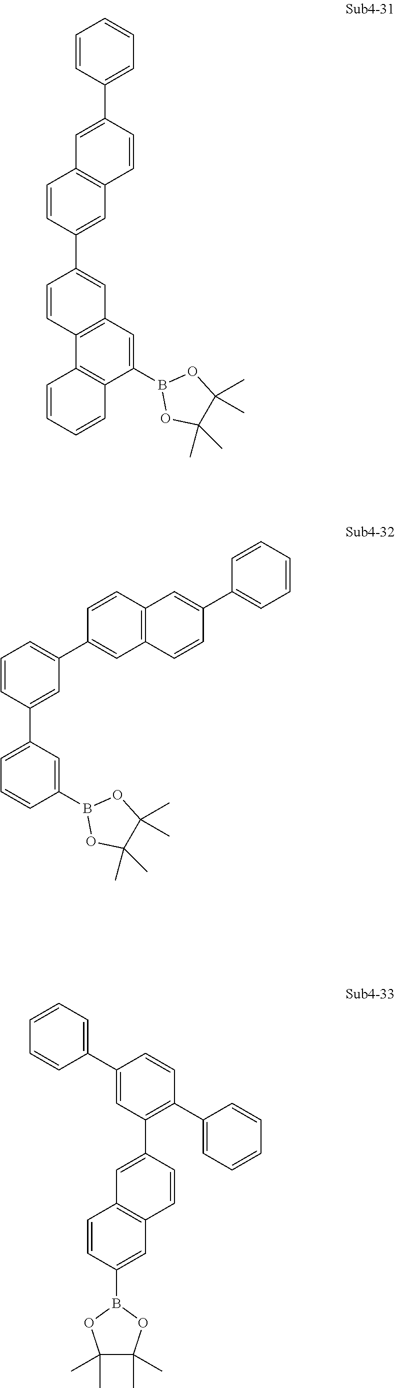 [SMILES: CC1(C)OB(c2cc3cc(-c4ccc5cc(-c6ccccc6)ccc5c4)ccc3c3ccccc23)OC1(C)C ; CC1(C)OB(c2cccc(-c3cccc(-c4ccc5cc(-c6ccccc6)ccc5c4)c3)c2)OC1(C)C ; CC1(C)OB(c2ccc3cc(-c4cc(-c5ccccc5)ccc4-c4ccccc4)ccc3c2)OC1(C)C]

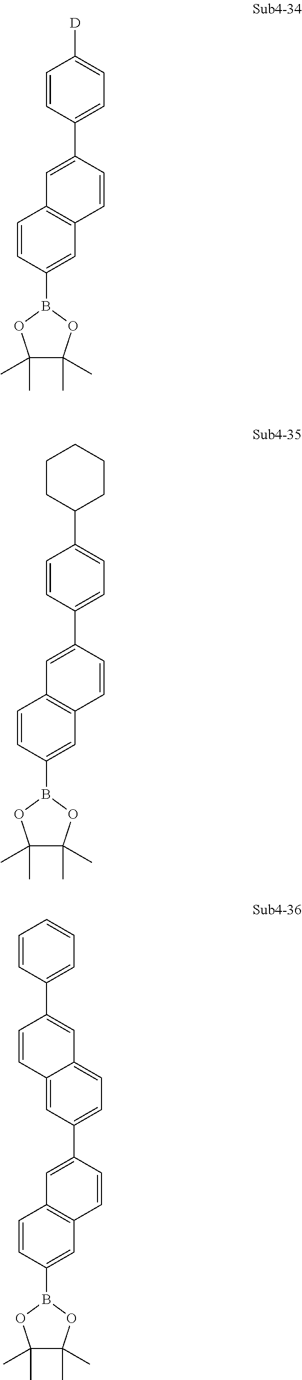

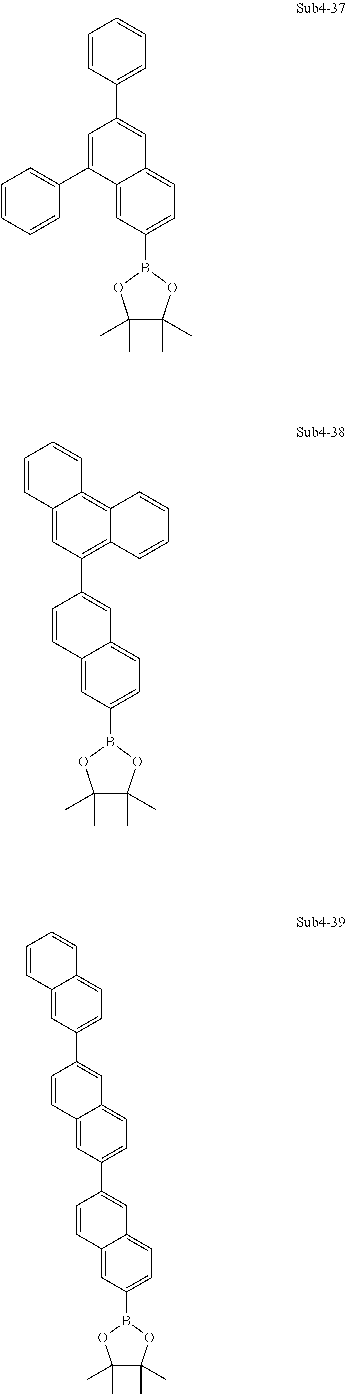 [SMILES: CC1(C)OB(c2ccc3cc(-c4ccccc4)cc(-c4ccccc4)c3c2)OC1(C)C ; CC1(C)OB(c2ccc3cc(-c4cc5ccccc5c5ccccc45)ccc3c2)OC1(C)C ; CC1(C)OB(c2ccc3cc(-c4ccc5cc(-c6ccc7ccccc7c6)ccc5c4)ccc3c2)OC1(C)C]

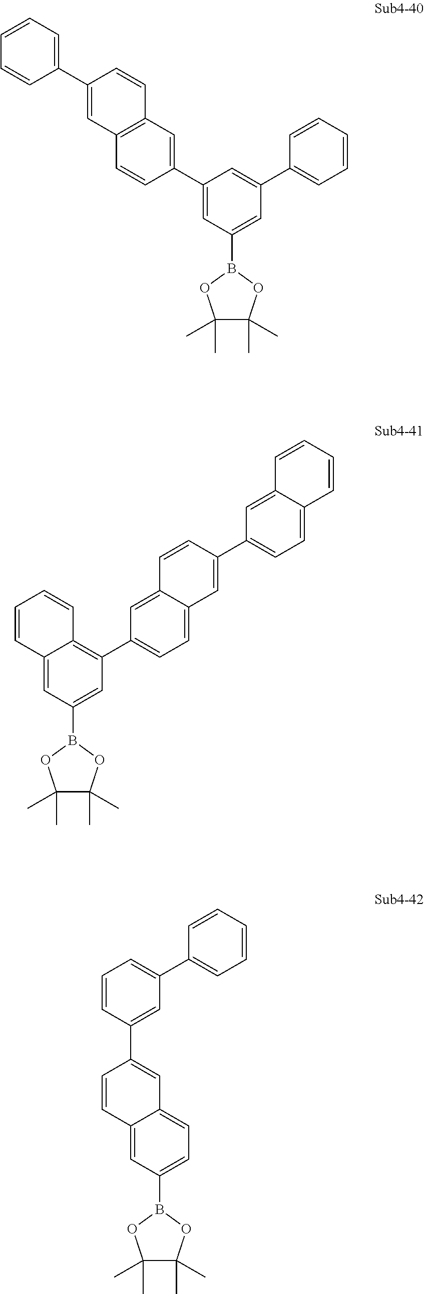 [SMILES: CC1(C)OB(c2cc(-c3ccccc3)cc(-c3ccc4cc(-c5ccccc5)ccc4c3)c2)OC1(C)C ; CC1(C)OB(c2cc(-c3ccc4cc(-c5ccc6ccccc6c5)ccc4c3)c3ccccc3c2)OC1(C)C ; CC1(C)OB(c2ccc3cc(-c4cccc(-c5ccccc5)c4)ccc3c2)OC1(C)C]

TABLE 6

| Compound | FD-MS | Compound | FD-MS |
|---|---|---|---|
| Sub4-1 | m/z = 330.18(C₂₂H₂₃BO₂ = 330.23) | Sub4-2 | m/z = 380.19(C₂₆H₂₅BO₂ = 380.29) |
| Sub4-3 | m/z = 380.19(C₂₆H₂₅BO₂ = 380.29) | Sub4-4 | m/z = 406.21(C₂₈H₂₇BO₂ = 406.33) |
| Sub4-5 | m/z = 406.21(C₂₈H₂₇BO₂ = 406.33) | Sub4-6 | m/z = 482.24(C₃₄H₃₁BO₂ = 482.43) |
| Sub4-7 | m/z = 456.23(C₃₂H₂₉BO₂ = 456.39) | Sub4-8 | m/z = 456.23(C₃₂H₂₉BO₂ = 456.39) |
| Sub4-9 | m/z = 482.24(C₃₄H₃₁BO₂ = 482.43) | Sub4-10 | m/z = 430.21(C₃₀H₂₇BO₂ = 430.35) |
| Sub4-11 | m/z = 482.24(C₃₄H₃₁BO₂ = 482.43) | Sub4-12 | m/z = 344.19(C₂₃H₂₅BO₂ = 344.26) |
| Sub4-13 | m/z = 344.19(C₂₃H₂₅BO₂ = 344.26) | Sub4-14 | m/z = 335.21(C₂₂H₁₈D₅BO₂ = 335.26) |
| Sub4-15 | m/z = 462.26(C₃₂H₂₃D₆BO₂ = 462,43) | Sub4-16 | m/z = 456.23(C₃₂H₂₉BO₂ = 456.39) |
| Sub4-17 | m/z = 341.25(C₂₂H₁₂D₁₁BO₂ = 341.3) | Sub4-18 | m/z = 456.23(C₃₂H₂₉BO₂ = 456.39) |
| Sub4-19 | m/z = 456.23(C₃₂H₂₉BO₂ = 456.39) | Sub4-20 | m/z = 332.19(C₂₂H₂₁D₂BO₂ = 332.25) |
| Sub4-21 | m/z = 456.23(C₃₂H₂₉BO₂ = 456.39) | Sub4-22 | m/z = 456.23(C₃₂H₂₉BO₂ = 456.39) |
| Sub4-23 | m/z = 482.24(C₃₄H₃₁BO₂ = 482.43) | Sub4-24 | m/z = 406.21(C₂₈H₂₇BO₂ = 406.33) |
| Sub4-25 | m/z = 506.24(C₃₆H₃₁BO₂ = 506.45) | Sub4-26 | m/z = 506.24(C₃₆H₃₁BO₂ = 506.45) |
| Sub4-27 | m/z = 456.23(C₃₂H₂₉BO₂ = 456.39) | Sub4-28 | m/z = 506.24(C₃₆H₃₁BO₂ = 506.45) |
| Sub4-29 | m/z = 506.24(C₃₂H₂₉BO₂ = 506.45) | Sub4-30 | m/z = 506.24(C₃₆H₃₁BO₂ = 506.45) |
| Sub4-31 | m/z = 506.24(C₃₆H₃₁BO₂ = 506.45) | Sub4-32 | m/z = 482.24(C₃₄H₃₁BO₂ = 482.43) |
| Sub4-33 | m/z = 482.24(C₃₄H₃₁BO₂ = 482.43) | Sub4-34 | m/z = 331.19(C₂₂H₂₂DBO₂ = 331.24) |
| Sub4-35 | m/z = 412.26(C₂₈H₃₃BO₂ = 412.38) | Sub4-36 | m/z = 456.23(C₃₂H₂₉BO₂ = 456.39) |
| Sub4-37 | m/z = 406.21(C₂₈H₂₇BO₂ = 406.33) | Sub4-38 | m/z = 430.21(C₃₀H₂₇BO₂ = 430.35) |
| Sub4-39 | m/z = 506.24(C₃₆H₃₁BO₂ = 506.45) | Sub4-40 | m/z = 482.24(C₃₄H₃₁BO₂ = 482.43) |
| Sub4-41 | m/z = 506.24(C₃₅H₃₁BO₂ = 506.45) | Sub4-42 | m/z = 406.21(C₂₈H₂₇BO₂ = 406.33) |

### Exemplary Compounds of Sub5

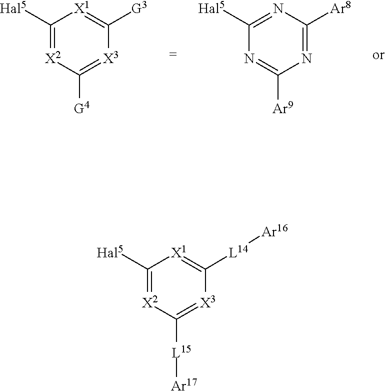

### Sub5

Compounds belonging to Sub 5 may be, but not limited to, the following compounds, and Table 7 shows FD-MS values of the following compounds.

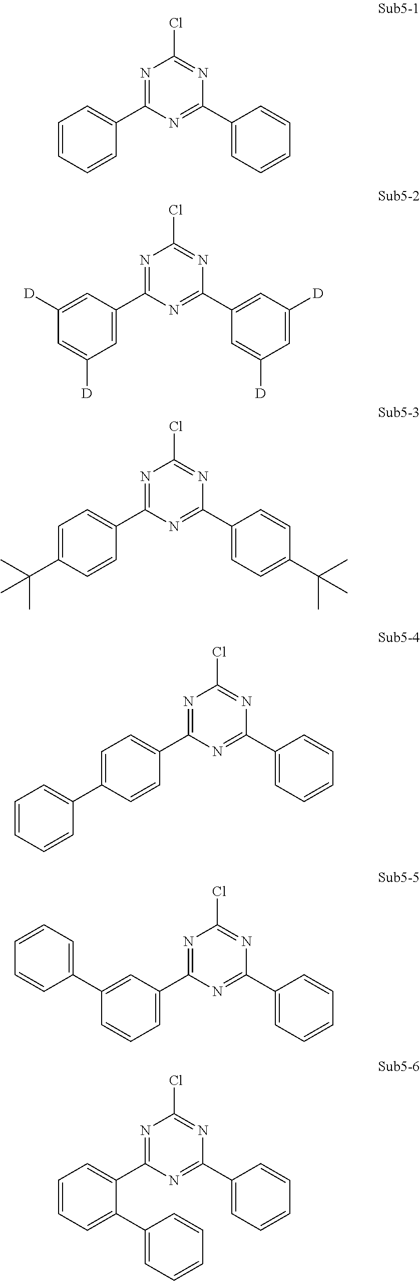 [SMILES: Clc1nc(-c2ccccc2)nc(-c2ccccc2)n1 ; [2H]c1cc([2H])cc(-c2nc(Cl)nc(-c3cc([2H])cc([2H])c3)n2)c1 ; CC(C)(C)c1ccc(-c2nc(Cl)nc(-c3ccc(C(C)(C)C)cc3)n2)cc1 ; Clc1nc(-c2ccccc2)nc(-c2ccc(-c3ccccc3)cc2)n1 ; Clc1nc(-c2ccccc2)nc(-c2cccc(-c3ccccc3)c2)n1 ; Clc1nc(-c2ccccc2)nc(-c2ccccc2-c2ccccc2)n1]

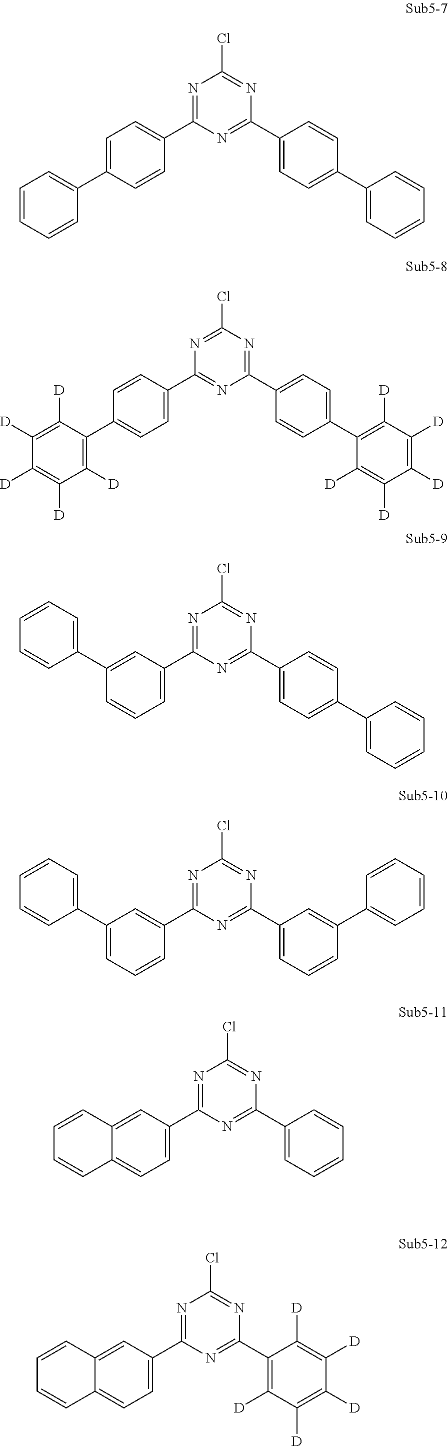 [SMILES: Clc1nc(-c2ccc(-c3ccccc3)cc2)nc(-c2ccc(-c3ccccc3)cc2)n1 ; [2H]c1c([2H])c([2H])c(-c2ccc(-c3nc(Cl)nc(-c4ccc(-c5c([2H])c([2H])c([2H])c([2H])c5[2H])cc4)n3)cc2)c([2H])c1[2H] ; Clc1nc(-c2ccc(-c3ccccc3)cc2)nc(-c2cccc(-c3ccccc3)c2)n1 ; Clc1nc(-c2cccc(-c3ccccc3)c2)nc(-c2cccc(-c3ccccc3)c2)n1 ; Clc1nc(-c2ccccc2)nc(-c2ccc3ccccc3c2)n1 ; [2H]c1c([2H])c([2H])c(-c2nc(Cl)nc(-c3ccc4ccccc4c3)n2)c([2H])c1[2H]]

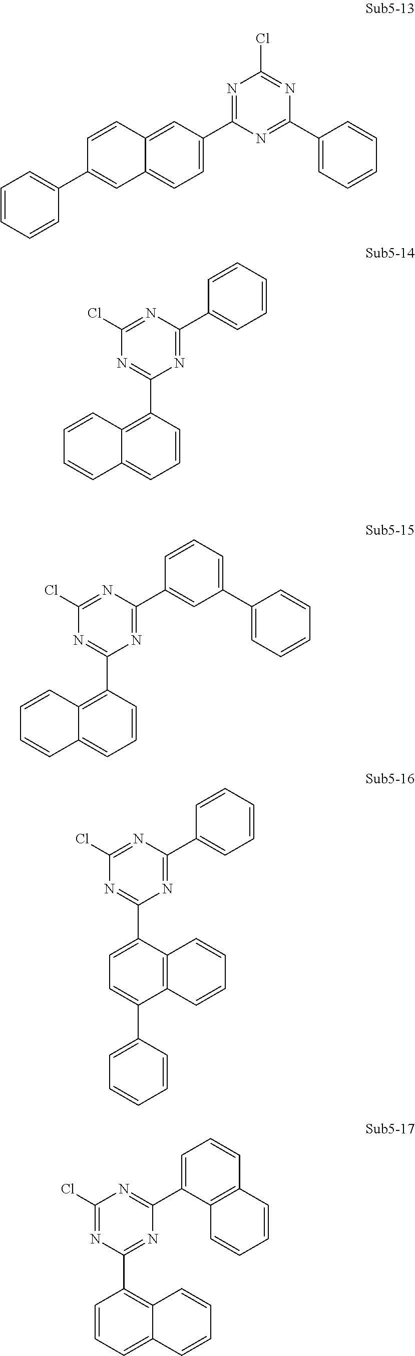 [SMILES: Clc1nc(-c2ccccc2)nc(-c2ccc3cc(-c4ccccc4)ccc3c2)n1 ; Clc1nc(-c2ccccc2)nc(-c2cccc3ccccc23)n1 ; Clc1nc(-c2cccc(-c3ccccc3)c2)nc(-c2cccc3ccccc23)n1 ; Clc1nc(-c2ccccc2)nc(-c2ccc(-c3ccccc3)c3ccccc23)n1 ; Clc1nc(-c2cccc3ccccc23)nc(-c2cccc3ccccc23)n1]

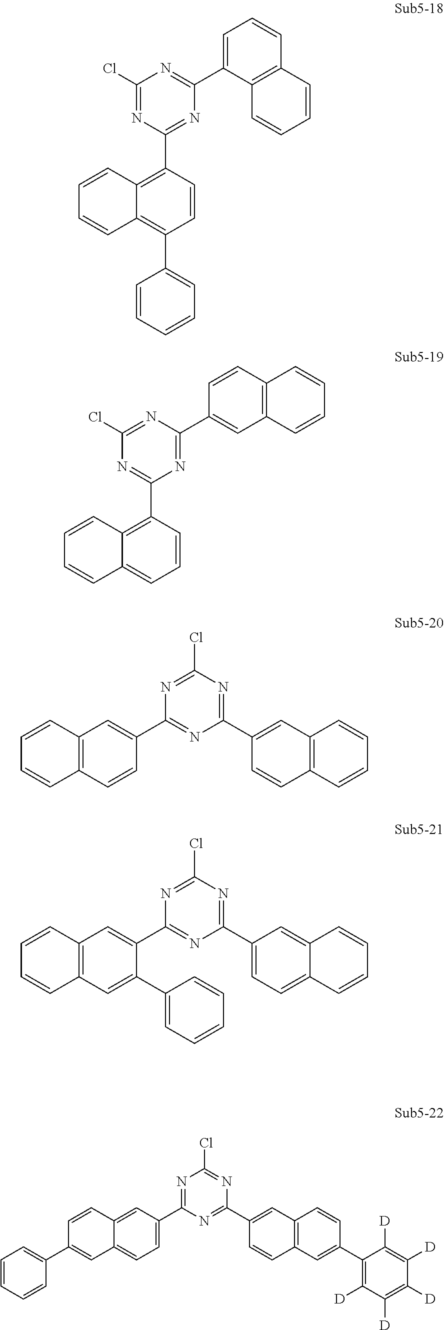 [SMILES: Clc1nc(-c2cccc3ccccc23)nc(-c2ccc(-c3ccccc3)c3ccccc23)n1 ; Clc1nc(-c2ccc3ccccc3c2)nc(-c2cccc3ccccc23)n1 ; Clc1nc(-c2ccc3ccccc3c2)nc(-c2ccc3ccccc3c2)n1 ; Clc1nc(-c2ccc3ccccc3c2)nc(-c2cc3ccccc3cc2-c2ccccc2)n1 ; [2H]c1c([2H])c([2H])c(-c2ccc3cc(-c4nc(Cl)nc(-c5ccc6cc(-c7ccccc7)ccc6c5)n4)ccc3c2)c([2H])c1[2H]]

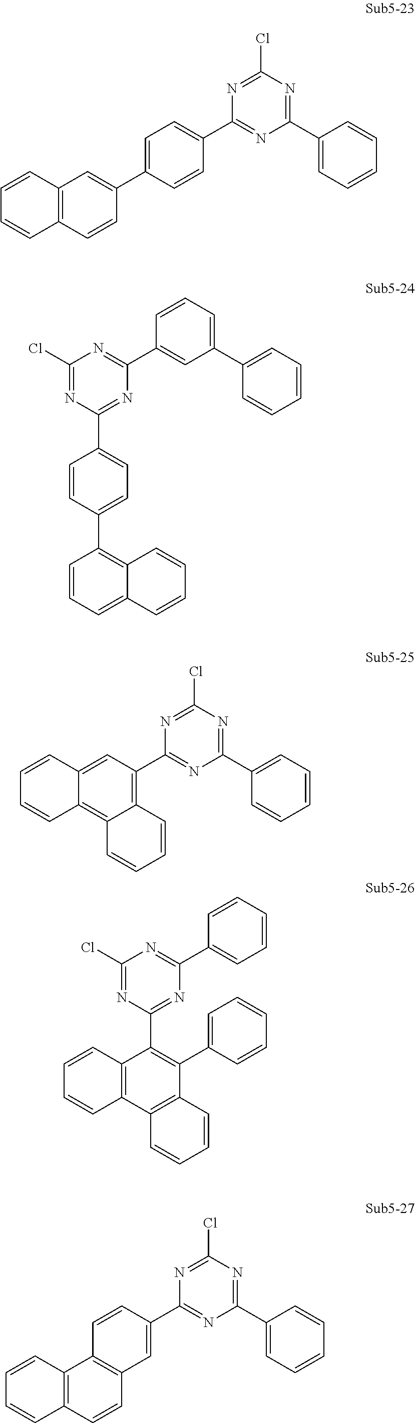 [SMILES: Clc1nc(-c2ccccc2)nc(-c2ccc(-c3ccc4ccccc4c3)cc2)n1 ; Clc1nc(-c2ccc(-c3cccc4ccccc34)cc2)nc(-c2cccc(-c3ccccc3)c2)n1 ; Clc1nc(-c2ccccc2)nc(-c2cc3ccccc3c3ccccc23)n1 ; Clc1nc(-c2ccccc2)nc(-c2c(-c3ccccc3)c3ccccc3c3ccccc23)n1 ; Clc1nc(-c2ccccc2)nc(-c2ccc3c(ccc4ccccc43)c2)n1]

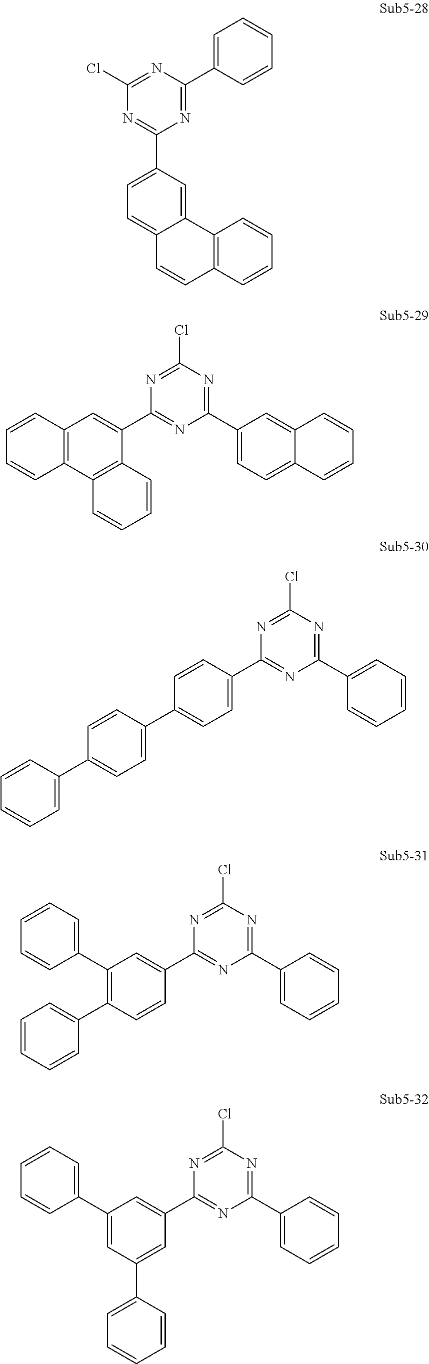

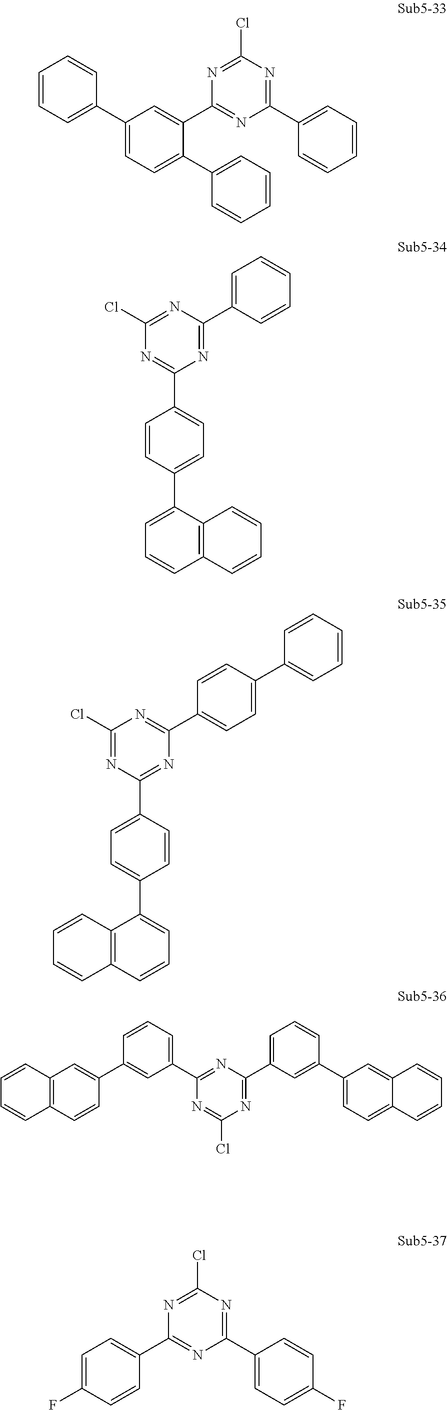

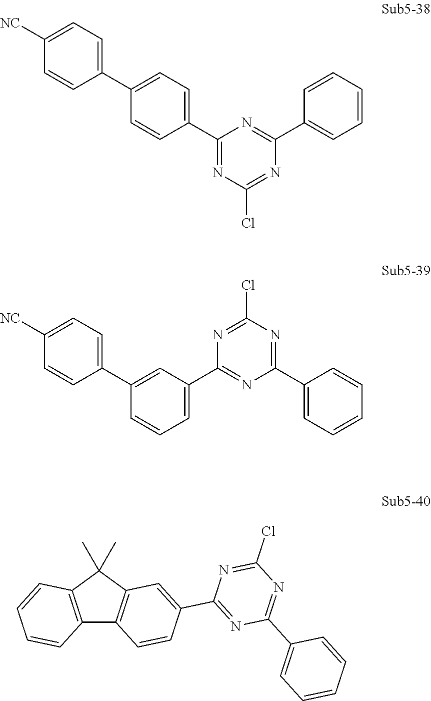 [SMILES: N#Cc1ccc(-c2ccc(-c3nc(Cl)nc(-c4ccccc4)n3)cc2)cc1 ; N#Cc1ccc(-c2cccc(-c3nc(Cl)nc(-c4ccccc4)n3)c2)cc1 ; CC1(C)c2ccccc2-c2ccc(-c3nc(Cl)nc(-c4ccccc4)n3)cc21]

TABLE 7

| Compound | FD-MS | Compound | FD-MS |
|---|---|---|---|
| Sub5-1 | m/z = 267.06(C₁₅H₁₀CIN₃ = 267.72) | Sub5-2 | m/z = 271.08(C₁₅H₆D₄CIN₃ = 271.74) |
| Sub5-3 | m/z = 379.18(C₂₃H₂₆CIN₃ = 379.93) | Sub5-4 | m/z = 343.09(C₂₁H₁₄CIN₃ = 343.81) |
| Sub5-5 | m/z = 343.09(C₂₁H₁₄CIN₃ = 343.81) | Sub5-6 | m/z = 343.09(C₂₁H₁₄CIN₃ = 343.81) |
| Sub5-7 | m/z = 419.12(C₂₇H₁₈CIN₃ = 419.91) | Sub5-8 | m/z = 429.18(C₂₇H₈D₁₀CIN₃ = 429.97) |
| Sub5-9 | m/z = 419.12(C₂₇H₁₈CIN₃ = 419.91) | Sub5-10 | m/z = 419.12(C₂₇H₁₈CIN₃ = 419.91) |
| Sub5-11 | m/z = 317.07(C₁₉H₁₂CIN₃ = 317.78) | Sub5-12 | m/z = 322.1(C₁₉H₇D₅CIN₃ = 322.81) |
| Sub5-13 | m/z = 393.1(C₂₅H₁₆CIN₃ = 393.87) | Sub5-14 | m/z = 317.07(C₁₉H₁₂CIN₃ = 317.78) |
| Sub5-15 | m/z = 393.1(C₂₅H₁₆CIN₃ = 393.87) | Sub5-16 | m/z = 393.1(C₂₅H₁₆CIN₃ = 393.87) |
| Sub5-17 | m/z = 367.09(C₂₃H₁₄CIN₃ = 367.84) | Sub5-18 | m/z = 443.12(C₂₉H₁₈CIN₃ = 443.93) |
| Sub5-19 | m/z = 367.09(C₂₃H₁₄CIN₃ = 367.84) | Sub5-20 | m/z = 367.09(C₂₃H₁₄CIN₃ = 367.84) |
| Sub5-21 | m/z = 443.12(C₂₉H₁₈CIN₃ = 443.93) | Sub5-22 | m/z = 524.18(C₃₅H₁₇D₅CIN₃ = 525.06) |
| Sub5-23 | m/z = 393.1(C₂₅H₁₆CIN₃ = 393.87) | Sub5-24 | m/z = 469.13(C₃₁H₂₀CIN₃ = 469.97) |
| Sub5-25 | m/z = 367.09(C₂₃H₁₄CIN₃ = 367.84) | Sub5-26 | m/z = 443.12(C₂₉H₁₈CIN₃ = 443.93) |
| Sub5-27 | m/z = 367.09(C₂₃H₁₄CIN₃ = 367.84) | Sub5-28 | m/z = 367.09(C₂₃H₁₄CIN₃ = 367.84) |
| Sub5-29 | m/z = 417.1(C₂₇H₁₆CIN₃ = 417.9) | Sub5-30 | m/z = 419.12(C₂₇H₁₈CIN₃ = 419.91) |
| Sub5-31 | m/z = 419.12(C₂₇H₁₈CIN₃ = 419.91) | Sub5-32 | m/z = 419.12(C₂₇H₁₈CIN₃ = 419.91) |
| Sub5-33 | m/z = 419.12(C₂₇H₁₈CIN₃ = 419.91) | Sub5-34 | m/z = 393.1(C₂₅H₁₆CIN₃ = 393.87) |
| Sub5-35 | m/z = 469.13(C₃₁H₂₀CIN₃ = 469.97) | Sub5-36 | m/z = 519.15(C₃₅H₂₂CIN₃ = 520.03) |
| Sub5-37 | m/z = 303.04(C₁₅H₈CIF₂N₃ = 303.7) | Sub5-38 | m/z = 368.08(C₂₂H₁₃CIN₄ = 368.82) |
| Sub5-39 | m/z = 368.08(C₂₂H₁₃CIN₄ = 368.82) | Sub5-40 | m/z = 383.12(C₂₄H₁₈CIN₃ = 383.88) |

### Synthesis Example of Final Compound

### 1. Synthesis Example of N-7

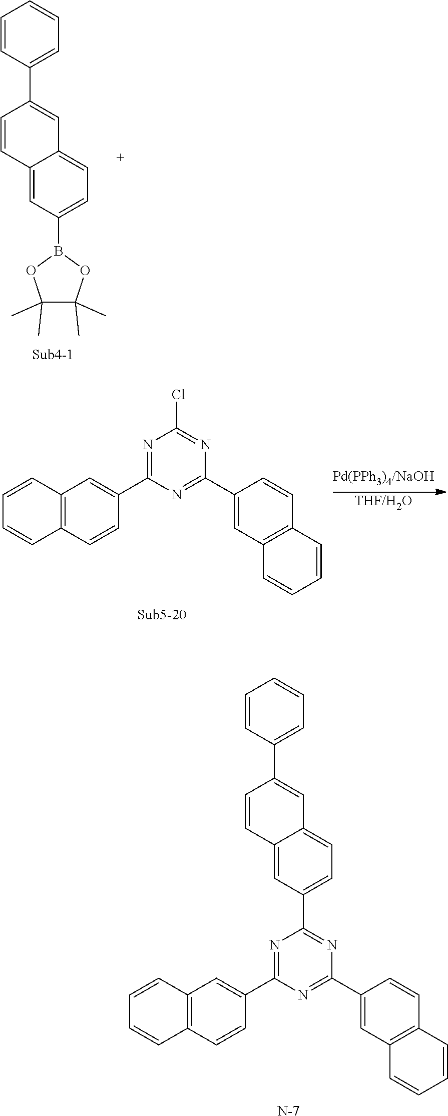

After dissolving Sub4-1 (10.0 g, 30.3 mmol) in THF (Tetrahydrofuran) (151 mL), Sub5-20 (11.1 g, 30.3 mmol), NaOH (3.6 g, 90.8 mmol), Pd(PPh₃)₄ (2.10 g, 1.82 mmol) and water (76 mL) are added thereto and the reaction is carried out at 80° C. When the reaction is completed, the reaction product is extracted with CH₂Cl₂ and water, and then the organic layer is dried with MgSO₄ and concentrated. Then, the concentrate is separated through a silica gel column and recrystallized to obtain 13.3 g (yield: 82%) of the product.

### 2. Synthesis Example of N-38

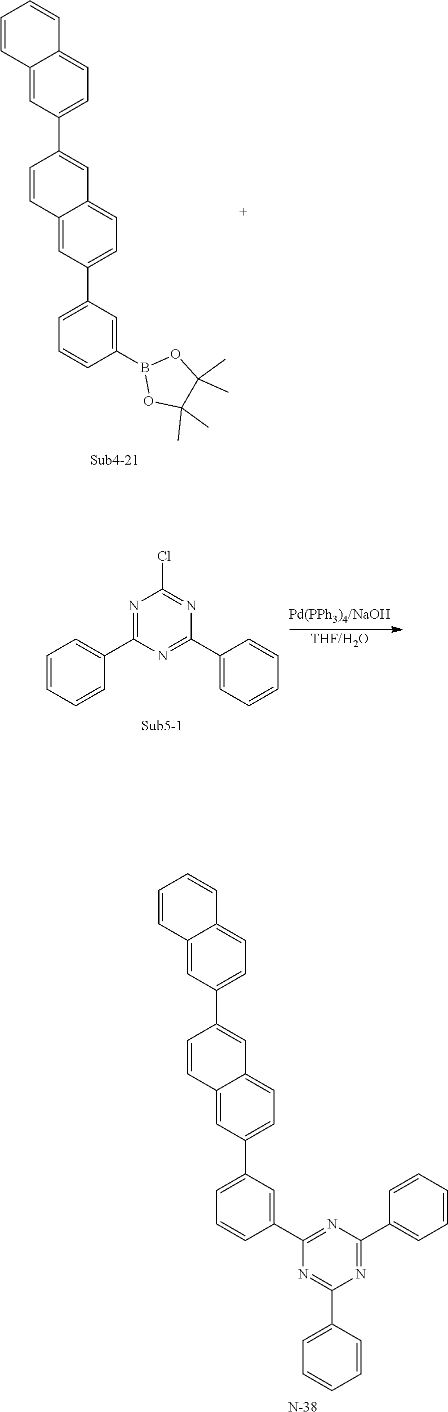

After dissolving Sub4-21 (10.0 g, 21.9 mmol) in THF (110 mL), Sub5-1 (5.9 g, 21.9 mmol), NaOH (2.6 g, 65.7 mmol), Pd(PPh₃)₄ (1.52 g, 1.31 mmol) and water (55 mL) are added thereto, and the synthesis is carried out in the same manner as the synthesis of N-7, and then purified to obtain 9.6 g (yield: 78%) of product.

### 3. Synthesis Example of N-65

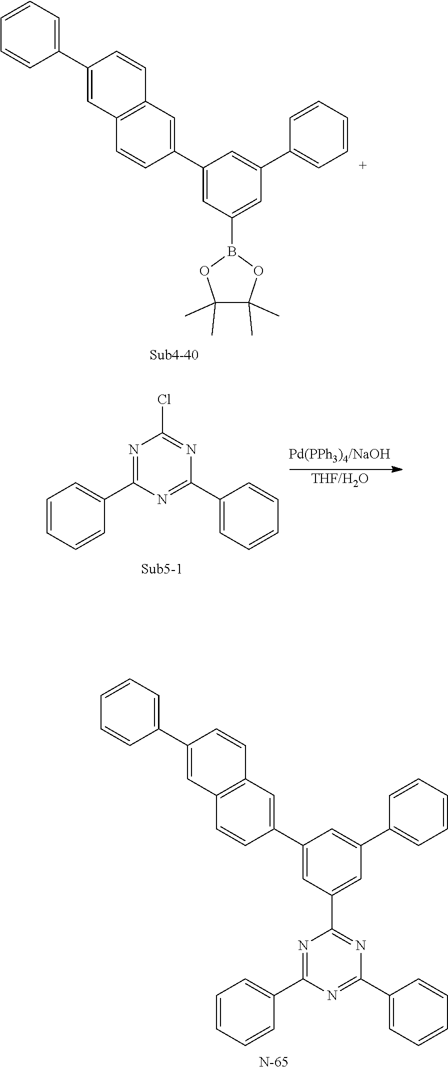

After dissolving Sub4-40 (10.0 g, 20.7 mmol) in THF (104 mL), Sub5-1 (5.5 g, 20.7 mmol), NaOH (2.5 g, 62.2 mmol), Pd(PPh₃)₄ (1.44 g, 1.24 mmol) and water (52 mL) are added thereto, and the synthesis is carried out in the same manner as the synthesis of N-7, and then purified to obtain 9.1 g (yield: 75%) of product.

The FD-MS values of the compounds N-1 to N-68 of the present invention prepared according to the above synthesis examples are shown in Table 8 below.

TABLE 8

| Compound | FD-MS | Compound | FD-MS |
|---|---|---|---|
| N-1 | m/z = 435.17(C₃₁H₂₁N₃ = 435.53) | N-2 | m/z = 485.19(C₃₅H₂₃N₃ = 485.59) |
| N-3 | m/z = 485.19(C₃₅H₂₃N₃ = 485.59) | N-4 | m/z = 485.19(C₃₅H₂₃N₃ = 485.59) |
| N-5 | m/z = 485.19(C₃₅H₂₃N₃ = 485.59) | N-6 | m/z = 535.2(C₃₉H₂₅N₃ = 535.65) |
| N-7 | m/z = 535.2(C₃₉H₂₅N₃ = 535.65) | N-8 | m/z = 585.22(C₄₃H₂₇N₃ = 585.71) |
| N-9 | m/z = 561.22(C₄₁H₂₇N₃ = 561.69) | N-10 | m/z = 511.2(C₃₇H₂₅N₃ = 511.63) |
| N-11 | m/z = 587.24(C₄₃H₂₉N₃ = 587.73) | N-12 | m/z = 663.27(C₄₉H₃₃N₃ = 663.82) |
| N-13 | m/z = 561.22(C₄₁H₂₇N₃ = 561.69) | N-14 | m/z = 637.25(Ca7H₃₁N₃ = 637.79) |
| N-15 | m/z = 561.22(C₄₁H₂₇N₃ = 561.69) | N-16 | m/z = 687.27(C₅₁H₃₃N₃ = 687.85) |
| N-17 | m/z = 637.25(C₄₇H₃₁N₃ = 637.79) | N-18 | m/z = 637.25(C₄₇H₃₁N₃ = 637.79) |
| N-19 | m/z = 663.27(C₄₉H₃₃N₃ = 663.82) | N-20 | m/z = 637.25(C₄₇H₃₁N₃ = 637.79) |
| N-21 | m/z = 535.2(C₃₉H₂₅N₃ = 535.65) | N-22 | m/z = 535.2(C₃₉H₂₅N₃ = 535.65) |
| N-23 | m/z = 663.27(C₄₉H₃₃N₃ = 663.82) | N-24 | m/z = 535.2(C₃₉H₂₅N₃ = 535.65) |
| N-25 | m/z = 739.3(C₅₅H₃₇N₃ = 739.92) | N-26 | m/z = 449.19(C₃₂H₂₃N₃ = 449.56) |
| N-27 | m/z = 449.19(C₃₂H₂₃N₃ = 449.56) | N-28 | m/z = 540.24(C₃₉H₂₀D₅N₃ = 540.68) |
| N-29 | m/z = 490.22(C₃₅H₁₈D₅N₃ = 490.62) | N-30 | m/z = 567.26(C₄₁H₂₁D₆N₃ = 567.72) |
| N-31 | m/z = 561.22(C₄₁H₂₇N₃ = 561.69) | N-32 | m/z = 546.27(C₃₉H₁₄D₁₁N₃ = 546.72) |
| N-33 | m/z = 602.33(C₄₃H₁₄D₁₅N₃ = 602.82) | N-34 | m/z = 561.22(C₄₁H₂₇N₃ = 561.69) |
| N-35 | m/z = 561.22(C₄₁H₂₇N₃ = 561.69) | N-36 | m/z = 441.21(C₃₁H₁₅D₆N₃ = 441.57) |
| N-37 | m/z = 611.24(C₄₅H₂₉N₃ = 611.75) | N-38 | m/z = 561.22(C₄₁H₂₇N₃ = 561.69) |
| N-39 | m/z = 561.22(C₄₁H₂₇N₃ = 561.69) | N-40 | m/z = 587.24(C₄₃H₂₉N₃ = 587.73) |
| N-41 | m/z = 561.22(C₄₁H₂₇N₃ = 561.69) | N-42 | m/z = 587.24(C₄₃H₂₉N₃ = 587.73) |
| N-43 | m/z = 611.24(C₄₅H₂₉N₃ = 611.75) | N-44 | m/z = 611.24(C₄₅H₂₉N₃ = 611.75) |
| N-45 | m/z = 611.24(C₄₅H₂₉N₃ = 611.75) | N-46 | m/z = 561.22(C₄₁H₂₇N₃ = 561.69) |
| N-47 | m/z = 711.27(C₅₃H₃₃N₃ = 711.87) | N-48 | m/z = 611.24(C₄₅H₂₉N₃ = 611.75) |
| N-49 | m/z = 611.24(C₄₅H₂₉N₃ = 611.75) | N-50 | m/z = 611.24(C₄₅H₂₉N₃ = 611.75) |
| N-51 | m/z = 663.27(C₄₅H₃₃N₃ = 663.82) | N-52 | m/z = 611.24(C₄₅H₂₉N₃ = 611.75) |
| N-53 | m/z = 692.3(C₅₁H₂₈D₅N₃ = 692.88) | N-54 | m/z = 490.22(C₃₅H₁₈D₅N₃ = 490.62) |
| N-55 | m/z = 739.3(C₄₅H₃₇N₃ = 739.92) | N-56 | m/z = 588.24(C₄₃H₂₈DN₃ = 588.73) |
| N-57 | m/z = 629.38(C₄₁H₄₇N₃ = 629.89) | N-58 | m/z = 561.22(C₄₁H₂₇N₃ = 561.69) |
| N-59 | m/z = 561.22(C₄₁H₂₇N₃ = 561.69) | N-60 | m/z = 561.22(C₄₁H₂₇N₃ = 561.69) |
| N-61 | m/z = 561.22(C₄₁H₂₇N₃ = 561.69) | N-62 | m/z = 535.2(C₃₉H₂₅N₃ = 535.65) |
| N-63 | m/z = 611.24(C₄₅H₂₉N₃ = 611.75) | N-64 | m/z = 585.22(C₄₃H₂₇N₃ = 585.71) |
| N-65 | m/z = 587.24(C₄₃H₂₉N₃ = 587.73) | N-66 | m/z = 637.25(C₄₇H₃₁N₃ = 637.79) |
| N-67 | m/z = 611.24(C₄₅H₂₉N₃ = 611.75) | N-68 | m/z = 687.27(C₅₁H₃₃N₃ = 687.85) |

### [Synthesis Example 4] Synthesis Example of Formula 4

The compound represented by Formula 4 (final product 4) according to the present invention can be synthesized as shown in Reaction Scheme 5 below, but is not limited thereto.

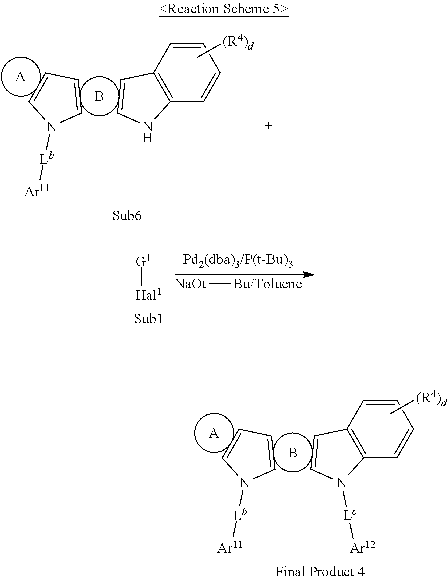

### Exemplary Compounds of Sub6

Compounds belonging to Sub6 may be, but not limited to, the following compounds, and Table 9 shows FD-MS values of the following compounds.

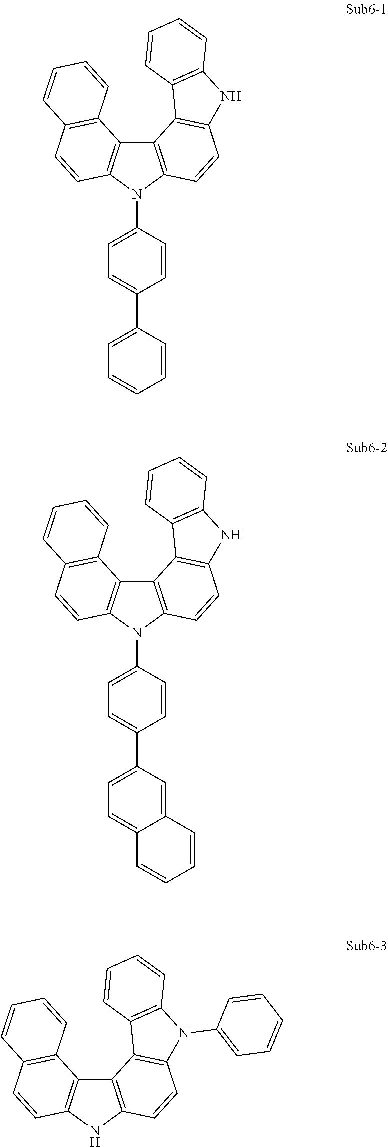 [SMILES: c1ccc(-c2ccc(-n3c4ccc5ccccc5c4c4c5c(ccc43)[nH]c3ccccc35)cc2)cc1 ; c1ccc2cc(-c3ccc(-n4c5ccc6ccccc6c5c5c6c(ccc54)[nH]c4ccccc46)cc3)ccc2c1 ; c1ccc(-n2c3ccccc3c3c4c(ccc32)[nH]c2ccc3ccccc3c24)cc1]

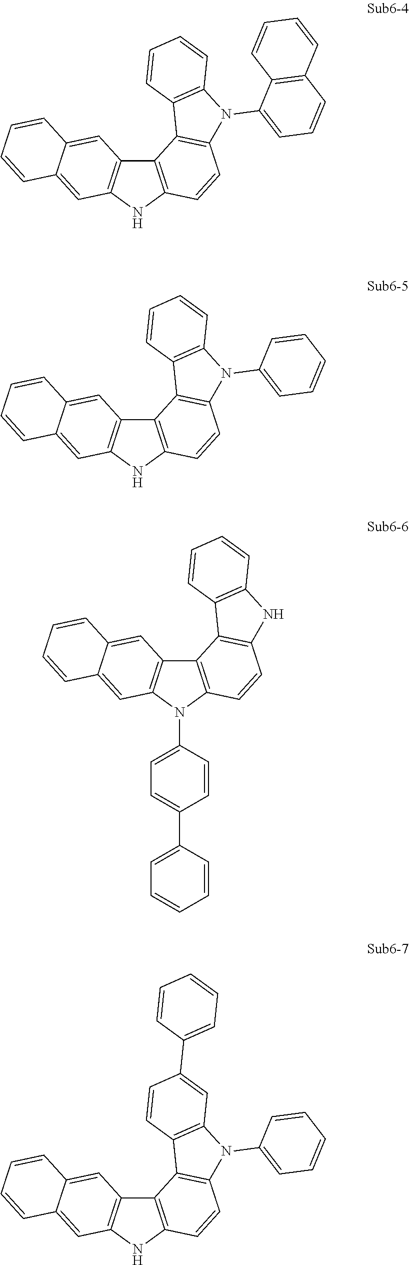 [SMILES: c1ccc2cc3c(cc2c1)[nH]c1ccc2c(c4ccccc4n2-c2cccc4ccccc24)c13 ; c1ccc(-n2c3ccccc3c3c4c(ccc32)[nH]c2cc3ccccc3cc24)cc1 ; c1ccc(-c2ccc(-n3c4cc5ccccc5cc4c4c5c(ccc43)[nH]c3ccccc35)cc2)cc1 ; c1ccc(-c2ccc3c4c5c(ccc4n(-c4ccccc4)c3c2)[nH]c2cc3ccccc3cc25)cc1]

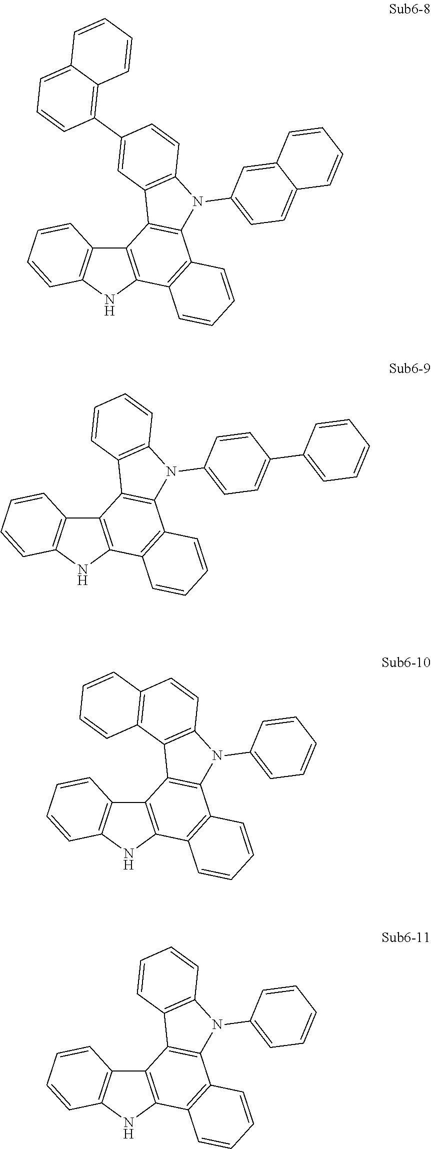 [SMILES: c1ccc2cc(-n3c4ccc(-c5cccc6ccccc56)cc4c4c5c6ccccc6[nH]c5c5ccccc5c43)ccc2c1 ; c1ccc(-c2ccc(-n3c4ccccc4c4c5c6ccccc6[nH]c5c5ccccc5c43)cc2)cc1 ; c1ccc(-n2c3ccc4ccccc4c3c3c4c5ccccc5[nH]c4c4ccccc4c32)cc1 ; c1ccc(-n2c3ccccc3c3c4c5ccccc5[nH]c4c4ccccc4c32)cc1]

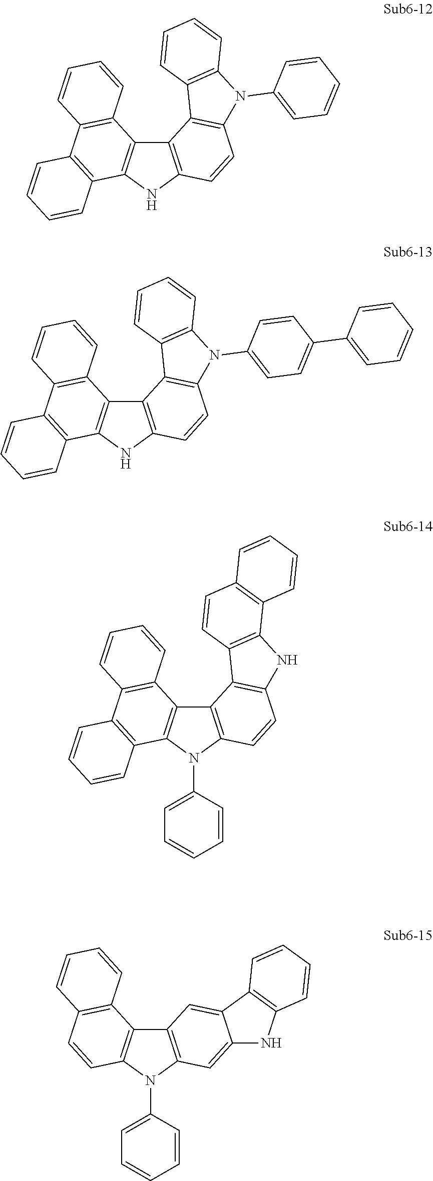 [SMILES: c1ccc(-n2c3ccccc3c3c4c(ccc32)[nH]c2c3ccccc3c3ccccc3c24)cc1 ; c1ccc(-c2ccc(-n3c4ccccc4c4c5c(ccc43)[nH]c3c4ccccc4c4ccccc4c35)cc2)cc1 ; c1ccc(-n2c3ccc4[nH]c5c6ccccc6ccc5c4c3c3c4ccccc4c4ccccc4c32)cc1 ; c1ccc(-n2c3cc4[nH]c5ccccc5c4cc3c3c4ccccc4ccc32)cc1]

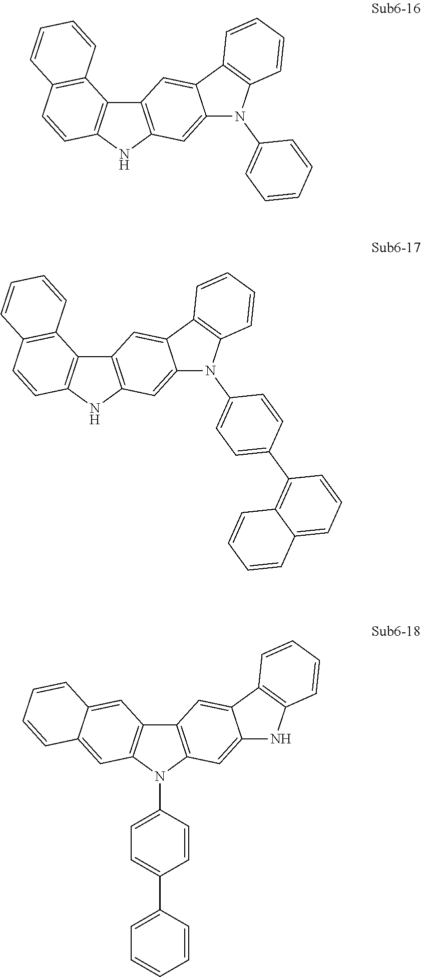 [SMILES: c1ccc(-n2c3ccccc3c3cc4c(cc32)[nH]c2ccc3ccccc3c24)cc1 ; c1ccc2c(-c3ccc(-n4c5ccccc5c5cc6c(cc54)[nH]c4ccc5ccccc5c46)cc3)cccc2c1 ; c1ccc(-c2ccc(-n3c4cc5ccccc5cc4c4cc5c(cc43)[nH]c3ccccc35)cc2)cc1]

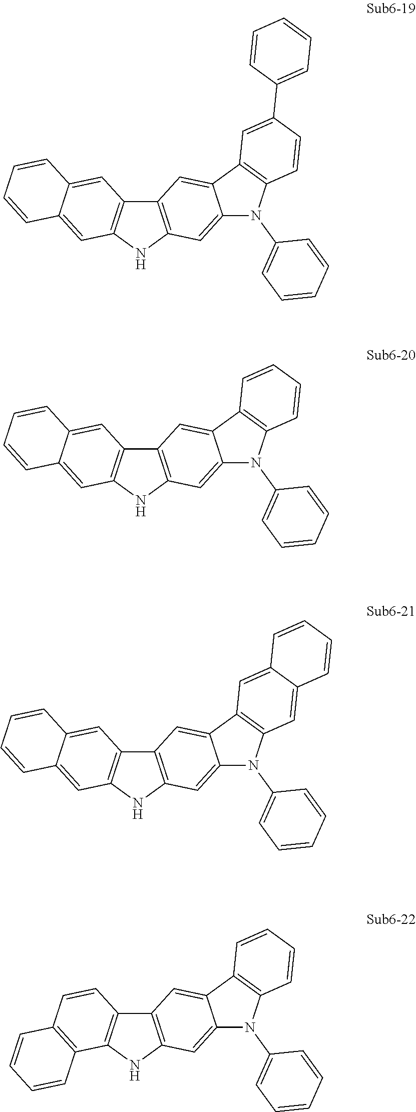 [SMILES: c1ccc(-c2ccc3c(c2)c2cc4c(cc2n3-c2ccccc2)[nH]c2cc3ccccc3cc24)cc1 ; c1ccc(-n2c3ccccc3c3cc4c(cc32)[nH]c2cc3ccccc3cc24)cc1 ; c1ccc(-n2c3cc4ccccc4cc3c3cc4c(cc32)[nH]c2cc3ccccc3cc24)cc1 ; c1ccc(-n2c3ccccc3c3cc4c(cc32)[nH]c2c3ccccc3ccc42)cc1]

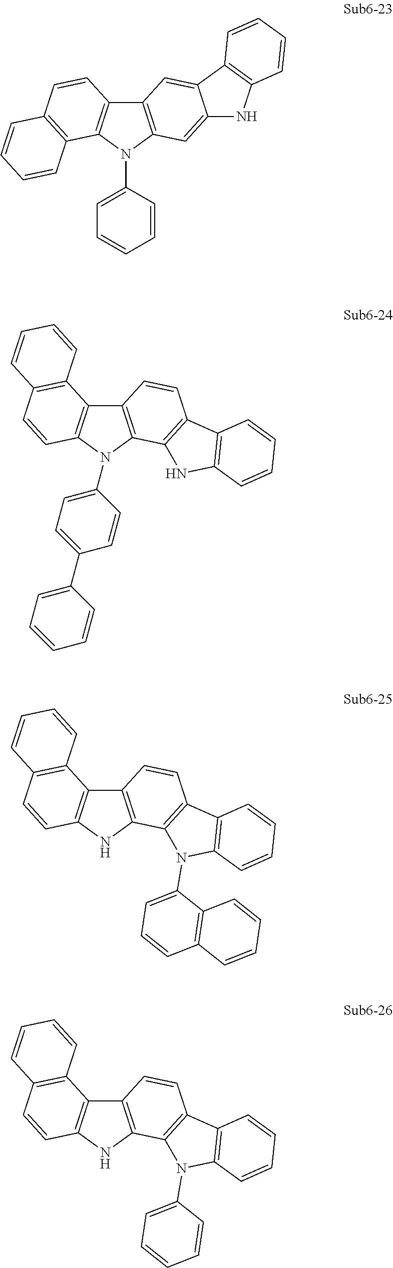 [SMILES: c1ccc(-n2c3cc4[nH]c5ccccc5c4cc3c3ccc4ccccc4c32)cc1 ; c1ccc(-c2ccc(-n3c4ccc5ccccc5c4c4ccc5c6ccccc6[nH]c5c43)cc2)cc1 ; c1ccc2c(-n3c4ccccc4c4ccc5c([nH]c6ccc7ccccc7c65)c43)cccc2c1 ; c1ccc(-n2c3ccccc3c3ccc4c([nH]c5ccc6ccccc6c54)c32)cc1]

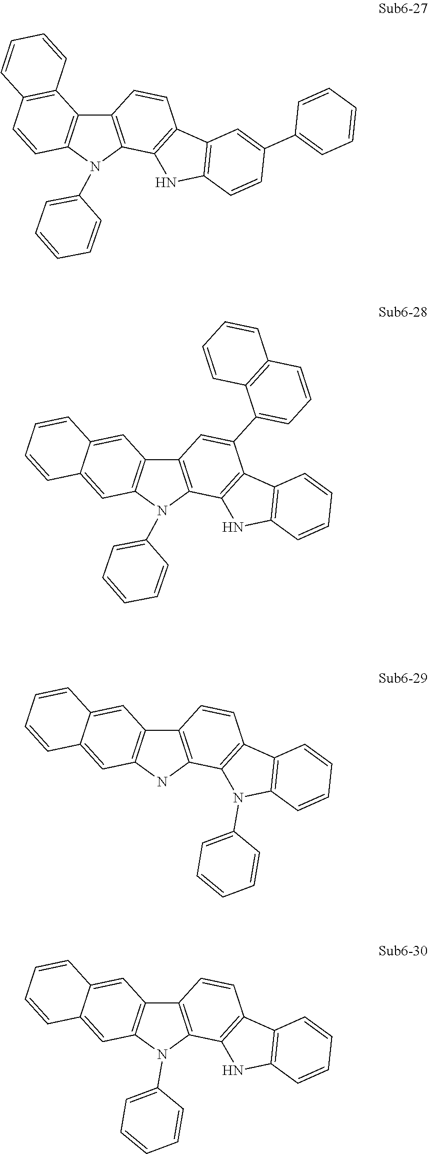 [SMILES: c1ccc(-c2ccc3[nH]c4c(ccc5c6c7ccccc7ccc6n(-c6ccccc6)c54)c3c2)cc1 ; c1ccc(-n2c3cc4ccccc4cc3c3cc(-c4cccc5ccccc45)c4c5ccccc5[nH]c4c32)cc1 ; c1ccc(-n2c3ccccc3c3ccc4c5cc6ccccc6cc5[nH]c4c32)cc1 ; c1ccc(-n2c3cc4ccccc4cc3c3ccc4c5ccccc5[nH]c4c32)cc1]

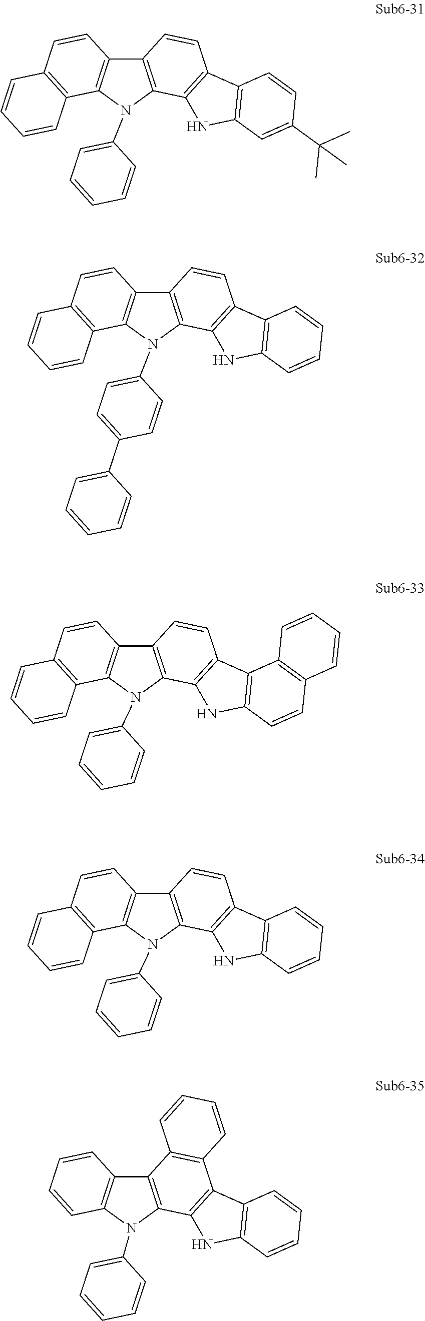 [SMILES: CC(C)(C)c1ccc2c(c1)[nH]c1c2ccc2c3ccc4ccccc4c3n(-c3ccccc3)c21 ; c1ccc(-c2ccc(-n3c4c5ccccc5ccc4c4ccc5c6ccccc6[nH]c5c43)cc2)cc1 ; c1ccc(-n2c3c4ccccc4ccc3c3ccc4c([nH]c5ccc6ccccc6c54)c32)cc1 ; c1ccc(-n2c3c4ccccc4ccc3c3ccc4c5ccccc5[nH]c4c32)cc1 ; c1ccc(-n2c3ccccc3c3c4ccccc4c4c5ccccc5[nH]c4c32)cc1]

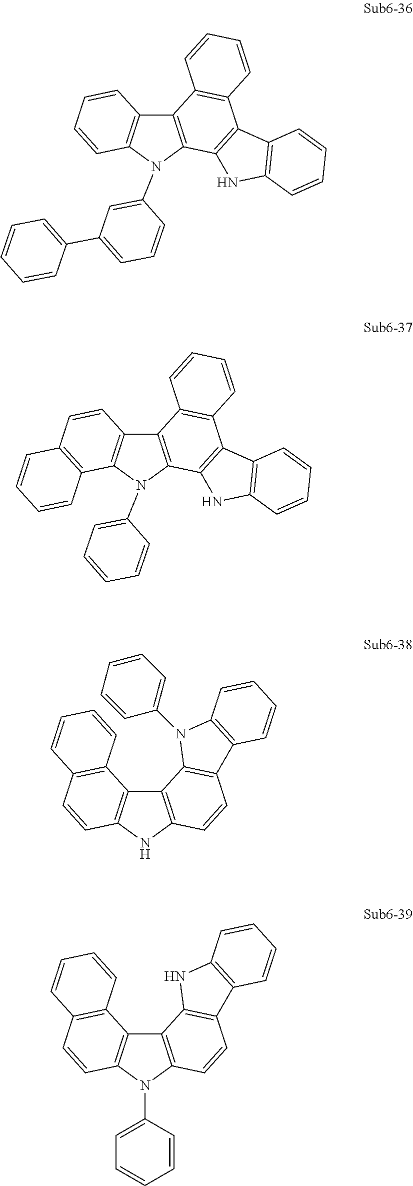 [SMILES: c1ccc(-c2cccc(-n3c4ccccc4c4c5ccccc5c5c6ccccc6[nH]c5c43)c2)cc1 ; c1ccc(-n2c3c4ccccc4ccc3c3c4ccccc4c4c5ccccc5[nH]c4c32)cc1 ; c1ccc(-n2c3ccccc3c3ccc4[nH]c5ccc6ccccc6c5c4c32)cc1 ; c1ccc(-n2c3ccc4ccccc4c3c3c4[nH]c5ccccc5c4ccc32)cc1]

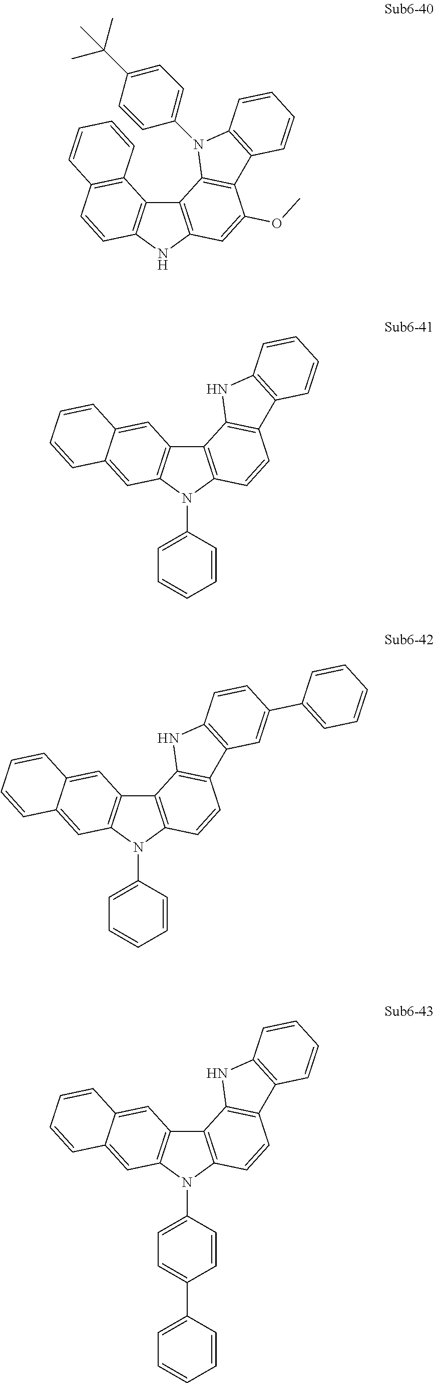 [SMILES: COc1cc2[nH]c3ccc4ccccc4c3c2c2c1c1ccccc1n2-c1ccc(C(C)(C)C)cc1 ; c1ccc(-n2c3cc4ccccc4cc3c3c4[nH]c5ccccc5c4ccc32)cc1 ; c1ccc(-c2ccc3[nH]c4c(ccc5c4c4cc6ccccc6cc4n5-c4ccccc4)c3c2)cc1 ; c1ccc(-c2ccc(-n3c4cc5ccccc5cc4c4c5[nH]c6ccccc6c5ccc43)cc2)cc1]

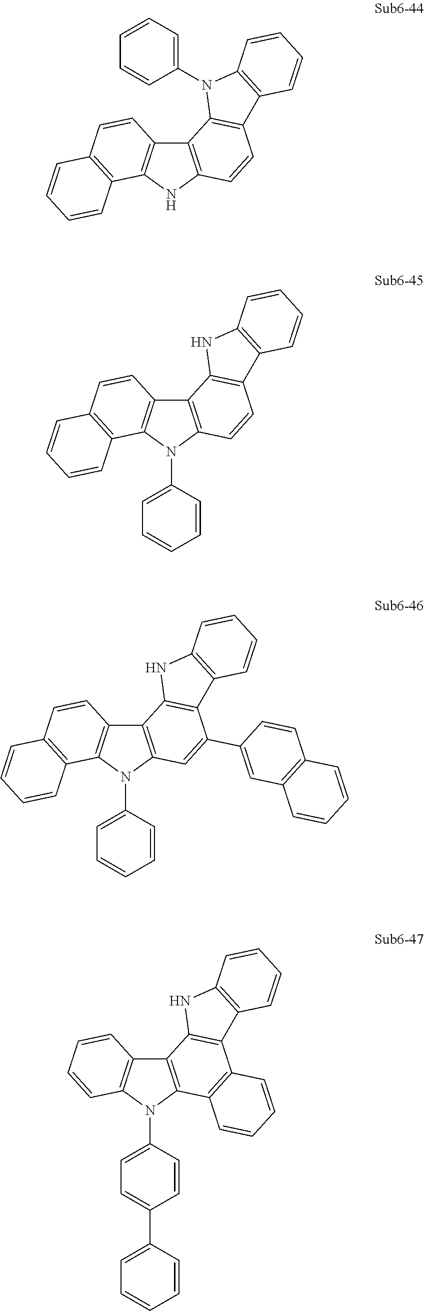 [SMILES: c1ccc(-n2c3ccccc3c3ccc4[nH]c5c6ccccc6ccc5c4c32)cc1 ; c1ccc(-n2c3ccc4c5ccccc5[nH]c4c3c3ccc4ccccc4c32)cc1 ; c1ccc(-n2c3cc(-c4ccc5ccccc5c4)c4c5ccccc5[nH]c4c3c3ccc4ccccc4c32)cc1 ; c1ccc(-c2ccc(-n3c4ccccc4c4c5[nH]c6ccccc6c5c5ccccc5c43)cc2)cc1]

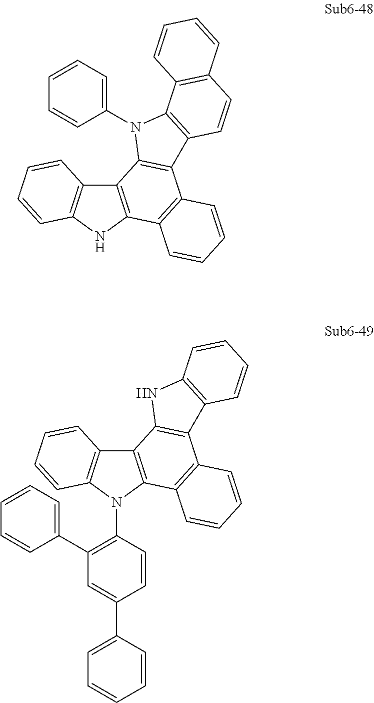 [SMILES: c1ccc(-n2c3c4ccccc4ccc3c3c4ccccc4c4[nH]c5ccccc5c4c32)cc1 ; c1ccc(-c2ccc(-n3c4ccccc4c4c5[nH]c6ccccc6c5c5ccccc5c43)c(-c3ccccc3)c2)cc1]

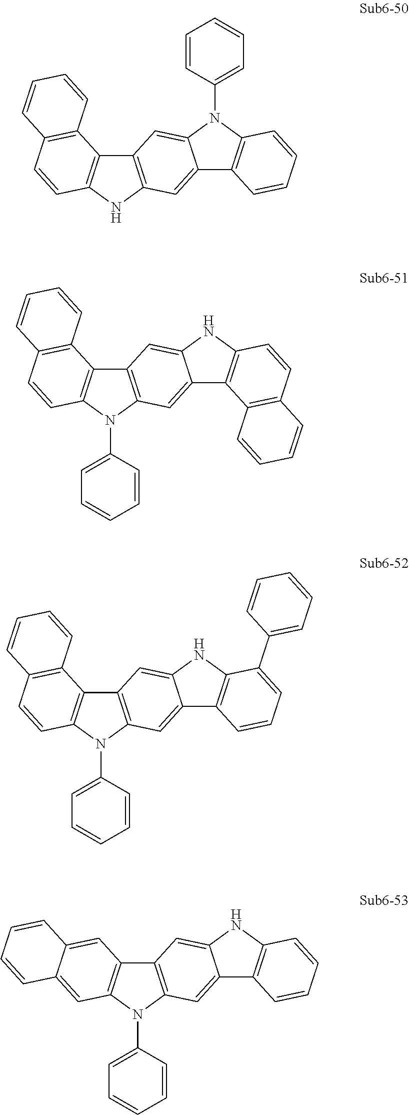 [SMILES: c1ccc(-n2c3ccccc3c3cc4[nH]c5ccc6ccccc6c5c4cc32)cc1 ; c1ccc(-n2c3cc4c(cc3c3c5ccccc5ccc32)[nH]c2ccc3ccccc3c24)cc1 ; c1ccc(-c2cccc3c2[nH]c2cc4c5c6ccccc6ccc5n(-c5ccccc5)c4cc23)cc1 ; c1ccc(-n2c3cc4ccccc4cc3c3cc4[nH]c5ccccc5c4cc32)cc1]

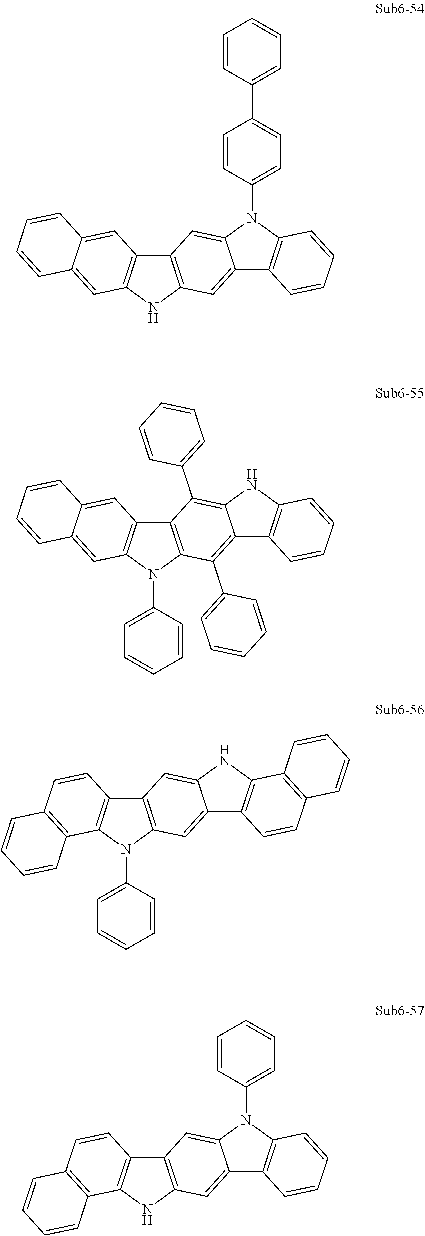 [SMILES: c1ccc(-c2ccc(-n3c4ccccc4c4cc5[nH]c6cc7ccccc7cc6c5cc43)cc2)cc1 ; c1ccc(-c2c3[nH]c4ccccc4c3c(-c3ccccc3)c3c2c2cc4ccccc4cc2n3-c2ccccc2)cc1 ; c1ccc(-n2c3cc4c(cc3c3ccc5ccccc5c32)[nH]c2c3ccccc3ccc42)cc1 ; c1ccc(-n2c3ccccc3c3cc4[nH]c5c6ccccc6ccc5c4cc32)cc1]

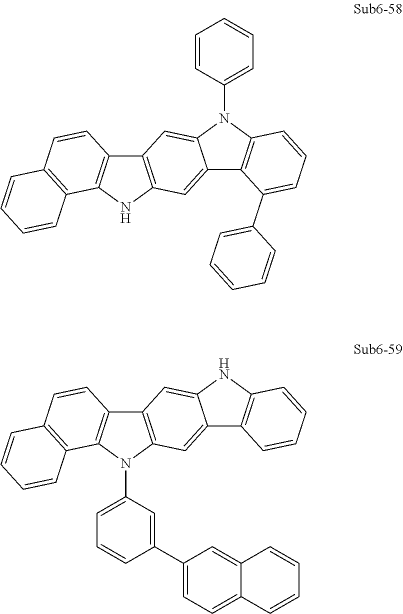 [SMILES: c1ccc(-c2cccc3c2c2cc4[nH]c5c6ccccc6ccc5c4cc2n3-c2ccccc2)cc1 ; c1cc(-c2ccc3ccccc3c2)cc(-n2c3cc4c(cc3c3ccc5ccccc5c32)[nH]c2ccccc24)c1]

TABLE 9

| Compound | FD-MS | Compound | FD-MS |
|---|---|---|---|
| Sub6-1 | m/z = 458.18(C₃₄H₂₂N₂ = 458.56) | Sub6-2 | m/z = 508.19(C₃₈H₂₄N₂ = 508.62) |
| Sub6-3 | m/z = 382.15(C₂₈H₁₈N₂ = 382.47) | Sub6-4 | m/z = 432.16(C₃₂H₂₀N₂ = 432.53) |
| Sub6-5 | m/z = 382.15(C₂₈H₁₈N₂ = 382.47) | Sub6-6 | m/z = 458.18(C₃₄H₂₂N₂ = 458.56) |
| Sub6-7 | m/z = 458.18(C₃₄H₂₂N₂ = 458.56) | Sub6-8 | m/z = 558.21(C₄₂H₂₆N₂ = 558.68) |
| Sub6-9 | m/z = 458.18(C₃₄H₂₂N₂ = 458.56) | Sub6-10 | m/z = 432.16(C₃₂H₂₀N₂ = 432.53) |
| Sub6-11 | m/z = 382.15(C₂₈H₁₈N₂ = 382.47) | Sub6-12 | m/z = 432.16(C₃₂H₂₀N₂ = 432.53) |
| Sub6-13 | m/z = 508.19(C₃₈H₂₄N₂ = 508.62) | Sub6-14 | m/z = 482.18(C₃₆H₂₂N₂ = 482.59) |
| Sub6-15 | m/z = 382.15(C₂₈H₁₈N₂ = 382.47) | Sub6-16 | m/z = 382.15(C₂₈H₁₈N₂ = 382.47) |
| Sub6-17 | m/z = 508.19(C₃₈H₂₄N₂ = 508.62) | Sub6-18 | m/z = 458.18(C₃₄H₂₂N₂ = 458.56) |
| Sub6-19 | m/z = 458.18(C₃₄H₂₂N₂ = 458.56) | Sub6-20 | m/z = 382.15(C₂₈H₁₈N₂ = 382.47) |
| Sub6-21 | m/z = 432.16(C₃₂H₂₀N₂ = 432.53) | Sub6-22 | m/z = 382.15(C₂₈H₁₈N₂ = 382.47) |
| Sub6-23 | m/z = 382.15(C₂₈H₁₈N₂ = 382.47) | Sub6-24 | m/z = 458.18(C₃₄H₂₂N₂ = 458.56) |
| Sub6-25 | m/z = 432.16(C₃₂H₂₀N₂ = 432.53) | Sub6-26 | m/z = 382.15(C₂₈H₁₈N₂ = 382.47) |
| Sub6-27 | m/z = 458.18(C₃₄H₂₂N₂ = 458.56) | Sub6-28 | m/z = 508.19(C₃₈H₂₄N₂ = 508.62) |
| Sub6-29 | m/z = 382.15(C₂₈H₁₈N₂ = 382.47) | Sub6-30 | m/z = 382.15(C₂₈H₁₈N₂ = 382.47) |
| Sub6-31 | m/z = 438.21(C₃₂H₂₆N₂ = 438.57) | Sub6-32 | m/z = 458.18(C₃₄H₂₂N₂ = 458.56) |
| Sub6-33 | m/z = 432.16(C₃₂H₂₀N₂ = 432.53) | Sub6-34 | m/z = 382.15(C₂₈H₁₈N₂ = 382.47) |
| Sub6-35 | m/z = 382.15(C₂₈H₁₈N₂ = 382.47) | Sub6-36 | m/z = 458.18(C₃₄H₂₂N₂ = 458.56) |
| Sub6-37 | m/z = 432.16(C₃₂H₂₀N₂ = 432.53) | Sub6-38 | m/z = 382.15(C₂₈H₁₈N₂ = 382.47) |
| Sub6-39 | m/z = 382.15(C₂₈H₁₈N₂ = 382.47) | Sub6-40 | m/z = 468.22(C₃₃H₂₈N₂O = 468.6) |
| Sub6-41 | m/z = 382.15(C₂₈H₁₈N₂ = 382.47) | Sub6-42 | m/z = 458.18(C₃₄H₂₂N₂ = 458.56) |
| Sub6-43 | m/z = 458.18(C₃₄H₂₂N₂ = 458.56) | Sub6-44 | m/z = 382.15(C₂₈H₁₈N₂ = 382.47) |
| Sub6-45 | m/z = 382.15(C₂₈H₁₈N₂ = 382.47) | Sub6-46 | m/z = 508.19(C₃₈H₂₄N₂ = 508.62) |
| Sub6-47 | m/z = 458.18(C₃₄H₂₂N₂ = 458.56) | Sub6-48 | m/z = 432.16(C₃₂H₂₀N₂ = 432.53) |
| Sub6-49 | m/z = 534.21(C₄₀H₂₆N₂ = 534.66) | Sub6-50 | m/z = 382.15(C₂₈H₁₈N₂ = 382.47) |
| Sub6-51 | m/z = 432.16(C₃₂H₂₀N₂ = 432.53) | Sub6-52 | m/z = 458.18(C₃₄H₂₂N₂ = 458.56) |
| Sub6-53 | m/z = 382.15(C₂₈H₁₈N₂ = 382.47) | Sub6-54 | m/z = 458.18(C₃₄H₂₂N₂ = 458.56) |
| Sub6-55 | m/z = 534.21(C₄₀H₂₆N₂ = 534.66) | Sub6-56 | m/z = 432.16(C₃₂H₂₀N₂ = 432.53) |
| Sub6-57 | m/z = 382.15(C₂₈H₁₈N₂ = 382.47) | Sub6-58 | m/z = 458.18(C₃₄H₂₂N₂ = 458.56) |
| Sub6-59 | m/z = 508.19(C₃₈H₂₄N₂ = 508.62) | | |

### Synthesis Example of Final Compound

### 1. Synthesis Example of P-10

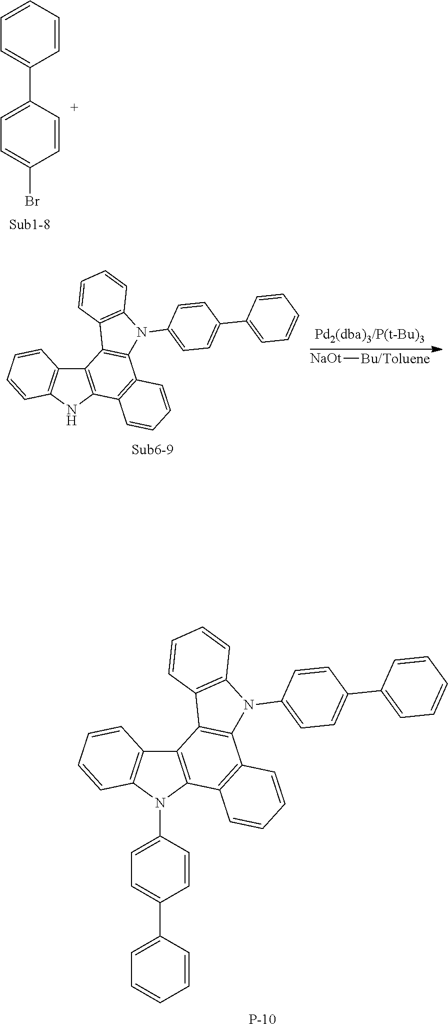

After dissolving Sub6-9 (10.0 g, 21.8 mmol) in toluene (109 mL), Sub1-8 (5.1 g, 21.8 mmol), Pd₂(dba)₃ (0.60 g, 0.65 mmol), P(t-Bu)₃ (0.26 g, 1.31 mmol), NaOt-Bu (4.2 g, 43.6 mmol) are added thereto and the reaction is carried out at 80° C. When the reaction is completed, the reaction product is extracted with CH₂Cl₂ and water, and then the organic layer is dried with MgSO₄ and concentrated. Then, the concentrate is separated through a silica gel column and recrystallized to obtain 10.3 g (yield: 77%) of the product.

### 2. Synthesis Example of P-20

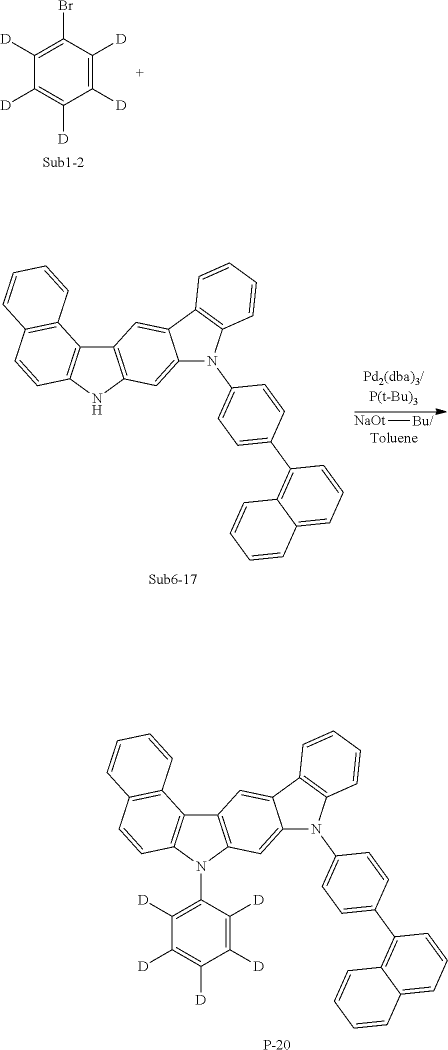

After dissolving Sub6-17 (10.0 g, 19.7 mmol) in toluene (98 mL), Sub1-2 (3.2 g, 19.7 mmol), Pd₂(dba)₃ (0.54 g, 0.59 mmol), P(t-Bu)₃ (0.24 g, 1.18 mmol), NaOt-Bu (3.8 g, 39.3 mmol) are added thereto, and the synthesis is carried out in the same manner as the synthesis of P-10 to obtain 9.4 g (yield: 81%) of product.

### 3. Synthesis Example of P-61

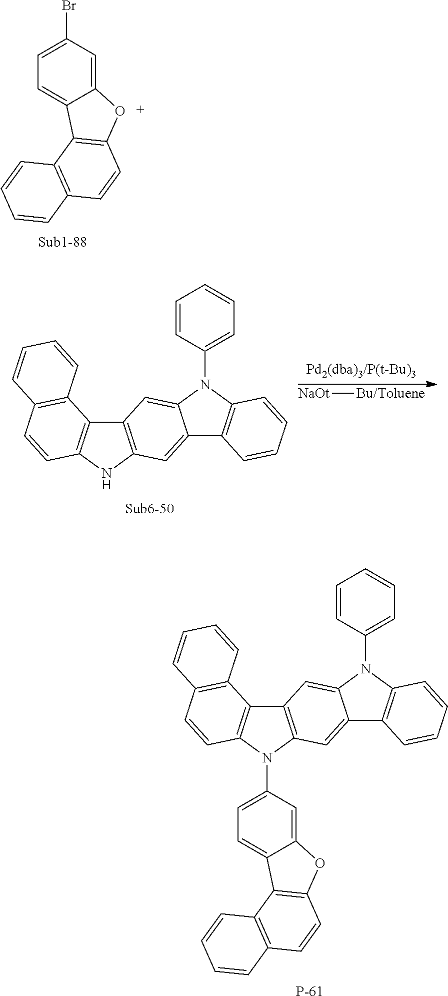

After dissolving Sub6-50 (10.0 g, 26.1 mmol) in toluene (131 mL), Sub1-88 (7.8 g, 26.1 mmol), Pd₂(dba)₃ (0.72 g, 0.78 mmol), P(t-Bu)₃ (0.32 g, 1.57 mmol), NaOt-Bu (5.0 g, 52.3 mmol) are added thereto, and the synthesis is carried out in the same manner as the synthesis of P-10 to obtain 11.9 g (yield: 76%) of product.

The FD-MS values of the compounds P-1 to P-72 of the present invention prepared according to the above synthesis examples are shown in Table 10 below.

TABLE 10

| Compound | FD-MS | Compound | FD-MS |
|---|---|---|---|
| P-1 | m/z = 610.24(C₄₆H₃₀N₂ = 610.76) | P-2 | m/z = 589.26(C₄₄H₂₃D₅N₂ = 589.75) |
| P-3 | m/z = 586.22(C₄₂H₂₆N₄ = 586.7) | P-4 | m/z = 584.23(C₄₄H₂₈N₂ = 584.72) |
| P-5 | m/z = 584.23(C₄₄H₂₈N₂ = 584.72) | P-6 | m/z = 614.18(C₄₄H₂₆N₂S = 614.77) |
| P-7 | m/z = 610.24(C₄₆H₃₀N₂ = 610.76) | P-8 | m/z = 610.24(C₄₆H₃₀N₂ = 610.76) |
| P-9 | m/z = 684.26(C₅₂H₃₂N₂ = 684.84) | P-10 | m/z = 610.24(C₄₆H₃₀N₂ = 610.76) |
| P-11 | m/z = 558.21(C₄₂H₂₆N₂ = 558.68) | P-12 | m/z = 584.23(C₄₄H₂₈N₂ = 584.72) |
| P-13 | m/z = 674.24(C₅₀H₃₀N₂O = 674.8) | P-14 | m/z = 660.26(C₅₀H₃₂N₂ = 660.82) |
| P-15 | m/z = 608.23(C₄₆H₂₈N₂ = 608.74) | P-16 | m/z = 634.24(C₄₈H₃₀N₂ = 634.78) |
| P-17 | m/z = 584.23(C₄₄H₂₈N₂ = 584.72) | P-18 | m/z = 587.24(C₄₄H₂₅D₃N₂ = 587.74) |
| P-19 | m/z = 598.2(C₄₄H₂₆N₂O = 598.71) | P-20 | m/z = 589.26(C₄₄H₂₃D₅N₂ = 589.75) |
| P-21 | m/z = 610.24(C₄₆H₃₀N₂ = 610.76) | P-22 | m/z = 584.23(C₄₄H₂₈N₂ = 584.72) |
| P-23 | m/z = 613.23(C₄₃H₂₇N₅ = 613.72) | P-24 | m/z = 584.23(C₄₄H₂₈N₂ = 584.72) |
| P-25 | m/z = 584.23(C₄₄H₂₈N₂ = 584.72) | P-26 | m/z = 584.23(C₄₄H2₈N₂ = 584.72) |
| P-27 | m/z = 574.24(C₄₃H₃₀N₂ = 574.73) | P-28 | m/z = 552.26(C₄₁H₃₂N₂ = 552.72) |
| P-29 | m/z = 610.24(C₄₆H₃₀N₂ = 610.76) | P-30 | m/z = 584.23(C₄₄H₂₈N₂ = 584.72) |
| P-31 | m/z = 558.21(C₄₂H₂₆N₂ = 558.68) | P-32 | m/z = 584.23(C₄₄H₂₈N₂ = 584.72) |
| P-33 | m/z = 584.23(C₄₄H₂₈N₂ = 584.72) | P-34 | m/z = 508.19(C₃₈H₂₄N₂ = 508.62) |
| P-35 | m/z = 623.24(C₄₆H₂₉N₃ = 623.76) | P-36 | m/z = 534.21(C₄₀H₂₆N₂ = 534.66) |
| P-37 | m/z = 590.27(C₄₄H₃₄N₂ = 590.77) | P-38 | m/z = 610.24(C₄₆H₃₀N₂ = 610.76) |
| P-39 | m/z = 508.19(C₃₈H₂₄N₂ = 508.62) | P-40 | m/z = 584.23(C₄₄H₂₈N₂ = 584.72) |
| P-41 | m/z = 613.23(C₄₃H₂₇N₅ = 613.72) | P-42 | m/z = 539.24(C₄₀H₂₁D₅N₂ = 539.69) |
| P-43 | m/z = 610.24(C₄₈H₃₀N₂ = 610.76) | P-44 | m/z = 558.21(C₄₂H₂₆N₂ = 558.68) |
| P-45 | m/z = 534.21(C₄₀H₂₆N₂ = 534.66) | P-46 | m/z = 584.23(C₄₄H₂₈N₂ = 584.72) |
| P-47 | m/z = 463.21(C₃₄H₁₇D₅N₂ = 463.59) | P-48 | m/z = 600.31(C₄₃H₄₀N₂O = 600.81) |
| P-49 | m/z = 614.18(C₄₄H₂₆N₂S = 614.77) | P-50 | m/z = 584.23(C₄₄H₂₈N₂ = 584.72) |
| P-51 | m/z = 552.2(C₄₀H₂₅FN₂ = 552.65) | P-52 | m/z = 610.24(C₄₆H₃₀N₂ = 610.76) |
| P-53 | m/z = 558.21(C₄₂H₂₆N₂ = 558.68) | P-54 | m/z = 610.24(C₄₆H₃₀N₂ = 610.76) |
| P-55 | m/z = 660.26(C₅₀H₃₂N₂ = 660.82) | P-56 | m/z = 584.23(C₄₄H₂₈N₂ = 584.72) |
| P-57 | m/z = 610.24(C₄₆H₃₀N₂ = 610.76) | P-58 | m/z = 558.21(C₄₂H₂₆N₂ = 558.68) |
| P-59 | m/z = 702.27(C₅₂H₃₄N₂O = 702.86) | P-60 | m/z = 634.24(C₄₈H₃₀N₂ = 634.78) |
| P-61 | m/z = 598.2(C₄₄H₂₆N₂O = 598.71) | P-62 | m/z = 608.23(C₄₆H₂₈N₂ = 608.74) |
| P-63 | m/z = 610.24(C₄₆H₃₀N₂ = 610.76) | P-64 | m/z = 610.24(C₄₆H₃₀N₂ = 610.76) |
| P-65 | m/z = 586.22(C₄₂H₂₆N₄ = 586.7) | P-66 | m/z = 610.24(C₄₆H₃₀N₂ = 610.76) |
| P-67 | m/z = 610.24(C₄₆H₃₀N₂ = 610.76) | P-68 | m/z = 634.24(C₄₈H₃₀N₂ = 634.78) |
| P-69 | m/z = 634.24(C₄₈H₃₀N₂ = 634.78) | P-70 | m/z = 584.23(C₄₄H₂₈N₂ = 584.72) |
| P-71 | m/z = 584.23(C₄₄H₂₈N₂ = 584.72) | P-72 | m/z = 589.26(C₄₄H₂₃D₅N₂ = 589.75) |

### [Synthesis Example 5] Synthesis Example of Formula 6

The compound represented by Formula 6 (final product 6) according to the present invention can be synthesized as shown in Reaction Scheme 6 below, but is not limited thereto.

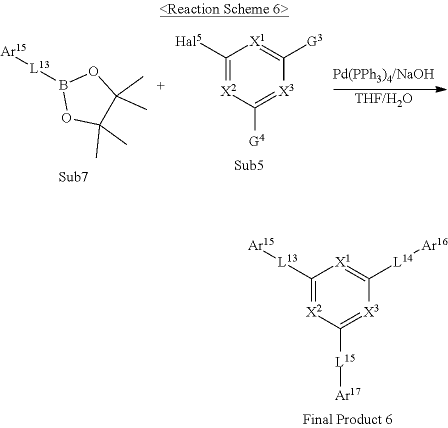

### Exemplary Compounds of Sub7

Compounds belonging to Sub7 may be, but not limited to, the following compounds, and Table 11 shows FD-MS values of the following compounds.

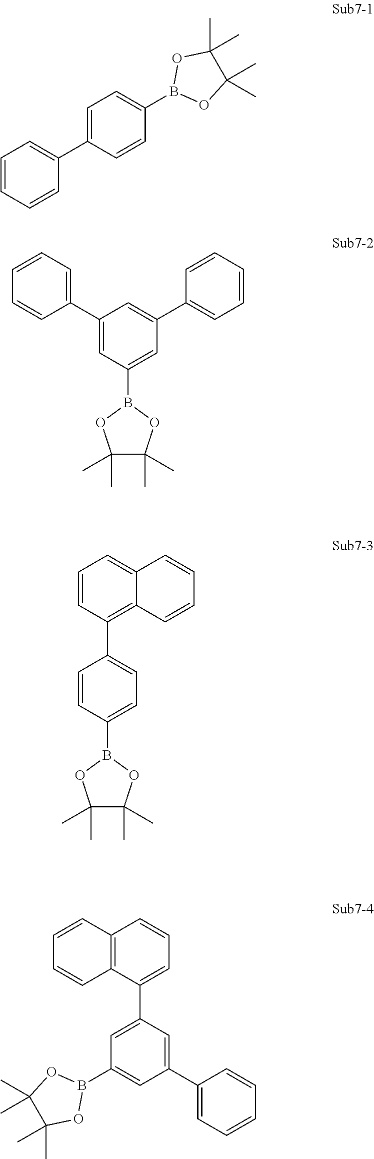

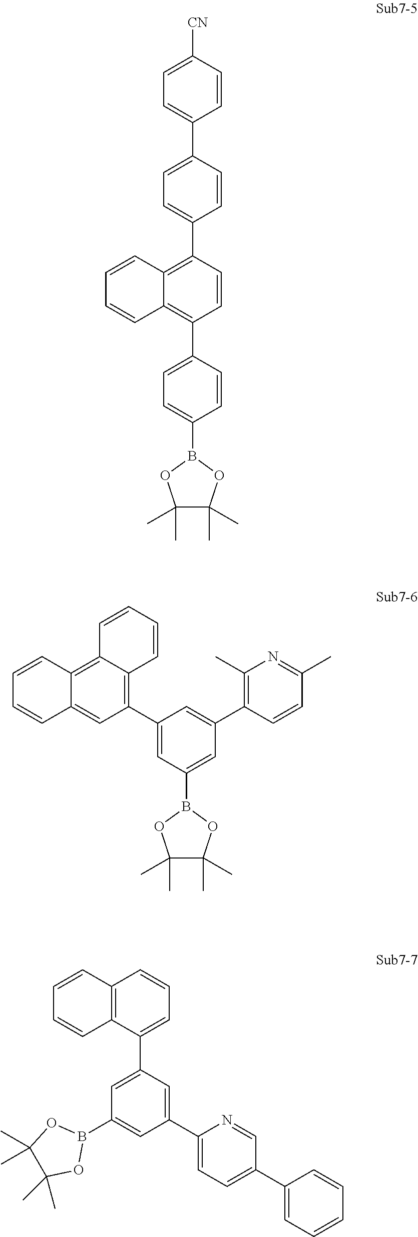

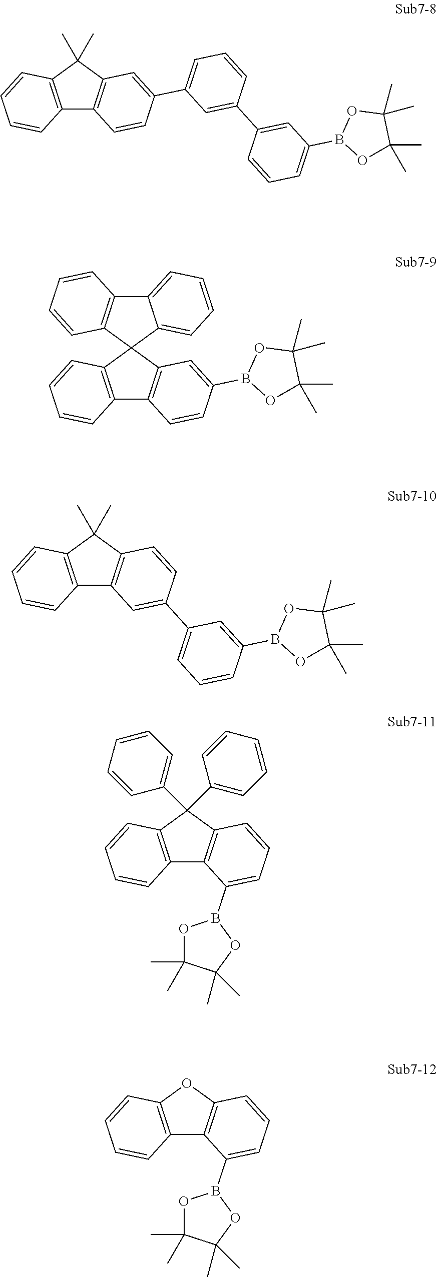 [SMILES: CC1(C)c2ccccc2-c2ccc(-c3cccc(-c4cccc(B5OC(C)(C)C(C)(C)O5)c4)c3)cc21 ; CC1(C)OB(c2ccc3c(c2)C2(c4ccccc4-c4ccccc42)c2ccccc2-3)OC1(C)C ; CC1(C)c2ccccc2-c2cc(-c3cccc(B4OC(C)(C)C(C)(C)O4)c3)ccc21 ; CC1(C)OB(c2cccc3c2-c2ccccc2C3(c2ccccc2)c2ccccc2)OC1(C)C ; CC1(C)OB(c2cccc3oc4ccccc4c23)OC1(C)C]

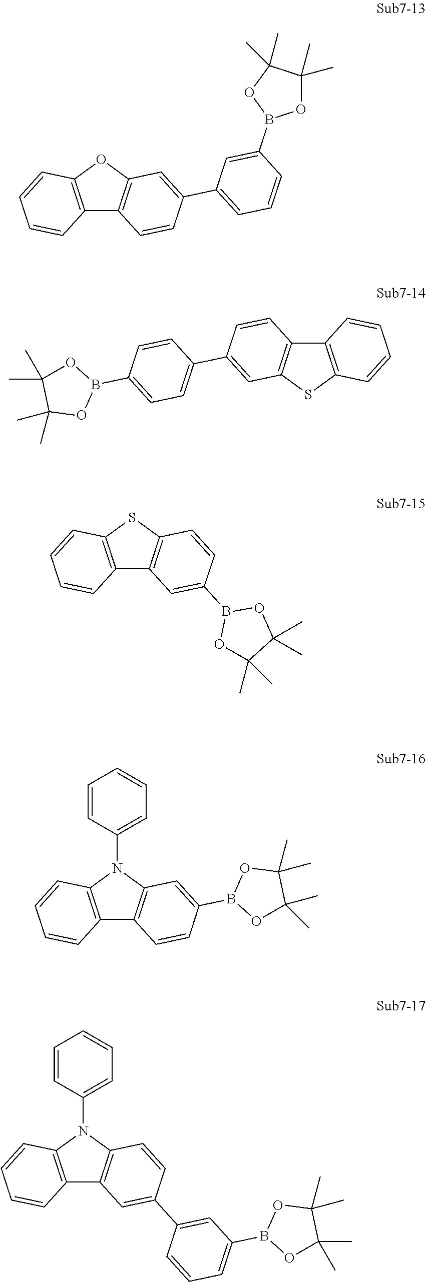

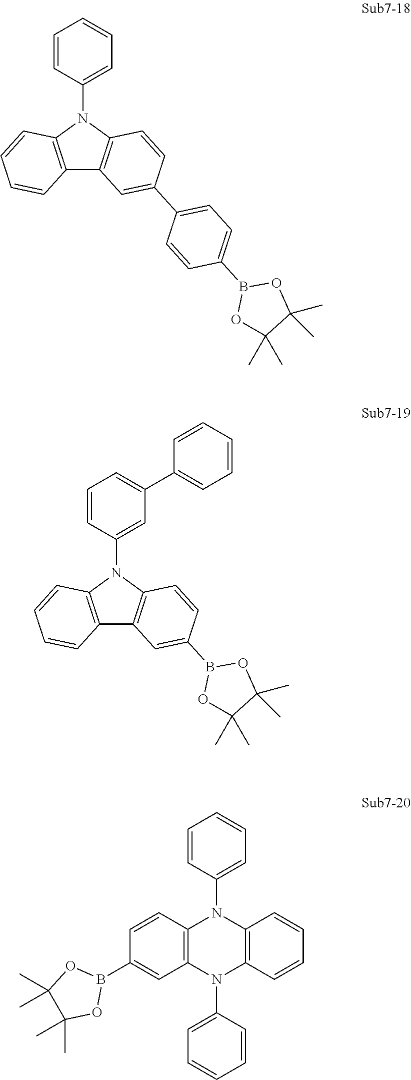

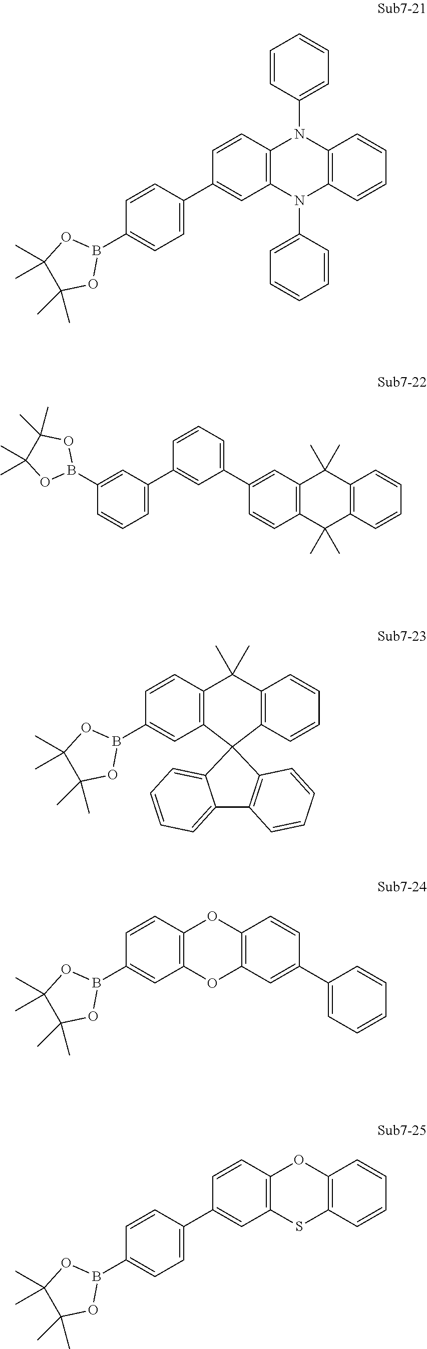 [SMILES: CC1(C)OB(c2ccc(-c3ccc4c(c3)N(c3ccccc3)c3ccccc3N4c3ccccc3)cc2)OC1(C)C ; CC1(C)c2ccccc2C(C)(C)c2cc(-c3cccc(-c4cccc(B5OC(C)(C)C(C)(C)O5)c4)c3)ccc21 ; CC1(C)c2ccccc2C2(c3ccccc3-c3ccccc32)c2cc(B3OC(C)(C)C(C)(C)O3)ccc21 ; CC1(C)OB(c2ccc3c(c2)Oc2cc(-c4ccccc4)ccc2O3)OC1(C)C ; CC1(C)OB(c2ccc(-c3ccc4c(c3)Sc3ccccc3O4)cc2)OC1(C)C]

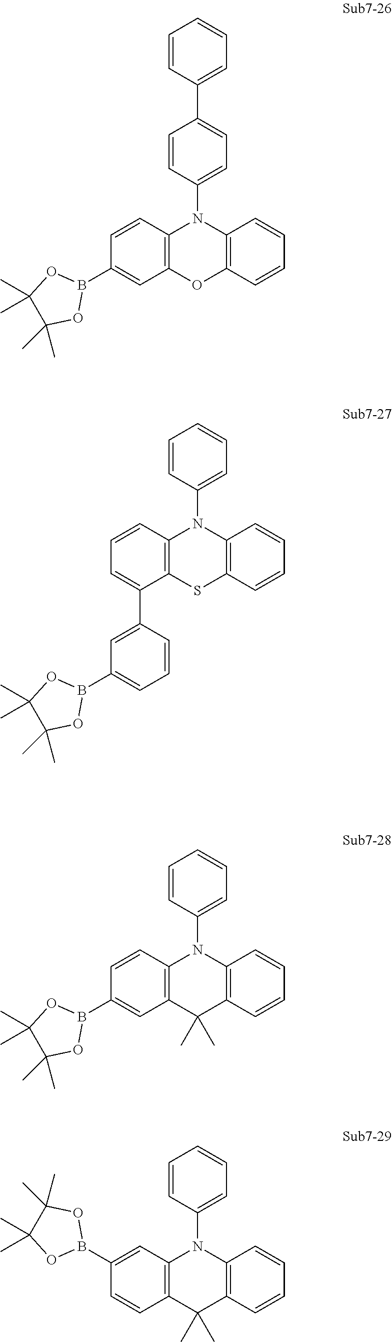 [SMILES: CC1(C)OB(c2ccc3c(c2)Oc2ccccc2N3c2ccc(-c3ccccc3)cc2)OC1(C)C ; CC1(C)OB(c2cccc(-c3cccc4c3Sc3ccccc3N4c3ccccc3)c2)OC1(C)C ; CC1(C)c2ccccc2N(c2ccccc2)c2ccc(B3OC(C)(C)C(C)(C)O3)cc21 ; CC1(C)c2ccccc2N(c2ccccc2)c2cc(B3OC(C)(C)C(C)(C)O3)ccc21]

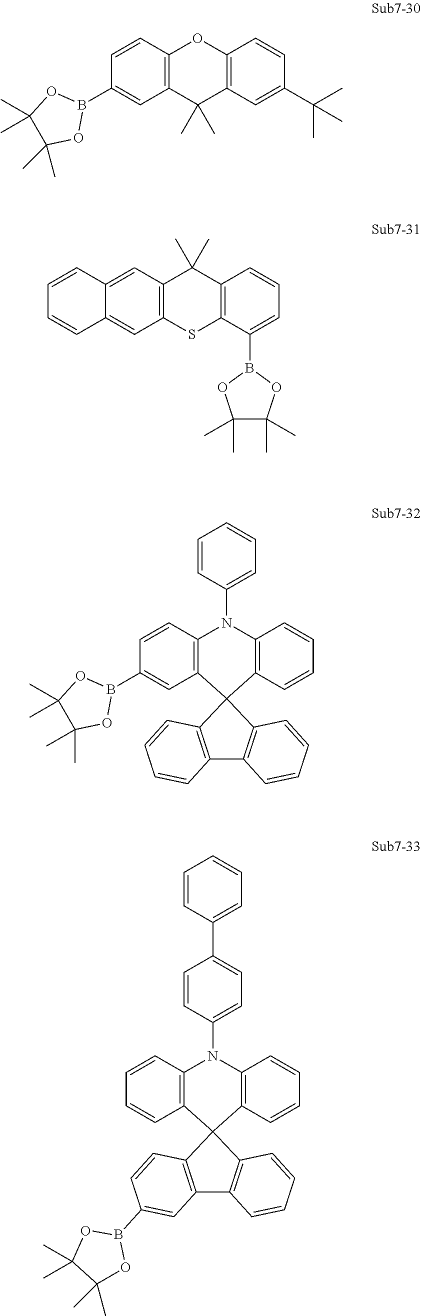

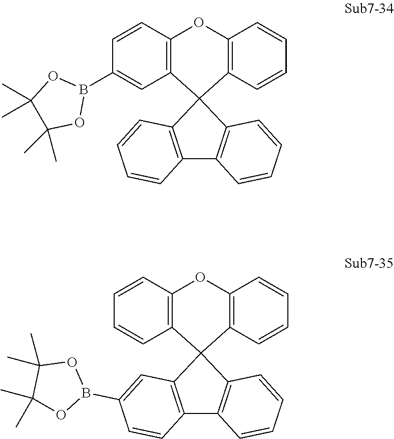 [SMILES: CC1(C)OB(c2ccc3c(c2)C2(c4ccccc4O3)c3ccccc3-c3ccccc32)OC1(C)C ; CC1(C)OB(c2ccc3c(c2)C2(c4ccccc4Oc4ccccc42)c2ccccc2-3)OC1(C)C]

TABLE 11

| Compound | FD-MS | Compound | FD-MS |
|---|---|---|---|
| Sub7-1 | m/z = 280.16(C₁₈H₂₁BO₂ = 280.17) | Sub7-2 | m/z = 356.19(C₂₄H₂₅BO₂ = 356.27) |
| Sub7-3 | m/z = 330.18(C₂₂H₂₃BO₂ = 330.23) | Sub7-4 | m/z = 406.21(C₂₈H₂₇BO₂ = 406.33) |
| Sub7-5 | m/z = 507.24(C₃₅H₃₀BNO₂ = 507.44) | Sub7-6 | m/z = 485.25(C₃₃H₃₂BNO₂ = 485.43) |
| Sub7-7 | m/z = 483.24(C₃₃H₃₀BNO₂ = 483.42) | Sub7-8 | m/z = 472.26(C₃₃H₃₃BO₂ = 472.44) |
| Sub7-9 | m/z = 442.21(C₃₁H₂₇BO₂ = 442.37) | Sub7-10 | m/z = 396.23(C₂₇H₂₉BO₂ = 396.34) |
| Sub7-11 | m/z = 444.23(C₃₁H₂₉BO₂ = 444.38) | Sub7-12 | m/z = 294.14(C₁₈H₁₉BO₃ = 294.16) |
| Sub7-13 | m/z = 370.17(C₂₄H₂₃BO₃ = 370.26) | Sub7-14 | m/z = 386.15(C₂₄H₂₃BO₂S = 386.32) |
| Sub7-15 | m/z = 310.12(C₁₈H₁₉BO₂S = 310.22) | Sub7-16 | m/z = 369.19(C₂₄H₂₄BNO₂ = 369.27) |
| Sub7-17 | m/z = 445.22(C₃₀H₂₈BNO₂ = 445.37) | Sub7-18 | m/z = 445.22(C₈₀H₂₈BNO₂ = 445.37) |
| Sub7-19 | m/z = 445.22(C₃₀H₂₈BNO₂ = 445.37) | Sub7-20 | m/z = 460.23(C₃₀H₂₉BN₂O₂ = 460.38) |
| Sub7-21 | m/z = 536.26(C₃₆H₃₃BN₂O₂ = 536.48) | Sub7-22 | m/z = 514.3(C₃₆H₃₉BO₂ = 514.52) |
| Sub7-23 | m/z = 484.26(C₃₄H₃₃BO₂ = 484.45) | Sub7-24 | m/z = 386.17(C₂₄H₂₃BO₄ = 386.25) |
| Sub7-25 | m/z = 402.15(C₂₄H₂₃BO₃S = 402.32) | Sub7-26 | m/z = 461.22(C₃₀H₂₈BNO₃ = 461.37) |
| Sub7-27 | m/z = 477.19(C₃₀H₂₆BNO₂S = 477.43) | Sub7-28 | m/z = 411.24(C₂₇H₃₀BNO₂ = 411.35) |
| Sub7-29 | m/z = 411.24(C₂₇H₃₀BNO₂ = 411.35) | Sub7-30 | m/z = 392.25(C₂₅H₃₃BO₃ = 392.35) |
| Sub7-31 | m/z = 402.18(C₂₅H₂₇BO₂S = 402.36) | Sub7-32 | m/z = 533.25(C₃₇H₃₂BNO₂ = 533.48) |
| Sub7-33 | m/z = 609.28(C₄₃H₃₆BNO₂ = 609.58) | Sub7-34 | m/z = 458.21(C₃₁H₂₇BO₃ = 458.36) |
| Sub7-35 | m/z = 458.21(C₃₁H₂₇BO₃ = 458.36) | | |

### Synthesis Example of Final Compound

### 1. Synthesis Example of 6-7

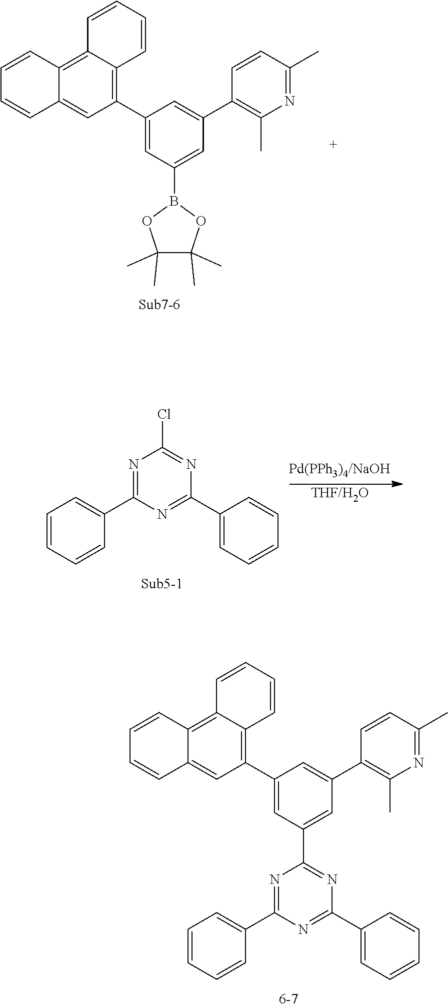

After dissolving Sub7-6 (10.0 g, 20.6 mmol) in THF (Tetrahydrofuran) (103 mL), Sub5-1 (5.5 g, 20.6 mmol), NaOH (2.5 g, 61.8 mmol), Pd(PPh₃)₄ (1.43 g, 1.24 mmol) and water (52 mL) are added thereto and the reaction is carried out at 80° C. When the reaction is completed, the reaction product is extracted with CH₂Cl₂ and water, and then the organic layer is dried with MgSO₄ and concentrated. Then, the concentrate is separated through a silica gel column and recrystallized to obtain 9.4 g (yield: 77%) of the product.

### 2. Synthesis Example of 6-9

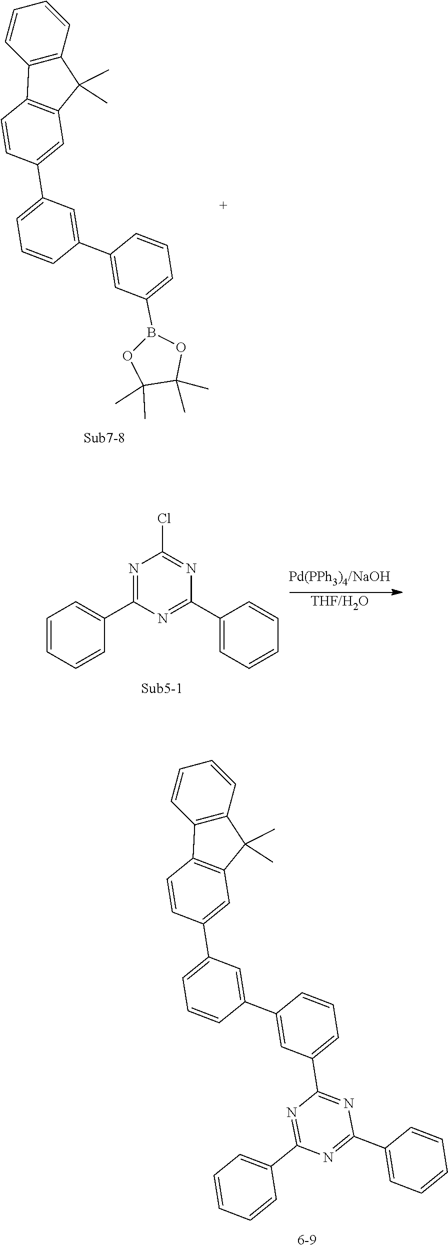

After dissolving Sub7-8 (10.0 g, 21.2 mmol) in THF (106 mL), Sub5-1 (5.7 g, 21.2 mmol), NaOH (2.5 g, 63.5 mmol), Pd(PPh₃)₄ (1.47 g, 1.27 mmol) and water (53 mL) are added thereto, and the synthesis is carried out in the same manner as the synthesis of 6-7 and then purified to obtain 9.5 g (yield: 78%) of product.

### 3. Synthesis Example of 6-35

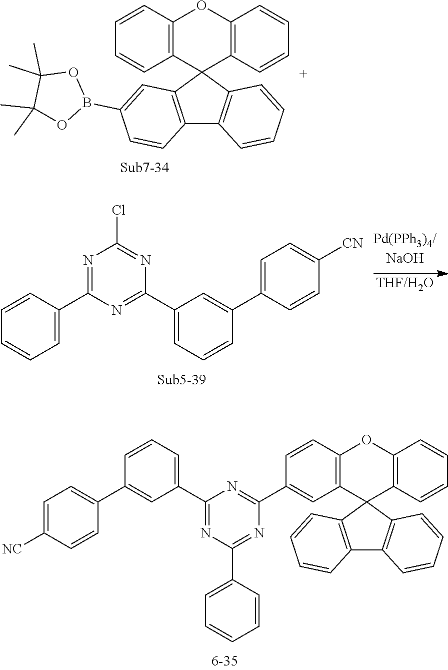 [SMILES: CC1(C)OB(c2ccc3c(c2)C2(c4ccccc4Oc4ccccc42)c2ccccc2-3)OC1(C)C ; N#Cc1ccc(-c2cccc(-c3nc(Cl)nc(-c4ccccc4)n3)c2)cc1 ; "THF/H2O" ; N#Cc1ccc(-c2cccc(-c3nc(-c4ccccc4)nc(-c4ccc5c(c4)C4(c6ccccc6O5)c5ccccc5-c5ccccc54)n3)c2)cc1]

After dissolving Sub7-34 (10.0 g, 21.8 mmol) in THF (110 mL), Sub5-39 (8.0 g, 21.8 mmol), NaOH (2.6 g, 65.5 mmol), Pd(PPh₃)₄ (1.15 g, 1.31 mmol) and water (55 mL) are added thereto, and the synthesis is carried out in the same manner as the synthesis of 6-7 and then purified to obtain 10.4 g (yield: 72%) of product.

The FD-MS values of the compounds 6-1 to 6-36 of the present invention prepared according to the above synthesis examples are shown in Table 12 below.

TABLE 12

| Compound | FD-MS | Compound | FD-MS |
|---|---|---|---|
| 6-1 | m/z = 537.22(C₃₉H₂₇N₃ = 537.67) | 6-2 | m/z = 511.2(C₃₇H₂₅N₃ = 511,63) |
| 6-3 | m/z = 587.24(C₄₃H₂₉N₃ = 587.73) | 6-4 | m/z = 612.23(C₄₄H₂₈N₄ = 612.74) |
| 6-5 | m/z = 613.25(C₄₅H₃₁N₃ = 613.76) | 6-6 | m/z = 587.24(C₄₃H₂₉N₃ = 587.73) |
| 6-7 | m/z = 590.25(C₄₂H₃₀N₄ = 590.73) | 6-8 | m/z = 588.23(C₄₂H₂₈N₄ = 588.71) |
| 6-9 | m/z = 577.25(C₄₂H₃₁N₃ = 577.73) | 6-10 | m/z = 623.24(C₄₆H₂₉N₃ = 623.76) |
| 6-11 | m/z = 577.25(C₄₂H₃₁N₃ = 577.73) | 6-12 | m/z = 625.25(C₄₆H₃₁N₃ = 625.78) |
| 6-13 | m/z = 601.22(C₄₃H₂₇N₃O = 601.71) | 6-14 | m/z = 627.23(C₄₅H₂₉N₃O = 627.75) |
| 6-15 | m/z = 591.18(C₄₁H₂₅N₃S = 591.73) | 6-16 | m/z = 667.21(C₄₇H₂₉N₃S = 667.83) |
| 6-17 | m/z = 626.25(C₄₅H₃₀N₄ = 626.76) | 6-18 | m/z = 626.25(C₄₅H₃₀N₄ = 626.76) |
| 6-19 | m/z = 702.28(C₅₁H₃₄N₄ = 702.86) | 6-20 | m/z = 702.28(C₅₁H₃₄N₄ = 702.86) |
| 6-21 | m/z = 681.29(C₄₈H₃₅N₅ = 681.84) | 6-22 | m/z = 641.26(C₄₅H₃₁N₅ = 641.78) |
| 6-23 | m/z = 619.3(C₄₅H₃₇N₃ = 619.81) | 6-24 | m/z = 589.25(C₄₃H₃₁N₃ = 589.74) |
| 6-25 | m/z = 541.18(C₃₇H₂₃N₃O₂ = 541.61) | 6-26 | m/z = 507.14(C₃₃H₂₁N₃OS = 507.61) |
| 6-27 | m/z = 616.23(C₄₃H₂₈N₄O = 616.72) | 6-28 | m/z = 658.22(C₄₅H₃₀N₄S = 658.82) |
| 6-29 | m/z = 642.28(C₄₆H₃₄N₄ = 642.81) | 6-30 | m/z = 592.26(C₄₂H₃₂N₄ = 592.75) |
| 6-31 | m/z = 533.23(C₃₄H₂₉F₂N₃O = 533.62) | 6-32 | m/z = 608.2(C₄₁H₂₈N₄S = 608.76) |
| 6-33 | m/z = 764.29(C₅₆H₃₆N₄ = 764.93) | 6-34 | m/z = 714.28(C₅₂H₃₄N₄ = 714.87) |
| 6-35 | m/z = 664.23(C₄₇H₂₈N₄O = 664.77) | 6-36 | m/z = 689.25(C₅₀H₃₁N₃O = 689.82) |

### Fabrication and Evaluation of Organic Electric Element

### [Test Example 1] Red Organic Electroluminescent Element

After vacuum-depositing 4,4′,4″-tris[2-naphthyl(phenyl)amino] triphenylamine (hereinafter abbreviated as “2-TNATA”) on an ITO layer (anode) formed on a glass substrate to form a hole injection layer of 70 nm thickness, a hole transport layer of 70 nm thickness was formed by vacuum-depositing compound A-1 on the hole injection layer.

Subsequently, a first light-emitting auxiliary layer (P1) of 70 nm thickness was formed by vacuum-depositing the compound 2-22 of the present invention on the hole transport layer and a second light-emitting auxiliary layer (P2) of 5 nm thickness was formed by vacuum-depositing the compound 1-13 of the present invention on the first light-emitting auxiliary layer.

Next, a mixed host and dopant were vacuum deposited at a weight ratio of 95:5 to form an light-emitting layer of 40 nm thickness, wherein a mixture of N-7 being a first host (H1) and P-10 being a second host (H2) at a weight ratio of 5:5 was used as the mixed host and bis-(1-phenylisoquinolyl) iridium (III) acetylacetonate ((hereinafter abbreviated as “(piq)₂Ir(acac)”) was used the dopant.

Next, C-1 was vacuum deposited to a thickness of 30 nm on the light-emitting layer to form an electron transport layer (ETL).

Thereafter, LiF was deposited to form an electron injection layer of 0.2 nm thickness, and then Al was deposited to form a cathode of 150 nm thickness.

### [Test Example 2] to [Test Example 40]

The organic electroluminescent elements were fabricated in the same manner as described in Test Example 1 except that the compounds listed in Table 13 below were used as material of a hole transport layer, a first light-emitting auxiliary layer, a second light-emitting auxiliary layer, an electron transport layer, and host material, respectively.

### [Comparative Example 1] to [Comparative Example 3]

The organic electroluminescent elements were fabricated in the same manner as described in Test Example 1 using the compounds listed in Table 13 below as material of a hole transport layer, an electron transport layer and host material. It differs from Example 1 in that a light-emitting auxiliary layer was not formed and a single material was used as a host.

### Comparative Example 4

The organic electroluminescent element was fabricated in the same manner as described in Test Example 1 using the compounds listed in Table 13 below as material of a hole transport layer, an electron transport layer and host material. It differs from Example 1 in that a light-emitting auxiliary layer was not formed.

### Comparative Example 5

The organic electroluminescent element was fabricated in the same manner as described in Test Example 1 using the compounds listed in Table 13 below as material of a hole transport layer, a light-emitting auxiliary layer, an electron transport layer and host material. It differs from Example 1 in that the light-emitting auxiliary layer was formed as a single layer of a single material and a single material was used as the host.

The structures of Compound A-1, Compound B-1, and Compound C-1 shown in Table 13 below are as follows.

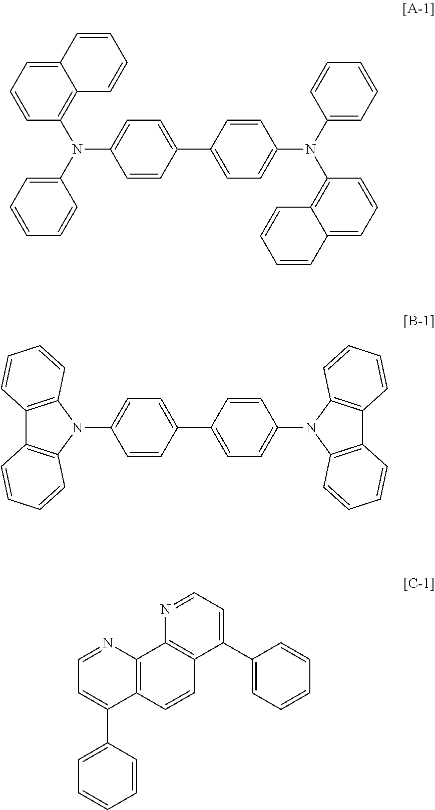 [SMILES: c1ccc(N(c2ccc(-c3ccc(N(c4ccccc4)c4cccc5ccccc45)cc3)cc2)c2cccc3ccccc23)cc1 ; c1ccc2c(c1)c1ccccc1n2-c1ccc(-c2ccc(-n3c4ccccc4c4ccccc43)cc2)cc1 ; c1ccc(-c2ccnc3c2ccc2c(-c4ccccc4)ccnc23)cc1]

Electroluminescence (EL) characteristics were measured with PR-650 (Photo research) by applying a forward bias DC voltage to the organic electroluminescent elements prepared in Test Examples and Comparative Examples. T95 life time was measured using a life time measuring apparatus manufactured by mc science Inc. at reference brightness of 2500 cd/m². The measurement results are shown in Tables 13 below.

TABLE 13

| | | | | | | | Voltage | Efficiency | Lifetime |
|---|---|---|---|---|---|---|---|---|---|
| | HTL | P1 | P2 | H1 | H2 | ETL | (V) | (cd/A) | T(95) |
| comp. Ex.(1) | A-1 | — | | B-1 | | C-1 | 6.5 | 8.5 | 65.4 |
| comp. Ex.(2) | A-1 | — | | N-7 | | C-1 | 5.8 | 13.2 | 72.8 |
| comp. Ex.(3) | A-1 | — | | P-10 | | C-1 | 5.5 | 15.6 | 85.3 |
| comp. Ex.(4) | A-1 | — | | N-7 | P-10 | C-1 | 5.1 | 20.3 | 123.2 |
| comp. Ex.(5) | A-1 | 2-22 | | B-1 | | C-1 | 5.2 | 18.9 | 102.3 |
| Test Ex.(1) | A-1 | 2-22 | 1-13 | N-7 | P-10 | C-1 | 4.6 | 31.8 | 170.1 |
| Test Ex.(2) | A-1 | 2-22 | 1-13 | N-7 | P-20 | C-1 | 4.5 | 34.6 | 175.3 |
| Test Ex.(3) | A-1 | 2-22 | 1-13 | N-7 | P-61 | C-1 | 4.8 | 30.7 | 165.8 |
| Test Ex.(4) | A-1 | 2-22 | 1-13 | N-38 | P-10 | C-1 | 4.5 | 33.1 | 174.9 |
| Test Ex.(5) | A-1 | 2-22 | 1-13 | N-38 | P-20 | C-1 | 4.4 | 35.7 | 179.5 |
| Test Ex.(6) | A-1 | 2-22 | 1-13 | N-38 | P-61 | C-1 | 4.7 | 32.1 | 170.0 |
| Test Ex.(7) | A-1 | 2-22 | 1-13 | N-65 | P-10 | C-1 | 4.8 | 28.5 | 165.2 |
| Test Ex.(8) | A-1 | 2-22 | 1-13 | N-65 | P-20 | C-1 | 4.7 | 29.5 | 170.4 |
| Test Ex.(9) | A-1 | 2-22 | 1-13 | N-65 | P-61 | C-1 | 4.9 | 26.9 | 159.6 |
| Test Ex.(10) | A-1 | 2-22 | | N-7 | P-10 | C-1 | 5.0 | 30.6 | 154.3 |
| Test Ex.(11) | A-1 | 2-22 | 1-7 | N-7 | P-10 | C-1 | 4.4 | 32.5 | 175.8 |
| Test Ex.(12) | A-1 | 2-22 | 2-15 | N-7 | P-10 | C-1 | 4.5 | 32.9 | 167.3 |
| Test Ex.(13) | A-1 | 1-28 | 1-7 | N-7 | P-10 | C-1 | 4.5 | 32.0 | 177.7 |
| Test Ex.(14) | A-1 | 1-28 | 1-13 | N-7 | P-10 | C-1 | 4.6 | 31.3 | 172.4 |
| Test Ex.(15) | A-1 | 1-28 | 2-15 | N-7 | P-10 | C-1 | 4.7 | 32.6 | 168.2 |
| Test Ex.(16) | A-1 | 1-90 | 1-7 | N-7 | P-10 | C-1 | 4.4 | 33.5 | 165.7 |
| Test Ex.(17) | A-1 | 1-90 | 1-13 | N-7 | P-10 | C-1 | 4.6 | 30.1 | 160.1 |
| Test Ex.(18) | A-1 | 1-90 | 2-15 | N-7 | P-10 | C-1 | 4.5 | 34.7 | 157.0 |
| Test Ex.(19) | A-1 | 1-28 | 2-15 | N-7 | P-20 | C-1 | 4.6 | 34.9 | 172.2 |
| Test Ex.(20) | A-1 | 1-90 | 1-7 | N-7 | P-20 | C-1 | 4.4 | 35.9 | 169.7 |
| Test Ex.(21) | A-1 | 1-28 | 2-15 | N-38 | P-10 | C-1 | 4.6 | 33.7 | 171.8 |
| Test Ex.(22) | A-1 | 1-90 | 1-7 | N-38 | P-10 | C-1 | 4.4 | 34.5 | 170.3 |
| Test Ex.(23) | A-1 | 1-28 | 2-15 | N-38 | P-20 | C-1 | 4.5 | 36.3 | 177.4 |
| Test Ex.(24) | A-1 | 1-90 | 1-7 | N-38 | P-20 | C-1 | 4.3 | 37.5 | 174.9 |
| Test Ex.(25) | 1-49 | 2-22 | 1-13 | N-7 | P-10 | C-1 | 4.3 | 35.1 | 184.6 |
| Test Ex.(26) | 1-104 | 2-22 | 1-13 | N-7 | P-10 | C-1 | 4.4 | 33.9 | 179.3 |
| Test Ex.(27) | A-1 | 2-22 | 1-13 | N-7 | P-10 | 6-7 | 4.5 | 32.9 | 172.4 |
| Test Ex.(28) | A-1 | 2-22 | 1-13 | N-7 | P-10 | 6-35 | 4.4 | 34.1 | 174.5 |
| Test Ex.(29) | 1-49 | 2-22 | 1-13 | N-7 | P-10 | 6-7 | 4.1 | 37.1 | 187.7 |
| Test Ex.(30) | 1-49 | 2-22 | 1-13 | N-7 | P-10 | 6-35 | 4.0 | 38.5 | 189.4 |
| Test Ex.(31) | 1-104 | 2-22 | 1-13 | N-7 | P-10 | 6-7 | 4.2 | 35.8 | 181.0 |
| Test Ex.(32) | 1-104 | 2-22 | 1-13 | N-7 | P-10 | 6-35 | 4.1 | 36.9 | 184.3 |
| Test Ex.(33) | 1-49 | 1-28 | 2-15 | N-7 | P-10 | 6-35 | 4.1 | 39.0 | 187.8 |
| Test Ex.(34) | 1-49 | 1-90 | 1-7 | N-7 | P-10 | 6-35 | 3.8 | 40.0 | 185.3 |
| Test Ex.(35) | 1-49 | 2-22 | 1-13 | N-7 | P-20 | 6-35 | 3.8 | 40.9 | 196.3 |
| Test Ex.(36) | 1-49 | 1-28 | 2-15 | N-7 | P-20 | 6-35 | 4.0 | 41.4 | 193.4 |
| Test Ex.(37) | 1-49 | 1-90 | 1-7 | N-7 | P-20 | 6-35 | 3.8 | 42.6 | 191.4 |
| Test Ex.(38) | 1-49 | 2-22 | 1-13 | N-38 | P-20 | 6-35 | 3.8 | 42.5 | 201.5 |
| Test Ex.(39) | 1-49 | 1-28 | 2-15 | N-38 | P-20 | 6-35 | 3.9 | 42.8 | 196.8 |
| Test Ex.(40) | 1-49 | 1-90 | 1-7 | N-38 | P-20 | 6-35 | 3.8 | 44.9 | 196.2 |

Referring to Table 13, it can be seen that when the organic material layer is configured as in the present invention, the driving voltage of the organic electric element is lowered and the efficiency and lifespan are significantly improved compared to Comparative Examples 1 to 5.

Looking at Comparative Examples 1 to 3, it can be seen that even when the hole transport layer and the electron transport layer are each formed of the same material without forming a light emitting auxiliary layer, the characteristics of the element vary depending on the type of host. That is, the element characteristics of Comparative Example 2 using compound N-7 were superior to those of Comparative Example 1 using compound B-1 as the host, and the element characteristics of Comparative Example 3 using compound P-10 as the host were better than those of Comparative Example 2. This shows that the characteristics of the element may vary depending on the host.

In addition, looking at Comparative Examples 1 to 4, it can be seen that in the case where the light-emitting auxiliary layer is not formed, the element characteristics of Comparative Example 4 using a mixed host are superior to Comparative Examples 1 to 3 using a single host.

In addition, looking at Comparative Example 1 and Comparative Example 5, it can be seen that the element characteristics of Comparative Example 5 in which the light-emitting auxiliary layer was formed as a single layer were better than in Comparative Example 1 in which the light-emitting auxiliary layer was not formed.

Therefore, in order to improve the characteristics of the element, the present invention forms a light-emitting auxiliary layer and uses a host mixed with two types of materials. It can be confirmed through the examples in Table 13 above that the characteristics of the element of the present invention are significantly improved compared to the comparative examples. In particular, looking at Comparative Example 4 and Test Example 10 of the present invention, it can be seen that the element characteristics of Example 10 of the present invention in which the light-emitting auxiliary layer was formed were significantly improved compared to Comparative Example 4 although the materials of the hole transport layer, the electron transport layer and host are the same and in Comparative Example 4 and Test Example 1.

When each layer of the organic material layer is composed of a combination of specific compounds as in the present invention, the energy level (HOMO, LUMO, T1 level) of the compound in each layer and the physical properties of the compound are appropriate value to improve the charge balance in the light emitting layer. As a result, light is emitted better inside the light-emitting layer rather than at the light-emitting layer interface, and deterioration at the light-emitting layer interface is also reduced, thereby improving driving voltage, efficiency, and lifespan.

Although the exemplary embodiments of the present invention have been described for illustrative purposes, those skilled in the art to which the present invention pertains will be capable of various modifications without departing from the essential characteristics of the present invention.

1. An organic electric element comprising a first electrode, a second electrode, and an organic material layer between the first electrode and the second electrode,
wherein the organic material layer comprises a light-emitting layer, a hole transport layer between the first electrode and the light-emitting layer, and a light-emitting auxiliary layer between the hole transport layer and the light-emitting layer,
wherein the light-emitting auxiliary layer comprises a compound represented by Formula 1, the light-emitting layer comprises a compound represented by Formula 4, and the hole transport layer comprises a compound represented by Formula 5: 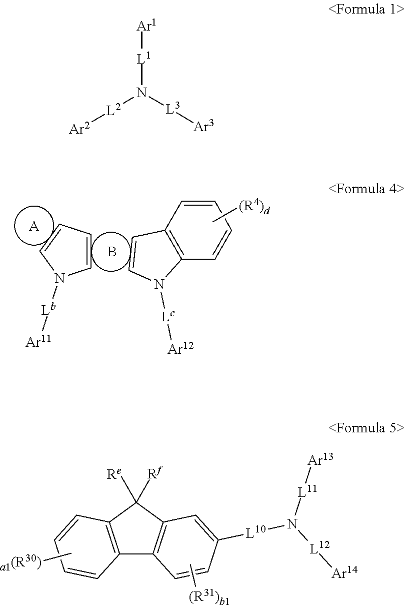
wherein:
Ar¹ to Ar³ are each independently a C₆-C₁₈ aryl group or a fluorenyl group, wherein at least one of Ar¹ to Ar³ is a fluorenyl group,
Ar¹¹ and Ar¹² are each independently a C₆-C₁₈ aryl group or a C₂-C₁₆ heterocyclic group containing at least one heteroatom of O and S,
Ar¹³ and Ar¹⁴ are each independently a C₆-C₁₈ aryl group or a fluorenyl group,
L¹ to L³, L¹⁰ to L¹², L^{b} and L^{c} are each independently a single bond or a C₆-C₁₂ arylene group,
A ring and B ring are each independently a C₆-C₁₀ aryl ring, and at least one of A ring and B ring is a C₁₀ aryl ring, and A ring and B ring may each be substituted with one or more R⁴ that are the same or different from each other,
R^{e} and R^{f} are each independently a C₁-C₁₀ alkyl group or a C₆-C₁₈ aryl group, and R^{e} and R^{f} may be bonded to each other to form a ring,
R⁴, R₄, R³⁰, R³¹ are each independently hydrogen or deuterium,
d and a1 are each an integer of 0 to 4, b1 is an integer of 0 to 3, and
the aryl group, the arylene group, the fluorenyl group, the heterocyclic group, and the ring formed by R^{e} and R^{f} may be each optionally substituted with one or more substituents selected from the group consisting of deuterium, a C₁-C₁₀ alkyl group, a C₆-C₁₈ aryl group, a fluorenyl group, a C₂-C₁₆ heterocyclic group containing at least one heteroatom of O, N and S.

2. The organic electric element of claim 1, wherein Formula 1 is represented by Formula 1-2: 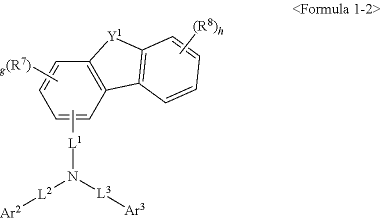
wherein:
Ar², Ar³, L¹ to L³ are the same as defined in Formula 1,
Y¹ is C(R₅)(R₆),
R₅ and R₆ are each independently a C₁-C₁₀ alkyl group,
R⁷ and R⁸ are each independently hydrogen or deuterium, and
g is an integer of 0 to 3, and h is an integer of 0 to 4.

3. The organic electric element of claim 1, wherein L¹ is a single bond.

4. The organic electric element of claim 1, wherein:
(i) L² is a single bond, and Ar² is a 9,9-diphenyl-9H-fluorenyl group which may be substituted with a C₁-C₁₀ alkyl group, or
(ii) L² is a phenylene group which may be substituted with a C₁-C₁₀ alkyl group, and Ar² is a fluorenyl group which may be substituted with a C₆ aryl group.

5. The organic electric element of claim 4, wherein:
(i) L³ is a phenylene group and Ar³ is a phenyl group, or
(ii) L³ a single bond and Ar³ is a biphenyl group.

6. The organic electric element of claim 1, wherein:
L¹ is a single bond and Ar¹ is a 9,9-dimethyl-9H-fluorenyl group, (i) L² is a single bond, and Ar² is a 9,9-diphenyl-9H-fluorenyl group which may be substituted with a C₁-C₁₀ alkyl group, or (ii) L² is a phenylene group which may be substituted with a C₁-C₁₀ alkyl group, and Ar² is a fluorenyl group which may substituted with a phenyl group, and
L³ is a single bond or a phenylene group, and Ar³ is a phenyl group or a biphenyl group.

7. The organic electric element of claim 6, wherein:

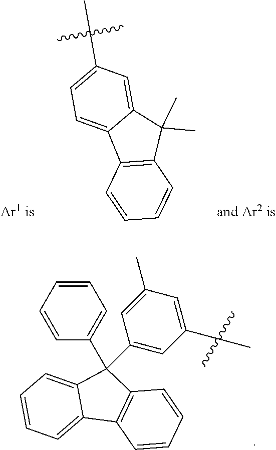

8. The organic electric element of claim 1, wherein Formula 4 is represented by Formula 4-1: 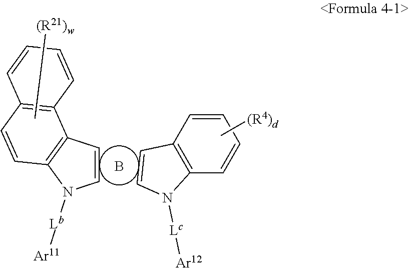
wherein:
B ring, L^{b}, L^{c}, Ar¹¹, Ar¹², R⁴, and d are the same as defined in Formula 4, R²¹ is the same as R₄ in Formula 4, w is an integer of 0 to 6.

9. The organic electric element of claim 8, wherein B ring is a C₆ aryl ring.

10. The organic electric element of claim 9, wherein Formula 4-1 is represented by the following Formula: 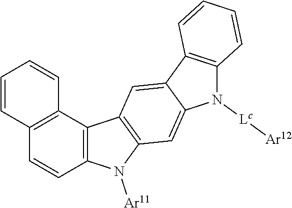
wherein:
Ar¹¹ is a C₆-C₁₂ aryl group,
L^{c} is a C₆-C₁₂ arylene group, and
Ar¹² is a C₁₂-C₁₆ heterocyclic group comprising O (oxygen).

11. The organic electric element of claim 10, wherein Ar¹¹ is a phenyl group, L^{c} is a phenylene group and Ar¹² is a dibenzofuryl group.

12. The organic electric element of claim 1, wherein L¹⁰ is a single bond.

13. The organic electric element of claim 12, wherein:
Ar¹³ is a 9,9-diphenyl-9H-fluorenyl group, a 9,9′-spirobifluorenyl group, or a C₆-C₁₂ aryl group, and
Ar¹⁴ is a C₆-C₁₂ aryl group.

14. The organic electric element of claim 13, wherein:
R^{e} and R^{f} are a methyl group,
L¹¹ is a single bond, Ar¹³ is a 9,9-diphenyl-9H-fluorenyl group,
L¹² is a single bond or a phenylene group, and Ar¹⁴ is a phenyl group or a biphenyl group.

15. The organic electric element of claim 14, wherein:
Ar¹³ is

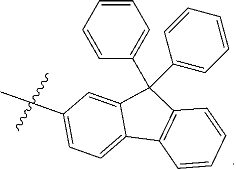 [SMILES: *c1ccc2c(c1)C(c1ccccc1)(c1ccccc1)c1ccccc1-2]

16. The organic electric element of claim 13, wherein:
R^{e} and R^{f} are bonded with each other to form a ring,
L¹¹ and L¹² are independently a single bond or a phenylene group, and
Ar¹³ or Ar¹⁴ are independently a phenyl group or a biphenyl group.

17. The organic electric element of claim 16, wherein R^{e} and R^{f} are bonded to each other to form a spiro compound.

18. The organic electric element of claim 17, wherein R^{e} and R^{f} are bonded to each other to form a fluorene ring, and the fluorene ring forms the spiro compound with a fluorene moiety bonded to R^{e} and R^{f}.

19. The organic electric element of claim 1, wherein the organic material layer comprises an electron transport layer formed between a second electrode and a light-emitting layer, and the electron transport layer comprises a compound represented by Formula 6: 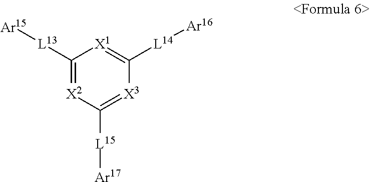
wherein:
X¹ to X³ are each N,
L¹³ to L¹⁵ are each independently a single bond or a C₆-C₂₄ arylene group,
Ar¹⁵ to Ar¹⁷ are each independently selected from the group consisting of a C₆-C₁₈ aryl group, or a C₂-C₂₅ heterocyclic group containing at least one heteroatom of O, N and S, and at least one of Ar¹⁵ to Ar¹⁷ comprises the heterocyclic group, and
the aryl group and the heterocyclic group may be each optionally substituted with one or more substituents selected from the group consisting of deuterium, a cyano group, a C₆-C₁₈ aryl group, a C₂-C₁₃ heterocyclic group containing at least one heteroatom of O, N and S.

20. The organic electric element of claim 19, wherein Formula 6 is one of Formula 6-1 to Formula 6-3: 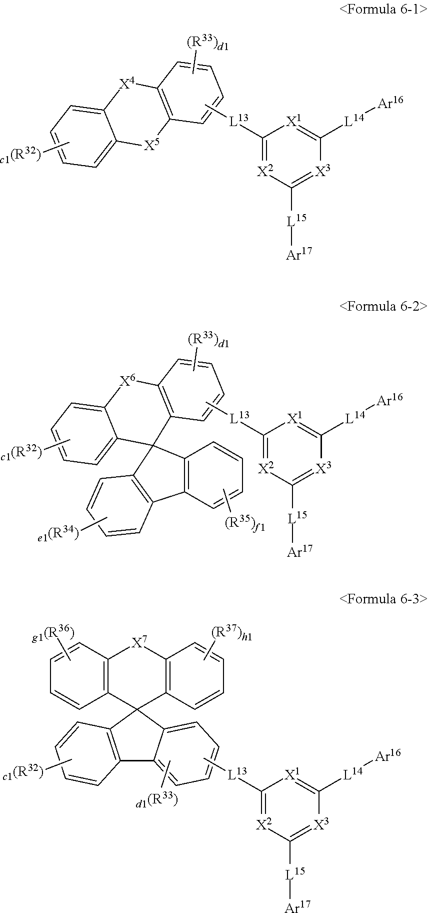
wherein:
X¹ to X³, L¹³ to L¹⁵, Ar¹⁶, Ar¹⁷ are the same as defined in Formula 6,
X⁴ is O or S,
X⁵ is O, S or C(R₂₁)(R₂₂),
X⁶ and X⁷ are O or S,
R³² to R³⁷ are hydrogen or deuterium,
R₂₁ and R₂₂ are a C₁-C₁₀ alkyl group, or R₂₁ and R₂₂ are bonded to each other to form a ring, and
c1, e1, f1, g1 and h1 are each an integer of 0 to 4, d1 is an integer of 0 to 3.

21. The organic electric element of claim 20, wherein:
Formula 6 is Formula 6-2,
X⁶ is O,
L¹³ and L¹⁴ are each a sing bond,
Ar¹⁶ is a phenyl group,
L¹⁵ is a single bond or a C₆ arylene group, and
Ar¹⁷ is a phenyl group or a biphenyl group which may be substituted with a cyano group.

22. The organic electric element of claim 19, wherein:
L¹³ is a single bond,
Ar¹⁵ is a C₁₃ heterocyclic group containing N,
(i) L¹⁴ is a single bond, and Ar¹⁶ is a C₆ aryl group which may substituted with at least one of a C₅ or a C₁₃ heterocyclic group containing N, or (ii) L¹⁴ is a C₆ arylene group which may substituted with a C₅ or a C₁₃ heterocyclic group containing N, and Ar¹⁶ is a C₅ or a C₁₃ heterocyclic group containing N, and
L¹⁵ is a single bond, and Ar¹⁷ is a phenyl group.

23. The organic electric element of claim 19, wherein:
L¹³ is a C₆-C₂₂ arylene group, and Ar¹⁵ is a C₃ heterocyclic group containing N which may be substituted with one or more C₆ aryl groups, and
L¹⁴ and L¹⁵ are a single bond, and Ar¹⁶ and Ar¹⁷ are a phenyl group.

24. The organic electric element of claim 1, wherein the organic material layer comprises two or more stacks, each stack comprising a hole transport layer, a light-emitting layer, and an electron transport layer sequentially formed on the first electrode.

25. The organic electric element of claim 1, wherein the organic electric element is a red organic electroluminescent element.

26. An electronic device comprising a display device and a control unit for driving the display device, wherein the display device comprises the organic electric element of claim 1.

27. The electronic device of claim 26, wherein the electronic device is wired and/or wireless communication terminal.

28. The electronic device of claim 27, wherein the wired and/or wireless communication terminal is selected from the group consisting of a cellular phone, a navigation unit, a game player, various kinds of TVs, and various kinds of computers.
